(19) United States
(12) Patent Application Publication
(10) Pub. No.: US 2023/0217804 A1
(43) Pub. Date: Jul. 6, 2023

(54) LIGHT EMITTING ELEMENT

(71) Applicant: Samsung Display Co., Ltd., Yongin-si (KR)

(72) Inventors: TAEIL KIM, Hwaseong-si (KR); SUN YOUNG PAK, Suwon-si (KR); JUNHA PARK, Gwacheon-si (KR); JANG YEOL BAEK, Yongin-si (KR); Kyoung SUNWOO, Hwaseong-si (KR); MUN-KI SIM, Seoul (KR); CHANSEOK OH, Seoul (KR); MINJUNG JUNG, Hongcheon-gun (KR)

(21) Appl. No.: 17/887,238

(22) Filed: Aug. 12, 2022

(30) Foreign Application Priority Data
Oct. 20, 2021 (KR) 10-2021-0140541

(51) Int. Cl. H01L 51/00; C07F 5/02; C09K 11/06

(52) U.S. Cl. CPC H01L 51/008; C07F 5/027; C09K 11/06; H01L 51/5012

(57) ABSTRACT

A light emitting element that includes a first compound represented by a specific chemical formula in which an ortho-type or kind penta-phenyl group is bonded to a fused polycyclic compound including at least one boron atom and a heteroatom is provided. The light emitting element has a long-lifetime.

### CROSS-REFERENCE TO RELATED APPLICATION

This application claims priority to and the benefit of Korean Patent Application No. 10-2021-0140541, filed on Oct. 20, 2021, the entire content of which is hereby incorporated by reference.

### BACKGROUND

### 1. Field

Aspects of one or more embodiments of the present disclosure relate to a light emitting element, and for example, to a light emitting element including multiple (more than one) materials and a I fused polycyclic compound utilized as a light emitting material in an emission layer.

### 2. Description of the Related Art

Recently, the development of an organic electroluminescence display device as an image display device is being actively conducted. The organic electroluminescence display device is a display device of a self-luminescent type or kind in which holes and electrons injected from a first electrode and a second electrode recombine in an emission layer so that a light emitting material in the emission layer emits light to achieve display.

In the application of an organic electroluminescence device to a display device, the decrease of a driving voltage and the increase of emission efficiency and lifetime of the organic electroluminescence device are desired, and development on materials for an organic electroluminescence device, stably achieving the requirements is being consistently conducted.

For example, recently, in order to achieve an organic electroluminescence device with high efficiency, techniques on phosphorescence emission which uses energy in a triplet state or delayed fluorescence emission which uses the generating phenomenon of singlet excitons by the collision of triplet excitons (triplet-triplet annihilation, TTA) are being developed, and development on a material for thermally activated delayed fluorescence (TADF) utilizing delayed fluorescence phenomenon is being conducted.

### SUMMARY

An aspect of one or more aspects of the present disclosure is directed toward a light emitting element having an improved (increased) element lifetime.

An embodiment of the present disclosure provides a light emitting element including: a first electrode; a second electrode on the first electrode; and an emission layer between the first electrode and the second electrode, wherein the emission layer includes: a first compound represented by Formula 1; and at least one selected from among a second compound represented by Formula HT, a third compound represented by Formula ET, and a fourth compound represented by Formula D-1.

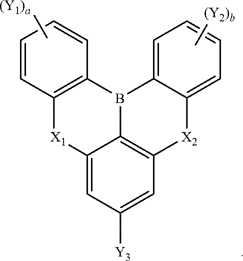

In Formula 1, X₁ and X₂ may each independently be CR₁R₂, NR₃, NR₄, O, S, or Se, in which at least one selected from among X₁ and X₂ is NR₄, Y₁ to Y₃ may each independently be a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, “a” and “b” may each independently be an integer of 0 to 4, R₁ to R₃ may each independently be a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring, and R₄ is represented by Formula 2 or Formula 3.

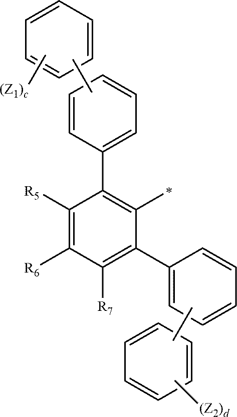

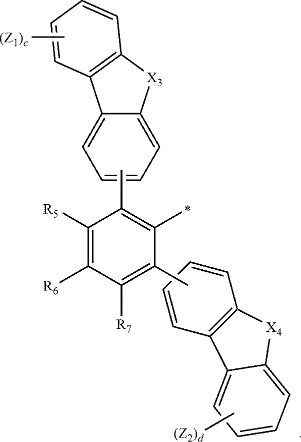

In Formula 2 and Formula 3, X₃ and X₄ may each independently be CR₈R₉, NR₁₀, O, S, or Se, Rs to R₁₀ may each independently be a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring, Z₁ and Z₂ may each independently be a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and “c” and “d” may each independently be an integer of 0 to 4.

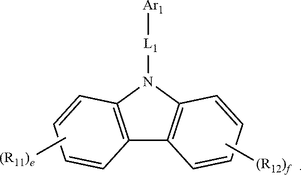

In Formula HT, L₁ is a direct linkage, a substituted or unsubstituted arylene group of 6 to 30 ring-forming carbon atoms, or a substituted or unsubstituted heteroarylene group of 2 to 30 ring-forming carbon atoms, Ar₁ is a substituted or unsubstituted aryl group of 6 to 30 ring-forming carbon atoms, or a substituted or unsubstituted heteroaryl group of 2 to 30 ring-forming carbon atoms, R₁₁ and R₁₂ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and “e” and “f” may each independently be an integer of 0 to 4.

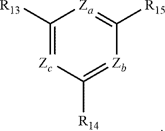

In Formula ET, at least one selected from among Zₐ to Z_{c} is N, and the remainder (the Zₐ to Z_{c} that are not N) are CR₁₆, and R₁₃ to R₁₆ may each independently be a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms.

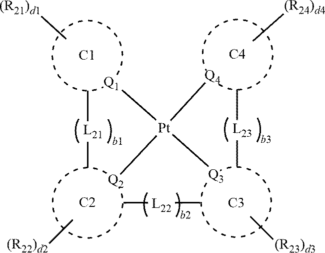

In Formula D-1, Q₁ to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₂₁ to L₂₃ may each independently be a direct linkage,

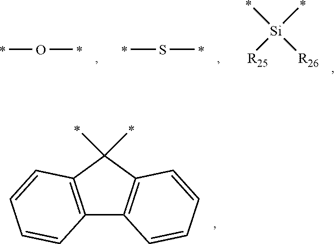

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b1 to b3 may each independently be 0 or 1, R₂₁ to R₂₆ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and d1 to d4 may each independently be an integer of 0 to 4.

In an embodiment, Formula 2 may be represented by Formula 2-1.

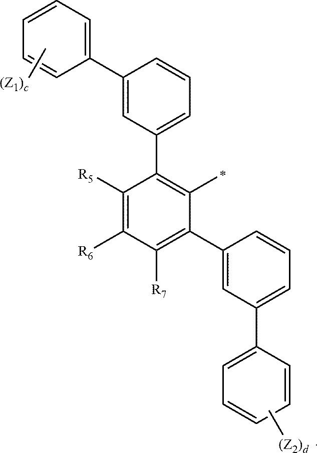

In Formula 2-1, R₅ to R₇, Z₁, Z₂, “c” and “d” may each independently be the same as defined in Formula 2.

In an embodiment, Formula 3 may be represented by a Formula selected from among Formula 3-1 to Formula 3-4.

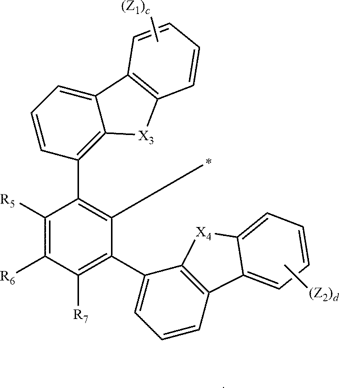

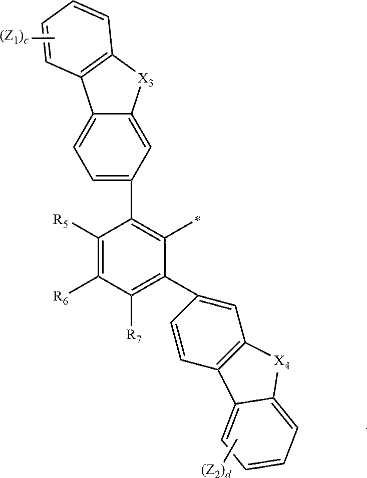

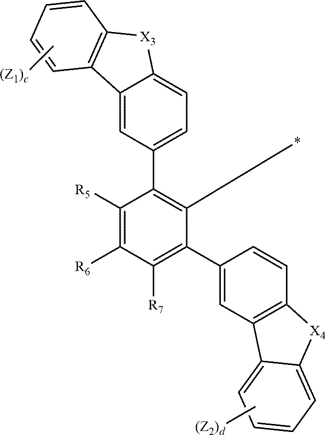

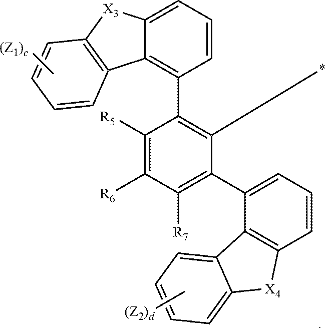

In Formula 3-1 to Formula 3-4, R₅ to R₇, X₃, X₄, Z₁, Z₂, “c” and “d” may each independently be the same as defined in Formula 3.

In an embodiment, the first compound may be represented by a Formula selected from among Formula 4-1 to Formula 4-3.

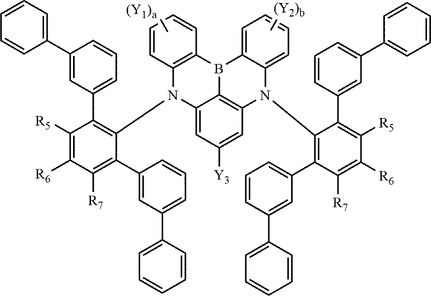

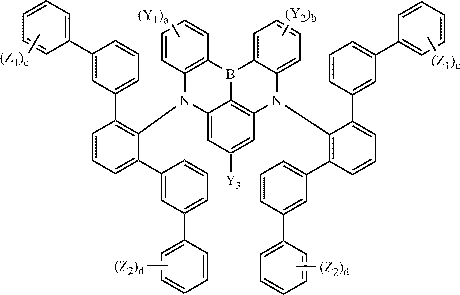

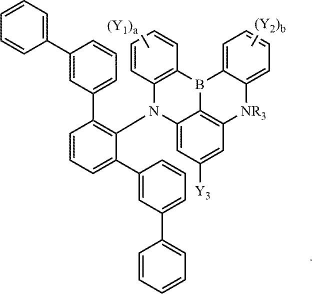

In Formula 4-1 to Formula 4-3, Y₁ to Y₃, R₃, R₅ to R₇, Z₁, Z₂, and “a” to “d” may each independently be the same as defined in Formula 1 and Formula 2.

In an embodiment, the first compound may be represented by a Formula selected from among Formula 5-1 to Formula 5-12.

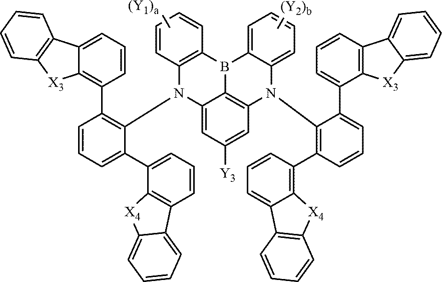

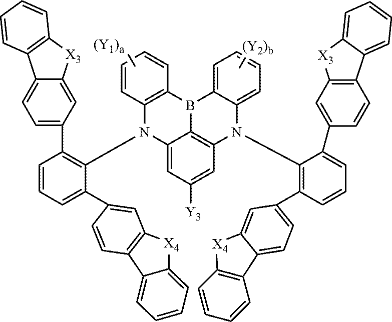

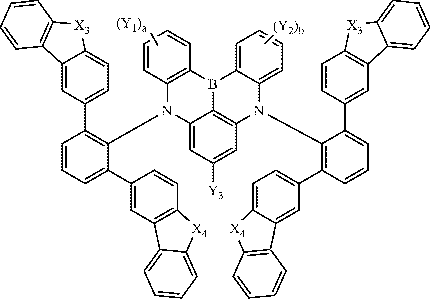

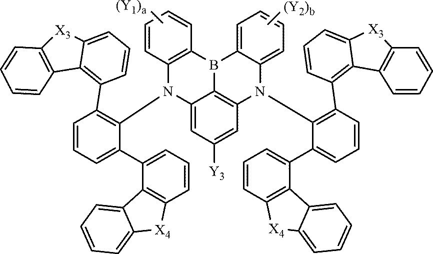

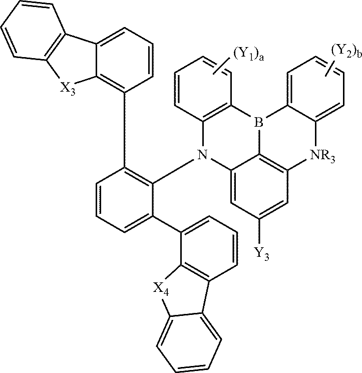

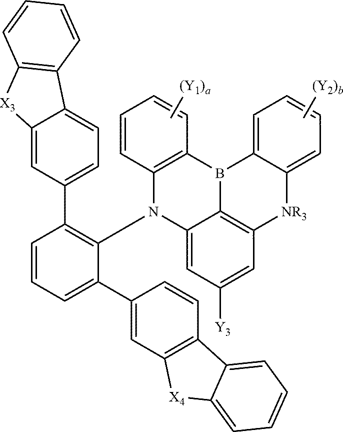

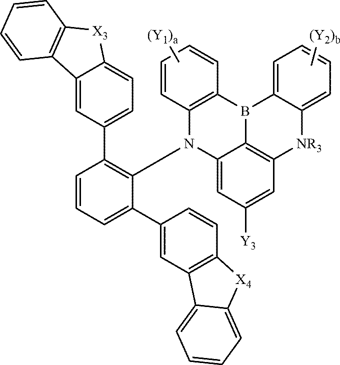

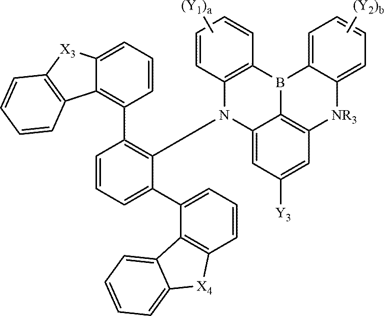

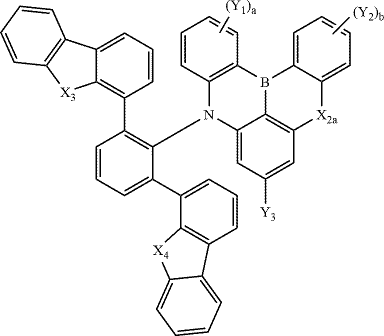

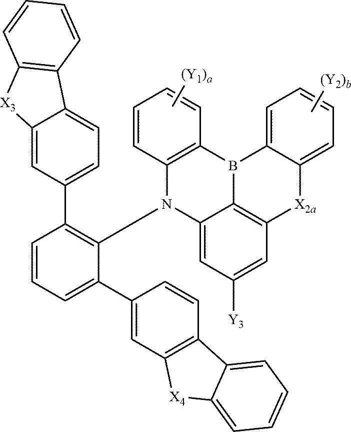

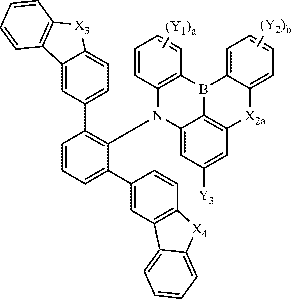

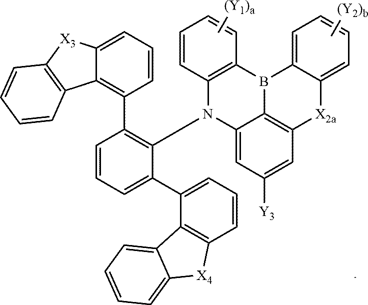

In Formula 5-1 to Formula 5-12, Y₁ to Y₃, R₃, “a”, “b”, X₃ and X₄ may each independently be the same as defined in Formula 1 and Formula 3, and X₂ₐ may be O, S or Se.

In an embodiment, the first compound may have a light emitting central wavelength in a wavelength region of about 440 nm to about 480 nm.

In an embodiment, the emission layer may emit delayed fluorescence.

In an embodiment, the emission layer may include the first compound, the second compound, and the third compound. In some embodiments, the emission layer may include the first compound, the second compound, the third compound, and the fourth compound.

In an embodiment, the second compound and the third compound may be included in the emission layer in a weight ratio of about 4:6 to about 7:3.

An embodiment of the present disclosure provides a light emitting element including: a first electrode; a hole transport region on the first electrode; an emission layer on the hole transport region; an electron transport region on the emission layer; and a second electrode on the electron transport region, wherein the emission layer includes a first compound represented by Formula 1, and the hole transport region includes a hole transport compound represented by Formula H-1.

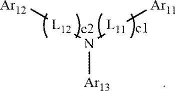

In Formula H-1, c1 and c2 may each independently be an integer of 0 to 10, L₁₁ and L₁₂ may each independently be a direct linkage, a substituted or unsubstituted arylene group of 6 to 30 ring-forming carbon atoms, or a substituted or unsubstituted heteroarylene group of 2 to 30 ring-forming carbon atoms, Ar₁₁ and Ar₁₂ may each independently be a substituted or unsubstituted aryl group of 6 to 30 ring-forming carbon atoms, or a substituted or unsubstituted heteroaryl group of 2 to 30 ring-forming carbon atoms, and Ar₁₃ is a substituted or unsubstituted aryl group of 6 to 30 ring-forming carbon atoms.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view showing a display apparatus according to an embodiment;

FIG. 2 is a cross-sectional view showing a part corresponding to line I-I′ in FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view showing a display apparatus according to an embodiment;

FIG. 8 is a cross-sectional view showing a display apparatus according to an embodiment;

FIG. 9 is a cross-sectional view showing a display apparatus according to an embodiment; and

FIG. 10 is a cross-sectional view showing a display apparatus according to an embodiment.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

In the description, it will be understood that when an element (or region, layer, part, etc.) is referred to as being “on”, “connected to” or “coupled to” another element, it can be directly on, connected or coupled to the other element or a third intervening elements may be present.

Like reference numerals refer to like elements throughout, and duplicative descriptions thereof may not be provided. In some embodiments, in the drawings, the thickness, the ratio, and the dimensions of constituent elements are exaggerated for effective explanation of technical contents. The term “and/or” includes one or more combinations which may be defined by relevant elements.

It will be understood that, although the terms first, second, etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise.

In some embodiments, the terms “below”, “beneath”, “on” and “above” are utilized for explaining the relation of elements shown in the drawings. The terms are relative concept and are explained based on the direction shown in the drawing.

In the description, it will be further understood that the terms “comprises,” “includes,” and/or “comprising,” “including,” when utilized in this disclosure, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

In the description, when a layer, a film, a region, a plate, etc. is referred to as being “on” or “above” another part, it can be “directly on” the other part, or intervening layers may also be present. In contrast, when a layer, a film, a region, a plate, etc. is referred to as being “under” or “below

” another part, it can be “directly under” the other part, or intervening layers may also be present. Also, when an element is referred to as being disposed “on” another element, it can be disposed under the other element.

In the description, the term “substituted or unsubstituted” corresponds to substituted or unsubstituted with at least one substituent selected from the group including (e.g., consisting of) a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may refer to forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some embodiments, the ring formed via the combination with an adjacent group may be combined with another ring to form a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some embodiments, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic type or kind. The carbon number of the alkyl group may be 1 to 60, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, a hydrocarbon ring group refers to an optional functional group or substituent derived from an aliphatic hydrocarbon ring or a fused ring of an aliphatic hydrocarbon ring group and an aromatic hydrocarbon ring group. The number of the ring-forming carbon of the hydrocarbon ring group may be 5 to 60, 5 to 30, or 6 to 30.

In the description, an aryl group refers to an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a heterocyclic group refers to an optional functional group or substituent derived from a ring including one or more selected from among B, O, N, P, Se, Si, and S as heteroatoms. The heterocyclic group includes an aliphatic heterocyclic group and/or an aromatic heterocyclic group. The aromatic heterocyclic group may be a heteroaryl group. The aliphatic heterocyclic group and the aromatic heterocyclic group may be a monocycle or a polycycle.

When the heterocyclic group includes two or more heteroatoms, two or more heteroatoms may be the same or different. The heterocyclic group may be a monocyclic heterocyclic group or a polycyclic heterocyclic group, and has the concept including (e.g., may include) a heteroaryl group. The carbon number for forming rings of the heterocyclic group may be 2 to 60, 2 to 30, 2 to 20, or 2 to 10.

In the disclosure, an aliphatic heterocyclic group may include one or more selected from among B, O, N, P, Se, Si, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the disclosure, a heteroaryl group may include one or more selected from among B, O, N, P, Se, Si, and S as heteroatoms. When the heteroaryl group includes two or more heteroatoms, and the two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the disclosure, the same explanation on the above-described aryl group may be applied to an arylene group except that the arylene group is a divalent group. The same explanation on the above-described heteroaryl group may be applied to a heteroarylene group except that the heteroarylene group is a divalent group.

In the disclosure, a fluorenyl group may be substituted, and two substituents may be combined with each other to form a spiro structure. Examples of a substituted fluorenyl group are as follows, but an embodiment of the present disclosure is not limited thereto.

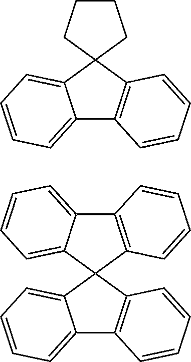

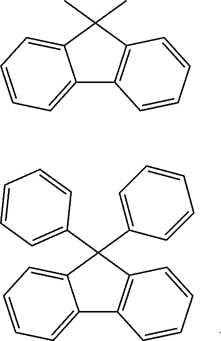

In the disclosure, a silyl group includes an alkyl silyl group and/or an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the disclosure, a thio group may include an alkyl thio group and/or an aryl thio group. The thio group may refer to the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the disclosure, an oxy group may refer to the above-defined alkyl group or aryl group which is combined with an oxygen atom. The oxy group may include an alkoxy group and/or an aryl oxy group. The alkoxy group may be a linear, branched or cyclic chain. The carbon number of the alkoxy group is not specifically limited but may be, for example, 1 to 60, 1 to 20 or 1 to 10. The number of ring-forming carbon atoms of the aryl oxy group is not specifically limited, but may be, for example, 6 to 60, 6 to 30, or 6 to 20. Examples of the oxy group may include methoxy, ethoxy, n-propoxy, isopropoxy, butoxy, pentyloxy, hexyloxy, octyloxy, nonyloxy, decyloxy, benzyloxy, etc. However, an embodiment of the present disclosure is not limited thereto.

In the disclosure, a boron group may refer to the above-defined alkyl group or aryl group, combined with a boron atom. The boron group includes an alkyl boron group and/or an aryl boron group. Examples of the boron group include a dimethylboron group, a diethylboron group, a t-butylmethylboron group, a diphenylboron group, a phenylboron group, etc., without limitation.

In the disclosure, the carbon number of an amine group is not specifically limited, and may be, for example, 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the disclosure, alkyl groups in an alkylthio group, alkylsulfoxy group, alkylaryl group, alkylamino group, alkylboron group, alkyl silyl group, and/or alkyl amine group may be the same as the examples of the above-described alkyl group.

In the disclosure, aryl groups in an aryloxy group, arylthio group, arylsulfoxy group, aryl amino group, arylboron group, and/or aryl silyl group may be the same as the examples of the above-described aryl group.

In the description, a direct linkage may refer to a single bond. In some embodiments, in the description,

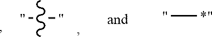

refer to positions to be connected.

Hereinafter, the light emitting element of an embodiment will be explained referring to the drawings.

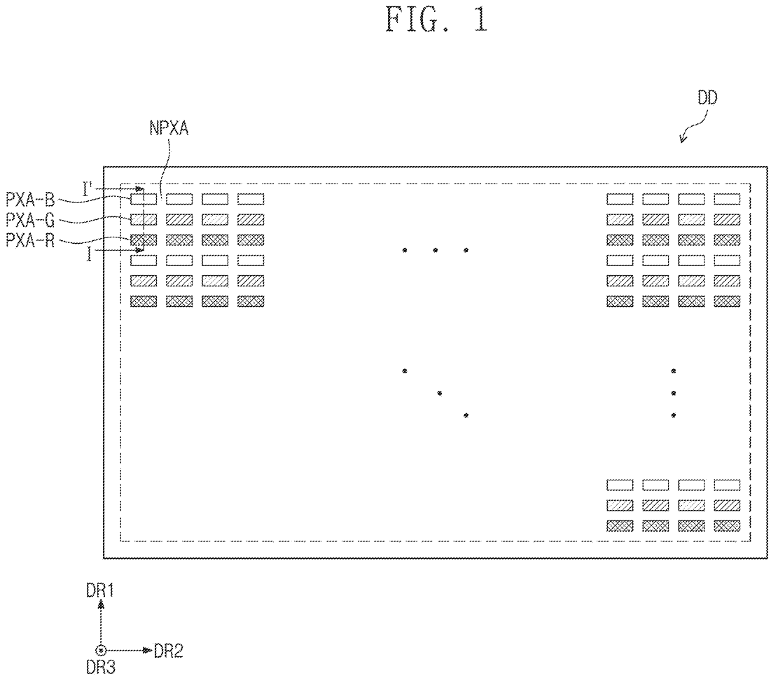

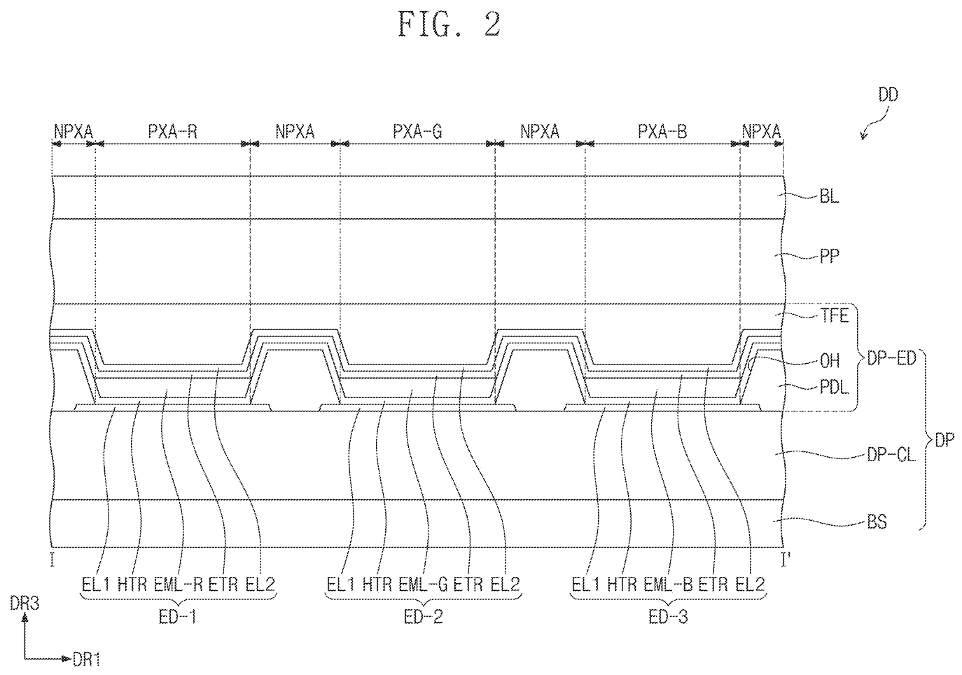

FIG. 1 is a plan view showing an embodiment of a display apparatus DD. FIG. 2 is a cross-sectional view of a display apparatus DD of an embodiment. FIG. 2 is a cross-sectional view showing a part corresponding to line I-I′ of FIG. 1.

The display apparatus DD may include a display panel DP and an optical layer PP disposed on the display panel DP. The display panel DP may include light emitting elements ED-1, ED-2 and ED-3. The display apparatus DD may include multiple light emitting elements ED-1, ED-2 and ED-3. The optical layer PP may be disposed on the display panel DP and control reflected light by external light at the display panel DP. The optical layer PP may include, for example, a polarization layer or a color filter layer. In some embodiments, different from the drawings, the optical layer PP may not be provided in the display apparatus DD of an embodiment.

On the optical layer PP, a base substrate BL may be disposed. The base substrate BL may be a member providing a base surface where the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer and/or a composite material layer. In some embodiments, different from the drawings, the base substrate BL may not be provided in an embodiment.

The display apparatus DD according to an embodiment may further include a plugging layer. The plugging layer may be between a display element layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display element layer DP-ED. The display element layer DP-ED may include a pixel definition layer PDL, light emitting elements ED-1, ED-2 and ED-3 in the pixel definition layer PDL, and an encapsulating layer TFE on the light emitting elements ED-1, ED-2 and ED-3.

The base layer BS may be a member providing a base surface where the display element layer DP-ED is disposed. The base layer BS may be a glass substrate, a metal substrate, a plastic substrate, etc. However, an embodiment of the present disclosure is not limited thereto, and the base layer BS may be an inorganic layer, an organic layer and/or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting elements ED-1, ED-2 and ED-3 of the display element layer DP-ED.

In FIG. 2, shown is an embodiment where the emission layers EML-R, EML-G and EML-B of light emitting elements ED-1, ED-2 and ED-3 are disposed in opening portions OH defined in a pixel definition layer PDL, and a hole transport region HTR, an electron transport region ETR and a second electrode EL2 are provided as common layers in all light emitting elements ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting elements ED-1, ED-2 and ED-3 may be patterned by an inkjet printing method and provided.

An encapsulating layer TFE may cover the light emitting elements ED-1, ED-2 and ED-3. The encapsulating layer TFE may encapsulate the display element layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and/or at least one encapsulating inorganic layer.

The encapsulating inorganic layer protects (reduces) the display element layer DP-ED from moisture/oxygen, and the encapsulating organic layer protects (reduces) the display element layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to a corresponding pixel. The pixel definition layer PDL may divide the light emitting elements ED-1, ED-2 and ED-3. The emission layers EML-R, EML-G and EML-B of the light emitting elements ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting elements ED-1, ED-2 and ED-3. In the display apparatus DD of an embodiment, shown in FIG. 1 and FIG. 2, three luminous areas PXA-R, PXA-G and PXA-B emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting elements ED-1, ED-2 and ED-3 may emit light having different wavelength regions. For example, in an embodiment, the display apparatus DD may include a first light emitting element ED-1 emitting red light, a second light emitting element ED-2 emitting green light, and a third light emitting element ED-3 emitting blue light. For example, the red luminous area PXA-R, the green luminous area PXA-G, and the blue luminous area PXA-B of the display apparatus DD may respectively correspond to the first light emitting element ED-1, the second light emitting element ED-2, and the third light emitting element ED-3.

However, an embodiment of the present disclosure is not limited thereto, and the first to third light emitting elements ED-1, ED-2 and ED-3 may emit light in substantially the same wavelength region, or at least one thereof may emit light in a different wavelength region. For example, all the first to third light emitting elements ED-1, ED-2 and ED-3 may emit blue light.

The luminous areas PXA-R, PXA-G and PXA-B in the display apparatus DD according to an embodiment may be arranged in a stripe shape. Referring to FIG. 1, multiple red luminous areas PXA-R, multiple green luminous areas PXA-G and multiple blue luminous areas PXA-B may be arranged along a second directional axis DR2. In some embodiments, the red luminous area PXA-R, the green luminous area PXA-G and the blue luminous area PXA-B may be arranged by turns along a first directional axis DR1. (DR3 is a third direction which is normal or perpendicular to the plane defined by the first direction DR1 and the second direction DR2).

In FIG. 1 and FIG. 2, the areas of the luminous areas PXA-R, PXA-G and PXA-B are shown similar, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas on a plane defined by the first directional axis DR1 and the second directional axis DR2.

In some embodiments, the arrangement type or kind of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required for the display apparatus DD. For example, the arrangement type or kind of the luminous areas PXA-R, PXA-G and PXA-B may be a PENTILE® arrangement type or kind, (for example, an RGBG matrix, an RGBG structure, or RGBG matrix structure) or a Diamond Pixel™ arrangement type or kind. PENTILE® is a duly registered trademark of Samsung Display Co., Ltd. Diamond Pixel™ is the atoms of Samsung’s OLED displays, consisting of red, blue, and green (RGB) screen dots in the shape of diamonds.

In some embodiments, the areas (i.e., sizes) of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

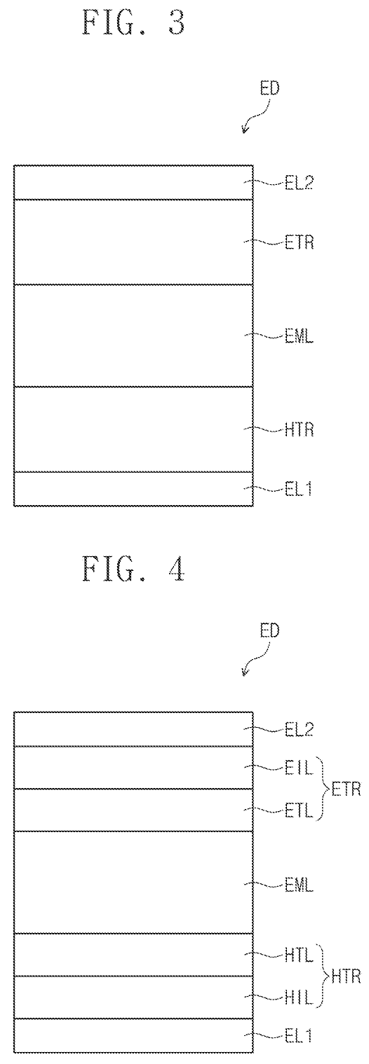

Hereinafter, FIGS. 3 to 6 are cross-sectional views schematically showing light emitting elements according to embodiments. The light emitting element ED according to an embodiment may include a first electrode EL1, a second electrode EL2 oppositely disposed to the first electrode EL1, and an emission layer EML disposed between the first electrode EL1 and the second electrode EL2. The light emitting element ED of an embodiment may include a first compound of an embodiment, described below, in the emission layer EML.

The light emitting element ED may include a hole transport region HTR, an emission layer EML, an electron transport region ETR, and/or the like, stacked in order. For example, the light emitting element ED of an embodiment may include a first electrode EL1, a hole transport region HTR, an emission layer EML, an electron transport region ETR, and a second electrode EL2, stacked in order.

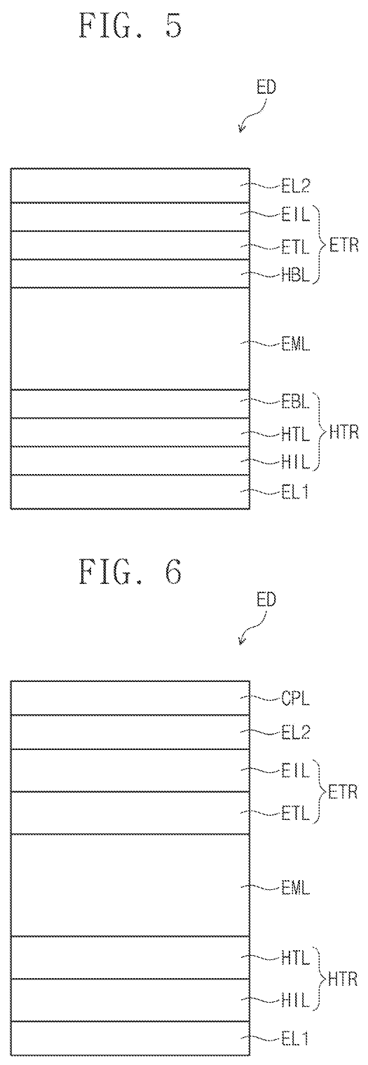

When compared with FIG. 3, FIG. 4 shows the cross-sectional view of a light emitting element ED of an embodiment, wherein a hole transport region HTR includes a hole injection layer HIL and a hole transport layer HTL, and an electron transport region ETR includes an electron injection layer EIL and an electron transport layer ETL. In some embodiments, when compared with FIG. 3, FIG. 5 shows the cross-sectional view of a light emitting element ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting element ED of an embodiment, including a capping layer CPL on the second electrode EL2.

The light emitting element ED of an embodiment may include a first compound of an embodiment, described below, in an emission layer EML. The first compound may be a fused polycyclic compound. In some embodiments, in a display apparatus DD (FIG. 2) of an embodiment, including multiple emission regions, a fused polycyclic compound of an embodiment, described below, may be included in an emission layer EML forming at least one emission region.

In the light emitting element ED according to an embodiment, the first electrode EL1 has conductivity (e.g., is a conductor). The first electrode EL1 may be formed utilizing a metal material, a metal alloy and/or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, compounds comprising one or more of the foregoing elements, combinations of two or more of the foregoing elements or compounds, mixtures of two or or more of the foregoing elements or compounds, or oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). In an embodiment, the structure of the first electrode EL1 may include multiple layers including a reflective layer and/or a transflective layer formed utilizing the above materials, and/or a transmissive conductive layer formed utilizing ITO, IZO, ZnO, or ITZO. For example, the first electrode EL1 may have a three-layer structure of ITO/Ag/ITO. However, an embodiment of the present disclosure is not limited thereto. The first electrode EL1 may include the above-described metal materials, combinations of two or more metal materials selected from the above-described metal materials, or two or more oxides of the above-described metal materials or one or more combinations thereof. The thickness of the first electrode EL1 may be from about 700 Å to about 10,000 Å. For example, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer, an emission auxiliary layer, or an electron blocking layer EBL. The thickness of the hole transport region HTR may be, for example, about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

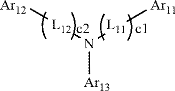

In Formula H-1 above, L₁₁ and L₁₂ may each independently be a direct linkage, a substituted or unsubstituted arylene group of 6 to 30 ring-forming carbon atoms, or a substituted or unsubstituted heteroarylene group of 2 to 30 ring-forming carbon atoms. c1 and c2 may each independently be an integer of 0 to 10. In some embodiments, when c1 or c2 is an integer of 2 or more, multiple L₁₁ and L₁₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁₁ and Ar₁₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₁₃ may be a substituted or unsubstituted aryl group of 6 to 30 ring-forming carbon atoms.

The compound represented by Formula H-1 may be a monoamine compound. In some embodiments, the compound represented by Formula H-1 may be a diamine compound in which at least one selected from among Ar₁₁ to Ar₁₃ includes an amine group as a substituent. In some embodiments, the compound represented by Formula H-1 may be a carbazole-based compound in which at least one selected from among Ar₁₁ and Ar₁₂ includes a substituted or unsubstituted carbazole group, or a fluorene-based compound in which at least one selected from among Ar₁₁ and Ar₁₂ includes a substituted or unsubstituted fluorene group.

The compound represented by Formula H-1 may be represented by any compound selected from among the compounds in Compound Group H. However, the compounds shown in Compound Group H are only illustrations, and the compound represented by Formula H-1 is not limited to the compounds represented in Compound Group H. Compound Group H

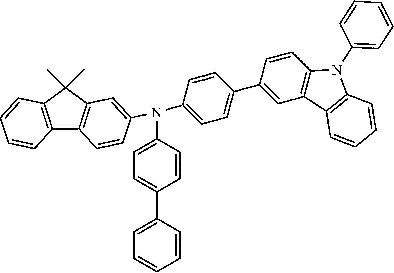 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

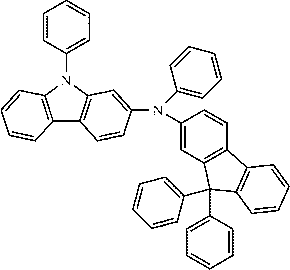 [SMILES: c1ccc(N(c2ccc3c(c2)C(c2ccccc2)(c2ccccc2)c2ccccc2-3)c2ccc3c4ccccc4n(-c4ccccc4)c3c2)cc1]

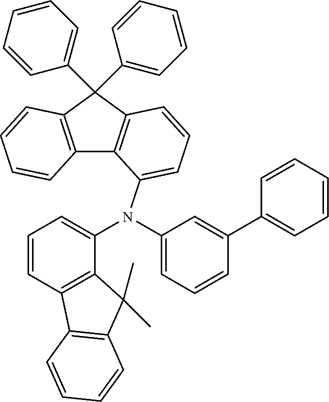 [SMILES: CC1(C)c2ccccc2-c2cccc(N(c3cccc(-c4ccccc4)c3)c3cccc4c3-c3ccccc3C4(c3ccccc3)c3ccccc3)c21]

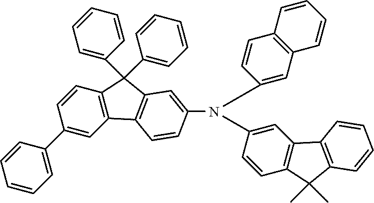 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

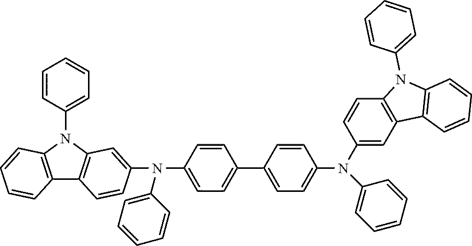 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

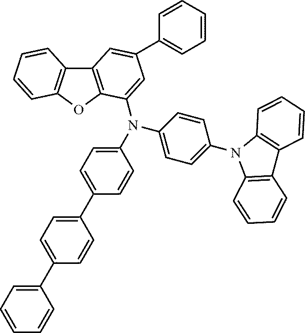 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

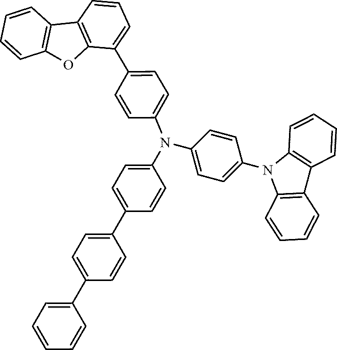 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

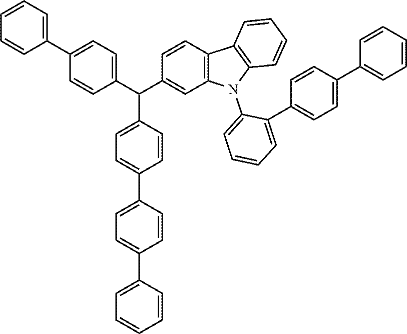 [SMILES: c1ccc(-c2ccc(-c3ccc(C(c4ccc(-c5ccccc5)cc4)c4ccc5c6ccccc6n(-c6ccccc6-c6ccc(-c7ccccc7)cc6)c5c4)cc3)cc2)cc1]

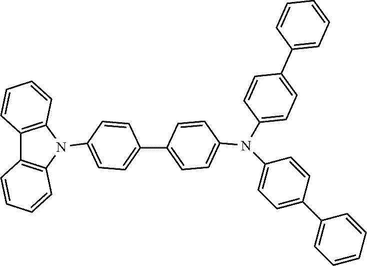 [SMILES: c1ccc(-c2ccc(N(c3ccc(-c4ccccc4)cc3)c3ccc(-c4ccc(-n5c6ccccc6c6ccccc65)cc4)cc3)cc2)cc1]

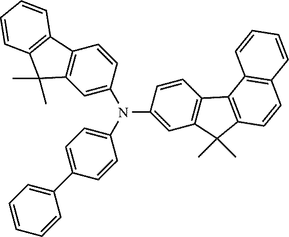 [SMILES: CC1(C)c2ccccc2-c2ccc(N(c3ccc(-c4ccccc4)cc3)c3ccc4c(c3)C(C)(C)c3ccc5ccccc5c3-4)cc21]

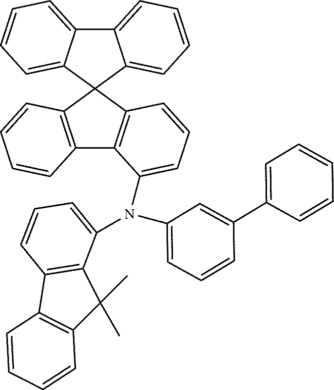 [SMILES: CC1(C)c2ccccc2-c2cccc(N(c3cccc(-c4ccccc4)c3)c3cccc4c3-c3ccccc3C43c4ccccc4-c4ccccc43)c21]

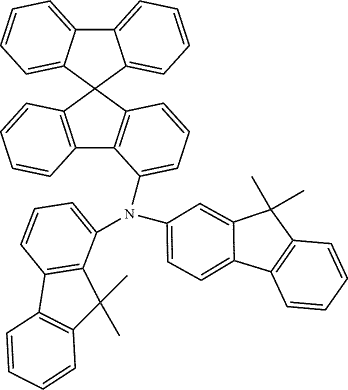 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21]

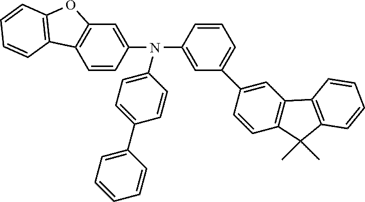 [SMILES: CC1(C)c2ccccc2-c2cc(-c3cccc(N(c4ccc(-c5ccccc5)cc4)c4ccc5c(c4)oc4ccccc45)c3)ccc21]

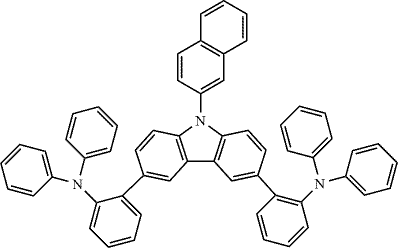 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

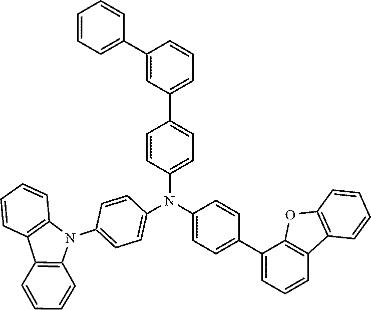 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

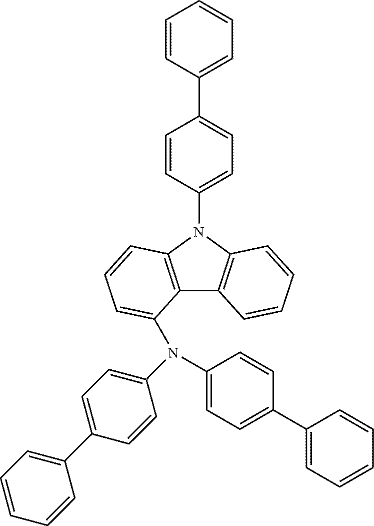 [SMILES: c1ccc(-c2ccc(N(c3ccc(-c4ccccc4)cc3)c3cccc4c3c3ccccc3n4-c3ccc(-c4ccccc4)cc3)cc2)cc1]

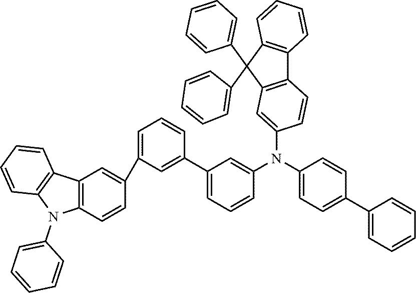 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

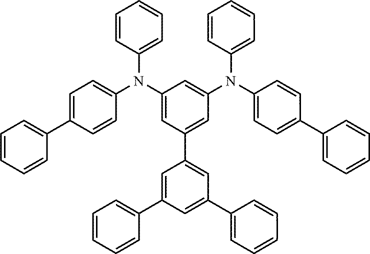 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

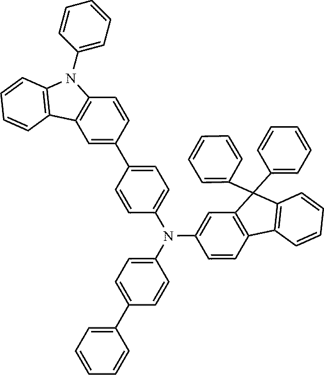 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

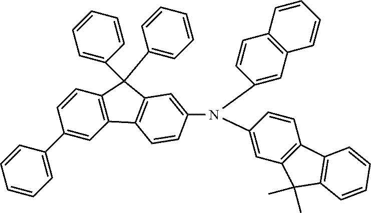 [SMILES: CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

The hole transport region HTR may include a phthalocyanine compound such as copper phthalocyanine, N¹,N¹′-([1,1′-biphenyl]-4,4′-diyl)bis(N¹-phenyl-N⁴,N⁴-dim-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB or NPD), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HAT-CN).

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection layer HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer EBL, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase of a driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as Cul and Rbl, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a buffer layer and an electron blocking layer EBL in addition to the hole injection layer HIL and the hole transport layer HTL. The buffer layer may compensate resonance distance according to the wavelength of light emitted from an emission layer EML and may increase emission efficiency. , Materials included in the hole transport region HTR may be utilized in the buffer layer. The electron blocking layer EBL is a layer playing the role of blocking the injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

In the light emitting element ED of an embodiment, the emission layer EML may include multiple light emitting materials. In an embodiment, the emission layer EML may include a first compound, and at least one selected from among a second compound, a third compound, and a fourth compound. In the light emitting element ED of an embodiment, the emission layer EML may include at least one host and at least one dopant. For example, the emission layer EML in an embodiment may include a first dopant, and a first host and a second host, which are different from each other. In some embodiments, the emission layer EML of an embodiment may include a first host and a second host, which are different from each other, and a first dopant and a second dopant, which are different from each other.

The first compound included in the emission layer EML of an embodiment may include a fused polycyclic compound having a fused structure of multiple aromatic rings through one boron atom and two heteroatoms. The first compound of an embodiment may include a fused structure of multiple aromatic rings through one boron atom and two heteroatoms selected from the group including (e.g., consisting of) nitrogen (N), oxygen (O), sulfur (S) and selenium (Se).

The first compound of an embodiment may include a fused polycyclic compound represented by Formula 1.

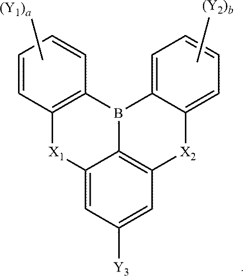

In Formula 1, X₁ and X₂ may each independently be CR₁R₂, NR₃, NR₄, O, S, or Se. Here, at least one selected from among X₁ and X₂ is NR₄. For example, both (e.g., simultaneously) X₁ and X₂ may be NR₄. In some embodiments, any one selected from among X₁ and X₂ may be NR₄, and the remainder (e.g., the X₁ or X₂ that is not NR₄) may be CR₁R₂, NR₃, O,S, or Se.

In Formula 1, Y₁ to Y₃ may each independently be, a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, Y₁ to Y₃ in Formula 1 may each independently be combined with an adjacent substituent, and/or the like to form a hydrocarbon ring or a heterocycle. Y₁ to Y₃ may each independently be combined with an adjacent substituent, and/or the like to form a hydrocarbon ring of 6 to 30 ring-forming carbon atoms or a heterocycle of 2 to 30 ring-forming carbon atoms, including an element of N, O, S, Se, and/or the like as a heteroatom.

For example, Y₁ and Y₂ may each independently be, a hydrogen atom, a substituted or unsubstituted amino group, a substituted or unsubstituted alkyl group of 1 to 20 carbon atoms, a substituted or unsubstituted oxy group, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. For example, Y₁ and Y₂ may each independently be a hydrogen atom, a substituted or unsubstituted t-butyl group, a substituted or unsubstituted phenyl group, a substituted or unsubstituted diarylamine group, a substituted or unsubstituted carbazole group, a substituted or unsubstituted dibenzofuran group, a substituted or unsubstituted biphenyl group, a substituted or unsubstituted naphthyl group, a substituted or unsubstituted anthracene group, a substituted or unsubstituted cyclohexane group, a substituted or unsubstituted tetralin group, a substituted or unsubstituted phenanthrene group, a substituted or unsubstituted phenoxy group, or a substituted or unsubstituted phenylthio group. In some embodiments, adjacent two substituents of each of Y₁ and Y₂ may be combined with each other to form a substituted or unsubstituted carbazole group, a substituted or unsubstituted dibenzofuran group, a substituted or unsubstituted dibenzothiophene group, and/or the like, without limitation.

For example, Y₃ may be a hydrogen atom, a substituted or unsubstituted amino group, a substituted or unsubstituted alkyl group of 1 to 20 carbon atoms, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms. For example, Y₃ may be a hydrogen atom, a substituted or unsubstituted ethyl group, a substituted or unsubstituted t-butyl group, a substituted or unsubstituted phenyl group, a substituted or unsubstituted diarylamine group, a substituted or unsubstituted carbazole group, a substituted or unsubstituted naphthyl group, a substituted or unsubstituted cyclohexane group, or a substituted or unsubstituted tetralin group, without limitation.

For example, at least one selected from among Y₁ to Y₃ may include a deuterium atom. For example, at least one selected from among Y₁ to Y₃ may be substituted with a deuterium atom.

In Formula 1, “a” and “b” may each independently be an integer of 0 to 4. When each of “a” and “b” is an integer of 2 or more, each of multiple Y₁ and Y₂ may be all the same, or at least one selected from among multiple Y₁ and Y₂ may be different. An embodiment in which “a” is 4, and multiple Y₁ are all hydrogen atoms in Formula 1, may be the same as Formula 1 in which “a” is 0. In some embodiments in which“b” is 4, and multiple Y₂ are all hydrogen atoms in Formula 1, may be the same as Formula 1 in which “b” is 0.

In Formula 1, R₁ to R₃ may each independently be a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring.

For example, R₁ and R₂ may each independently be a substituted or unsubstituted alkyl group of 1 to 20 carbon atoms, or a substituted or unsubstituted aryl group of 6 to 20 ring-forming carbon atoms, or R₁ and R₂ may be combined to form a fluorenyl group. However, an embodiment of the present disclosure is not limited thereto.

For example, when any one selected from among X₁ and X₂ is NR₃, and the remainder (the X₁ to X₂ that is not NR₃) is NR₄, R₃ may be a substituted or unsubstituted phenyl group, a substituted or unsubstituted biphenyl group, a substituted or unsubstituted terphenyl group, and/or the like, but an embodiment of the present disclosure is not limited thereto.

In Formula 1, R₄ may have a connected structure of a multiple resonance plate-type or kind structure including a boron atom with an ortho-type or kind penta-phenyl group. For example, R₄ may have a structure in which a phenyl group to which a boron atom is bonded at a para position is combined with two substituted or unsubstituted biphenyl groups in ortho relations. In some embodiments, in a multiple resonance plate-type or kind structure including a boron atom of Formula 1, two substituted or unsubstituted biphenyl groups are combined in ortho relations to the phenyl group to which a boron atom is bonded at a para position, and each of the biphenyl groups may be combined with an adjacent substituent to form a heterocycle. For example, in Formula 1, R₄ may have a structure in which two substituted or unsubstituted dibenzohetero groups are bonded in ortho relationship to the phenyl group to which a boron atom is bonded at a para position.

In an embodiment, R₄ may be represented by Formula 2 or Formula 3. When both (e.g., simultaneously) X₁ and X₂ are NR₄ in Formula 1, multiple R₄ all may be represented by Formula 2 or represented by Formula 3. In some embodiments, any one selected from among multiple R₄ may be represented by Formula 2, and the remainder (the R₄ grouos not represented by Formula 2) may be represented by Formula 3.

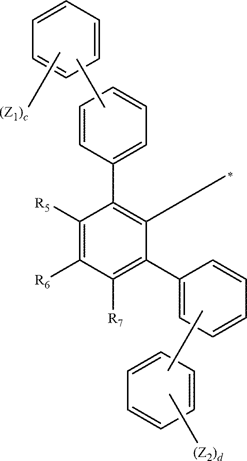

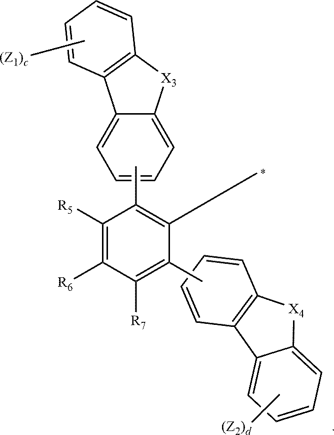

In Formula 3, X₃ and X₄ may each independently be CR₈R₉, NR₁₀, O,S, or Se. For example, X₃ and X₄ may be the same, and both (e.g., simultaneously) X₃ and X₄ may be NR₁₀, O,S, or Se.

In Formula 2 and Formula 3, R₅ to R₁₀ may each independently be a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring. For example, R₅ to R₇ may each independently be a hydrogen atom or a substituted or unsubstituted alkyl group of 1 to 20 carbon atoms. For example, R₅ to R₇ may each independently be a hydrogen atom or a substituted or unsubstituted t-butyl group, without limitation.

In some embodiments, when X₃ and X₄ are NR₁₀, R₁₀ may be a substituted or unsubstituted phenyl group, without limitation.

In Formula 2 and Formula 3, Z₁ and Z₂ may each independently be a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms. For example, Z₁ and Z₂ may each independently be a hydrogen atom or a substituted or unsubstituted alkyl group of 1 to 20 carbon atoms. For example, Z₁ and Z₂ may each independently be a hydrogen atom or a substituted or unsubstituted t-butyl group, without limitation.

In Formula 2 and Formula 3, “c” and “d” may each independently be an integer of 0 to 4. When each of “c” and “d” is an integer of 2 or more, each of multiple Z₁ and Z₂ may be all the same, or at least one selected from among multiple Z₁ and Z₂ may be different. Embodiments of Formula 2 and Formula 3 in which “c” is 4, and multiple Z₁ are all hydrogen atoms, may be the same as Formula 2 and Formula 3 where “a” is 0, respectively. Embodiments of Formula 2 and Formula 3 where “d” is 4, and multiple Z₂ are all hydrogen atoms, may be the same as Formula 2 and Formula 3 where “d” is 0, respectively.

The first compound of an embodiment may include a fused structure of multiple aromatic rings through at least one boron atom and at least one heteroatom. The first compound may include a fused structure of multiple aromatic rings through one boron atom and at least one nitrogen atom. The first compound may include a connected structure of an ortho-type or kind penta-phenyl group at the para position to the boron atom. Accordingly, a vacant p-orbital of the boron atom of Formula 1 is protected by the ortho-type or kind penta-phenyl group, and a trigonal bonding structure of the boron atom may be effectively maintained. In some embodiments, the first compound of the present disclosure may relatively (relative to not having the penta-phenyl group) increase an intermolecular distance by including the ortho-type or kind penta-phenyl group in a multiple resonance plate-type or kind structure including a boron atom. Accordingly, the first compound may reduce the probability of generating an intermolecular interaction which may be a factor in reducing element lifetime and emission efficiency, such as the generation of intermolecular aggregation, the formation of intermolecular excimer and/or the formation of intermolecular exiplex. The intermolecular aggregation phenomenon of the first compound of an embodiment of the present disclosure may be prevented or reduced, and accordingly, solubility may increase, the purification of a compound may become easy, and material stability against thermal decomposition during sublimation purification, and/or the like may be improved. In some embodiments, the first compound of an embodiment may show substantially the same wavelength of light emitting spectrum measured in a solution phase and light emitting spectrum measured from a deposited layer, and high color purity.

The light emitting element of the present disclosure includes the first compound of an embodiment in an emission layer, and the deterioration phenomenon of the element may be reduced, the lifetime of the element may be improved (increased), and high color purity may be shown.

In an embodiment, Formula 2 may be represented by Formula 2-1.

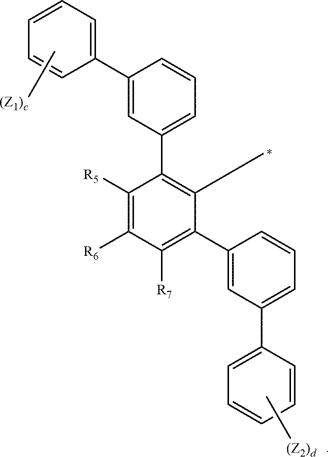

Formula 2-1 corresponds to Formula 2 in which a connecting structure in a penta-phenyl group is embodied. In Formula 2-1, the same explanation on Z₁, Z₂, R₅, R₆, R₇, “c” and “d” referring to Formula 2 may be applied.

In an embodiment, Formula 3 may be represented by any one selected from among Formula 3-1 to Formula 3-4.

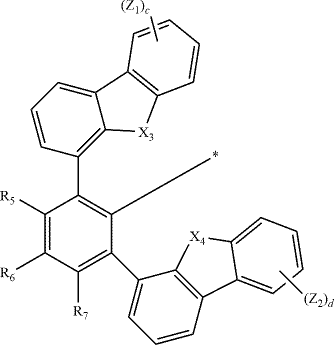

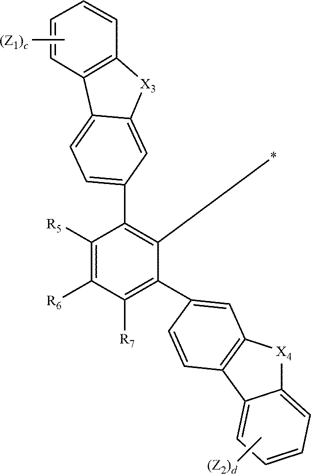

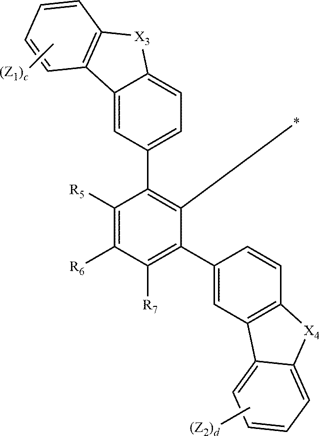

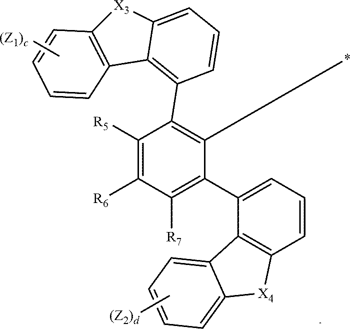

Formula 3-1 to Formula 3-4 correspond to Formula 3 in which a connecting structure in a penta-phenyl group is embodied. In Formula 3-1 to Formula 3-4, the same explanation on R₅ to R₇, X₃, X₄, Z₁, Z₂, “c” and “d” referring to Formula 3 may be applied.

In an embodiment, the first compound represented by Formula 1 may be represented by any one selected from among Formula 4-1 to Formula 4-3.

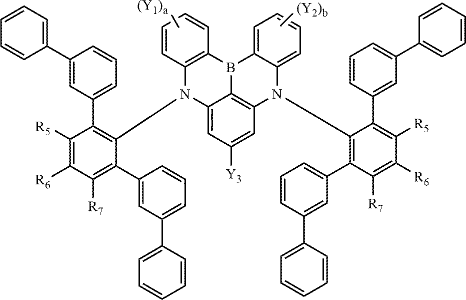

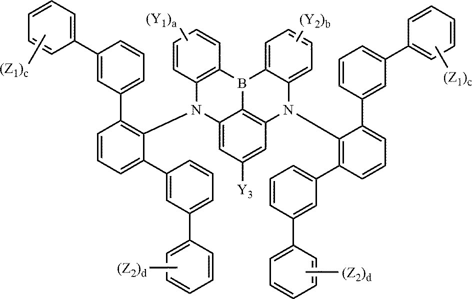

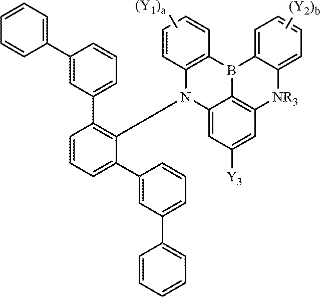

Formula 4-1 to Formula 4-3 correspond to Formula 1 in which X₁ and X₂ are embodied. Formula 4-1 and Formula 4-2 correspond to Formula 1 where X₁ and X₂ are NR₄, and Formula 4-3 corresponds to Formula 1 where X₁ is NR₄, X₂ is NR₃, and R₄ is represented by Formula 2.

For example, when at least one selected from among X₁ and X₂ is NR₄, and R₄ is represented by Formula 2, Z₁ and Z₂ may be all hydrogen atoms as in Formula 4-1 and Formula 4-3, or R₅ to R₇ may be all hydrogen atoms as in Formula 4-2 and Formula 4-3.

In some embodiments, in Formula 4-1 to Formula 4-3, the same explanation on Y₁ to Y₃, R₃, R5 to R₇, Z₁, Z₂, and “a” to “d” referring to Formula 1 and Formula 2 may be applied.

In an embodiment, the first compound represented by Formula 1 may be represented by any one selected from among Formula 5-1 to Formula 5-12.

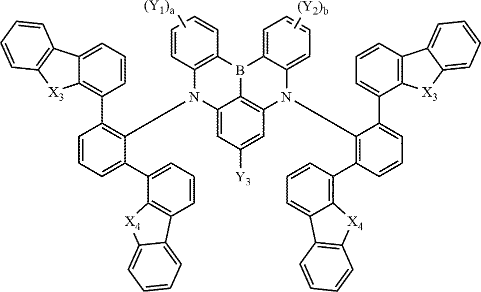

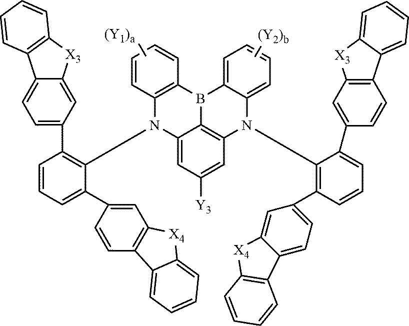

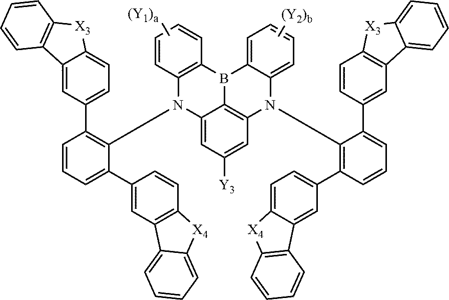

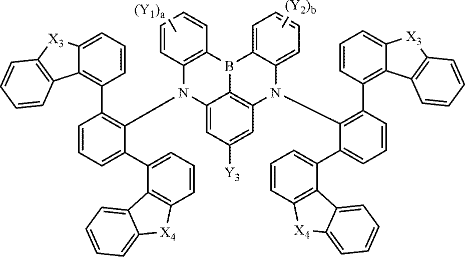

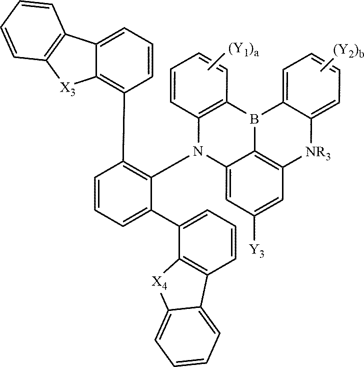

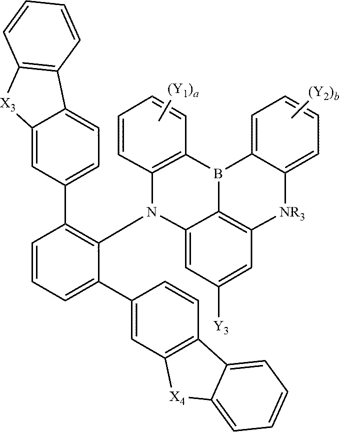

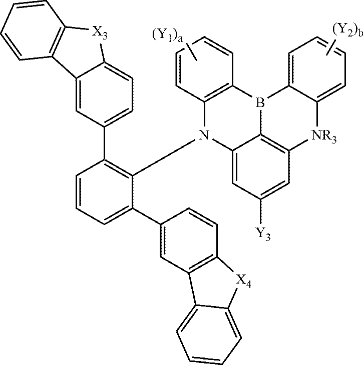

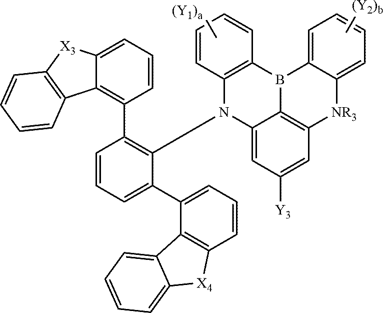

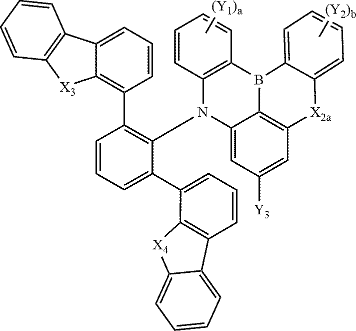

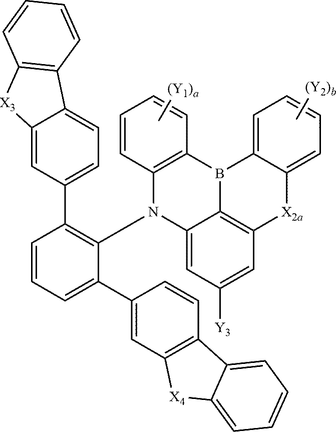

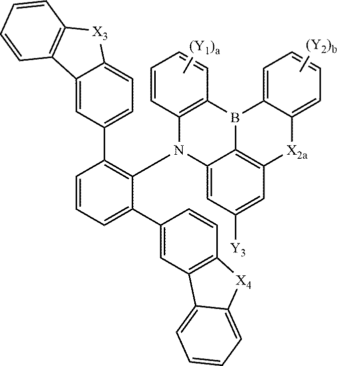

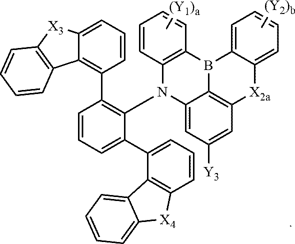

Formula 5-1 to Formula 5-12 correspond to Formula 1 in which X₁ and X₂ are embodied. Formula 5-1 to Formula 5-4 correspond to Formula 1 in which X₁ and X₂ are NR₄, Formula 5-5 to Formula 5-8 correspond to Formula 1 in which X₁ is NR₄, and X₂ is NR₃, and Formula 5-9 to Formula 5-12 correspond to Formula 1 where X₁ is NR₄, and X₂ is X₂ₐ. In some embodiments, Formula 5-1 to Formula 5-12 correspond to embodiments in which R₄ is represented by Formula 3.

For example, when at least one selected from among X₁ and X₂ is NR₄, and R₄ is represented by Formula 3, Rs to R₇, Z₁ and Z₂ may all be hydrogen atoms.

In some embodiments, in Formula 5-1 to Formula 5-12, the same explanation of Y₁ to Y₃, R₃, “a”, “b”, X₃ and X₄ referring to Formula 1 and Formula 3 may be applied. In Formula 5-7 to Formula 5-12 in an embodiment, X₂ₐ may be CR₁R₂, O,S or Se.

As described above, the first compound of an embodiment includes an ortho-type or kind penta-phenyl group in a multiple resonance plate-type or kind structure including a boron atom, and a relative (relative to not having a penta-phenyl group) intermolecular distance may increase, intermolecular aggregation phenomenon may be prevented or reduced, and material stability may be improved. In some embodiments, the first compound includes a penta-phenyl group, and a bonding structure in a molecule of a boron atom may be stabilized. Accordingly, the multiple resonance structure of the first compound may be reinforced (stabilized).

The first compound of an embodiment may be any one selected from among the compounds represented in Compound Group 1. The light emitting element ED of an embodiment may include at least one selected from among the compounds represented in Compound Group 1 in an emission layer EML as the first compound.

### Compound Group 1

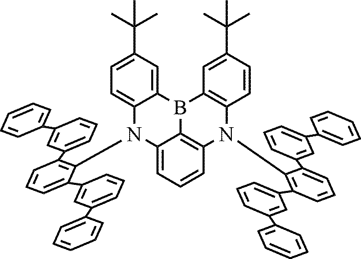 [SMILES: CC(C)(C)c1ccc2c(c1)B1c3cc(C(C)(C)C)ccc3N(c3c(-c4cccc(-c5ccccc5)c4)cccc3-c3cccc(-c4ccccc4)c3)c3cccc(c31)N2c1c(-c2cccc(-c3ccccc3)c2)cccc1-c1cccc(-c2ccccc2)c1]

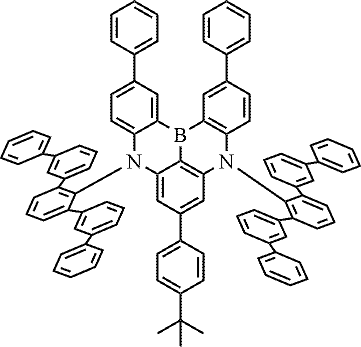 [SMILES: CC(C)(C)c1ccc(-c2cc3c4c(c2)N(c2c(-c5cccc(-c6ccccc6)c5)cccc2-c2cccc(-c5ccccc5)c2)c2ccc(-c5ccccc5)cc2B4c2cc(-c4ccccc4)ccc2N3c2c(-c3cccc(-c4ccccc4)c3)cccc2-c2cccc(-c3ccccc3)c2)cc1]

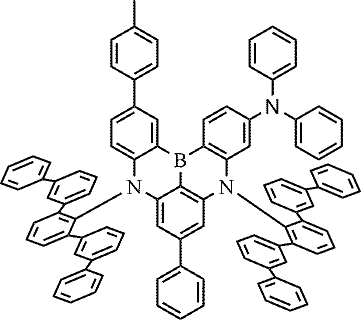 [SMILES: Cc1ccc(-c2ccc3c(c2)B2c4ccc(N(c5ccccc5)c5ccccc5)cc4N(c4c(-c5cccc(-c6ccccc6)c5)cccc4-c4cccc(-c5ccccc5)c4)c4cc(-c5ccccc5)cc(c42)N3c2c(-c3cccc(-c4ccccc4)c3)cccc2-c2cccc(-c3ccccc3)c2)cc1]

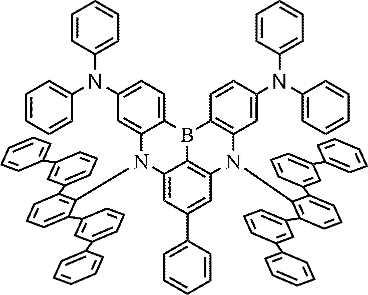 [SMILES: c1ccc(-c2cccc(-c3cccc(-c4cccc(-c5ccccc5)c4)c3N3c4cc(N(c5ccccc5)c5ccccc5)ccc4B4c5ccc(N(c6ccccc6)c6ccccc6)cc5N(c5c(-c6cccc(-c7ccccc7)c6)cccc5-c5cccc(-c6ccccc6)c5)c5cc(-c6ccccc6)cc3c54)c2)cc1]

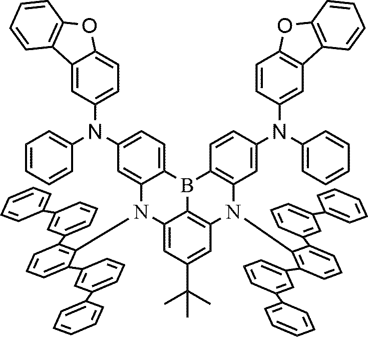 [SMILES: CC(C)(C)c1cc2c3c(c1)N(c1c(-c4cccc(-c5ccccc5)c4)cccc1-c1cccc(-c4ccccc4)c1)c1cc(N(c4ccccc4)c4ccc5oc6ccccc6c5c4)ccc1B3c1ccc(N(c3ccccc3)c3ccc4oc5ccccc5c4c3)cc1N2c1c(-c2cccc(-c3ccccc3)c2)cccc1-c1cccc(-c2ccccc2)c1]

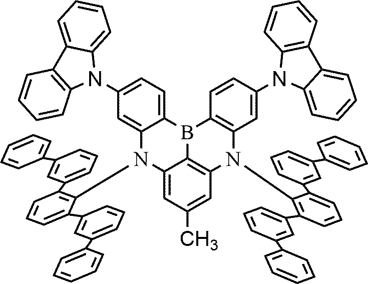 [SMILES: Cc1cc2c3c(c1)N(c1c(-c4cccc(-c5ccccc5)c4)cccc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(-c3ccccc3)c2)cccc1-c1cccc(-c2ccccc2)c1]

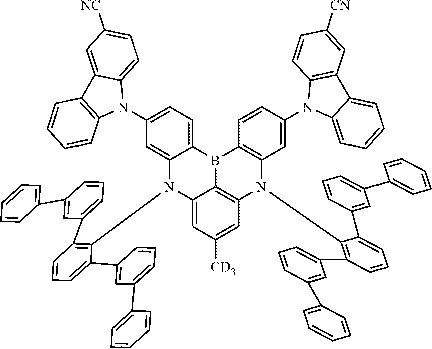 [SMILES: [2H]C([2H])([2H])c1cc2c3c(c1)N(c1c(-c4cccc(-c5ccccc5)c4)cccc1-c1cccc(-c4ccccc4)c1)c1cc(-n4c5ccccc5c5cc(C#N)ccc54)ccc1B3c1ccc(-n3c4ccccc4c4cc(C#N)ccc43)cc1N2c1c(-c2cccc(-c3ccccc3)c2)cccc1-c1cccc(-c2ccccc2)c1]

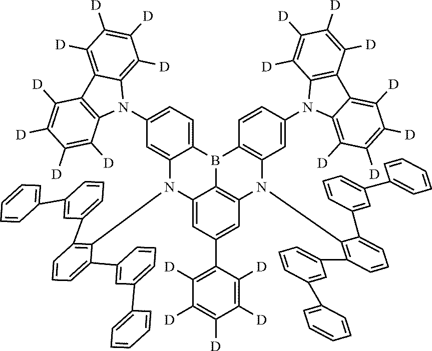 [SMILES: [2H]c1c([2H])c([2H])c(-c2cc3c4c(c2)N(c2c(-c5cccc(-c6ccccc6)c5)cccc2-c2cccc(-c5ccccc5)c2)c2cc(-n5c6c([2H])c([2H])c([2H])c([2H])c6c6c([2H])c([2H])c([2H])c([2H])c65)ccc2B4c2ccc(-n4c5c([2H])c([2H])c([2H])c([2H])c5c5c([2H])c([2H])c([2H])c([2H])c54)cc2N3c2c(-c3cccc(-c4ccccc4)c3)cccc2-c2cccc(-c3ccccc3)c2)c([2H])c1[2H]]

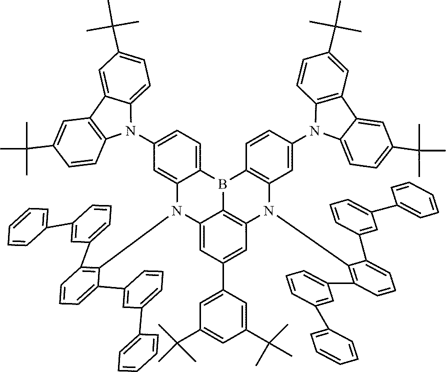 [SMILES: CC(C)(C)c1cc(-c2cc3c4c(c2)N(c2c(-c5cccc(-c6ccccc6)c5)cccc2-c2cccc(-c5ccccc5)c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3cccc(-c4ccccc4)c3)cccc2-c2cccc(-c3ccccc3)c2)cc(C(C)(C)C)c1]

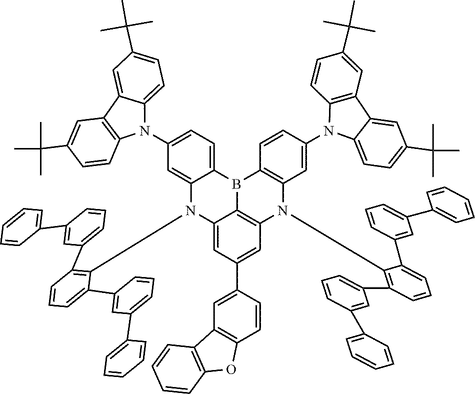 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4oc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1]

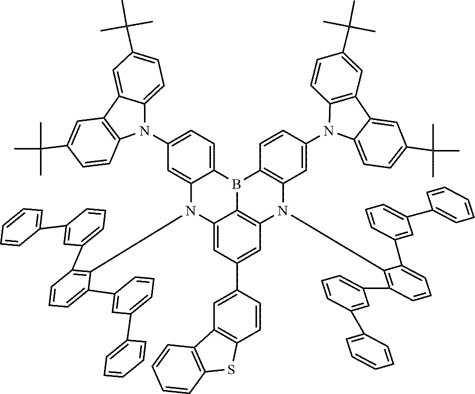 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4sc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1]

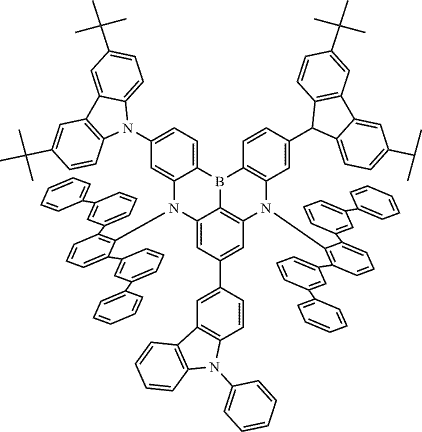 [SMILES: CC(C)c1ccc2c(c1)-c1cc(C(C)(C)C)ccc1C2c1ccc2c(c1)N(c1c(-c3cccc(-c4ccccc4)c3)cccc1-c1cccc(-c3ccccc3)c1)c1cc(-c3ccc4c(c3)c3ccccc3n4-c3ccccc3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1]

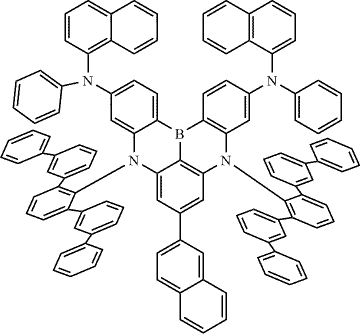 [SMILES: c1ccc(-c2cccc(-c3cccc(-c4cccc(-c5ccccc5)c4)c3N3c4cc(N(c5ccccc5)c5cccc6ccccc56)ccc4B4c5ccc(N(c6ccccc6)c6cccc7ccccc67)cc5N(c5c(-c6cccc(-c7ccccc7)c6)cccc5-c5cccc(-c6ccccc6)c5)c5cc(-c6ccc7ccccc7c6)cc3c54)c2)cc1]

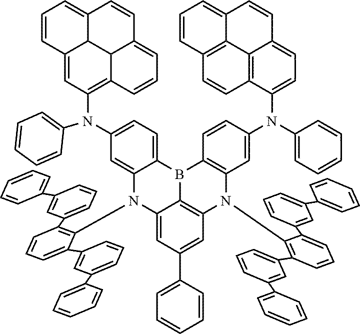 [SMILES: C1=CC2=CC(N(c3ccccc3)c3ccc4c(c3)N(c3c(-c5cccc(-c6ccccc6)c5)cccc3-c3cccc(-c5ccccc5)c3)c3cc(-c5ccccc5)cc5c3B4c3ccc(N(c4ccccc4)c4ccc6ccc7cccc8ccc4c6c78)cc3N5c3c(-c4cccc(-c5ccccc5)c4)cccc3-c3cccc(-c4ccccc4)c3)=C3C=CC=C4C=CC(=C1)C2C43]

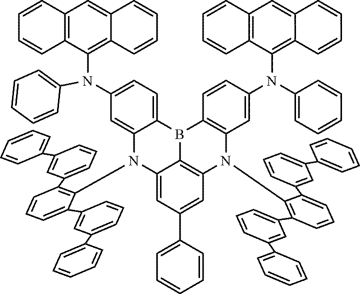 [SMILES: c1ccc(-c2cccc(-c3cccc(-c4cccc(-c5ccccc5)c4)c3N3c4cc(N(c5ccccc5)c5c6ccccc6cc6ccccc56)ccc4B4c5ccc(N(c6ccccc6)c6c7ccccc7cc7ccccc67)cc5N(c5c(-c6cccc(-c7ccccc7)c6)cccc5-c5cccc(-c6ccccc6)c5)c5cc(-c6ccccc6)cc3c54)c2)cc1]

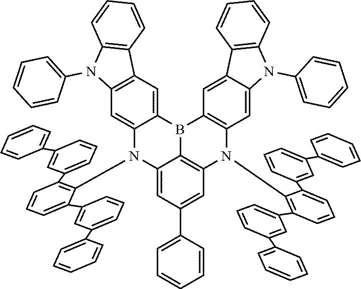 [SMILES: c1ccc(-c2cccc(-c3cccc(-c4cccc(-c5ccccc5)c4)c3N3c4cc5c(cc4B4c6cc7c8ccccc8n(-c8ccccc8)c7cc6N(c6c(-c7cccc(-c8ccccc8)c7)cccc6-c6cccc(-c7ccccc7)c6)c6cc(-c7ccccc7)cc3c64)c3ccccc3n5-c3ccccc3)c2)cc1]

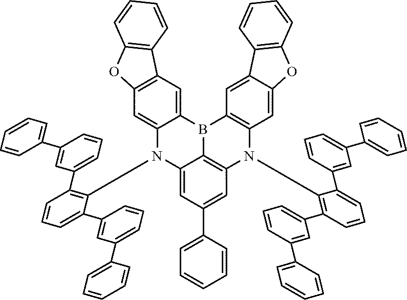 [SMILES: c1ccc(-c2cccc(-c3cccc(-c4cccc(-c5ccccc5)c4)c3N3c4cc5oc6ccccc6c5cc4B4c5cc6c(cc5N(c5c(-c7cccc(-c8ccccc8)c7)cccc5-c5cccc(-c7ccccc7)c5)c5cc(-c7ccccc7)cc3c54)oc3ccccc36)c2)cc1]

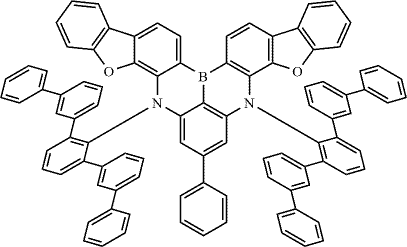 [SMILES: c1ccc(-c2cccc(-c3cccc(-c4cccc(-c5ccccc5)c4)c3N3c4cc(-c5ccccc5)cc5c4B(c4ccc6c(oc7ccccc76)c43)c3ccc4c(oc6ccccc64)c3N5c3c(-c4cccc(-c5ccccc5)c4)cccc3-c3cccc(-c4ccccc4)c3)c2)cc1]

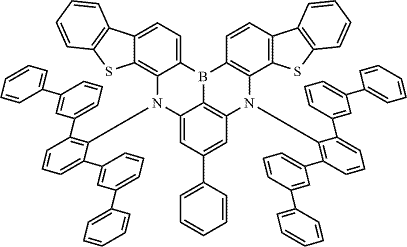 [SMILES: c1ccc(-c2cccc(-c3cccc(-c4cccc(-c5ccccc5)c4)c3N3c4cc(-c5ccccc5)cc5c4B(c4ccc6c(sc7ccccc76)c43)c3ccc4c(sc6ccccc64)c3N5c3c(-c4cccc(-c5ccccc5)c4)cccc3-c3cccc(-c4ccccc4)c3)c2)cc1]

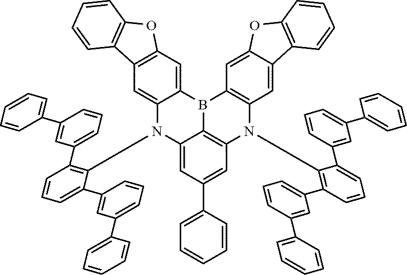 [SMILES: c1ccc(-c2cccc(-c3cccc(-c4cccc(-c5ccccc5)c4)c3N3c4cc5c(cc4B4c6cc7oc8ccccc8c7cc6N(c6c(-c7cccc(-c8ccccc8)c7)cccc6-c6cccc(-c7ccccc7)c6)c6cc(-c7ccccc7)cc3c64)oc3ccccc35)c2)cc1]

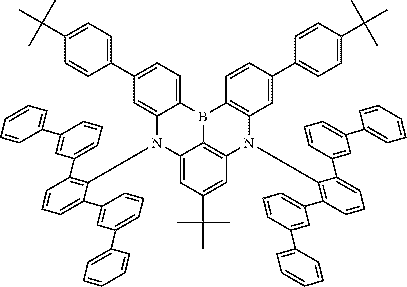 [SMILES: CC(C)(C)c1ccc(-c2ccc3c(c2)N(c2c(-c4cccc(-c5ccccc5)c4)cccc2-c2cccc(-c4ccccc4)c2)c2cc(C(C)(C)C)cc4c2B3c2ccc(-c3ccc(C(C)(C)C)cc3)cc2N4c2c(-c3cccc(-c4ccccc4)c3)cccc2-c2cccc(-c3ccccc3)c2)cc1]

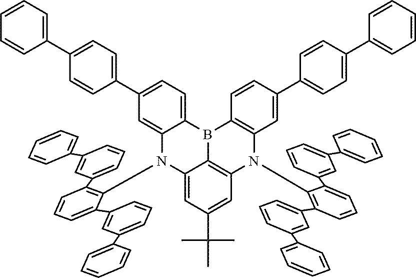 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)cc4)ccc1B3c1ccc(-c3ccc(-c4ccccc4)cc3)cc1N2c1c(-c2cccc(-c3ccccc3)c2)cccc1-c1cccc(-c2ccccc2)c1]

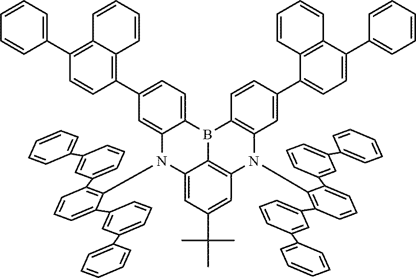 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)c5ccccc45)ccc1B3c1ccc(-c3ccc(-c4ccccc4)c4ccccc34)cc1N2c1c(-c2cccc(-c3ccccc3)c2)cccc1-c1cccc(-c2ccccc2)c1]

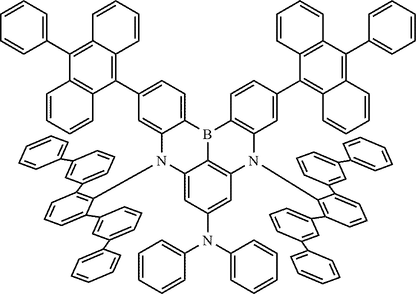 [SMILES: c1ccc(-c2cccc(-c3cccc(-c4cccc(-c5ccccc5)c4)c3N3c4cc(-c5c6ccccc6c(-c6ccccc6)c6ccccc56)ccc4B4c5ccc(-c6c7ccccc7c(-c7ccccc7)c7ccccc67)cc5N(c5c(-c6cccc(-c7ccccc7)c6)cccc5-c5cccc(-c6ccccc6)c5)c5cc(N(c6ccccc6)c6ccccc6)cc3c54)c2)cc1]

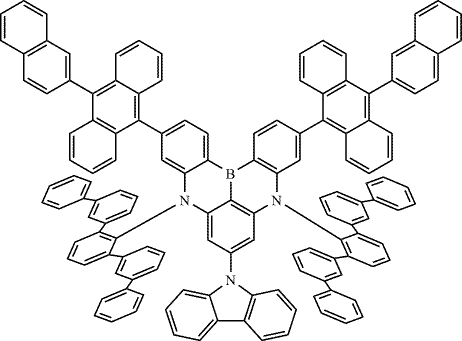 [SMILES: c1ccc(-c2cccc(-c3cccc(-c4cccc(-c5ccccc5)c4)c3N3c4cc(-c5c6ccccc6c(-c6ccc7ccccc7c6)c6ccccc56)ccc4B4c5ccc(-c6c7ccccc7c(-c7ccc8ccccc8c7)c7ccccc67)cc5N(c5c(-c6cccc(-c7ccccc7)c6)cccc5-c5cccc(-c6ccccc6)c5)c5cc(-n6c7ccccc7c7ccccc76)cc3c54)c2)cc1]

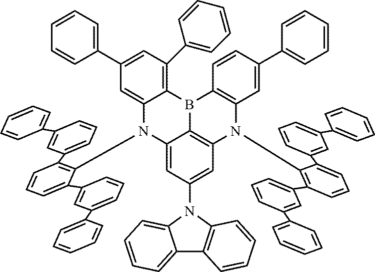 [SMILES: c1ccc(-c2cccc(-c3cccc(-c4cccc(-c5ccccc5)c4)c3N3c4cc(-c5ccccc5)ccc4B4c5c(-c6ccccc6)cc(-c6ccccc6)cc5N(c5c(-c6cccc(-c7ccccc7)c6)cccc5-c5cccc(-c6ccccc6)c5)c5cc(-n6c7ccccc7c7ccccc76)cc3c54)c2)cc1]

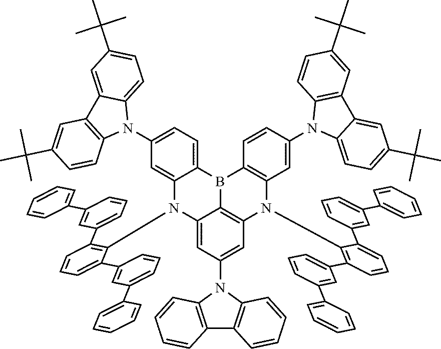 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-n3c4ccccc4c4ccccc43)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1]

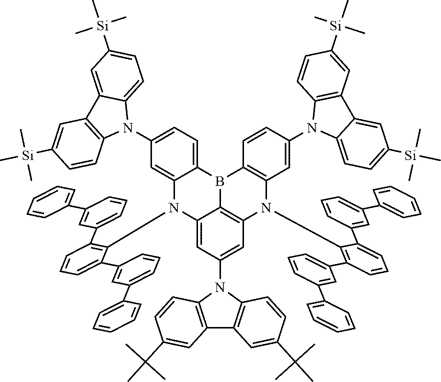

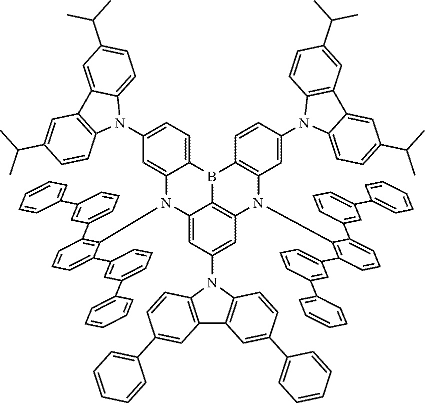 [SMILES: CC(C)c1ccc2c(c1)c1cc(C(C)C)ccc1n2-c1ccc2c(c1)N(c1c(-c3cccc(-c4ccccc4)c3)cccc1-c1cccc(-c3ccccc3)c1)c1cc(-n3c4ccc(-c5ccccc5)cc4c4cc(-c5ccccc5)ccc43)cc3c1B2c1ccc(-n2c4ccc(C(C)C)cc4c4cc(C(C)C)ccc42)cc1N3c1c(-c2cccc(-c3ccccc3)c2)cccc1-c1cccc(-c2ccccc2)c1]

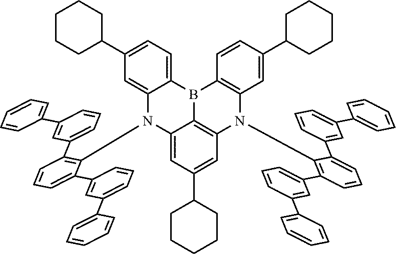 [SMILES: c1ccc(-c2cccc(-c3cccc(-c4cccc(-c5ccccc5)c4)c3N3c4cc(C5CCCCC5)ccc4B4c5ccc(C6CCCCC6)cc5N(c5c(-c6cccc(-c7ccccc7)c6)cccc5-c5cccc(-c6ccccc6)c5)c5cc(C6CCCCC6)cc3c54)c2)cc1]

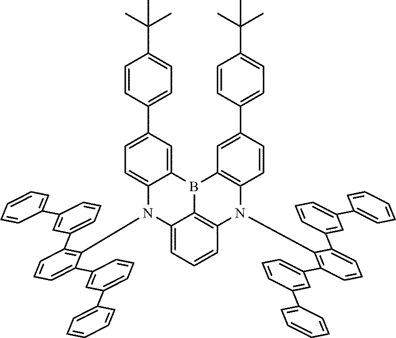 [SMILES: CC(C)(C)c1ccc(-c2ccc3c(c2)B2c4cc(-c5ccc(C(C)(C)C)cc5)ccc4N(c4c(-c5cccc(-c6ccccc6)c5)cccc4-c4cccc(-c5ccccc5)c4)c4cccc(c42)N3c2c(-c3cccc(-c4ccccc4)c3)cccc2-c2cccc(-c3ccccc3)c2)cc1]

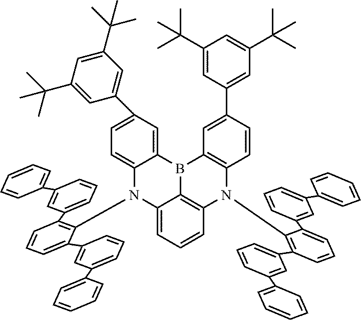 [SMILES: CC(C)(C)c1cc(-c2ccc3c(c2)B2c4cc(-c5cc(C(C)(C)C)cc(C(C)(C)C)c5)ccc4N(c4c(-c5cccc(-c6ccccc6)c5)cccc4-c4cccc(-c5ccccc5)c4)c4cccc(c42)N3c2c(-c3cccc(-c4ccccc4)c3)cccc2-c2cccc(-c3ccccc3)c2)cc(C(C)(C)C)c1]

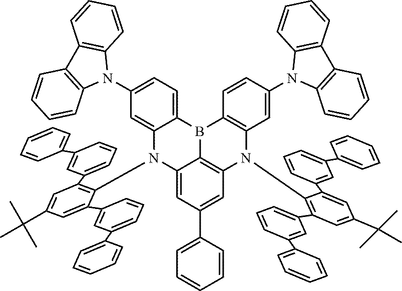 [SMILES: CC(C)(C)c1cc(-c2cccc(-c3ccccc3)c2)c(N2c3cc(-n4c5ccccc5c5ccccc54)ccc3B3c4ccc(-n5c6ccccc6c6ccccc65)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1]

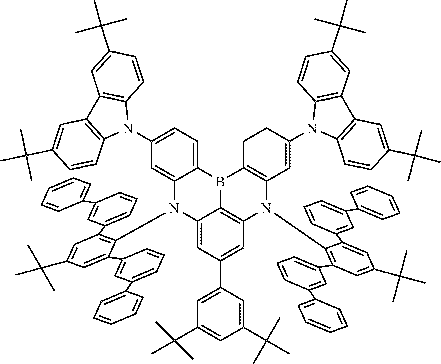 [SMILES: CC(C)(C)c1cc(-c2cc3c4c(c2)N(c2c(-c5cccc(-c6ccccc6)c5)cc(C(C)(C)C)cc2-c2cccc(-c5ccccc5)c2)c2cc(-n5c6ccc(C(C)(C)C)cc6c6cc(C(C)(C)C)ccc65)ccc2B4C2=C(C=C(n4c5ccc(C(C)(C)C)cc5c5cc(C(C)(C)C)ccc54)CC2)N3c2c(-c3cccc(-c4ccccc4)c3)cc(C(C)(C)C)cc2-c2cccc(-c3ccccc3)c2)cc(C(C)(C)C)c1]

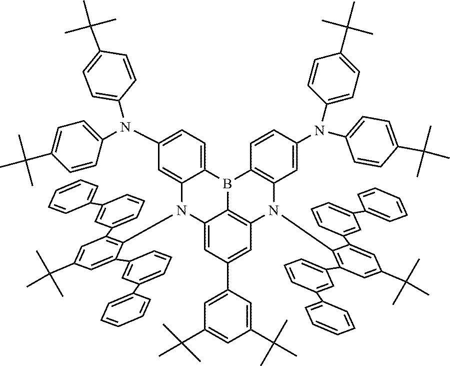 [SMILES: CC(C)(C)c1ccc(N(c2ccc(C(C)(C)C)cc2)c2ccc3c(c2)N(c2c(-c4cccc(-c5ccccc5)c4)cc(C(C)(C)C)cc2-c2cccc(-c4ccccc4)c2)c2cc(-c4cc(C(C)(C)C)cc(C(C)(C)C)c4)cc4c2B3c2ccc(N(c3ccc(C(C)(C)C)cc3)c3ccc(C(C)(C)C)cc3)cc2N4c2c(-c3cccc(-c4ccccc4)c3)cc(C(C)(C)C)cc2-c2cccc(-c3ccccc3)c2)cc1]

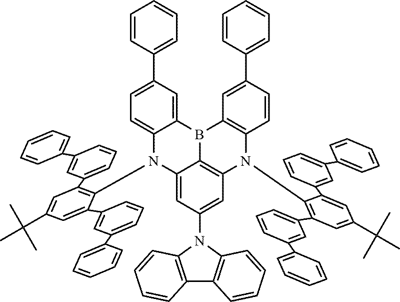 [SMILES: CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc(-c5ccccc5)c4)c4cc(-n5c6ccccc6c6ccccc65)cc2c43)c(-c2cccc(-c3ccccc3)c2)c1]

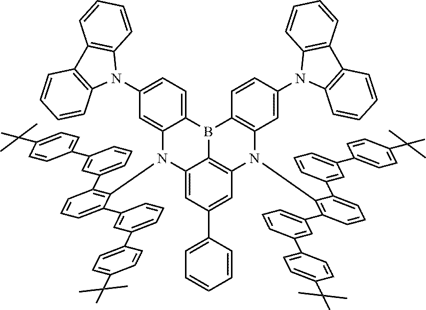 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-c6ccccc6)cc3c54)c2)cc1]

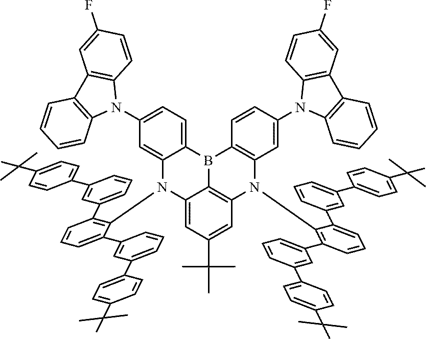 [SMILES: CC(C)(C)c1ccc(-c2cccc(-c3cccc(-c4cccc(-c5ccc(C(C)(C)C)cc5)c4)c3N3c4cc(-n5c6ccccc6c6cc(F)ccc65)ccc4B4c5ccc(-n6c7ccccc7c7cc(F)ccc76)cc5N(c5c(-c6cccc(-c7ccc(C(C)(C)C)cc7)c6)cccc5-c5cccc(-c6ccc(C(C)(C)C)cc6)c5)c5cc(C(C)(C)C)cc3c54)c2)cc1]

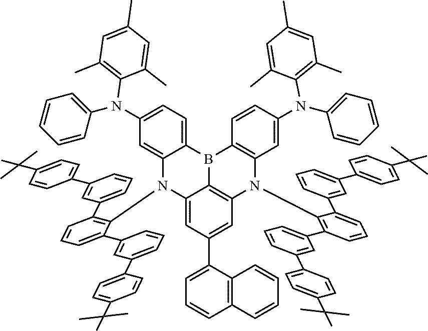 [SMILES: Cc1cc(C)c(N(c2ccccc2)c2ccc3c(c2)N(c2c(-c4cccc(-c5ccc(C(C)(C)C)cc5)c4)cccc2-c2cccc(-c4ccc(C(C)(C)C)cc4)c2)c2cc(-c4cccc5ccccc45)cc4c2B3c2ccc(N(c3ccccc3)c3c(C)cc(C)cc3C)cc2N4c2c(-c3cccc(-c4ccc(C(C)(C)C)cc4)c3)cccc2-c2cccc(-c3ccc(C(C)(C)C)cc3)c2)c(C)c1]

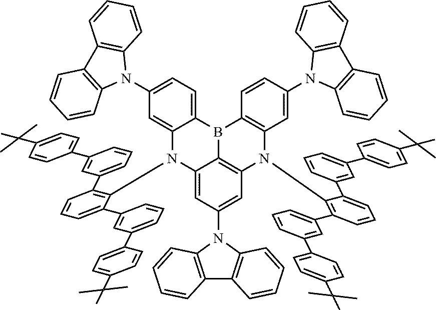 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-n6c7ccccc7c7ccccc76)cc3c54)c2)cc1]

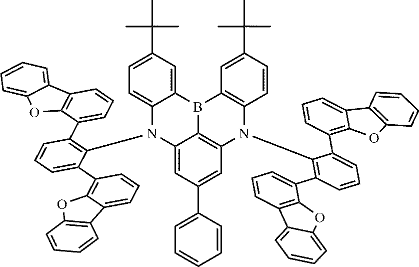 [SMILES: CC(C)(C)c1ccc2c(c1)B1c3cc(C(C)(C)C)ccc3N(c3c(-c4cccc5c4oc4ccccc45)cccc3-c3cccc4c3oc3ccccc34)c3cc(-c4ccccc4)cc(c31)N2c1c(-c2cccc3c2oc2ccccc23)cccc1-c1cccc2c1oc1ccccc12]

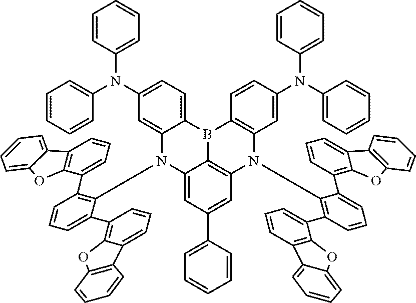 [SMILES: c1ccc(-c2cc3c4c(c2)N(c2c(-c5cccc6c5oc5ccccc56)cccc2-c2cccc5c2oc2ccccc25)c2cc(N(c5ccccc5)c5ccccc5)ccc2B4c2ccc(N(c4ccccc4)c4ccccc4)cc2N3c2c(-c3cccc4c3oc3ccccc34)cccc2-c2cccc3c2oc2ccccc23)cc1]

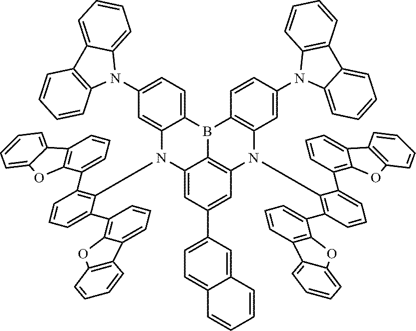 [SMILES: c1cc(-c2cccc3c2oc2ccccc23)c(N2c3cc(-n4c5ccccc5c5ccccc54)ccc3B3c4ccc(-n5c6ccccc6c6ccccc65)cc4N(c4c(-c5cccc6c5oc5ccccc56)cccc4-c4cccc5c4oc4ccccc45)c4cc(-c5ccc6ccccc6c5)cc2c43)c(-c2cccc3c2oc2ccccc23)c1]

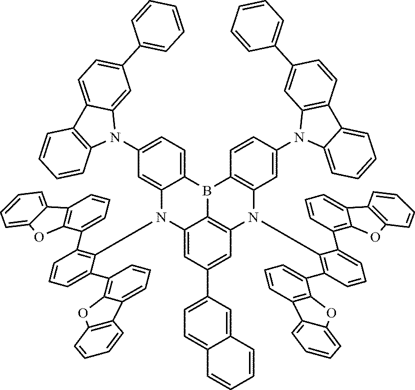 [SMILES: c1ccc(-c2ccc3c4ccccc4n(-c4ccc5c(c4)N(c4c(-c6cccc7c6oc6ccccc67)cccc4-c4cccc6c4oc4ccccc46)c4cc(-c6ccc7ccccc7c6)cc6c4B5c4ccc(-n5c7ccccc7c7ccc(-c8ccccc8)cc75)cc4N6c4c(-c5cccc6c5oc5ccccc56)cccc4-c4cccc5c4oc4ccccc45)c3c2)cc1]

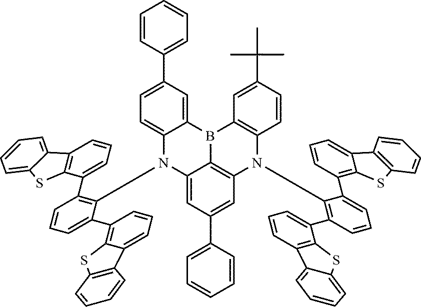 [SMILES: CC(C)(C)c1ccc2c(c1)B1c3cc(-c4ccccc4)ccc3N(c3c(-c4cccc5c4sc4ccccc45)cccc3-c3cccc4c3sc3ccccc34)c3cc(-c4ccccc4)cc(c31)N2c1c(-c2cccc3c2sc2ccccc23)cccc1-c1cccc2c1sc1ccccc12]

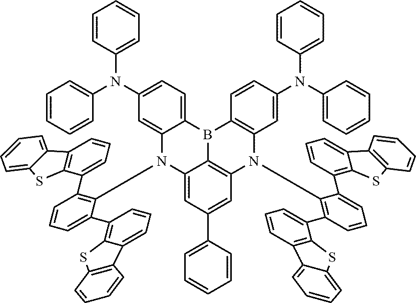 [SMILES: c1ccc(-c2cc3c4c(c2)N(c2c(-c5cccc6c5sc5ccccc56)cccc2-c2cccc5c2sc2ccccc25)c2cc(N(c5ccccc5)c5ccccc5)ccc2B4c2ccc(N(c4ccccc4)c4ccccc4)cc2N3c2c(-c3cccc4c3sc3ccccc34)cccc2-c2cccc3c2sc2ccccc23)cc1]

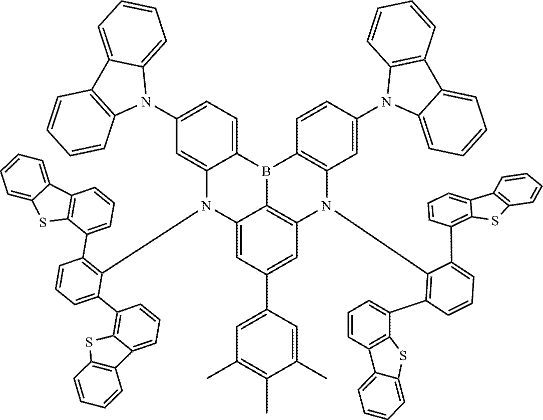 [SMILES: Cc1cc(-c2cc3c4c(c2)N(c2c(-c5cccc6c5sc5ccccc56)cccc2-c2cccc5c2sc2ccccc25)c2cc(-n5c6ccccc6c6ccccc65)ccc2B4c2ccc(-n4c5ccccc5c5ccccc54)cc2N3c2c(-c3cccc4c3sc3ccccc34)cccc2-c2cccc3c2sc2ccccc23)cc(C)c1C]

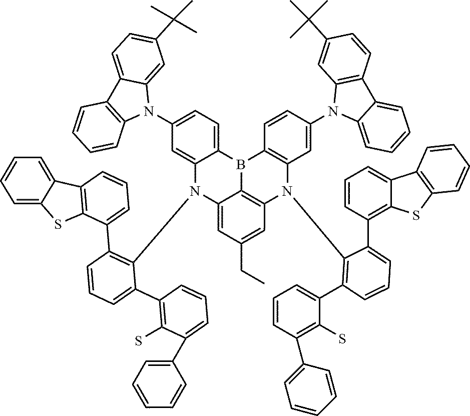 [SMILES: CCc1cc2c3c(c1)N(c1c(-c4cccc(-c5ccccc5)c4S)cccc1-c1cccc4c1sc1ccccc14)c1cc(-n4c5ccccc5c5ccc(C(C)(C)C)cc54)ccc1B3c1ccc(-n3c4ccccc4c4ccc(C(C)(C)C)cc43)cc1N2c1c(-c2cccc(-c3ccccc3)c2S)cccc1-c1cccc2c1sc1ccccc12]

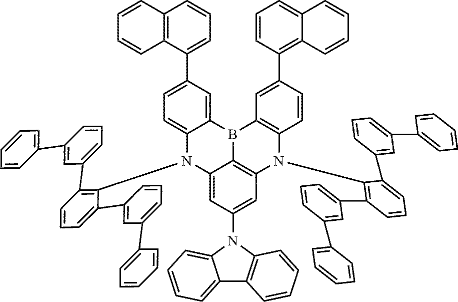 [SMILES: c1ccc(-c2cccc(-c3cccc(-c4cccc(-c5ccccc5)c4)c3N3c4ccc(-c5cccc6ccccc56)cc4B4c5cc(-c6cccc7ccccc67)ccc5N(c5c(-c6cccc(-c7ccccc7)c6)cccc5-c5cccc(-c6ccccc6)c5)c5cc(-n6c7ccccc7c7ccccc76)cc3c54)c2)cc1]

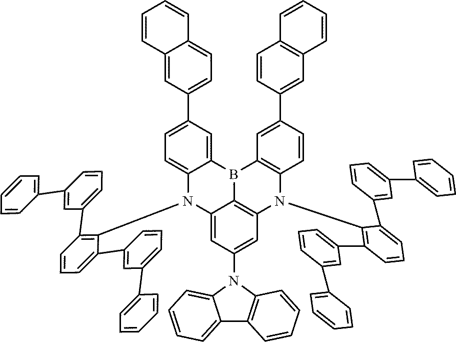 [SMILES: c1ccc(-c2cccc(-c3cccc(-c4cccc(-c5ccccc5)c4)c3N3c4ccc(-c5ccc6ccccc6c5)cc4B4c5cc(-c6ccc7ccccc7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1]

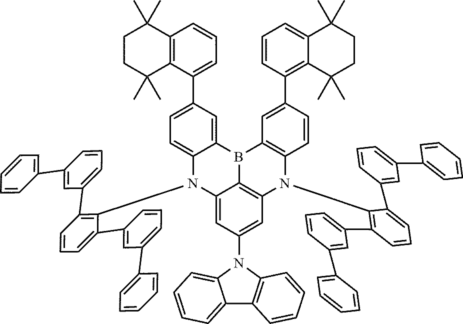 [SMILES: CC1(C)CCC(C)(C)c2c(-c3ccc4c(c3)B3c5cc(-c6cccc7c6C(C)(C)CCC7(C)C)ccc5N(c5c(-c6cccc(-c7ccccc7)c6)cccc5-c5cccc(-c6ccccc6)c5)c5cc(-n6c7ccccc7c7ccccc76)cc(c53)N4c3c(-c4cccc(-c5ccccc5)c4)cccc3-c3cccc(-c4ccccc4)c3)cccc21]

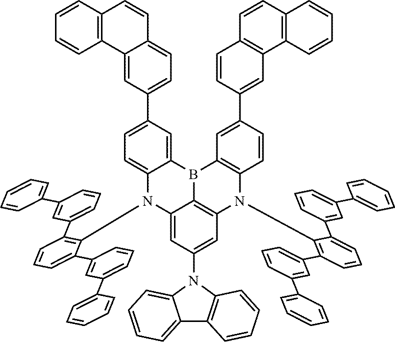 [SMILES: c1ccc(-c2cccc(-c3cccc(-c4cccc(-c5ccccc5)c4)c3N3c4ccc(-c5ccc6ccc7ccccc7c6c5)cc4B4c5cc(-c6ccc7ccc8ccccc8c7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1]

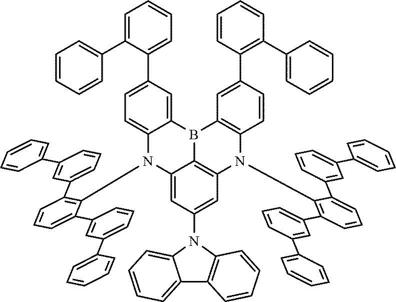 [SMILES: c1ccc(-c2cccc(-c3cccc(-c4cccc(-c5ccccc5)c4)c3N3c4ccc(-c5ccccc5-c5ccccc5)cc4B4c5cc(-c6ccccc6-c6ccccc6)ccc5N(c5c(-c6cccc(-c7ccccc7)c6)cccc5-c5cccc(-c6ccccc6)c5)c5cc(-n6c7ccccc7c7ccccc76)cc3c54)c2)cc1]

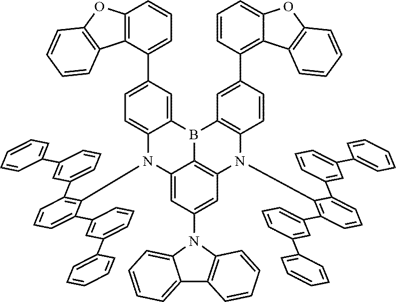 [SMILES: c1ccc(-c2cccc(-c3cccc(-c4cccc(-c5ccccc5)c4)c3N3c4ccc(-c5cccc6oc7ccccc7c56)cc4B4c5cc(-c6cccc7oc8ccccc8c67)ccc5N(c5c(-c6cccc(-c7ccccc7)c6)cccc5-c5cccc(-c6ccccc6)c5)c5cc(-n6c7ccccc7c7ccccc76)cc3c54)c2)cc1]

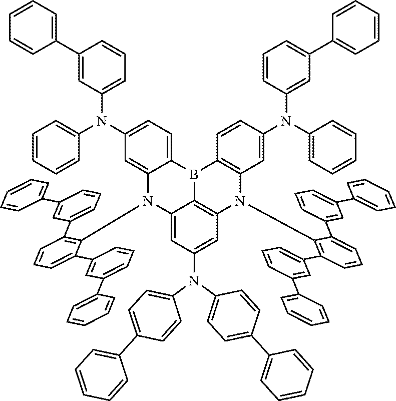 [SMILES: c1ccc(-c2ccc(N(c3ccc(-c4ccccc4)cc3)c3cc4c5c(c3)N(c3c(-c6cccc(-c7ccccc7)c6)cccc3-c3cccc(-c6ccccc6)c3)c3cc(N(c6ccccc6)c6cccc(-c7ccccc7)c6)ccc3B5c3ccc(N(c5ccccc5)c5cccc(-c6ccccc6)c5)cc3N4c3c(-c4cccc(-c5ccccc5)c4)cccc3-c3cccc(-c4ccccc4)c3)cc2)cc1]

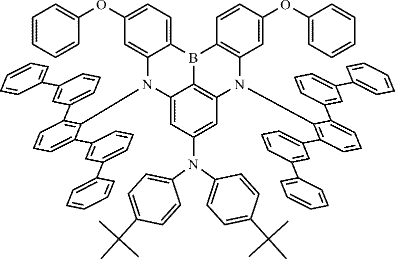 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(Oc5ccccc5)ccc2B4c2ccc(Oc4ccccc4)cc2N3c2c(-c3cccc(-c4ccccc4)c3)cccc2-c2cccc(-c3ccccc3)c2)cc1]

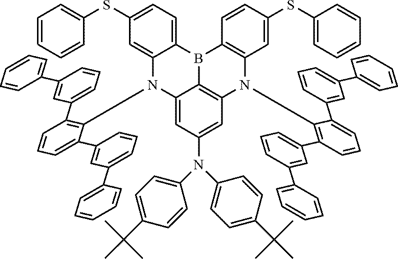 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(Sc5ccccc5)ccc2B4c2ccc(Sc4ccccc4)cc2N3c2c(-c3cccc(-c4ccccc4)c3)cccc2-c2cccc(-c3ccccc3)c2)cc1]

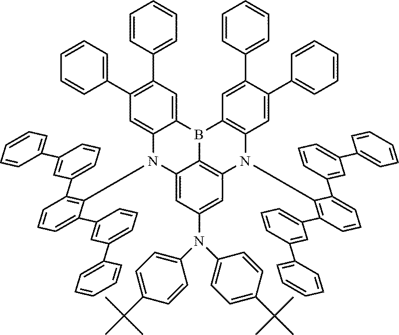 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)c(-c5ccccc5)cc2B4c2cc(-c4ccccc4)c(-c4ccccc4)cc2N3c2c(-c3cccc(-c4ccccc4)c3)cccc2-c2cccc(-c3ccccc3)c2)cc1]

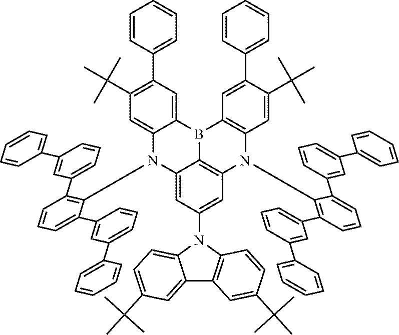 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(C(C)(C)C)c(-c4ccccc4)cc1B3c1cc(-c3ccccc3)c(C(C)(C)C)cc1N2c1c(-c2cccc(-c3ccccc3)c2)cccc1-c1cccc(-c2ccccc2)c1]

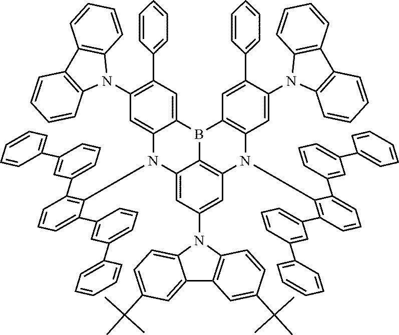 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(-n4c5ccccc5c5ccccc54)c(-c4ccccc4)cc1B3c1cc(-c3ccccc3)c(-n3c4ccccc4c4ccccc43)cc1N2c1c(-c2cccc(-c3ccccc3)c2)cccc1-c1cccc(-c2ccccc2)c1]

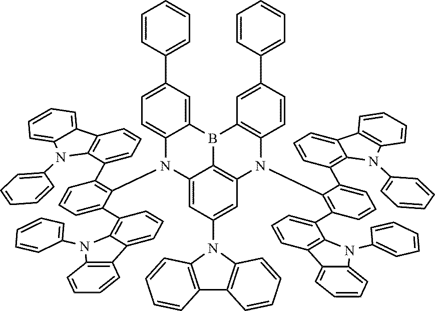 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)N3c2c(-c3cccc4c5ccccc5n(-c5ccccc5)c34)cccc2-c2cccc3c4ccccc4n(-c4ccccc4)c23)cc1]

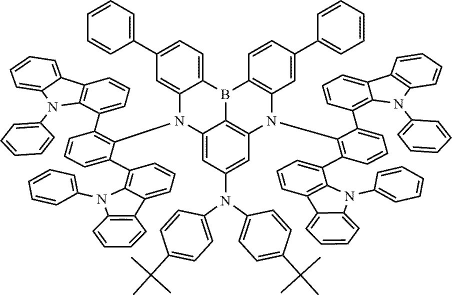 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2N3c2c(-c3cccc4c5ccccc5n(-c5ccccc5)c34)cccc2-c2cccc3c4ccccc4n(-c4ccccc4)c23)cc1]

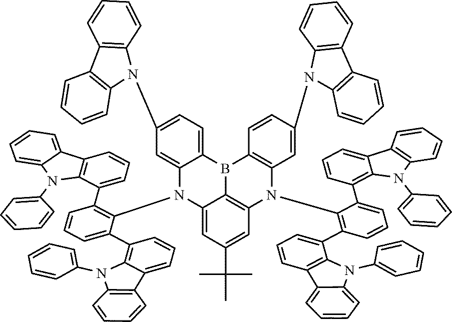 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1N2c1c(-c2cccc3c4ccccc4n(-c4ccccc4)c23)cccc1-c1cccc2c3ccccc3n(-c3ccccc3)c12]

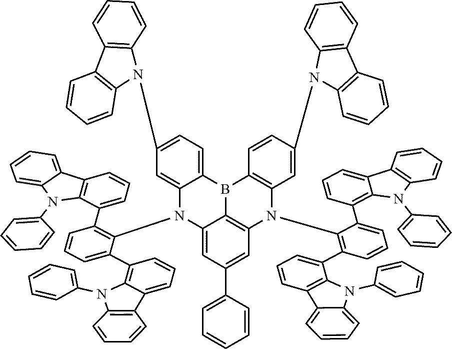 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2N3c2c(-c3cccc4c5ccccc5n(-c5ccccc5)c34)cccc2-c2cccc3c4ccccc4n(-c4ccccc4)c23)cc1]

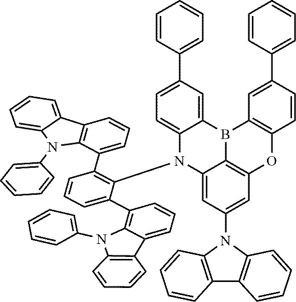 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)O3)cc1]

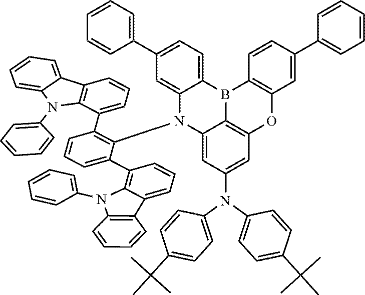 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2O3)cc1]

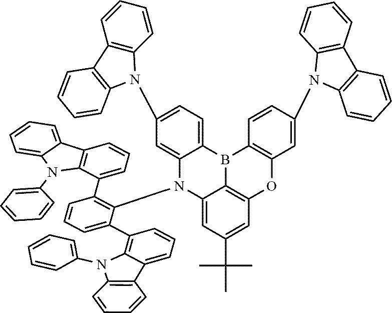 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1O2]

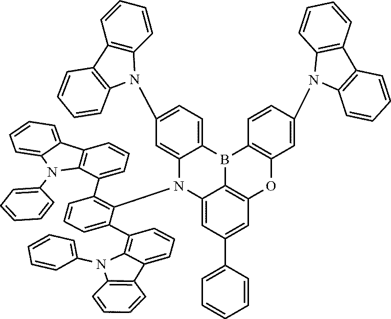 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2O3)cc1]

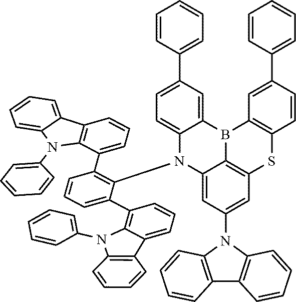 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)S3)cc1]

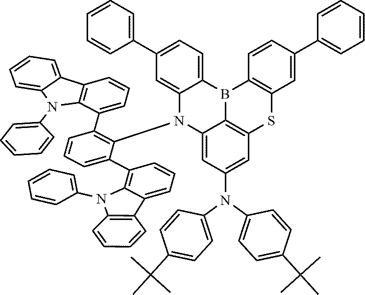 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2S3)cc1]

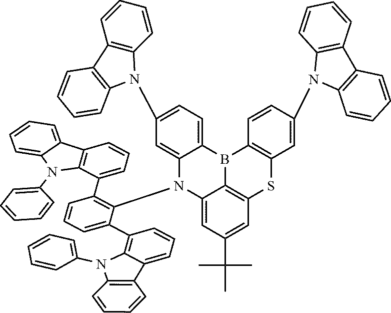 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1S2]

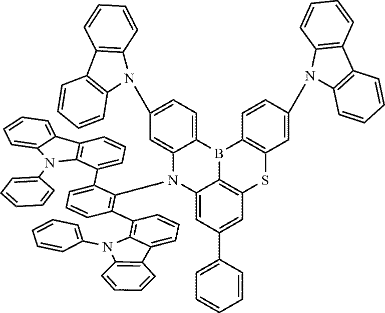 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2S3)cc1]

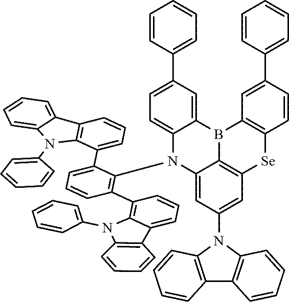 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)[Se]3)cc1]

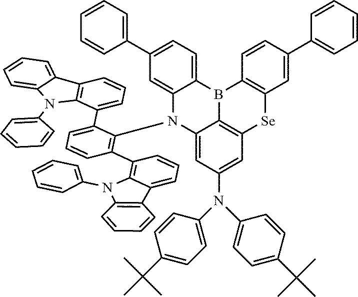 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2[Se]3)cc1]

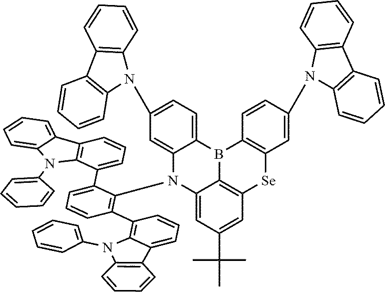 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1[Se]2]

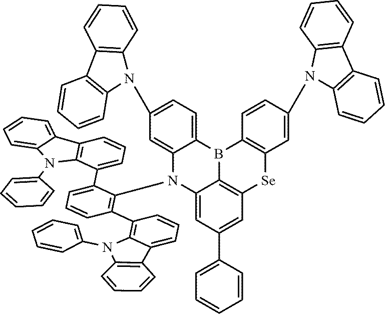 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2[Se]3)cc1]

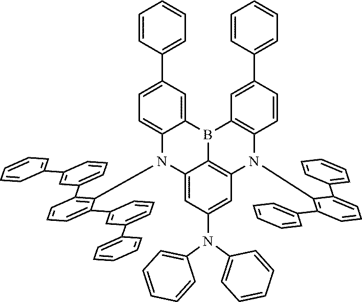 [SMILES: c1ccc(-c2cccc(-c3cccc(-c4cccc(-c5ccccc5)c4)c3N3c4ccc(-c5ccccc5)cc4B4c5cc(-c6ccccc6)ccc5N(c5c(-c6ccccc6)cccc5-c5ccccc5)c5cc(N(c6ccccc6)c6ccccc6)cc3c54)c2)cc1]

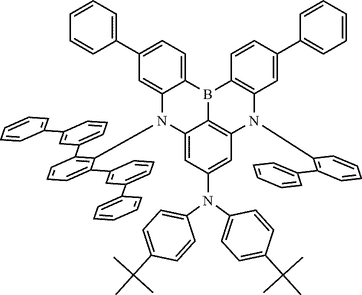 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)ccc2B4c2ccc(-c4ccccc4)cc2N3c2ccccc2-c2ccccc2)cc1]

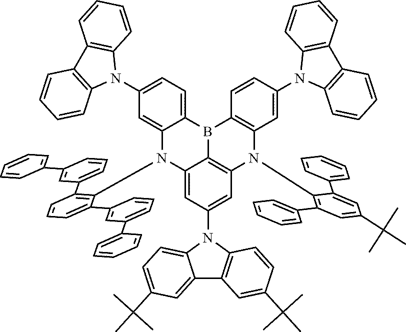 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc(-c6ccccc6)c5)cccc4-c4cccc(-c5ccccc5)c4)c4cc(-n5c6ccc(C(C)(C)C)cc6c6cc(C(C)(C)C)ccc65)cc2c43)c(-c2ccccc2)c1]

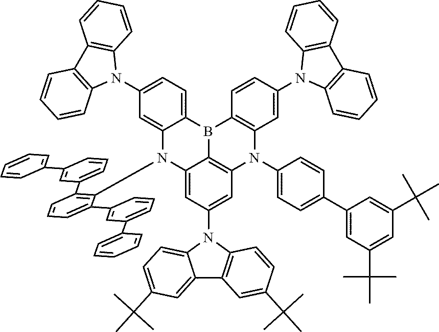 [SMILES: CC(C)(C)c1cc(-c2ccc(N3c4cc(-n5c6ccccc6c6ccccc65)ccc4B4c5ccc(-n6c7ccccc7c7ccccc76)cc5N(c5c(-c6cccc(-c7ccccc7)c6)cccc5-c5cccc(-c6ccccc6)c5)c5cc(-n6c7ccc(C(C)(C)C)cc7c7cc(C(C)(C)C)ccc76)cc3c54)cc2)cc(C(C)(C)C)c1]

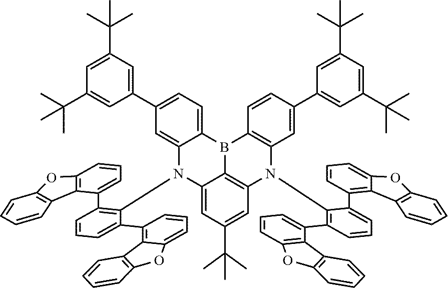 [SMILES: CC(C)(C)c1cc(-c2ccc3c(c2)N(c2c(-c4cccc5oc6ccccc6c45)cccc2-c2cccc4oc5ccccc5c24)c2cc(C(C)(C)C)cc4c2B3c2ccc(-c3cc(C(C)(C)C)cc(C(C)(C)C)c3)cc2N4c2c(-c3cccc4oc5ccccc5c34)cccc2-c2cccc3oc4ccccc4c23)cc(C(C)(C)C)c1]

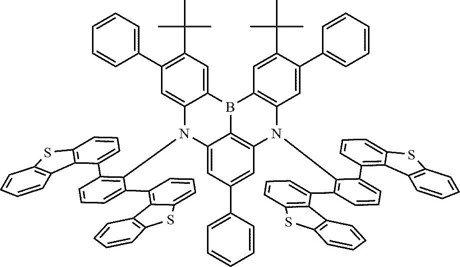 [SMILES: CC(C)(C)c1cc2c(cc1-c1ccccc1)N(c1c(-c3cccc4sc5ccccc5c34)cccc1-c1cccc3sc4ccccc4c13)c1cc(-c3ccccc3)cc3c1B2c1cc(C(C)(C)C)c(-c2ccccc2)cc1N3c1c(-c2cccc3sc4ccccc4c23)cccc1-c1cccc2sc3ccccc3c12]

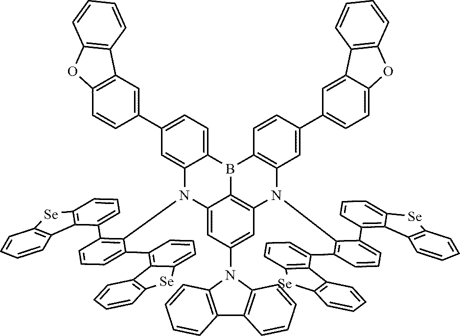 [SMILES: c1cc(-c2cccc3[se]c4ccccc4c23)c(N2c3cc(-c4ccc5oc6ccccc6c5c4)ccc3B3c4ccc(-c5ccc6oc7ccccc7c6c5)cc4N(c4c(-c5cccc6[se]c7ccccc7c56)cccc4-c4cccc5[se]c6ccccc6c45)c4cc(-n5c6ccccc6c6ccccc65)cc2c43)c(-c2cccc3[se]c4ccccc4c23)c1]

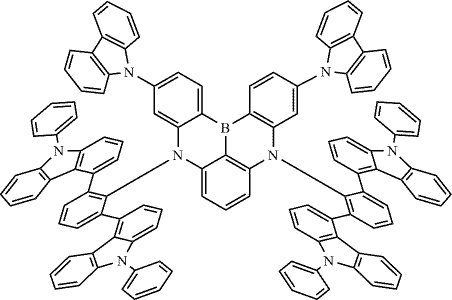 [SMILES: c1ccc(-n2c3ccccc3c3c(-c4cccc(-c5cccc6c5c5ccccc5n6-c5ccccc5)c4N4c5cc(-n6c7ccccc7c7ccccc76)ccc5B5c6ccc(-n7c8ccccc8c8ccccc87)cc6N(c6c(-c7cccc8c7c7ccccc7n8-c7ccccc7)cccc6-c6cccc7c6c6ccccc6n7-c6ccccc6)c6cccc4c65)cccc32)cc1]

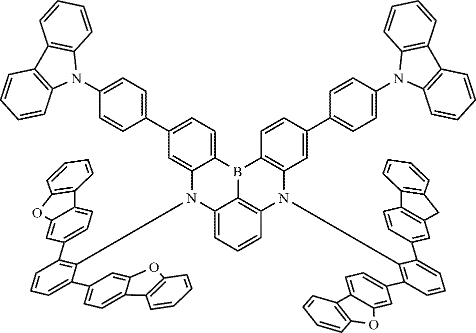 [SMILES: c1ccc2c(c1)Cc1cc(-c3cccc(-c4ccc5c(c4)oc4ccccc45)c3N3c4cc(-c5ccc(-n6c7ccccc7c7ccccc76)cc5)ccc4B4c5ccc(-c6ccc(-n7c8ccccc8c8ccccc87)cc6)cc5N(c5c(-c6ccc7c(c6)oc6ccccc67)cccc5-c5ccc6c(c5)oc5ccccc56)c5cccc3c54)ccc1-2]

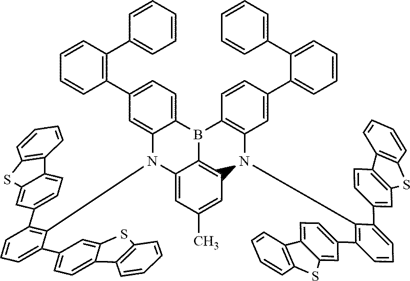

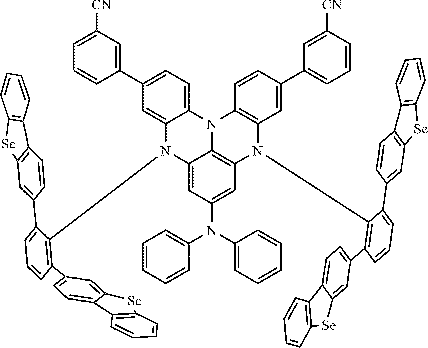 [SMILES: N#Cc1cccc(-c2ccc3c(c2)N(c2c(-c4ccc5c(c4)[se]c4ccccc45)cccc2-c2ccc4c(c2)[se]c2ccccc24)c2cc(N(c4ccccc4)c4ccccc4)cc4c2N3c2ccc(-c3cccc(C#N)c3)cc2N4c2c(-c3ccc4c(c3)[se]c3ccccc34)cccc2-c2ccc3c(c2)[se]c2ccccc23)c1]

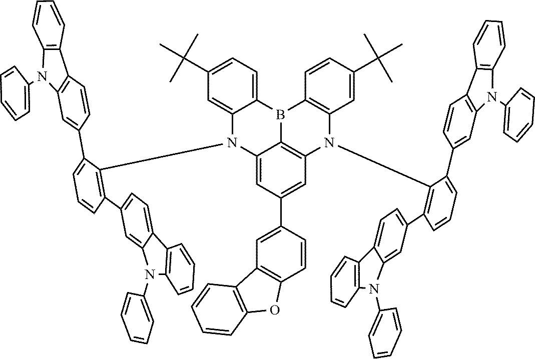 [SMILES: CC(C)(C)c1ccc2c(c1)N(c1c(-c3ccc4c5ccccc5n(-c5ccccc5)c4c3)cccc1-c1ccc3c4ccccc4n(-c4ccccc4)c3c1)c1cc(-c3ccc4oc5ccccc5c4c3)cc3c1B2c1ccc(C(C)(C)C)cc1N3c1c(-c2ccc3c4ccccc4n(-c4ccccc4)c3c2)cccc1-c1ccc2c3ccccc3n(-c3ccccc3)c2c1]

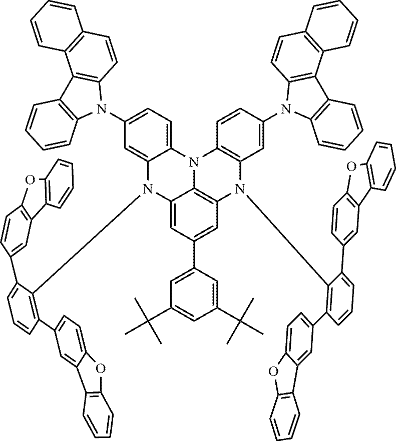 [SMILES: CC(C)(C)c1cc(-c2cc3c4c(c2)N(c2c(-c5ccc6oc7ccccc7c6c5)cccc2-c2ccc5oc6ccccc6c5c2)c2cc(-n5c6ccccc6c6c7ccccc7ccc65)ccc2N4c2ccc(-n4c5ccccc5c5c6ccccc6ccc54)cc2N3c2c(-c3ccc4oc5ccccc5c4c3)cccc2-c2ccc3oc4ccccc4c3c2)cc(C(C)(C)C)c1]

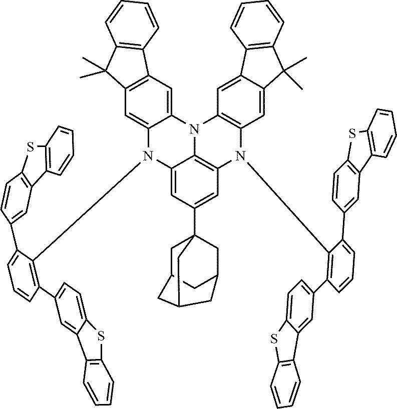 [SMILES: CC1(C)c2ccccc2-c2cc3c(cc21)N(c1c(-c2ccc4sc5ccccc5c4c2)cccc1-c1ccc2sc4ccccc4c2c1)c1cc(C24CC5CC(CC(C5)C2)C4)cc2c1N3c1cc3c(cc1N2c1c(-c2ccc4sc5ccccc5c4c2)cccc1-c1ccc2sc4ccccc4c2c1)C(C)(C)c1ccccc1-3]

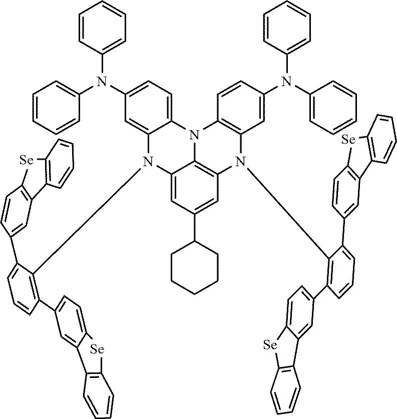 [SMILES: c1ccc(N(c2ccccc2)c2ccc3c(c2)N(c2c(-c4ccc5[se]c6ccccc6c5c4)cccc2-c2ccc4[se]c5ccccc5c4c2)c2cc(C4CCCCC4)cc4c2N3c2ccc(N(c3ccccc3)c3ccccc3)cc2N4c2c(-c3ccc4[se]c5ccccc5c4c3)cccc2-c2ccc3[se]c4ccccc4c3c2)cc1]

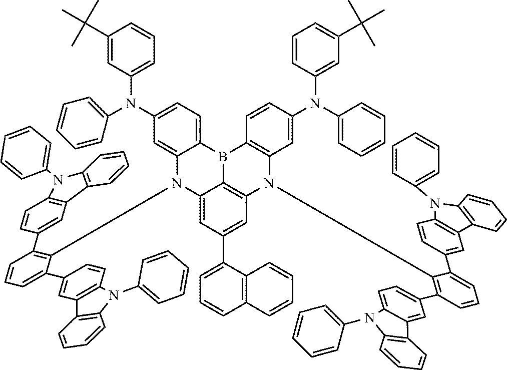 [SMILES: CC(C)(C)c1cccc(N(c2ccccc2)c2ccc3c(c2)N(c2c(-c4ccc5c(c4)c4ccccc4n5-c4ccccc4)cccc2-c2ccc4c(c2)c2ccccc2n4-c2ccccc2)c2cc(-c4cccc5ccccc45)cc4c2B3c2ccc(N(c3ccccc3)c3cccc(C(C)(C)C)c3)cc2N4c2c(-c3ccc4c(c3)c3ccccc3n4-c3ccccc3)cccc2-c2ccc3c(c2)c2ccccc2n3-c2ccccc2)c1]

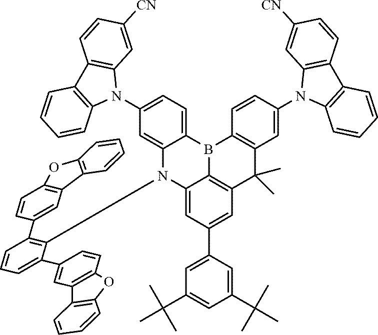

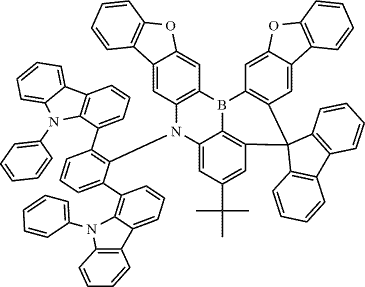 [SMILES: CC(C)(C)c1cc2c3c(c1)C1(c4cc5c(cc4B3c3cc4oc6ccccc6c4cc3N2c2c(-c3cccc4c6ccccc6n(-c6ccccc6)c34)cccc2-c2cccc3c4ccccc4n(-c4ccccc4)c23)oc2ccccc25)c2ccccc2-c2ccccc21]

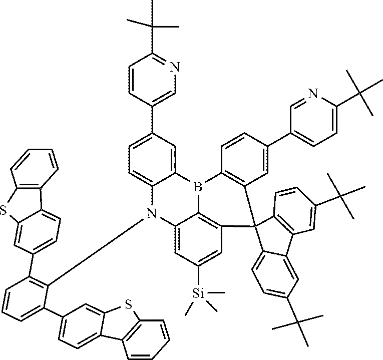 [SMILES: CC(C)(C)c1ccc2c(c1)-c1cc(C(C)(C)C)ccc1C21c2cc(-c3ccc(C(C)(C)C)nc3)ccc2B2c3cc(-c4ccc(C(C)(C)C)nc4)ccc3N(c3c(-c4ccc5c(c4)sc4ccccc45)cccc3-c3ccc4c(c3)sc3ccccc34)c3cc([Si](C)(C)C)cc1c32]

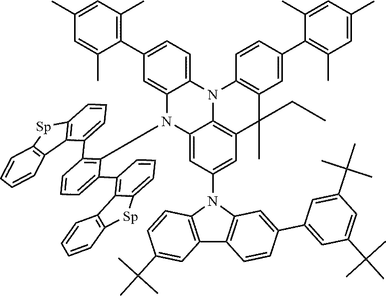

In the structure of the compounds of Compound Group 1, D refers to a deuterium atom.

The light emitting spectrum of the first compound of an embodiment, represented by Formula 1 may have a full width at a half maximum of about 20-60 nm. Because the light emitting spectrum of the first compound of an embodiment, represented by Formula 1 has the full width at half maximum in the range, when applied to an element, emission efficiency may be improved. In some embodiments, when utilized as a material for a blue light emitting element, element lifetime may be improved (increased).

The first compound of an embodiment, represented by Formula 1 may be a material for emitting thermally activated delayed fluorescence. In some embodiments, the first compound of an embodiment, represented by Formula 1 may be a thermally activated delayed fluorescence dopant having a difference ΔE_{ST}) between the lowest triplet excitation energy level (T1 level) and the lowest singlet excitation energy level (S1 level) of about 0.2 eV or less.

The first compound of an embodiment, represented by Formula 1 may be a light emitting material having a light emitting central wavelength in a wavelength region of about 440 nm to about 480 nm. For example, the first compound of an embodiment, represented by Formula 1 may be a blue thermally activated delayed fluorescence (TADF) dopant. However, an embodiment of the present disclosure is not limited thereto. In case of utilizing the first compound of an embodiment as a light emitting material, the first compound may be utilized as a dopant material emitting light in one or more suitable wavelength regions including a red light emitting dopant, a green light emitting dopant, etc.

In the light emitting element ED of an embodiment, an emission layer EML may be to emit delayed fluorescence. For example, the emission layer EML may be to emit thermally activated delayed fluorescence (TADF).

In some embodiments, the emission layer EML of the light emitting element ED may be to emit blue light. For example, the emission layer EML of the light emitting element ED of an embodiment may be to emit blue light having a central wavelength of about 440 nm to about 480 nm. However, an embodiment of the present disclosure is not limited thereto. The emission layer EML may emit blue light of greater than about 480 nm, or emit green light or red light.

In the light emitting element ED of an embodiment, the emission layer EML may include a host for emitting delayed fluorescence and a dopant for emitting delayed fluorescence and may include the first compound as a dopant for emitting delayed fluorescence. The emission layer EML may include at least one selected from among the fused polycyclic compounds represented in Compound Group 1 as a thermally activated delayed fluorescence dopant.

As described above, in the light emitting element ED of an embodiment, the emission layer EML may include a host. The host may play the role of not emitting light but transferring energy to a dopant in the light emitting element ED. The emission layer EML may include one or more types (kinds) of hosts. For example, the emission layer EML may include two different types (kinds) of hosts. In the embodiment in which the emission layer EML includes two types (kinds) of hosts, the two types (kinds) of hosts may include a hole transport host and an electron transport host. However, an embodiment of the present disclosure is not limited thereto, and the emission layer EML may include one type or kind of a host or a mixture of two or more different types (kinds) of hosts.

In an embodiment, the emission layer EML may include two different hosts. The host may include a second compound and a third compound which is different from the second compound. The host may include a second compound having a hole transport moiety and a third compound having an electron transport moiety. In the light emitting element ED of an embodiment, the second compound and the third compound of the host may form an exciplex.

In an embodiment, the emission layer EML may include a second compound represented by Formula HT. For example, the second compound may also be utilized as a hole transport host material.

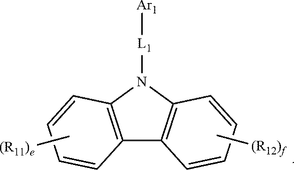

In Formula HT, L₁ may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, Ar₁ may be a substituted or unsubstituted aryl group of 6 to 30 ring-forming carbon atoms, or a substituted or unsubstituted heteroaryl group of 2 to 30 ring-forming carbon atoms.

In Formula HT, R₁₁ and R₁₂ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₁₁ and R₁₂ may each independently be a hydrogen atom or a deuterium atom.

In Formula HT, “e” and “f” may each independently be an integer of 0 to 4, and R₁₁ and R₁₂ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, when each of “e” and “f” is an integer of 2 or more, multiple R₁₁ and multiple R₁₂ may be the same, or at least one thereof may be different. For example, in Formula HT, “e” and “f” may be 0. In this case, the carbazole group of Formula HT corresponds to an unsubstituted one.

In Formula HT, L₁ may be a direct linkage, a phenylene group, a divalent biphenyl group, a divalent carbazole group, and/or the like, but an embodiment of the present disclosure is not limited thereto. In some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but an embodiment of the present disclosure is not limited thereto.

In the light emitting element ED of an embodiment, the emission layer EML may include a compound represented by Formula ET as the third compound.

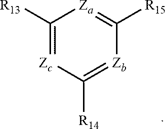

In Formula ET, at least one selected from among Zₐ to Z_{c} may be N. The remainder among Zₐ to Z_{c} may be CR₁₆. For example, the third compound represented by Formula ET may include a pyridine moiety, a pyrimidine moiety, or a triazine moiety.

In Formula ET, R₁₃ to R₁₅ may each independently be a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms.

In Formula ET, R₁₃ to R₁₅ may each independently be a substituted or unsubstituted phenyl group, a substituted or unsubstituted carbazole group, and/or the like, but an embodiment of the present disclosure is not limited thereto.

When the emission layer EML of the light emitting element ED of an embodiment includes the second compound represented by Formula HT and the third compound represented by Formula ET concurrently (e.g., simultaneously), excellent or suitable long-lifetime characteristics may be achieved. For example, in the emission layer EML of the light emitting element ED of an embodiment, the host may be an exciplex formed by the second compound represented by Formula HT and the third compound represented by Formula ET.

Among two host materials included in the emission layer EML concurrently (e.g., simultaneously), the second compound may be a hole transport host, and the third compound may be an electron transport host. The light emitting element ED of an embodiment includes both (e.g., simultaneously) the second compound having excellent or suitable hole transport properties and the third compound having excellent or suitable electron transport properties, and efficient energy transfer to dopant compounds explained below, may be possible.

The light emitting element ED of an embodiment may further include a fourth compound in addition to the first compound represented by Formula 1. The emission layer EML may include an organometallic complex including platinum (Pt) as a central metal element and ligands bonded to the central metal element, as the fourth compound. In the light emitting element ED of an embodiment, the emission layer EML may include a compound represented by Formula D-1 as the fourth compound.

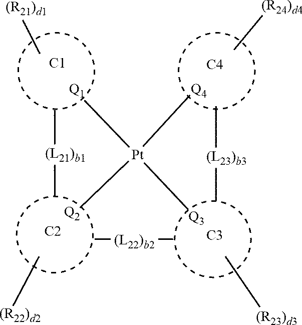

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₂₁ to L₂₃ may each independently be a direct linkage,

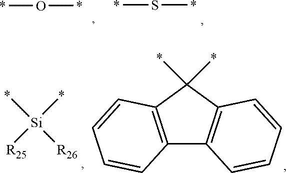

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₂₁ to L₂₃,

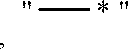

may refer to a part connected with C1 to C4.

In Formula D-1, b1 to b3 may each independently be 0 or 1. When b1 is 0, C1 and C2 may not be connected with each other. When b2 is 0, C2 and C3 may not be connected with each other. When b3 is 0, C3 and C4 may not be connected with each other.

In Formula D-1, R₂₁ to R₂₆ may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 1 to 30 ring-forming carbon atoms, and/or combined with an adjacent group to form a ring. For example, R₂₁ to R₂₆ may each independently be a methyl group or a t-butyl group.

In Formula D-1, d1 to d4 may each independently be an integer of 0 to 4. In some embodiments, when each of d1 to d4 is an integer of 2 or more, multiple R₂₁ to R₂₄ may be all the same, or at least one thereof may be different.

In Formula D-1, C1 to C4 may each independently be a substituted or unsubstituted hydrocarbon ring or a substituted or unsubstituted heterocycle, represented by any one selected from among C-1 to C-3.

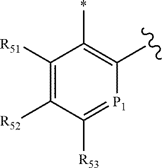

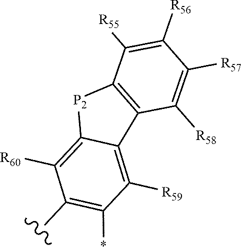

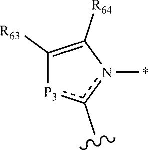

In C-1 to C-3, P₁ may be

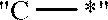

or CR₅₄, P₂ may be

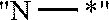

or NR₆₁, and P₃ may be

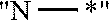

or NR₆₂. R₅₁ to R₆₄ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 6 to 30 ring-forming carbon atoms, and/or combined with an adjacent group to form a ring.

In some embodiments, in C-1 to C-3,

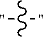

is a part connected with a Pt central metal element, and

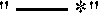

is a part connected with neighboring ring groups (C1 to C4) or linkers (L₂₁ to L₂₄).

The fourth compound represented by Formula D-1 may be a phosphorescence dopant.

In an embodiment, the first compound may be a light emitting dopant emitting blue light, and the emission layer EML may emit fluorescence. In some embodiments, for example, the emission layer EML may emit blue light of delayed fluorescence.

In an embodiment, the fourth compound included in the emission layer EML may be a sensitizer. In the light emitting element ED of an embodiment, the fourth compound included in the emission layer EML may play the role of a sensitizer, transferring energy from the host to the first compound which is a light emitting dopant. For example, the fourth compound which plays the role of an auxiliary dopant may accelerate energy transfer to the first compound which is a light emitting dopant to increase the light emitting ratio of the first compound. Accordingly, the emission efficiency of the emission layer EML of an embodiment may be improved (increased). In some embodiments, when the energy transfer to the first compound increases, excitons formed in the emission layer EML may not be accumulated in the emission layer EML but may emit light rapidly, thereby reducing the deterioration of an element. Accordingly, the lifetime of the light emitting element ED of an embodiment may increase.

In an embodiment, the weight ratio of the second compound and the third compound in the light emitting element ED may be about 4:6 to about 7:3, or about 5:5 to about 7:3. For example, the weight ratio of the second compound and the third compound may be about 4:6, about 5:5, about 6:4, or about 7:3. However, an embodiment of the present disclosure is not limited thereto. When the amounts of the second compound and third compound satisfy the above-described ratio, charge balance properties in the emission layer EML may be improved, and the emission efficiency and element lifetime may increase. When the amounts of the second compound and third compound deviate from the above-described ratio range, charge balance in the emission layer EML may be broken (unfavorable), emission efficiency may be degraded, and the element may be easily deteriorated.

The light emitting element ED of an embodiment includes all of the first compound, the second compound, the third compound, and the fourth compound, and the emission layer EML may include a combination of two host materials and two dopant materials. In the light emitting element ED of an embodiment, the emission layer EML may include two different hosts, a first compound emitting delayed fluorescence, and a fourth compound including an organometallic complex, concurrently (e.g., simultaneously), and excellent or suitable emission efficiency properties may be achieved.

In an embodiment, the second compound represented by Formula HT may be represented by any one selected from among the compounds represented in Compound Group 2. The emission layer EML may include at least one selected from among the compounds represented in Compound Group 2 as a hole transport host material.

### Compound Group 2

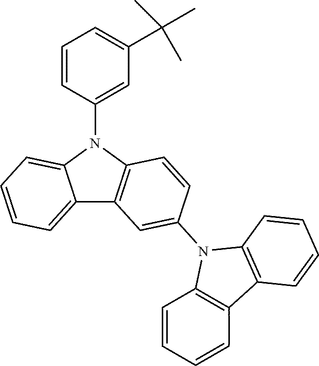 [SMILES: CC(C)(C)c1cccc(-n2c3ccccc3c3cc(-n4c5ccccc5c5ccccc54)ccc32)c1]

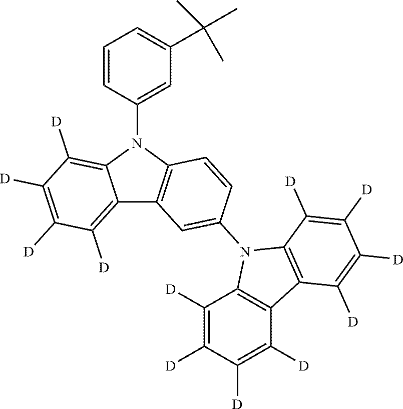 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

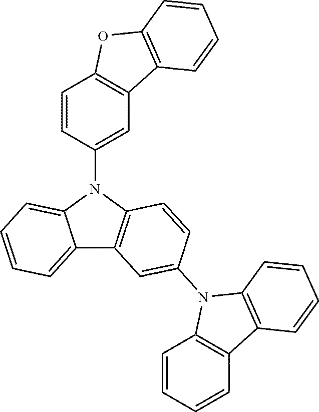 [SMILES: c1ccc2c(c1)oc1ccc(-n3c4ccccc4c4cc(-n5c6ccccc6c6ccccc65)ccc43)cc12]

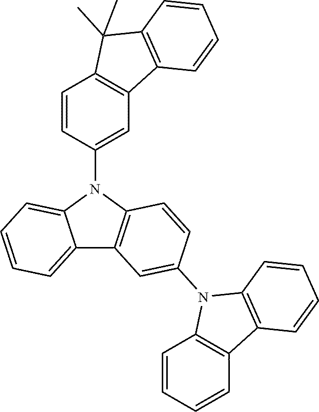 [SMILES: CC1(C)c2ccccc2-c2cc(-n3c4ccccc4c4cc(-n5c6ccccc6c6ccccc65)ccc43)ccc21]

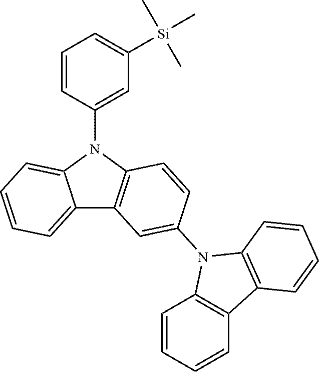 [SMILES: C[Si](C)(C)c1cccc(-n2c3ccccc3c3cc(-n4c5ccccc5c5ccccc54)ccc32)c1]

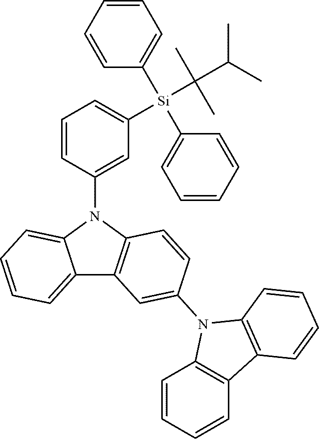 [SMILES: CC(C)C(C)(C)[Si](c1ccccc1)(c1ccccc1)c1cccc(-n2c3ccccc3c3cc(-n4c5ccccc5c5ccccc54)ccc32)c1]

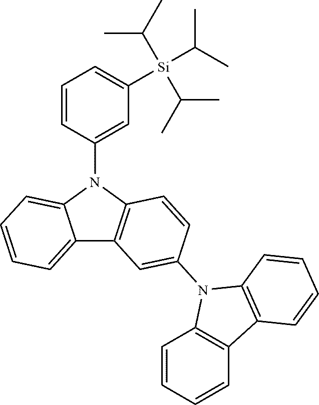 [SMILES: CC(C)[Si](c1cccc(-n2c3ccccc3c3cc(-n4c5ccccc5c5ccccc54)ccc32)c1)(C(C)C)C(C)C]

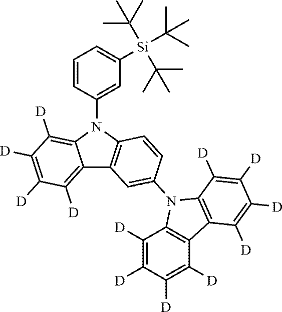 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc([Si](C(C)(C)C)(C(C)(C)C)C(C)(C)C)c1]

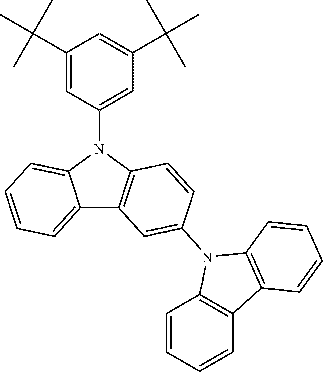 [SMILES: CC(C)(C)c1cc(-n2c3ccccc3c3cc(-n4c5ccccc5c5ccccc54)ccc32)cc(C(C)(C)C)c1]

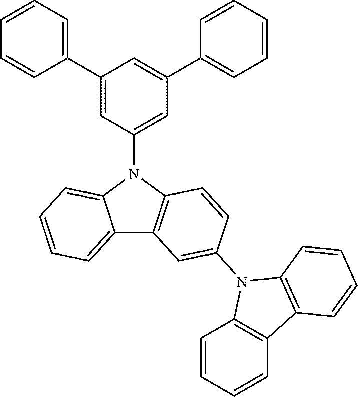 [SMILES: c1ccc(-c2cc(-c3ccccc3)cc(-n3c4ccccc4c4cc(-n5c6ccccc6c6ccccc65)ccc43)c2)cc1]

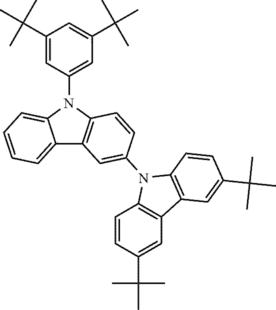 [SMILES: CC(C)(C)c1cc(-n2c3ccccc3c3cc(-n4c5ccc(C(C)(C)C)cc5c5cc(C(C)(C)C)ccc54)ccc32)cc(C(C)(C)C)c1]

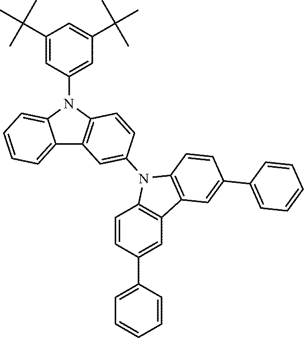 [SMILES: CC(C)(C)c1cc(-n2c3ccccc3c3cc(-n4c5ccc(-c6ccccc6)cc5c5cc(-c6ccccc6)ccc54)ccc32)cc(C(C)(C)C)c1]

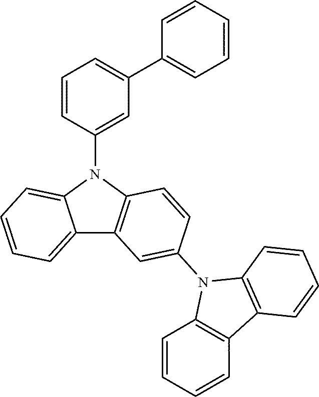 [SMILES: c1ccc(-c2cccc(-n3c4ccccc4c4cc(-n5c6ccccc6c6ccccc65)ccc43)c2)cc1]

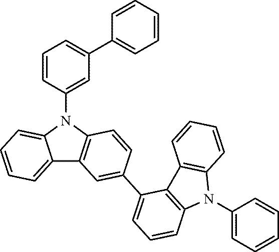 [SMILES: c1ccc(-c2cccc(-n3c4ccccc4c4cc(-c5cccc6c5c5ccccc5n6-c5ccccc5)ccc43)c2)cc1]

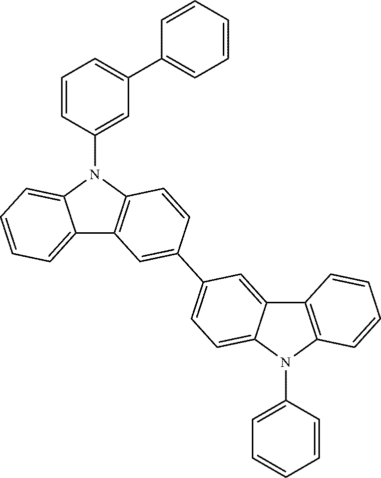 [SMILES: c1ccc(-c2cccc(-n3c4ccccc4c4cc(-c5ccc6c(c5)c5ccccc5n6-c5ccccc5)ccc43)c2)cc1]

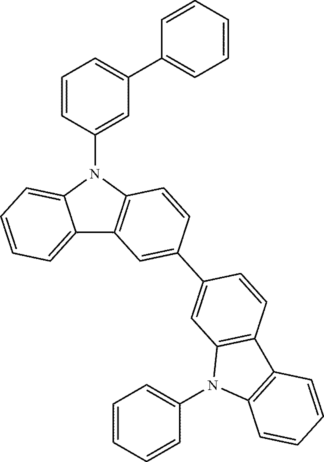 [SMILES: c1ccc(-c2cccc(-n3c4ccccc4c4cc(-c5ccc6c7ccccc7n(-c7ccccc7)c6c5)ccc43)c2)cc1]

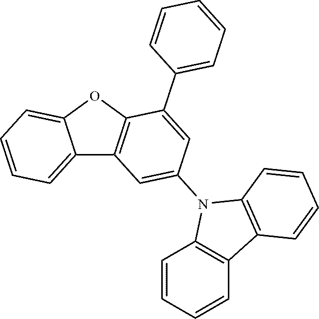 [SMILES: c1ccc(-c2cc(-n3c4ccccc4c4ccccc43)cc3c2oc2ccccc23)cc1]

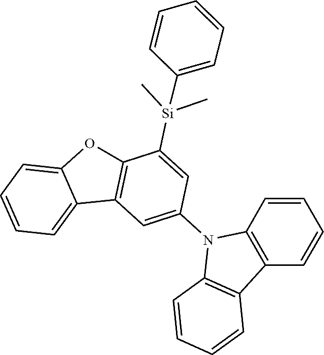 [SMILES: C[Si](C)(c1ccccc1)c1cc(-n2c3ccccc3c3ccccc32)cc2c1oc1ccccc12]

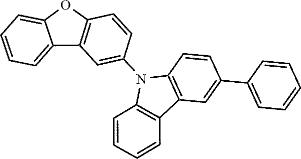 [SMILES: c1ccc(-c2ccc3c(c2)c2ccccc2n3-c2ccc3oc4ccccc4c3c2)cc1]

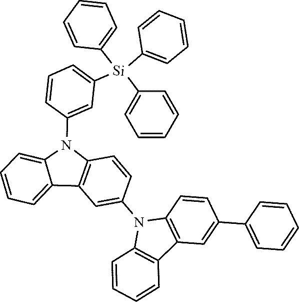 [SMILES: c1ccc(-c2ccc3c(c2)c2ccccc2n3-c2ccc3c(c2)c2ccccc2n3-c2cccc([Si](c3ccccc3)(c3ccccc3)c3ccccc3)c2)cc1]

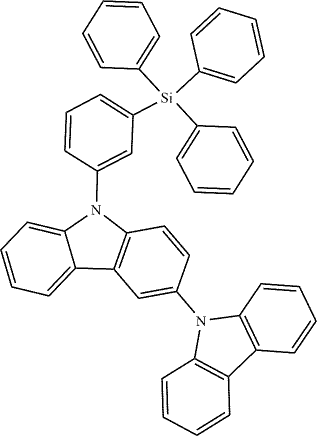 [SMILES: c1ccc([Si](c2ccccc2)(c2ccccc2)c2cccc(-n3c4ccccc4c4cc(-n5c6ccccc6c6ccccc65)ccc43)c2)cc1]

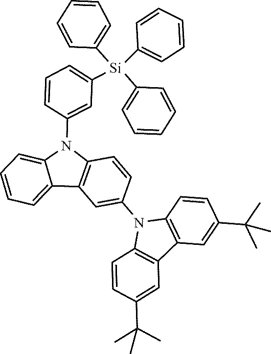 [SMILES: CC(C)(C)c1ccc2c(c1)c1cc(C(C)(C)C)ccc1n2-c1ccc2c(c1)c1ccccc1n2-c1cccc([Si](c2ccccc2)(c2ccccc2)c2ccccc2)c1]

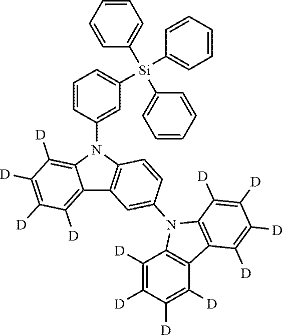 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc([Si](c2ccccc2)(c2ccccc2)c2ccccc2)c1]

In an embodiment, the third compound represented by Formula ET may be represented by any one selected from among the compounds represented in Compound Group 3. The emission layer EML may include at least one selected from among the compounds represented in Compound Group 3 as an electron transport host material.

### Compound Group 3

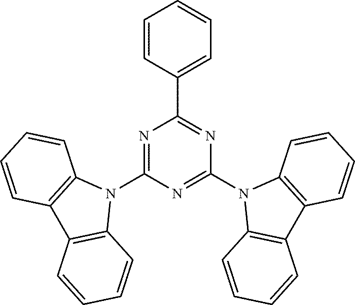 [SMILES: c1ccc(-c2nc(-n3c4ccccc4c4ccccc43)nc(-n3c4ccccc4c4ccccc43)n2)cc1]

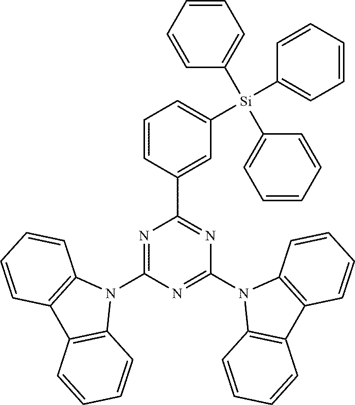 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

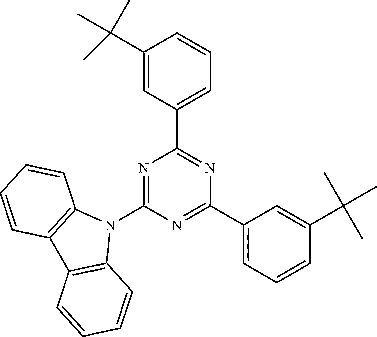 [SMILES: CC(C)(C)c1cccc(-c2nc(-c3cccc(C(C)(C)C)c3)nc(-n3c4ccccc4c4ccccc43)n2)c1]

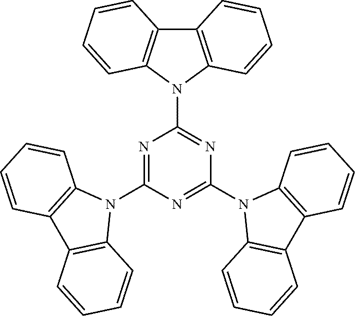 [SMILES: c1ccc2c(c1)c1ccccc1n2-c1nc(-n2c3ccccc3c3ccccc32)nc(-n2c3ccccc3c3ccccc32)n1]

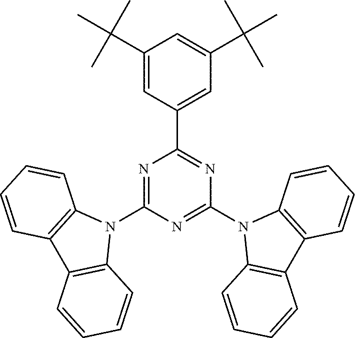 [SMILES: CC(C)(C)c1cc(-c2nc(-n3c4ccccc4c4ccccc43)nc(-n3c4ccccc4c4ccccc43)n2)cc(C(C)(C)C)c1]

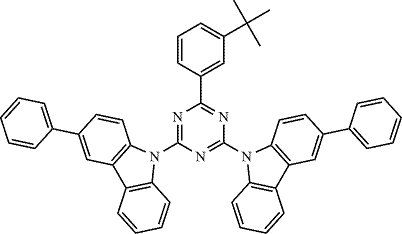 [SMILES: CC(C)(C)c1cccc(-c2nc(-n3c4ccccc4c4cc(-c5ccccc5)ccc43)nc(-n3c4ccccc4c4cc(-c5ccccc5)ccc43)n2)c1]

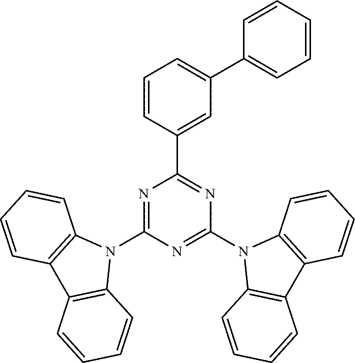 [SMILES: c1ccc(-c2cccc(-c3nc(-n4c5ccccc5c5ccccc54)nc(-n4c5ccccc5c5ccccc54)n3)c2)cc1]

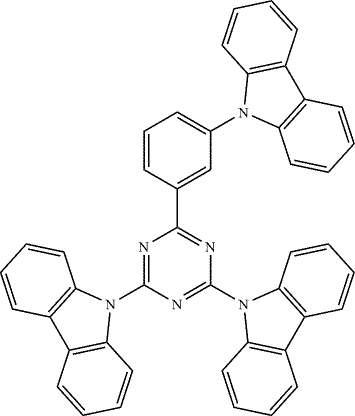 [SMILES: c1cc(-c2nc(-n3c4ccccc4c4ccccc43)nc(-n3c4ccccc4c4ccccc43)n2)cc(-n2c3ccccc3c3ccccc32)c1]

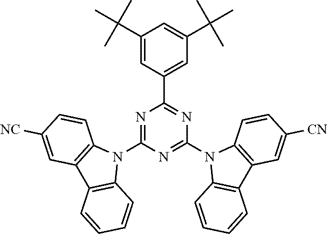 [SMILES: CC(C)(C)c1cc(-c2nc(-n3c4ccccc4c4cc(C#N)ccc43)nc(-n3c4ccccc4c4cc(C#N)ccc43)n2)cc(C(C)(C)C)c1]

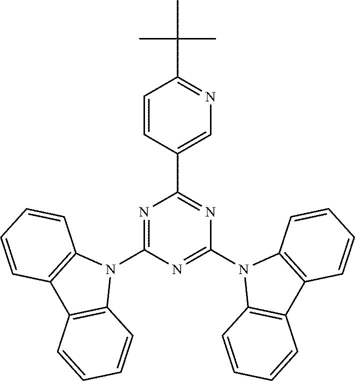 [SMILES: CC(C)(C)c1ccc(-c2nc(-n3c4ccccc4c4ccccc43)nc(-n3c4ccccc4c4ccccc43)n2)cn1]

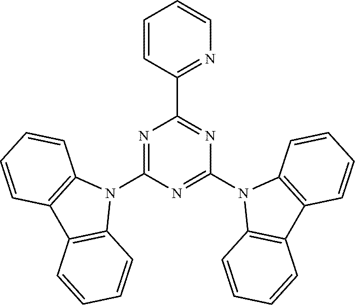 [SMILES: c1ccc(-c2nc(-n3c4ccccc4c4ccccc43)nc(-n3c4ccccc4c4ccccc43)n2)nc1]

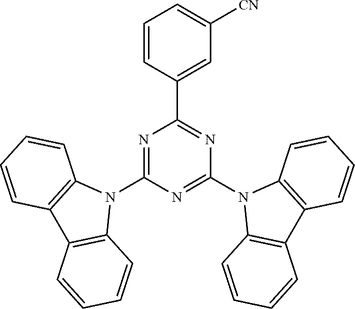 [SMILES: N#Cc1cccc(-c2nc(-n3c4ccccc4c4ccccc43)nc(-n3c4ccccc4c4ccccc43)n2)c1]

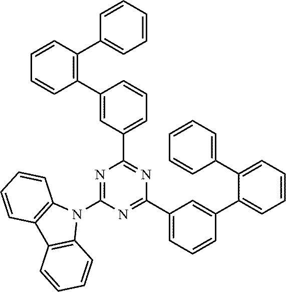 [SMILES: c1ccc(-c2ccccc2-c2cccc(-c3nc(-c4cccc(-c5ccccc5-c5ccccc5)c4)nc(-n4c5ccccc5c5ccccc54)n3)c2)cc1]

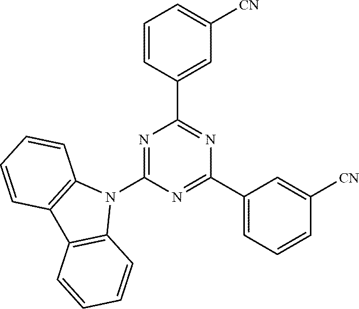 [SMILES: N#Cc1cccc(-c2nc(-c3cccc(C#N)c3)nc(-n3c4ccccc4c4ccccc43)n2)c1]

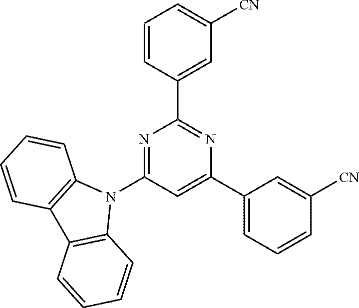 [SMILES: N#Cc1cccc(-c2cc(-n3c4ccccc4c4ccccc43)nc(-c3cccc(C#N)c3)n2)c1]

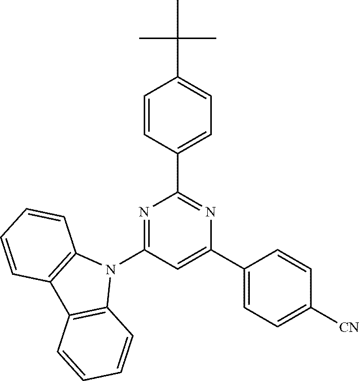 [SMILES: CC(C)(C)c1ccc(-c2nc(-c3ccc(C#N)cc3)cc(-n3c4ccccc4c4ccccc43)n2)cc1]

In an embodiment, the fourth compound represented by Formula D-1 may include at least one selected from among the compounds represented in Compound Group 4. The emission layer EML may include at least one selected from among the compounds represented in Compound Group 4 as a sensitizer material. Compound Group 4

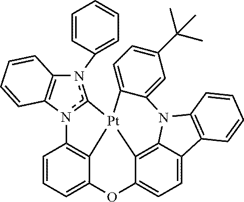

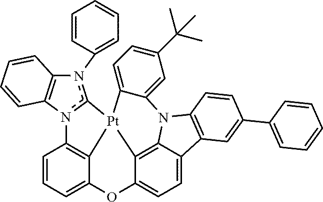

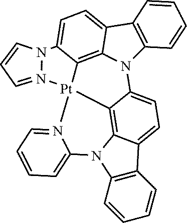

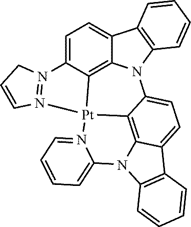

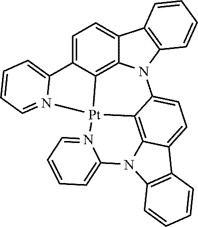

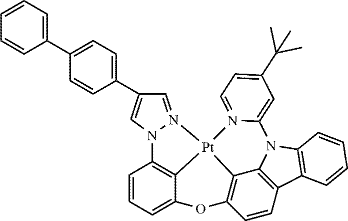

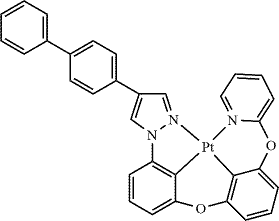

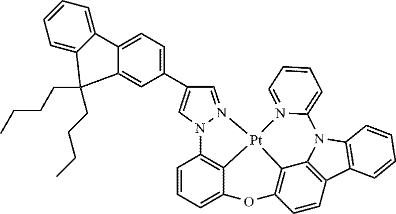

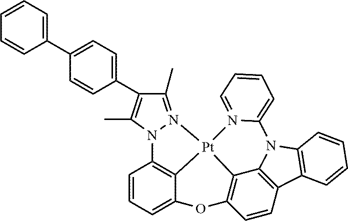

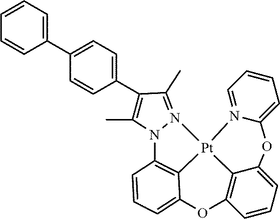

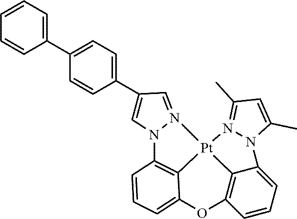

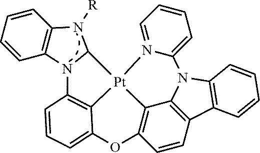

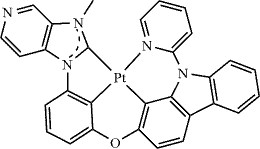

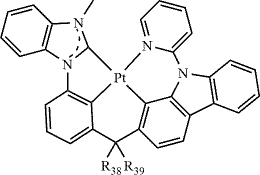

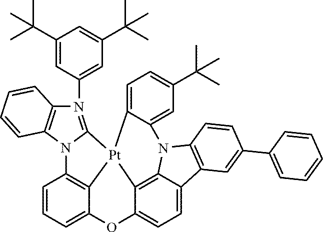

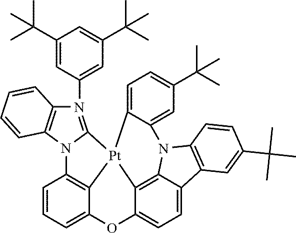

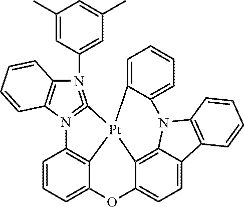

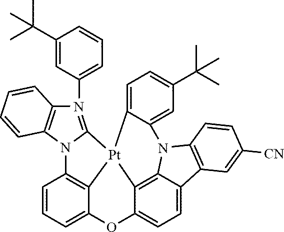

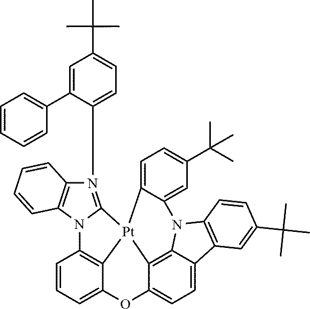

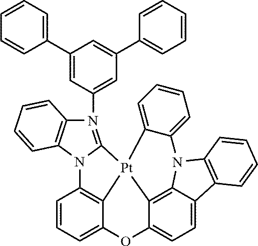

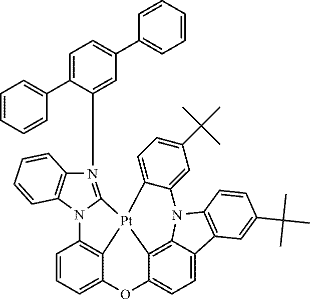

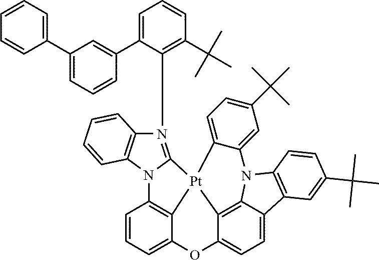

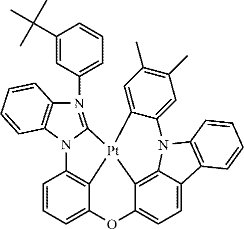

In the compounds included in Compound Group 4, R, R₃₈ and R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In some embodiments, the light emitting element ED of an embodiment may include multiple emission layers. The multiple emission layers may be provided by stacking (e.g., laminated) in order (e.g., in suitable order), for example, the light emitting element ED including the multiple stacked emission layers may emit white light. The light emitting element including the multiple emission layers may be a light emitting element with a tandem structure. When the light emitting element ED includes multiple emission layers, at least one emission layer EML may include all of the first compound, the second compound, the third compound and the fourth compound as described above.

In the light emitting element ED of an embodiment, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting elements ED of embodiments, shown in FIG. 3 to FIG. 6, the emission layer EML may further include suitable hosts and dopants in addition to the above-described hosts and dopants, and the emission layer EML may include a compound represented by Formula E-1. The compound represented by Formula E-1 may be utilized as a fluorescence host material.

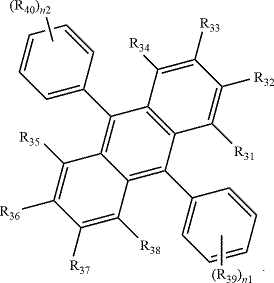

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, n1 and n2 may each independently be an integer of 0 to 5.

Formula E-1 may be represented by any one selected from among Compound E1 to Compound E20.

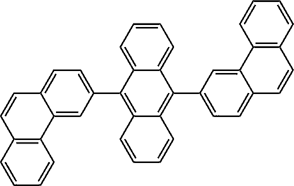 [SMILES: c1ccc2c(c1)ccc1ccc(-c3c4ccccc4c(-c4ccc5ccc6ccccc6c5c4)c4ccccc34)cc12]

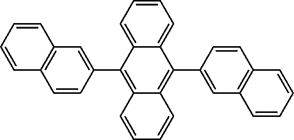 [SMILES: c1ccc2cc(-c3c4ccccc4c(-c4ccc5ccccc5c4)c4ccccc34)ccc2c1]

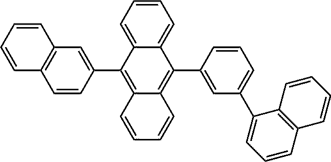 [SMILES: c1cc(-c2cccc3ccccc23)cc(-c2c3ccccc3c(-c3ccc4ccccc4c3)c3ccccc23)c1]

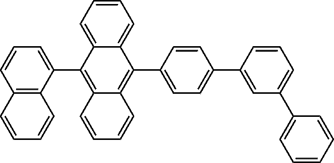 [SMILES: c1ccc(-c2cccc(-c3ccc(-c4c5ccccc5c(-c5cccc6ccccc56)c5ccccc45)cc3)c2)cc1]

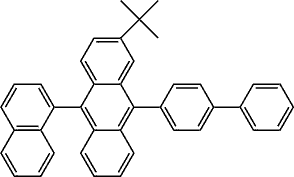 [SMILES: CC(C)(C)c1ccc2c(-c3cccc4ccccc34)c3ccccc3c(-c3ccc(-c4ccccc4)cc3)c2c1]

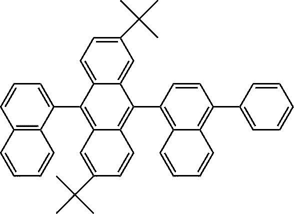 [SMILES: CC(C)(C)c1ccc2c(-c3ccc(-c4ccccc4)c4ccccc34)c3cc(C(C)(C)C)ccc3c(-c3cccc4ccccc34)c2c1]

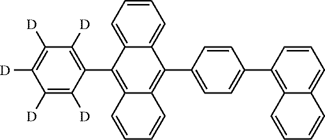 [SMILES: [2H]c1c([2H])c([2H])c(-c2c3ccccc3c(-c3ccc(-c4cccc5ccccc45)cc3)c3ccccc23)c([2H])c1[2H]]

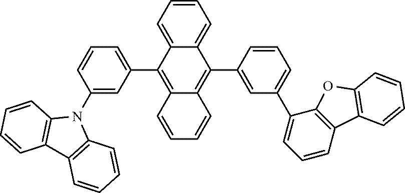 [SMILES: c1cc(-c2c3ccccc3c(-c3cccc(-n4c5ccccc5c5ccccc54)c3)c3ccccc23)cc(-c2cccc3c2oc2ccccc23)c1]

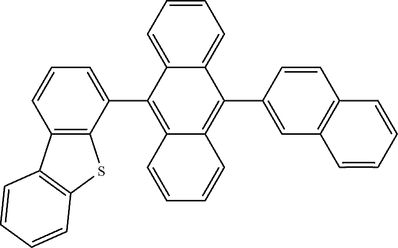 [SMILES: c1ccc2cc(-c3c4ccccc4c(-c4cccc5c4sc4ccccc45)c4ccccc34)ccc2c1]

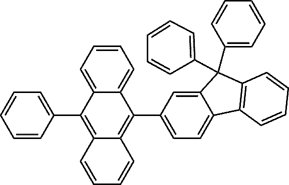 [SMILES: c1ccc(-c2c3ccccc3c(-c3ccc4c(c3)C(c3ccccc3)(c3ccccc3)c3ccccc3-4)c3ccccc23)cc1]

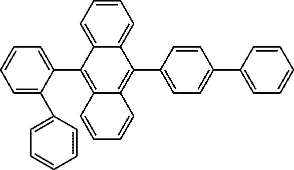 [SMILES: c1ccc(-c2ccc(-c3c4ccccc4c(-c4ccccc4-c4ccccc4)c4ccccc34)cc2)cc1]

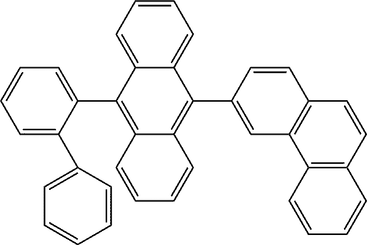 [SMILES: c1ccc(-c2ccccc2-c2c3ccccc3c(-c3ccc4ccc5ccccc5c4c3)c3ccccc23)cc1]

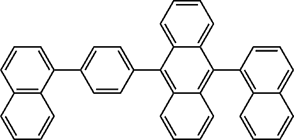 [SMILES: c1ccc2c(-c3ccc(-c4c5ccccc5c(-c5cccc6ccccc56)c5ccccc45)cc3)cccc2c1]

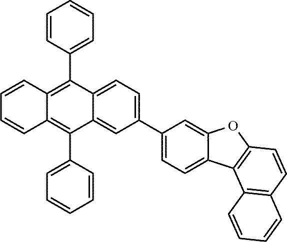 [SMILES: c1ccc(-c2c3ccccc3c(-c3ccccc3)c3cc(-c4ccc5c(c4)oc4ccc6ccccc6c45)ccc23)cc1]

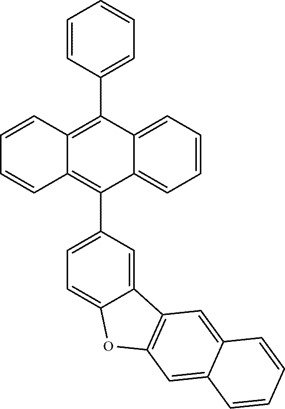 [SMILES: c1ccc(-c2c3ccccc3c(-c3ccc4oc5cc6ccccc6cc5c4c3)c3ccccc23)cc1]

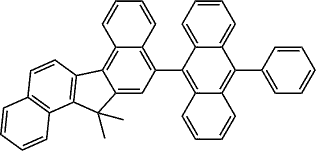 [SMILES: CC1(C)c2cc(-c3c4ccccc4c(-c4ccccc4)c4ccccc34)c3ccccc3c2-c2ccc3ccccc3c21]

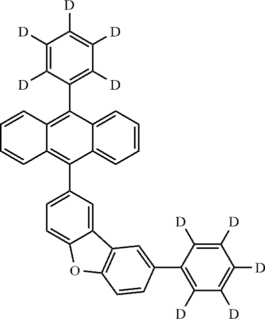 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H]]

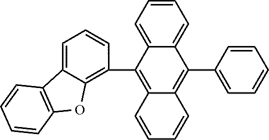 [SMILES: c1ccc(-c2c3ccccc3c(-c3cccc4c3oc3ccccc34)c3ccccc23)cc1]

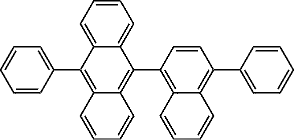 [SMILES: c1ccc(-c2ccc(-c3c4ccccc4c(-c4ccccc4)c4ccccc34)c3ccccc23)cc1]

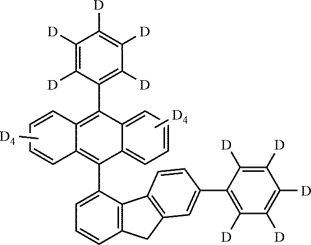

In an embodiment, the emission layer EML may further include a compound represented by Formula E-2b. The compound represented by Formula E-2b may be utilized as a phosphorescence host material.

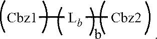

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are merely illustrations, and the compound represented by Formula E-2a or Formula E-2b is not limited to the compounds represented in Compound Group E-2.

### Compound Group E-2

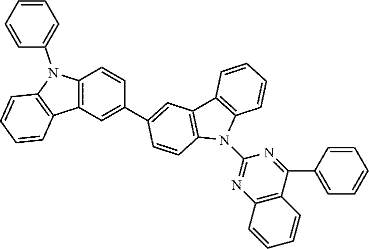 [SMILES: c1ccc(-c2nc(-n3c4ccccc4c4cc(-c5ccc6c(c5)c5ccccc5n6-c5ccccc5)ccc43)nc3ccccc23)cc1]

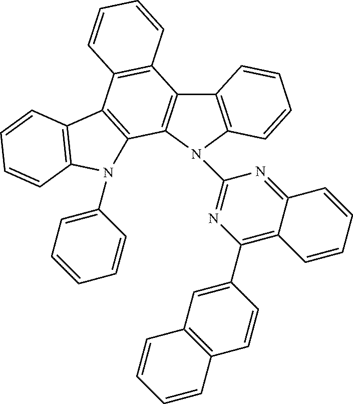 [SMILES: c1ccc(-n2c3ccccc3c3c4ccccc4c4c5ccccc5n(-c5nc(-c6ccc7ccccc7c6)c6ccccc6n5)c4c32)cc1]

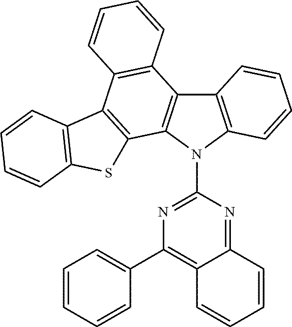 [SMILES: c1ccc(-c2nc(-n3c4ccccc4c4c5ccccc5c5c6ccccc6sc5c43)nc3ccccc23)cc1]

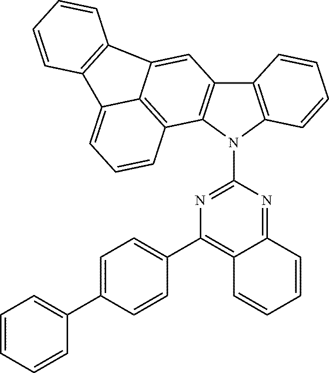 [SMILES: c1ccc(-c2ccc(-c3nc(-n4c5ccccc5c5cc6c7c(cccc7c54)-c4ccccc4-6)nc4ccccc34)cc2)cc1]

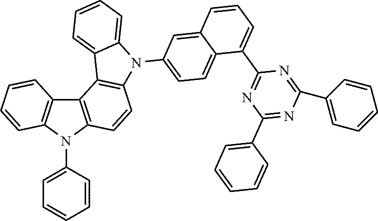 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1]

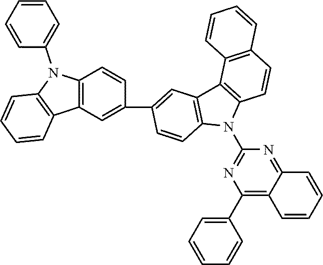 [SMILES: c1ccc(-c2nc(-n3c4ccc(-c5ccc6c(c5)c5ccccc5n6-c5ccccc5)cc4c4c5ccccc5ccc43)nc3ccccc23)cc1]

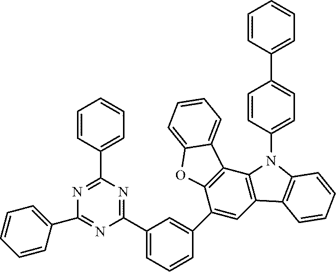 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

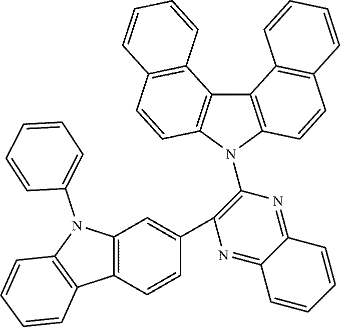 [SMILES: c1ccc(-n2c3ccccc3c3ccc(-c4nc5ccccc5nc4-n4c5ccc6ccccc6c5c5c6ccccc6ccc54)cc32)cc1]

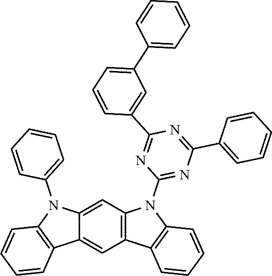 [SMILES: c1ccc(-c2cccc(-c3nc(-c4ccccc4)nc(-n4c5ccccc5c5cc6c7ccccc7n(-c7ccccc7)c6cc54)n3)c2)cc1]

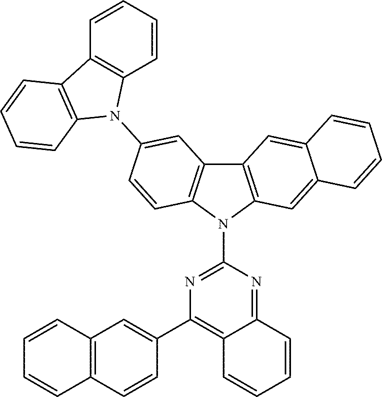 [SMILES: c1ccc2cc(-c3nc(-n4c5ccc(-n6c7ccccc7c7ccccc76)cc5c5cc6ccccc6cc54)nc4ccccc34)ccc2c1]

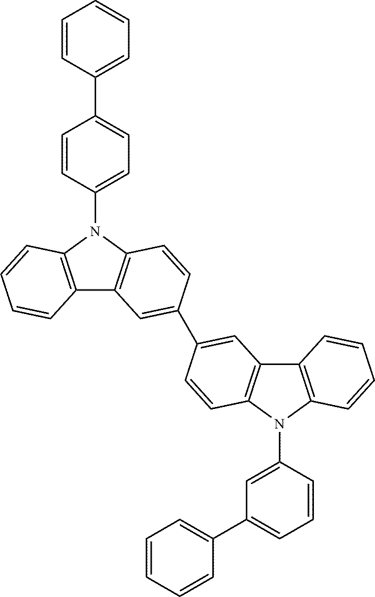 [SMILES: c1ccc(-c2ccc(-n3c4ccccc4c4cc(-c5ccc6c(c5)c5ccccc5n6-c5cccc(-c6ccccc6)c5)ccc43)cc2)cc1]

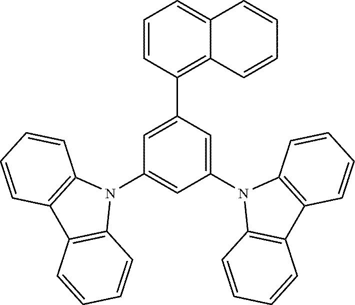 [SMILES: c1ccc2c(-c3cc(-n4c5ccccc5c5ccccc54)cc(-n4c5ccccc5c5ccccc54)c3)cccc2c1]

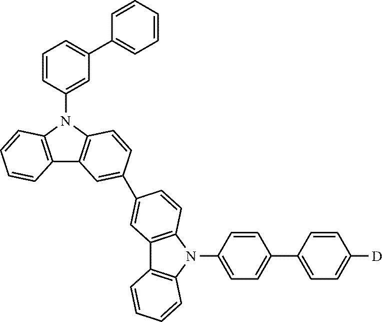 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1]

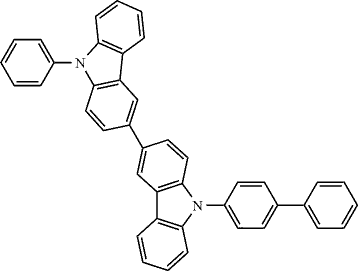 [SMILES: c1ccc(-c2ccc(-n3c4ccccc4c4cc(-c5ccc6c(c5)c5ccccc5n6-c5ccccc5)ccc43)cc2)cc1]

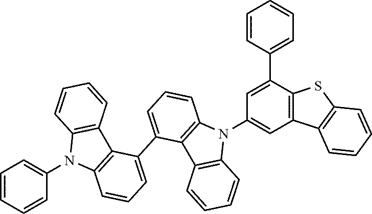 [SMILES: c1ccc(-c2cc(-n3c4ccccc4c4c(-c5cccc6c5c5ccccc5n6-c5ccccc5)cccc43)cc3c2sc2ccccc23)cc1]

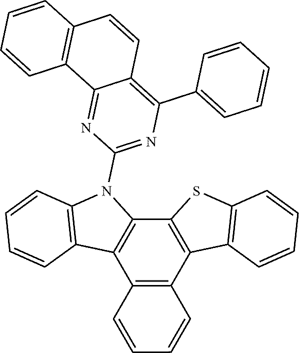 [SMILES: c1ccc(-c2nc(-n3c4ccccc4c4c5ccccc5c5c6ccccc6sc5c43)nc3c2ccc2ccccc23)cc1]

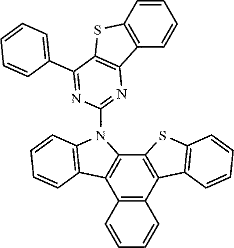 [SMILES: c1ccc(-c2nc(-n3c4ccccc4c4c5ccccc5c5c6ccccc6sc5c43)nc3c2sc2ccccc23)cc1]

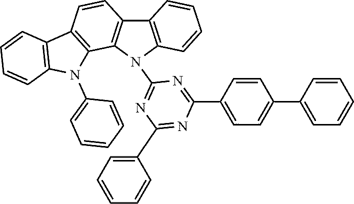 [SMILES: c1ccc(-c2ccc(-c3nc(-c4ccccc4)nc(-n4c5ccccc5c5ccc6c7ccccc7n(-c7ccccc7)c6c54)n3)cc2)cc1]

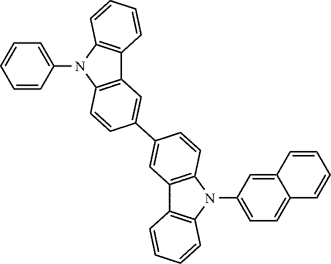 [SMILES: c1ccc(-n2c3ccccc3c3cc(-c4ccc5c(c4)c4ccccc4n5-c4ccc5ccccc5c4)ccc32)cc1]

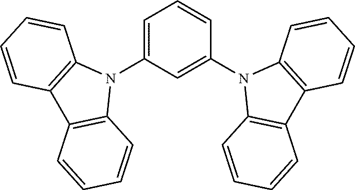 [SMILES: c1cc(-n2c3ccccc3c3ccccc32)cc(-n2c3ccccc3c3ccccc32)c1]

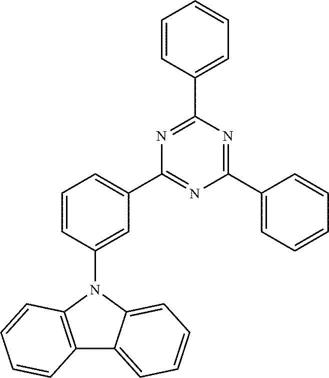 [SMILES: c1ccc(-c2nc(-c3ccccc3)nc(-c3cccc(-n4c5ccccc5c5ccccc54)c3)n2)cc1]

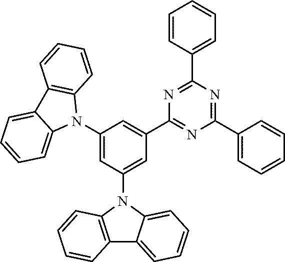 [SMILES: c1ccc(-c2nc(-c3ccccc3)nc(-c3cc(-n4c5ccccc5c5ccccc54)cc(-n4c5ccccc5c5ccccc54)c3)n2)cc1]

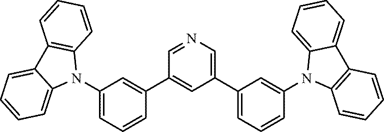 [SMILES: c1cc(-c2cncc(-c3cccc(-n4c5ccccc5c5ccccc54)c3)c2)cc(-n2c3ccccc3c3ccccc32)c1]

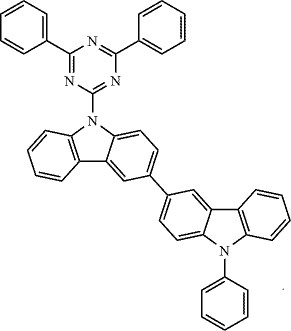

The emission layer EML may further include a common material suitable in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may include a compound represented by Formula M-a. The compound represented by Formula M-a may be utilized as a phosphorescence dopant material. In an embodiment, the compound represented by Formula M-a may be utilized as an auxiliary dopant material.

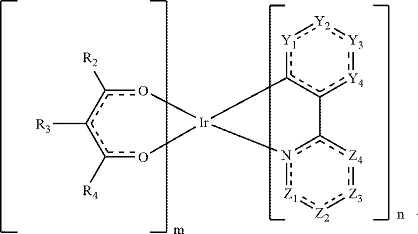

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one among Compounds M-a1 to M-a25. However, Compounds M-a1 to M-a25 are illustrations, and the compound represented by Formula M-a is not limited to the compounds represented by Compounds M-a1 to M-a25.

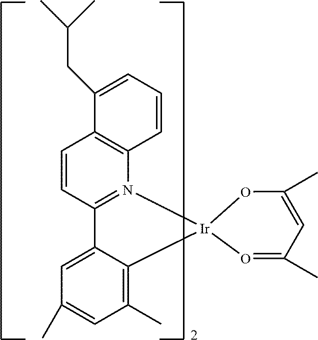

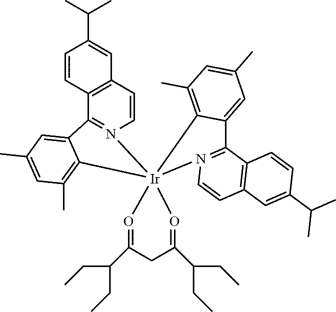

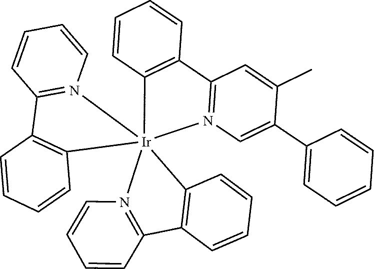

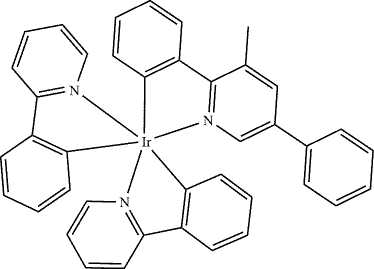

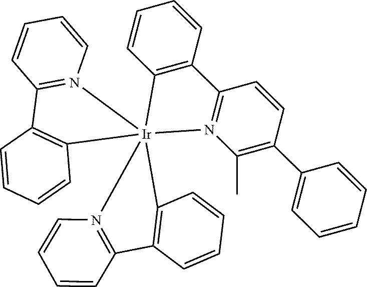

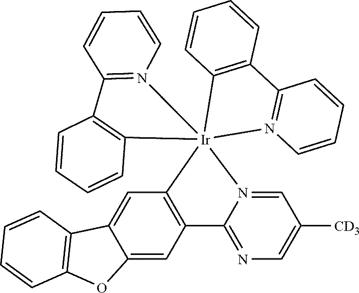

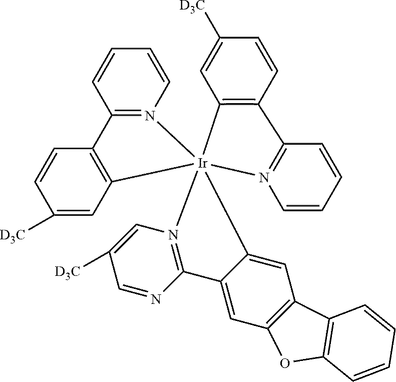

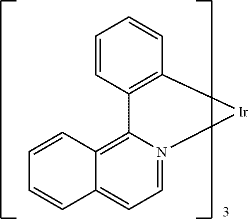

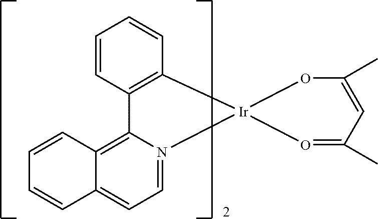

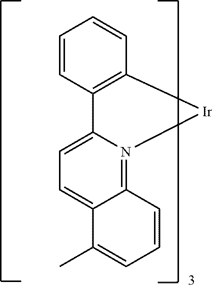

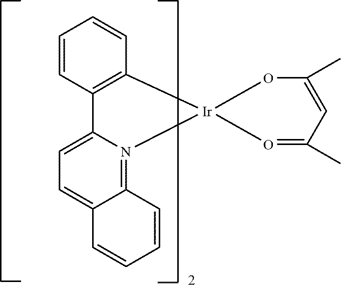

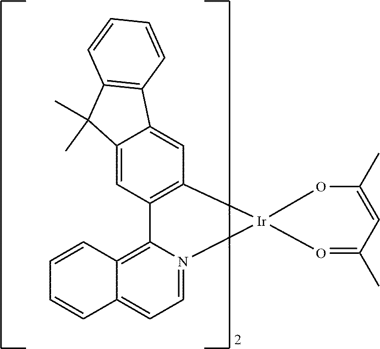

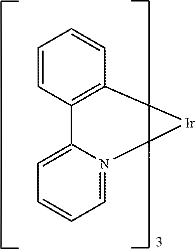

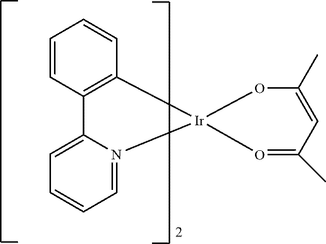

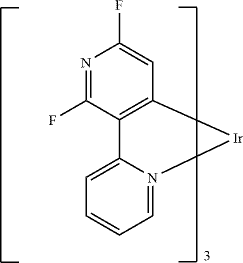

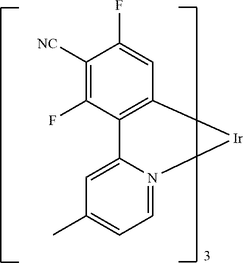

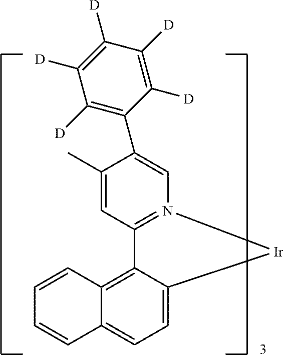

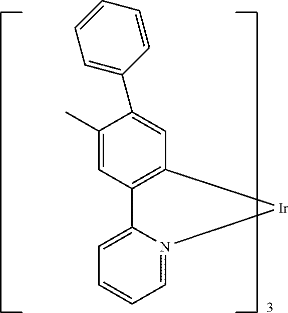

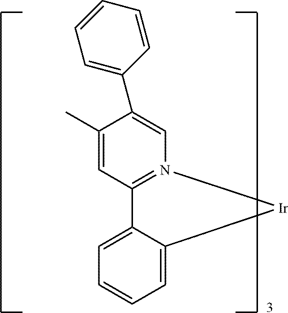

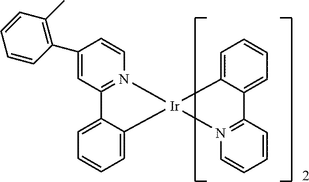

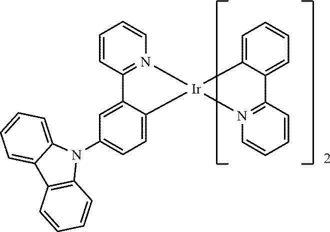

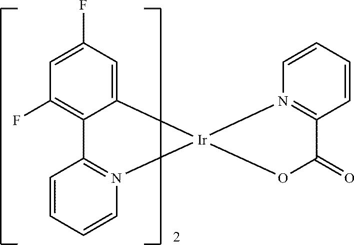

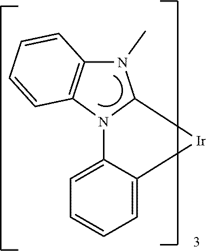

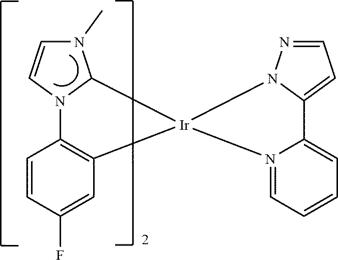

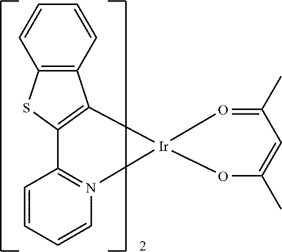

Compound M-a1 and Compound M-a2 may be utilized as red dopant materials, and Compound M-a3 to Compound M-a7 may be utilized as green dopant materials.

The emission layer EML may include any one selected from among Formula F-a to Formula F-c. The compounds represented by Formula F-a to Formula F-c may be utilized as fluorescence dopant materials.

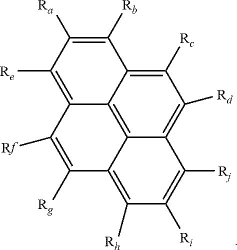

In Formula F-a, any two substituents selected from Rₐ to Rⱼ may each independently be substituted with ∗—NAr₁Ar₂. The remainder (of substituents) not substituted with ∗—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In ∗—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

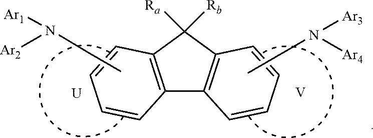

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

In an embodiment, the emission layer EML may include as a suitable dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

The emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and one or more combinations thereof.

The II-VI group compound may be selected from the group including (e.g., consisting of): a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof; a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof; and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The III-V group compound may include a binary compound such as In₂S₃, and In₂Se₃, a ternary compound such as InGaS₃, and InGaSe₃, or optional combinations (one or more combinations) thereof.

The I-III-VI group compound may be selected from a ternary compound selected from the group including (e.g., consisting of)AgInS, AgInS₂, CuInS, CuInS₂, AgGaS₂, CuGaS₂, CuGaO₂, AgGaO₂, AgAlO₂ and one or more compounds or mixtures thereof, or a quaternary compound such as AgInGaS₂, and CuInGaS₂ (the quaternary compound may be used alone or in combination with any of the foregoing compounds or mixtures; and the quaternary compound may also be combined with other quaternary compounds).

The III-V group compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAINP, InAINAs, InAINSb, InAIPAs, InAIPSb, and or one compounds or mixtures thereof. In some embodiments, the III-V group compound may further include a II group metal. For example, InZnP, etc. may be selected as a III-II-V group compound.

The IV-VI group compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compunds or mixtures thereof, and a quaternary compound selected from the group including (e.g., consisting of) SnPbSSe, SnPbSeTe, SnPbSTe, and one or more compounds or mixtures thereof. The IV group element may be selected from the group including (e.g., consisting of)Si, Ge, and one or more elements or mixtures thereof. The IV group compound may be a binary compound selected from the group including (e.g., consisting of) SiC, SiGe, and one or more compounds or mixtures thereof.

In the foregoing embodiment or embodiments, the binary compound, the ternary compound or the quaternary compound may be present at a substantially uniform concentration in a particle (particle form) or may be present at a partially different concentration distribution state in substantially the same particle (particle form). In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or one or more combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, etc., but an embodiment of the present disclosure is not limited thereto.

The quantum dot may have a full width of half maximum (FWHM) of emission wavelength spectrum of about 45 nm or less, about 40 nm or less, or about 30 nm or less. Within this range, color purity or color reproducibility may be improved. In some embodiments, light emitted via such quantum dot is emitted in all directions, and light view angle properties may be improved (increased).

In some embodiments, the shape of the quantum dot may be generally utilized shapes in the art, without specific limitation. For example, the shape of a substantially spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red and green.

In the light emitting elements ED of embodiments, as shown in FIG. 3 to FIG. 6, the electron transport region ETR is provided on the emission layer EML. The electron transport region ETR may include at least one of an electron blocking layer HBL, an electron transport layer ETL, or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2.

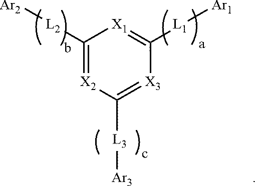

In Formula ET-2, at least one selected from among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, “L₁” to “L₃” may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are each an integer of 2 or more, “L₁” to “L₃” may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1 -ylphenyl)-9,10-dinaphthylanthracene, 1,3,5-tri(1 -phenyl-1 H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or one or more compounds or mixtures thereof, without limitation.

The electron transport region ETR may include at least one selected from among Compounds ET1 to ET36.

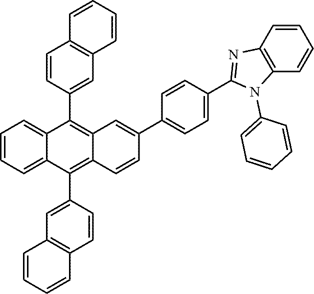 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

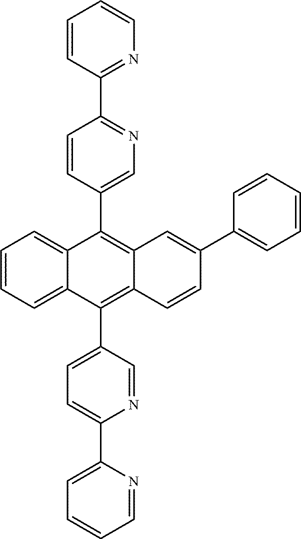 [SMILES: c1ccc(-c2ccc3c(-c4ccc(-c5ccccn5)nc4)c4ccccc4c(-c4ccc(-c5ccccn5)nc4)c3c2)cc1]

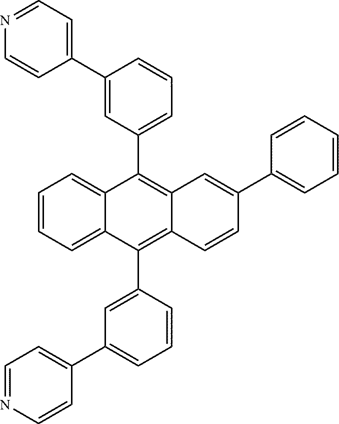 [SMILES: c1ccc(-c2ccc3c(-c4cccc(-c5ccncc5)c4)c4ccccc4c(-c4cccc(-c5ccncc5)c4)c3c2)cc1]

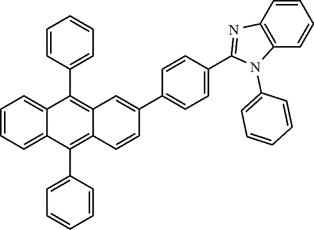 [SMILES: c1ccc(-c2c3ccccc3c(-c3ccccc3)c3cc(-c4ccc(-c5nc6ccccc6n5-c5ccccc5)cc4)ccc23)cc1]

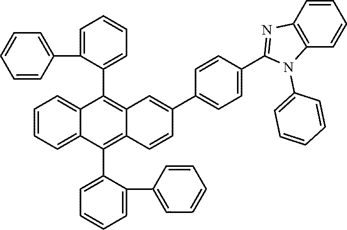 [SMILES: c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

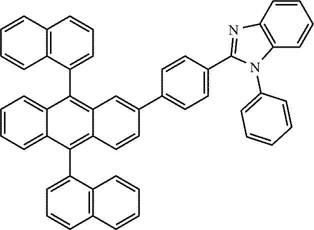 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1]

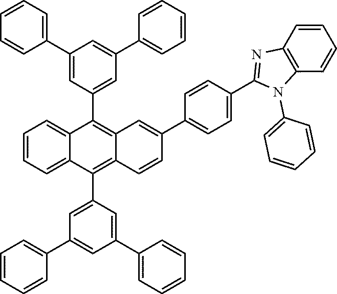 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

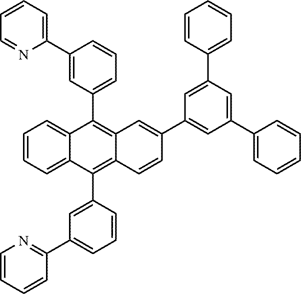 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

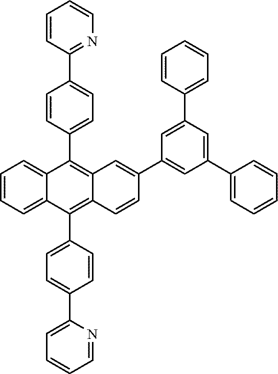 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

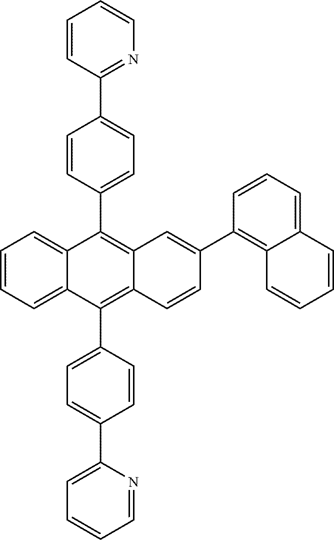 [SMILES: c1ccc(-c2ccc(-c3c4ccccc4c(-c4ccc(-c5ccccn5)cc4)c4cc(-c5cccc6ccccc56)ccc34)cc2)nc1]

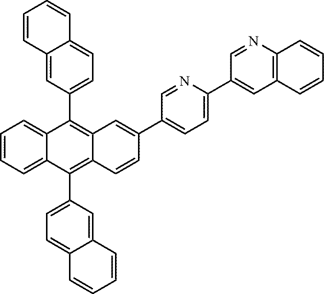 [SMILES: c1ccc2cc(-c3c4ccccc4c(-c4ccc5ccccc5c4)c4cc(-c5ccc(-c6cnc7ccccc7c6)nc5)ccc34)ccc2c1]

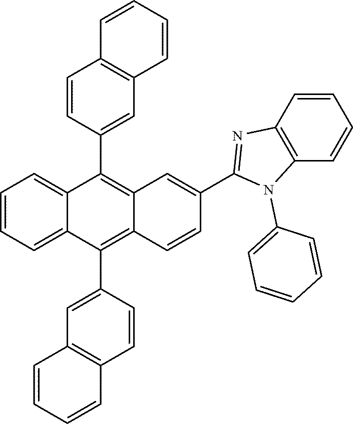 [SMILES: c1ccc(-n2c(-c3ccc4c(-c5ccc6ccccc6c5)c5ccccc5c(-c5ccc6ccccc6c5)c4c3)nc3ccccc32)cc1]

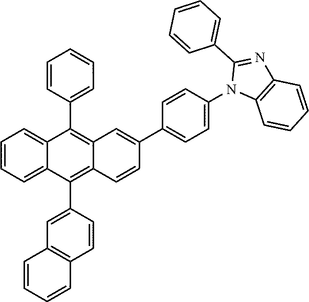 [SMILES: c1ccc(-c2c3ccccc3c(-c3ccc4ccccc4c3)c3ccc(-c4ccc(-n5c(-c6ccccc6)nc6ccccc65)cc4)cc23)cc1]

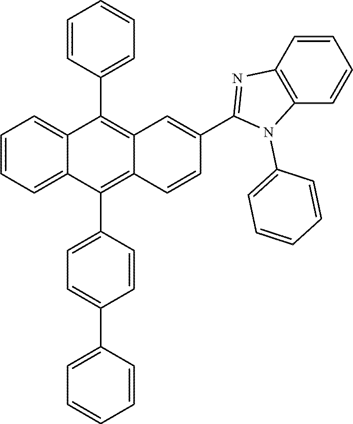 [SMILES: c1ccc(-c2ccc(-c3c4ccccc4c(-c4ccccc4)c4cc(-c5nc6ccccc6n5-c5ccccc5)ccc34)cc2)cc1]

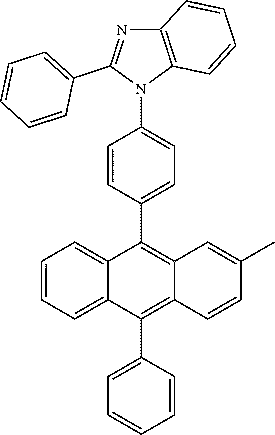 [SMILES: Cc1ccc2c(-c3ccccc3)c3ccccc3c(-c3ccc(-n4c(-c5ccccc5)nc5ccccc54)cc3)c2c1]

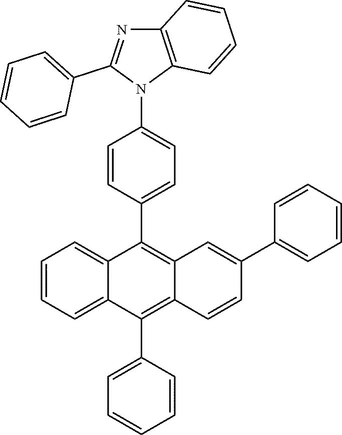 [SMILES: c1ccc(-c2ccc3c(-c4ccccc4)c4ccccc4c(-c4ccc(-n5c(-c6ccccc6)nc6ccccc65)cc4)c3c2)cc1]

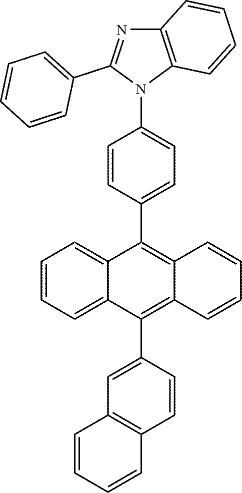 [SMILES: c1ccc(-c2nc3ccccc3n2-c2ccc(-c3c4ccccc4c(-c4ccc5ccccc5c4)c4ccccc34)cc2)cc1]

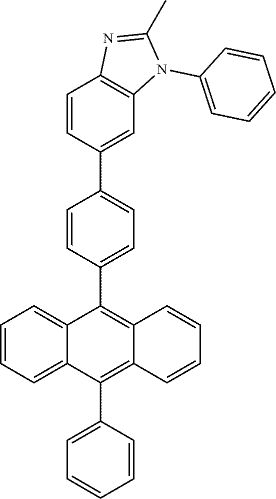 [SMILES: Cc1nc2ccc(-c3ccc(-c4c5ccccc5c(-c5ccccc5)c5ccccc45)cc3)cc2n1-c1ccccc1]

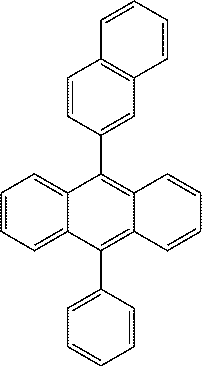 [SMILES: c1ccc(-c2c3ccccc3c(-c3ccc4ccccc4c3)c3ccccc23)cc1]

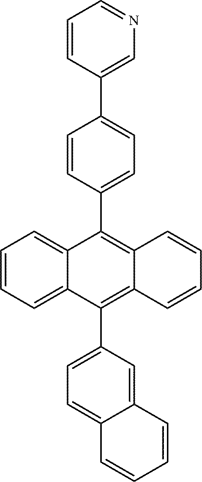 [SMILES: c1cncc(-c2ccc(-c3c4ccccc4c(-c4ccc5ccccc5c4)c4ccccc34)cc2)c1]

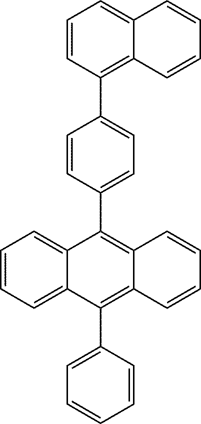 [SMILES: c1ccc(-c2c3ccccc3c(-c3ccc(-c4cccc5ccccc45)cc3)c3ccccc23)cc1]

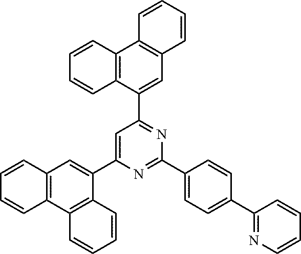 [SMILES: c1ccc(-c2ccc(-c3nc(-c4cc5ccccc5c5ccccc45)cc(-c4cc5ccccc5c5ccccc45)n3)cc2)nc1]

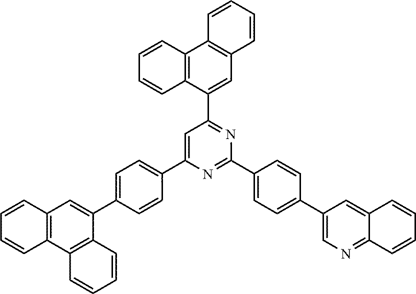 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1]

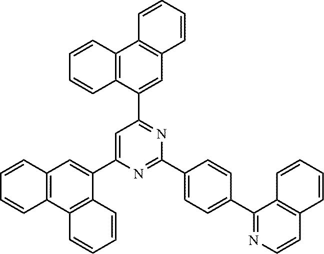 [SMILES: c1ccc2c(-c3ccc(-c4nc(-c5cc6ccccc6c6ccccc56)cc(-c5cc6ccccc6c6ccccc56)n4)cc3)nccc2c1]

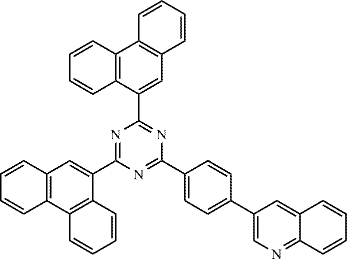 [SMILES: c1ccc2ncc(-c3ccc(-c4nc(-c5cc6ccccc6c6ccccc56)nc(-c5cc6ccccc6c6ccccc56)n4)cc3)cc2c1]

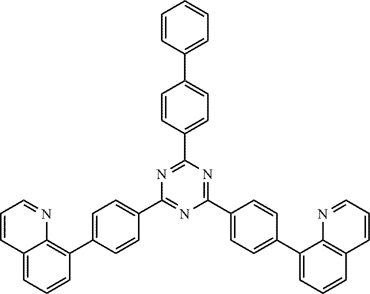 [SMILES: c1ccc(-c2ccc(-c3nc(-c4ccc(-c5cccc6cccnc56)cc4)nc(-c4ccc(-c5cccc6cccnc56)cc4)n3)cc2)cc1]

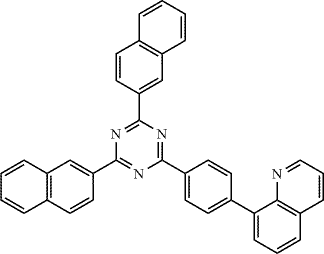 [SMILES: c1ccc2cc(-c3nc(-c4ccc(-c5cccc6cccnc56)cc4)nc(-c4ccc5ccccc5c4)n3)ccc2c1]

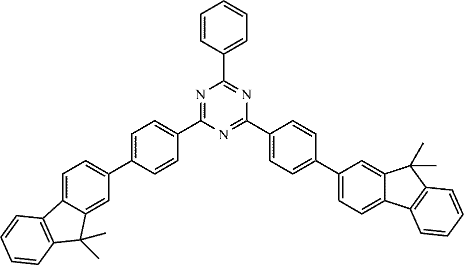 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

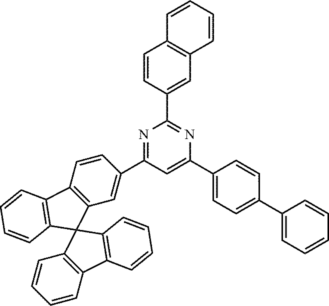 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

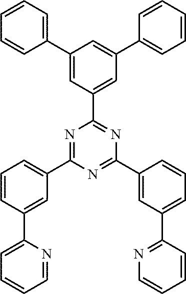 [SMILES: c1ccc(-c2cc(-c3ccccc3)cc(-c3nc(-c4cccc(-c5ccccn5)c4)nc(-c4cccc(-c5ccccn5)c4)n3)c2)cc1]

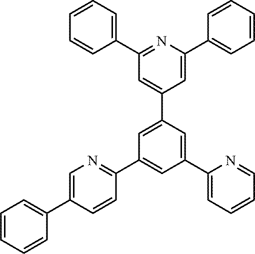 [SMILES: c1ccc(-c2ccc(-c3cc(-c4cc(-c5ccccc5)nc(-c5ccccc5)c4)cc(-c4ccccn4)c3)nc2)cc1]

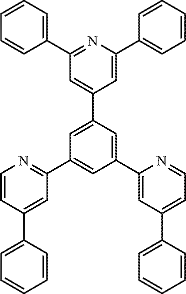 [SMILES: c1ccc(-c2ccnc(-c3cc(-c4cc(-c5ccccc5)nc(-c5ccccc5)c4)cc(-c4cc(-c5ccccc5)ccn4)c3)c2)cc1]

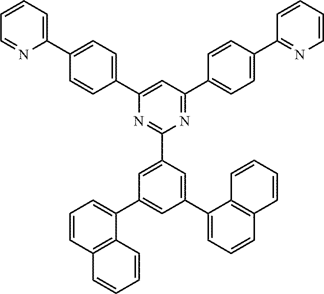 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

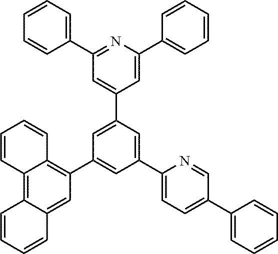 [SMILES: c1ccc(-c2ccc(-c3cc(-c4cc(-c5ccccc5)nc(-c5ccccc5)c4)cc(-c4cc5ccccc5c5ccccc45)c3)nc2)cc1]

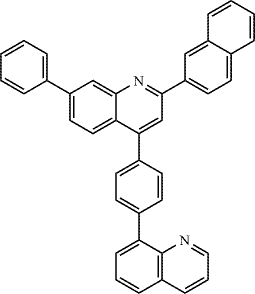 [SMILES: c1ccc(-c2ccc3c(-c4ccc(-c5cccc6cccnc56)cc4)cc(-c4ccc5ccccc5c4)nc3c2)cc1]

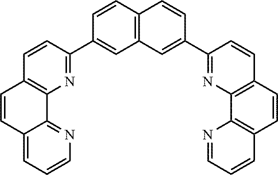 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCI, CsF, RbCI, RbI, CuI and KI, a lanthanide metal such as Yb, or a co-depositing material of the metal halide and the lanthanide metal. For example, the electron transport region ETR may include KI:Yb, RbI:Yb, etc., as the co-depositing material. In some embodiments, the electron transport region ETR may utilize a metal oxide such as Li₂O and BaO, or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, or metal stearates.

The electron transport region ETR may include at least one selected from among 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å.When the thickness of the electron transport layer ETL satisfies the above-described range, satisfactory electron transport properties may be obtained without substantial increase of a driving voltage. When the electron transport region ETR includes the electron injection layer EIL, the thickness of the electron injection layer EIL may be from about 1 Å to about 100 Å, and from about 3 Å to about 90 Å. When the thickness of the electron injection layer EIL satisfies the above described range, satisfactory electron injection properties may be obtained without inducing a substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, AI, Pt, Pd, Au, Ni, Nd, Ir, Cr, Li, Ca, LiF/Ca, LiF/AI, Mo, Ti, Yb, W, one or more compounds thereof, or one or more mixtures thereof (for example, AgMg, AgYb, or MgYb). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal materials, combinations of two or more metal materials selected from the aforementioned metal materials, and/or oxide(s) of the aforementioned metal materials.

The second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED of an embodiment, a capping layer CPL may be further disposed. The capping layer CPL may include a multilayer or a single layer.

In an embodiment, the capping layer CPL may be (or include) an organic layer and/or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or includes an epoxy resin, or acrylate such as methacrylate. In some embodiments, a capping layer CPL may include at least one selected from among Compounds P1 to P5, but an embodiment of the present disclosure is not limited thereto.

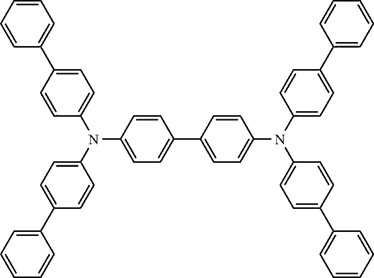 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

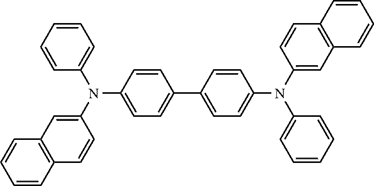 [SMILES: c1ccc(N(c2ccc(-c3ccc(N(c4ccccc4)c4ccc5ccccc5c4)cc3)cc2)c2ccc3ccccc3c2)cc1]

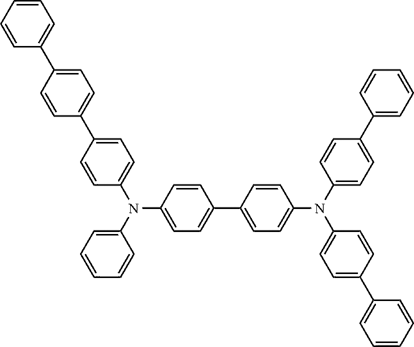 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

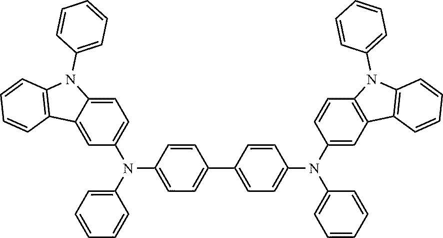 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

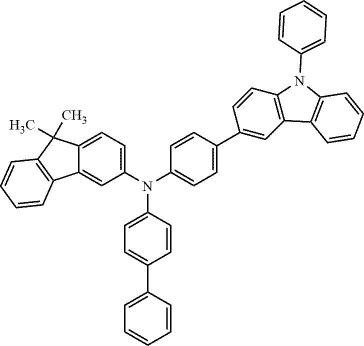 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

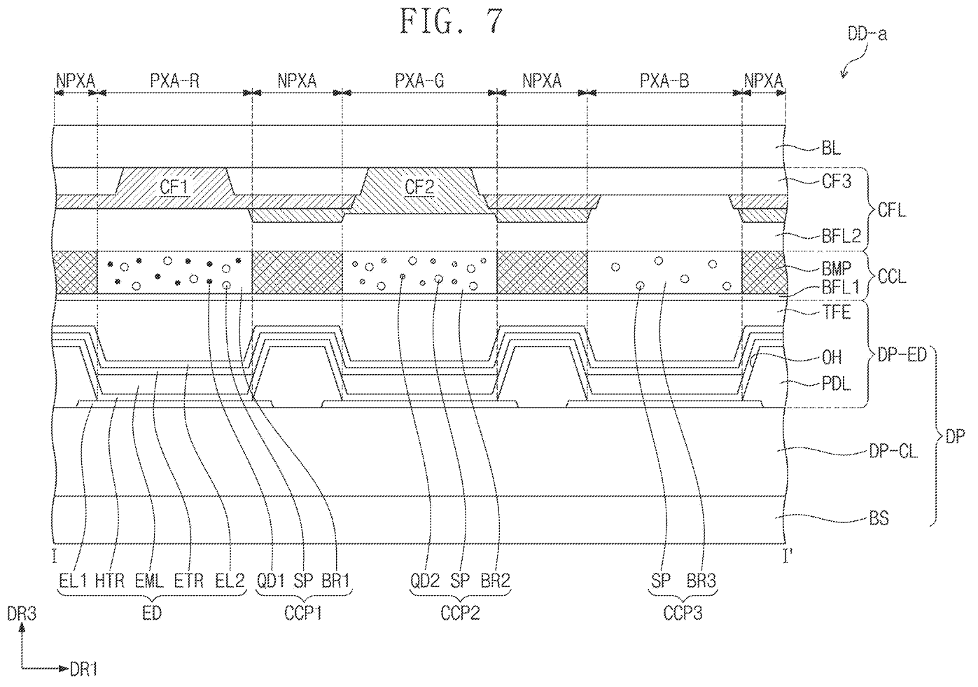

FIG. 7 to FIG. 10 are cross-sectional views on display apparatuses according to embodiments. In the explanation on the display apparatuses of embodiments, referring to FIG. 7 to FIG. 10, the overlapping/duplicative parts with the explanation on FIG. 1 to FIG. 6 may not be provided, and the different features will primarily be explained.

Referring to FIG. 7, a display apparatus DD-a according to an embodiment may include a display panel DP including a display element layer DP-ED, a light controlling layer CCL on the display panel DP, and a color filter layer CFL.

In an embodiment shown in FIG. 7, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 on the electron transport region ETR. In some embodiments, the same structures of the light emitting elements of FIG. 3 to FIG. 6 may be applied to the structure of the light emitting element ED shown in FIG. 7.

The emission layer EML of the light emitting element ED included in the display apparatus DD-a according to an embodiment may include at least one selected from among the second compound, the third compound and the fourth compound, and the first compound of an embodiment, described above.

Referring to FIG. 7, the emission layer EML may be in an opening part OH defined in a pixel definition layer PDL. For example, the emission layer EML divided by the pixel definition layer PDL and correspondingly provided to each of luminous areas PXA-R, PXA-G and PXA-B may emit light in substantially the same wavelength region. In the display apparatus DD of an embodiment, the emission layer EML may emit blue light. In some embodiments, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot or a phosphor. The light converter may transform the wavelength of light provided and then emit. For example, the light controlling layer CCL may include a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be between the separated light controlling parts CCP1, CCP2 and CCP3, but an embodiment of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting element ED into second color light, a second light controlling part CCP2 including a second quantum dot QD2 converting first color light into third color light, and a third light controlling part CCP3 transmitting first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same description used above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, AI₂O₃, SiO₂, and hollow silica. The scatterer SP may include at least one selected from among TiO₂, ZnO, AI₂O₃, SiO₂, and hollow silica, or may include (e.g., be) one or more of the compounds thereof or one or more mixtures of two or more materials selected from among TiO₂, ZnO, AI₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may be on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between the light controlling parts CCP1, CCP2 and CCP3 and a color filter layer CFL.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a metal thin film, to thereby securing light transmittance. In some embodiments, the barrier layers BFL1 and BFL2 may further include an organic layer. The barrier layers BFL1 and BFL2 may be composed of a single layer or multiple layers.

In the display apparatus DD-a of an embodiment, the color filter layer CFL may be on the light controlling layer CCL. For example, the color filter layer CFL may be directly on the light controlling layer CCL. In this embodiment, the barrier layer BFL2 may not be provided.

The color filter layer CFL may include filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye. An embodiment of the present disclosure is not limited thereto, and the third filter CF3 may not include (e.g., may exclude) the pigment and/or dye. The third filter CF3 may include a polymer photosensitive resin and not include (e.g., may exclude) a pigment or dye. The third filter CF3 may be transparent. The third filter CF3 may be formed utilizing a transparent photosensitive resin.

In some embodiments, the first filter CF1 and/or the second filter CF2 may be yellow filters. The first filter CF1 and the second filter CF2 may be provided in one body without distinction (without division or boundaries). Each of the first to third filters CF1, CF2 and CF3 may be disposed corresponding to each of a red luminous area PXA-R, green luminous area PXA-G, and blue luminous area PXA-B.

In some embodiments, the color filter layer CFL may include a light blocking part. The color filter layer CFL may include the light blocking part disposed so as to overlap with the boundaries of the neighboring filters CF1, CF2 and CF3. The light blocking part may be a black matrix. The light blocking part may be formed by including an organic light blocking material and/or an inorganic light blocking material, including a black pigment or black dye. The light blocking part may divide the boundaries among adjacent filters CF1, CF2 and CF3. In some embodiments, the light blocking part may be formed as a blue filter.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer and/or a composite material layer. In some embodiments, the base substrate BL may not be provided in an embodiment.

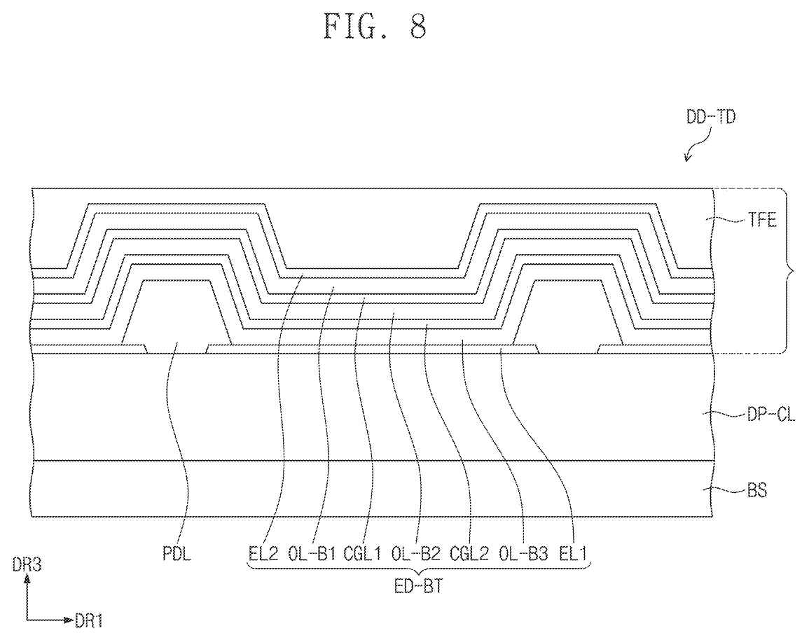

FIG. 8 is a cross-sectional view showing a portion of the display apparatus according to an embodiment. In FIG. 8, the cross-sectional view of a portion corresponding to the display panel DP in FIG. 7 is shown. In a display apparatus DD-TD of an embodiment, the light emitting element ED-BT may include multiple light emitting structures OL-B1, OL-B2 and OL-B3. The light emitting element ED-BT may include oppositely disposed first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), a hole transport region HTR and an electron transport region ETR disposed with the emission layer EML (FIG. 7) therebetween.

For example, the light emitting element ED-BT included in the display apparatus DD-TD of an embodiment may be a light emitting element of a tandem structure including multiple emission layers.

In an embodiment shown in FIG. 8, light emitted from the light emitting structures OL-B1, OL-B2 and OL-B3 may be all blue light. However, an embodiment of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be disposed. The charge generating layers CGL1 and CGL2 may include a p-type or kind charge generating layer and/or an n-type or kind charge generating layer.

In at least one selected from among the light emitting structures OL-B1, OL-B2 and OL-B3, included in the display apparatus DD-TD of an embodiment, the first compound of an embodiment, and at least one selected from among the second compound, the third compound and the fourth compound may be included.

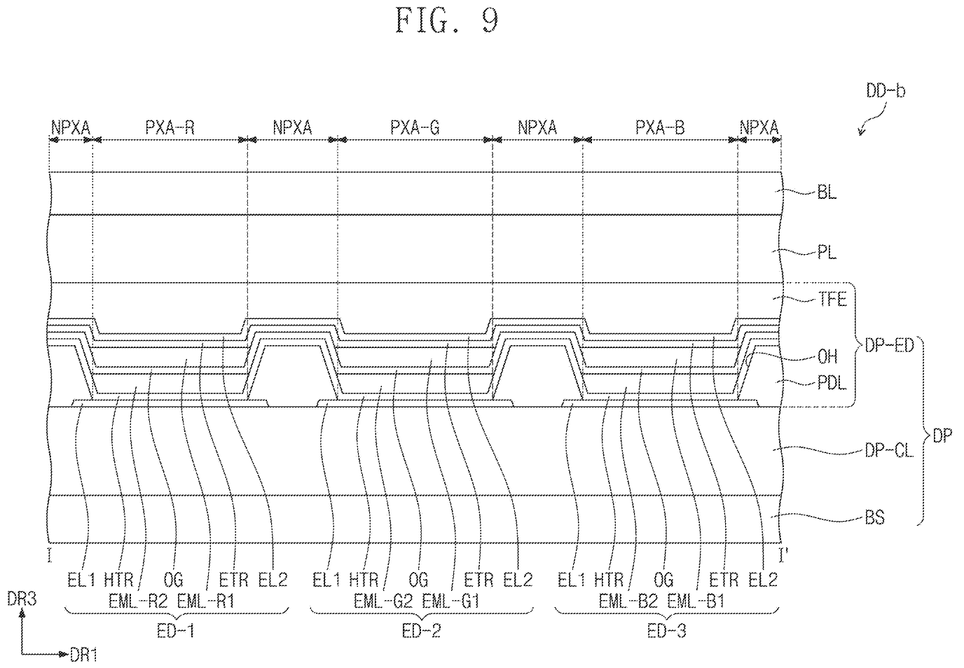

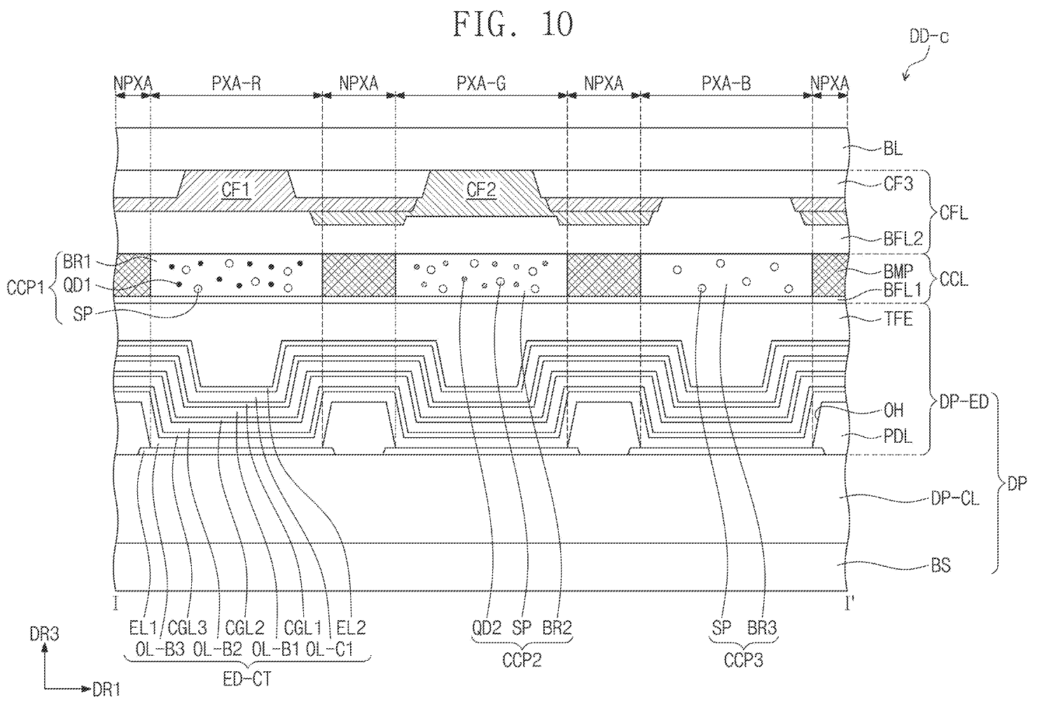

Referring to FIG. 9, a display apparatus DD-b according to an embodiment may include light emitting elements ED-1, ED-2 and ED-3, formed by stacking two emission layers. Compared to the display apparatus DD of an embodiment, shown in FIG. 2, an embodiment shown in FIG. 9 is different in that the first to third light emitting elements ED-1, ED-2 and ED-3 include two emission layers each stacked in a thickness direction. In the first to third light emitting elements ED-1, ED-2 and ED-3, two emission layers may emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. More particularly, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be between the hole transport region HTR and the emission auxiliary part OG. The second red emission layer EML-R2, the second green emission layer EML-G2 and the second blue emission layer EML-B2 may be between the emission auxiliary part OG and the electron transport region ETR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

In some embodiments, an optical auxiliary layer PL may be on a display element layer DP-ED. The optical auxiliary layer PL may include a polarization layer. The optical auxiliary layer PL may be on a display panel DP and may control reflected light at the display panel DP by external light. The optical auxiliary layer PL may not be provided from the display apparatus according to an embodiment.

Different from FIG. 8 and FIG. 9, a display apparatus DD-c in FIG. 10 is shown to include four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in order in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. Among the four light emitting structures, the first to third light emitting structures OL-B1, OL-B2 and OL-B3 may emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

Charge generating layers CGL1, CGL2 and CGL3 disposed among neighboring light emitting structures OL-B1, OL-B2, OL-B3 and OL-C1 may include a p-type or kind charge generating layer and/or an n-type or kind charge generating layer.

In at least one selected from among the light emitting structures OL-B1, OL-B2, OL-B3 and OL-C1, included in the display apparatus DD-c of an embodiment, at least one selected from among the first compound, the second compound, the third compound and the fourth compound of an embodiment may be included.

The light emitting element ED according to an embodiment of the present disclosure may include the first compound of an embodiment in at least one selected from among a hole transport region HTR, an emission layer EML, and an electron transport region ETR, disposed between a first electrode EL1 and a second electrode EL2, or in a capping layer CPL.

For example, the first compound according to an embodiment may be included in the emission layer EML of the light emitting element ED of an embodiment, and the light emitting element of an embodiment may show long-lifetime characteristics.

The first compound of an embodiment includes a connected structure of a fused structure formed with a boron atom as a center with at least one penta-phenyl group, and the trigonal bonding structure of the boron atom is protected by the penta-phenyl group, and molecular stability and multiple resonance properties may be improved.

In the first compound of an embodiment, at least one penta-phenyl group is bonded to a multiple resonance plate-type or kind structure, and the penta-phenyl group is present in perpendicular from a light emitting core (for example, boron atom of Formula 1), and accordingly, molecular interaction may be suppressed or reduced. The first compound of an embodiment introduces a penta-phenyl group, and may show excellent or suitable thermal stability and improved element lifetime.

For example, in order to improve the purity of the compounds utilized as the materials of a light emitting element, a sublimation purification process is required. Materials not introducing a penta-phenyl group to a fused structure formed with a boron atom as a center have high sublimation temperature due to intermolecular interaction, and when sublimation is performed at a high temperature for a long time, thermal stability may be deteriorated including the cleavage of the bond of molecules. However, as in the first compound of an embodiment, materials in which a penta-phenyl group is bonded to a fused structure formed with a boron atom as a center may suppress or reduce intermolecular interaction to assist the reduction of a sublimation temperature, and excellent or suitable thermal stability may be secured. In some embodiments, the penta-phenyl group has properties of not distributing orbital (orbital may not be accessible). Accordingly, when the first compound of an embodiment introducing a penta-phenyl group is utilized as an element material during manufacturing a light emitting element, the approach of radicals, excitons, plarons, or the lifetime, having high energy may be blocked (reduced), and dexter energy transfer from a host/host+pt sensitizer may be suppressed or reduced. Accordingly, when the first compound of an embodiment is utilized, the deterioration phenomenon of a light emitting element may be reduced, material stability may be improved, and the lifetime of a light emitting element may be improved.

Hereinafter, referring to embodiments and comparative embodiments (examples), the fused polycyclic compound utilized as the first compound according to an embodiment and the light emitting element according to an embodiment of the present disclosure will be explained. The following embodiments are illustrations to assist in the understanding of the present disclosure, but the scope of the present disclosure is not limited thereto.

### EXAMPLES

### 1. Synthesis of Fused Polycyclic Compound of an Embodiment

First, the synthetic method of the fused polycyclic compound according to an embodiment will be explained by illustrating the synthetic methods of Compound 8, Compound 14, Compound 16, Compound 24, Compound 42, Compound 65, Compound 72, Compound 75, Compound 81, Compound 88 and Compound 89. In some embodiments, the synthetic methods of the fused polycyclic compounds explained hereinafter are embodiments, and the synthetic method of the fused polycyclic compound according to an embodiment of the present disclosure is not limited by the following embodiments.

### Synthesis of Compound 8

Fused Polycyclic Compound 8 according to an embodiment may be synthesized, for example, by the steps (e.g., acts) of Reaction 1.

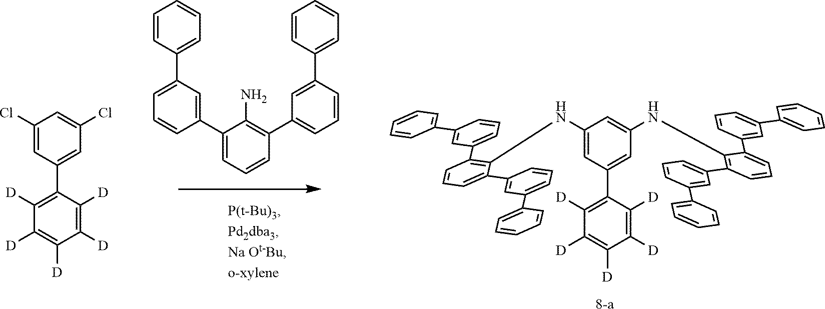

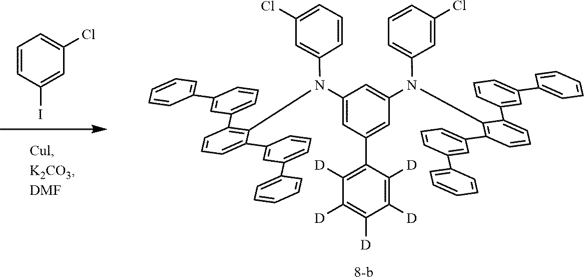

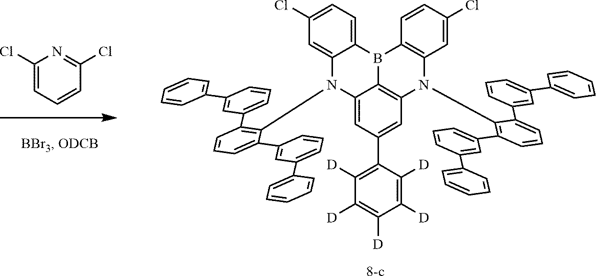

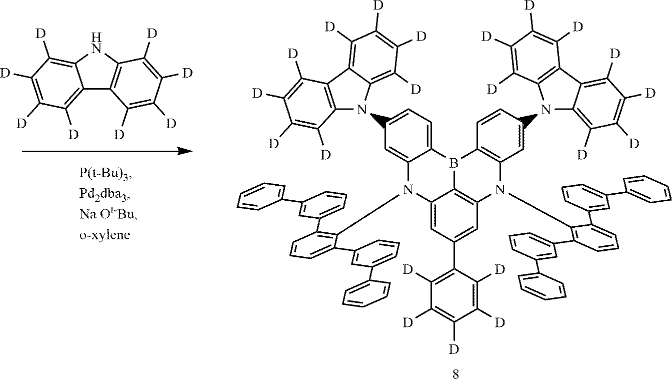

### 1) Synthesis of Intermediate Compound 8-a

Under an argon atmosphere, in a 1 L flask, 3,5-dichloro-1,1′-biphenyl-2′,3′,4′,5′,6′-d5 (5 g, 22 mmol), [1,1′:3′,1″:3″,1‴:3‴,1‴′-quinquephenyl]-2″-amine (17.5 g, 44 mmol), Pd₂dba₃ (1 g, 1.1 mmol), tris-tert-butyl phosphine (1 mL, 2.2 mmol), and sodium tert-butoxide (6.3 g, 66 mmol) were dissolved in 200 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 8-a (white solid, 15 g, 72%). Through ESI-LCMS, the solid thus obtained was identified as Intermediate Compound 8-a.

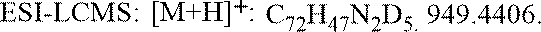

### 2) Synthesis of Intermediate Compound 8-b

Intermediate Compound 8-a (15 g, 16 mmol), 1-chloro-3-iodobenzene (40 g, 160 mmol), CuI (3 g, 16 mmol), and K₂CO₃ (22 g, 160 mmol) were dissolved in 200 mL of DMF, and stirred at about 140° C. for about 3 days under a high pressure in a high pressure reactor. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 8-b (white solid, 10 g, 54%). Through ESI-LCMS, the solid thus obtained was identified as Intermediate Compound 8-b.

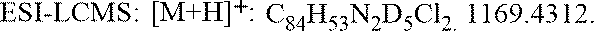

### 3) Synthesis of Intermediate Compound 8-c

Intermediate Compound 8-b (10 g, 16 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 8-c (yellow solid, 1.9 g, 10%). Through ESI-LCMS, the solid thus obtained was identified as Intermediate Compound 8-c.

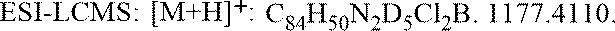

### 4) Synthesis of Compound 8

Under an argon atmosphere, in a 1 L flask, Intermediate Compound 8-c (1.2 g, 1 mmol), 9H-carbazole-1,2,3,4,5,6,7,8-d8 (0.35 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 8 (yellow solid, 1 g, 73%). Through ESI-LCMS, the yellow solid thus obtained was identified as Compound 8.

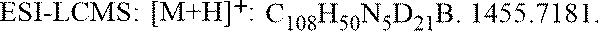

¹H-NMR (400 MHz, CDCI₃): 8.83 (d, 2H), 8.21 (d, 4H), 7.94 (s, 4H), 7.75 (m, 12H), 7.61 (m, 8H), 7.43 (m, 16H), 7.23 (s, 2H), 6.93 (s, 2H).

### Synthesis of Compound 14

Fused Polycyclic Compound 14 according to an embodiment may be synthesized, for example, by the steps of Reaction 2.

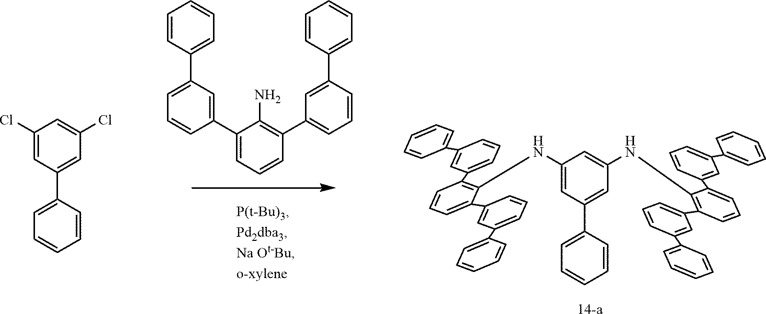

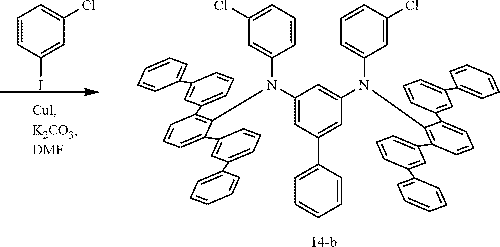

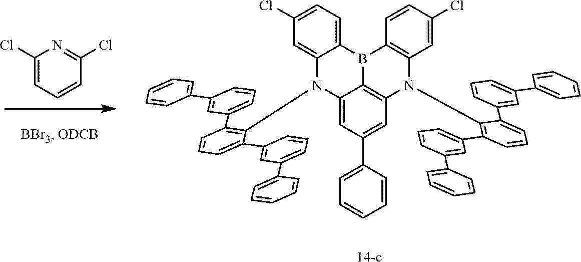

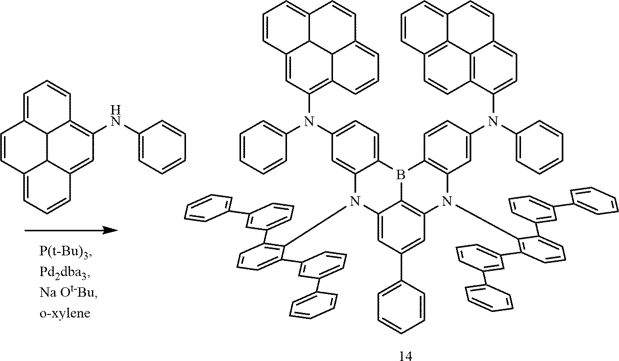

### 1) Synthesis of Intermediate Compound 14-a

Under an argon atmosphere, in a 1 L flask, 3,5-dichloro-1,1′-biphenyl (5 g, 22 mmol), [1,1′:3′,1″:3″,1‴:3‴,1′‴-quinquephenyl]-2″-amine (17.5 g, 44 mmol), Pd₂dba₃ (1 g, 1.1 mmol), tris-tert-butyl phosphine (1 mL, 2.2 mmol), and sodium tert-butoxide (6.3 g, 66 mmol) were dissolved in 200 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 14-a (white solid, 15 g, 72%). Through ESI-LCMS, the solid thus obtained was identified as Intermediate Compound 14-a.

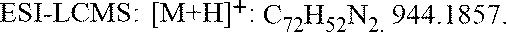

### 2) Synthesis of Intermediate Compound 14-b

Intermediate Compound 14-a (15 g, 16 mmol), 1-chloro-3-iodobenzene (40 g, 160 mmol), CuI (3 g, 16 mmol), and K₂CO₃ (22 g, 160 mmol) were dissolved in 200 mL of DMF, and stirred at about 140° C. for about 3 days under a high pressure in a high pressure reactor. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 14-b (white solid, 10 g, 54%). Through ESI-LCMS, the solid thus obtained was identified as Intermediate Compound 14-b.

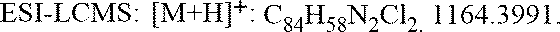

### 3) Synthesis of Intermediate Compound 14-c

Intermediate Compound 14-b (10 g, 16 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 14-c (yellow solid, 1.1 g, 6%). Through ESI-LCMS, the solid thus obtained was identified as Intermediate Compound 14-c.

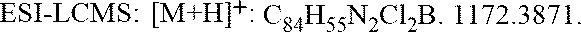

### 4) Synthesis of Compound 14

Under an argon atmosphere, in a 1 L flask, Intermediate Compound 14-c (1.1 g, 1 mmol), N-phenyl-3a1,5a1-dihydropyren-4-amine (0.59 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 14 (yellow solid, 1.4 g, 68%). Through ESI-LCMS and ¹H-NMR, the solid thus obtained was identified as Compound 14.

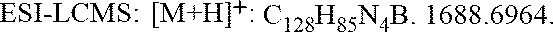

¹H-NMR (400 MHz, CDCI₃): 9.12 (d, 2H), 8.31 (d, 2H), 8.20 (m, 4H), 8.07 (m, 10H), 7.94 (s, 6H), 7.75 (m, 22H), 7.41 (m, 17H), 7.24 (m, 4H), 7.10 (m, 6H), 6.93 (s, 2H), 6.84 (m, 4H).

### Synthesis of Compound 16

Fused Polycyclic Compound 16 according to an embodiment may be synthesized, for example, by the steps of Reaction 3.

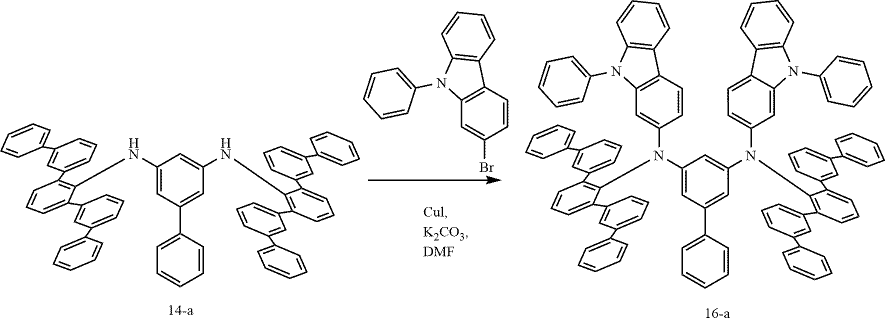

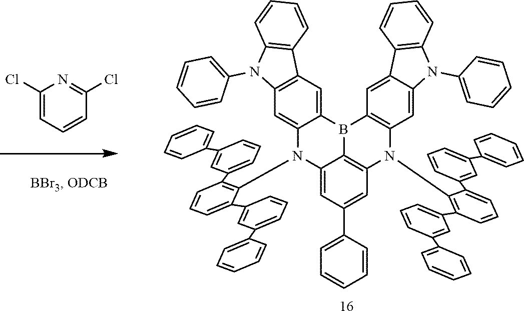

### 1) Synthesis of Intermediate Compound 16-a

Intermediate Compound 14-a (10 g, 10 mmol), 2-bromo-9-phenyl-9H-carbazole (34 g, 100 mmol), CuI (1.9 g, 10 mmol), and K₂CO₃ (14 g, 100 mmol) were dissolved in 100 mL of DMF, and stirred at about 140° C. for about 3 days under a high pressure in a high pressure reactor. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 16-a (white solid, 8.3 g, 58%). Through ESI-LCMS, the solid thus obtained was identified as Intermediate Compound 16-a.

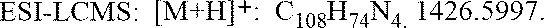

### 2) Synthesis of Compound 16

Intermediate Compound 16-a (8 g, 5.6 mmol) was dissolved in 100 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Compound 16 (yellow solid, 0.88 g, 12%). Through ESI-LCMS and ¹H-NMR, the solid thus obtained was identified as Intermediate Compound 16.

¹H-NMR (400 MHz, CDCI₃): 9.33 (d, 2H), 8.55 (d, 4H), 7.94 (m, 6H), 7.75 (m, 14H), 7.55 (m, 15H), 7.36 (m, 22H), 7.25 (s, 2H), 7.16 (t, 2H), 6.93 (s, 2H).

### Synthesis of Compound 24

Fused Polycyclic Compound 24 according to an embodiment may be synthesized, for example, by the steps of Reaction 4.

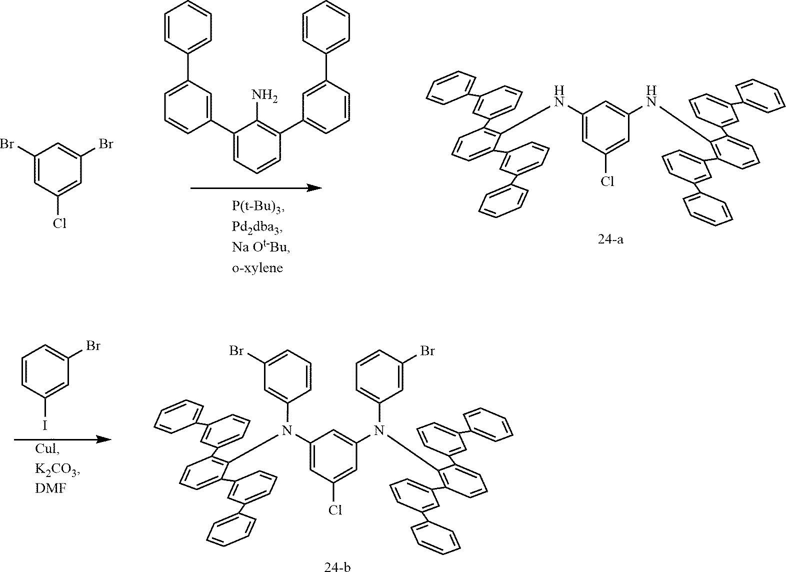

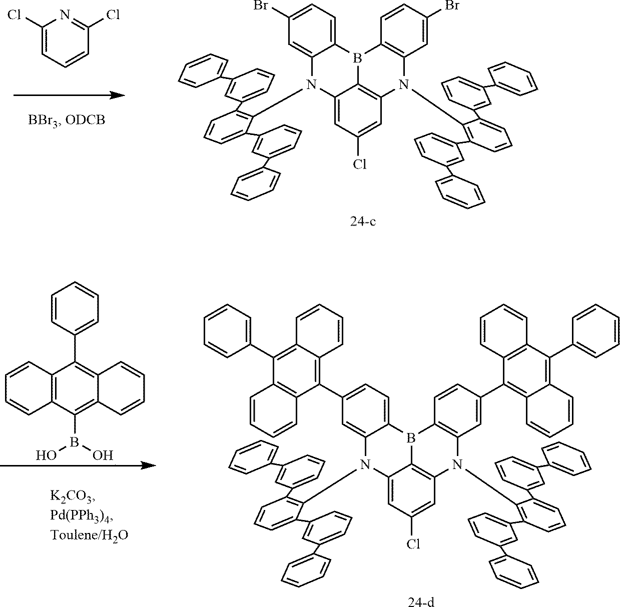

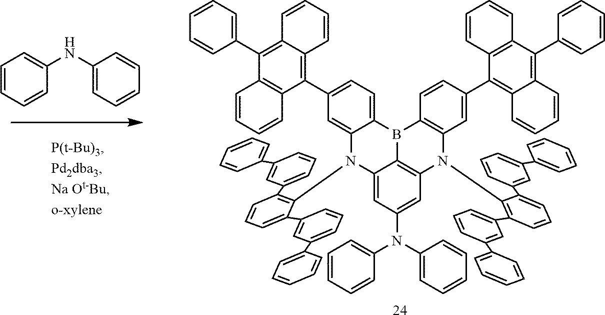

### 1) Synthesis of Intermediate Compound 24-a

Under an argon atmosphere, in a 1 L flask, 1,3-dibromo-5-chlorobenzene (10 g, 37 mmol), [1,1′:3′,1″:3″,1‴:3‴,1‴′-quinquephenyl]-2″-amine (29.4 g, 74 mmol), Pd₂dba₃ (1.7 g, 1.9 mmol), tris-tert-butyl phosphine (1.8 mL, 3.8 mmol), and sodium tert-butoxide (10.6 g, 111 mmol) were dissolved in 400 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 24-a (white solid, 24 g, 73%). Through ESI-LCMS, the solid thus obtained was identified as Intermediate Compound 24-a.

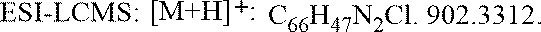

### 2) Synthesis of Intermediate Compound 24-b

Intermediate Compound 24-a (24 g, 26 mmol), 1-chloro-3-iodobenzene (37 g, 132 mmol), CuI (5 g, 26 mmol), and K₂CO₃ (36 g, 260 mmol) were dissolved in 300 mL of DMF, and stirred at about 140° C. for about 3 days under a high pressure in a high pressure reactor. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 24-b (white solid, 15 g, 47%). Through ESI-LCMS, the solid thus obtained was identified as Intermediate Compound 24-b.

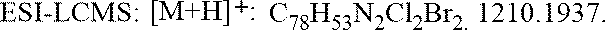

### 3) Synthesis of Intermediate Compound 24-c

Intermediate Compound 24-b (15 g, 12 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 24-c (yellow solid, 1.2 g, 8%). Through ESI-LCMS, the solid thus obtained was identified as Intermediate Compound 24-c.

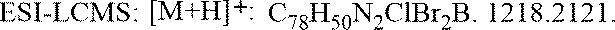

### 4) Synthesis of Intermediate Compound 24-d

Under an argon atmosphere, in a 1 L flask, Intermediate Compound 24-c (1.2 g, 1 mmol), (10-phenylanthracen-9-yl)boronic acid (0.7 mmol), K₂CO₃ (0.4 g, 3 mmol), and Pd(PPh₃)₄ (0.35 g, 0.03 mmol) were dissolved in 10 mL of toluene and 3 mL of water, and stirred at about 100° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 24-d (white solid, 1.2 g, 73%). Through ESI-LCMS, the solid thus obtained was identified as Intermediate Compound 24-d.

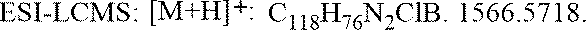

### 5) Synthesis of Compound 24

Under an argon atmosphere, in a 1 L flask, Intermediate Compound 24-d (1.5 g, 1 mmol), diphenylamine (0.34 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 24 (yellow solid, 1.1 g, 65%). Through ESI-LCMS and ¹H-NMR, the solid thus obtained was identified as Compound 24.

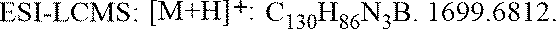

¹H-NMR (400 MHz, CDCI₃): 9.26 (d, 2H), 8.21 (d, 12H), 7.94 (s, 4H), 7.73 (m, 12H), 7.55 (m, 8H), 7.49 (m, 4H), 7.39 (m, 16H), 7.24 (m, 6H), 7.08 (m, 6H), 6.49 (s, 2H).

### Synthesis of Compound 42

Fused Polycyclic Compound 42 according to an embodiment may be synthesized, for example, by the steps of Reaction 5.

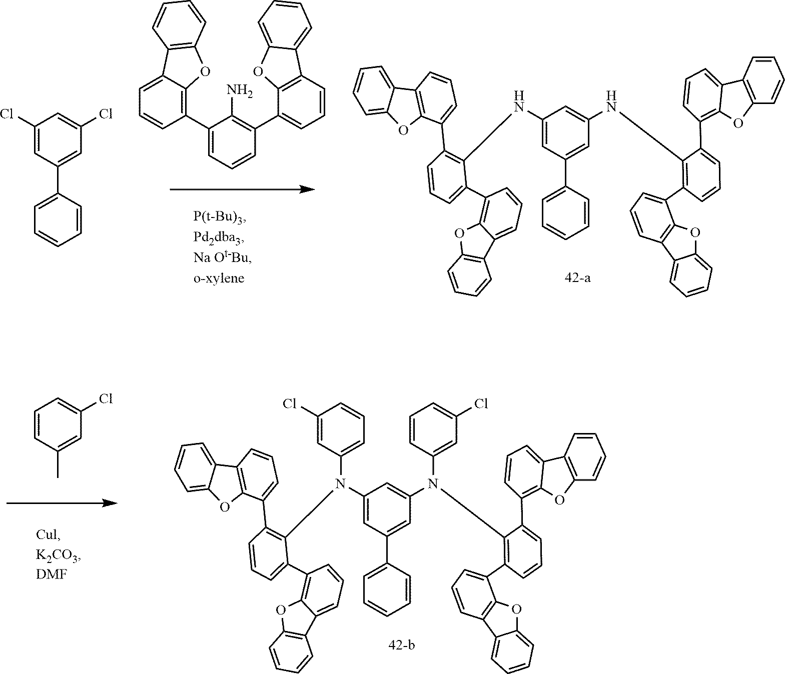

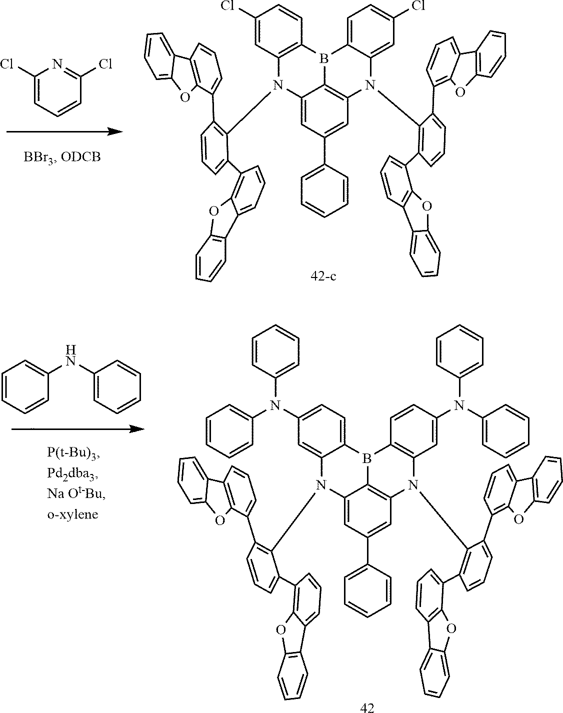

### 1) Synthesis of Intermediate Compound 42-a

Under an argon atmosphere, in a 1 L flask, 1,3-dichloro-1,1′-biphenyl (22 g, 100 mmol), 2,6-bis(dibenzo[b,d]furan-4-yl)aniline (84 g, 200 mmol), Pd₂dba₃ (4.7 g, 5 mmol), tris-tert-butyl phosphine (4.8 mL, 10 mmol), and sodium tert-butoxide (29.1 g, 300 mmol) were dissolved in 1 L of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 42-a (white solid, 53 g, 53%). Through ESI-LCMS, the solid thus obtained was identified as Intermediate Compound 42-a.

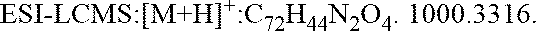

### 2) Synthesis of Intermediate Compound 42-b

Intermediate Compound 42-a (53 g, 52 mmol), 1-chloro-3-iodobenzene (74 g, 260 mmol), CuI (10 g, 52 mmol), and K₂CO₃ (72 g, 520 mmol) were dissolved in 300 mL of DMF, and stirred at about 140° C. for about 3 days under a high pressure in a high pressure reactor. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 42-b (white solid, 26 g, 43%). Through ESI-LCMS, the solid thus obtained was identified as Intermediate Compound 42-b.

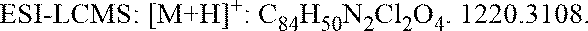

### 3) Synthesis of Intermediate Compound 42-c

Intermediate Compound 42-b (25 g, 20 mmol) was dissolved in 500 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 42-c (yellow solid, 2.2 g, 9%). Through ESI-LCMS, the solid thus obtained was identified as Intermediate Compound 42-c.

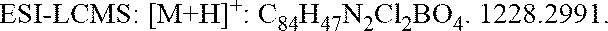

### 4) Synthesis of Compound 42

Under an argon atmosphere, in a 1 L flask, Intermediate Compound 42-c (1.2 g, 1 mmol), diphenylamine (0.34 g, 2 mmol), Pd₂dba₃ (0.05 g, 0.05 mmol), tris-tert-butyl phosphine (0.05 mL, 0.1 mmol), sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 42 (yellow solid, 1.1 g, 65%). Through ESI-LCMS and ¹H-NMR, the solid thus obtained was identified as Compound 42.

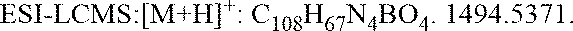

¹H-NMR (400 MHz, CDCI₃): 9.17 (d, 2H), 8.20 (d, 4H), 8.08 (d, 4H), 7.98 (m, 4H), 7.75 (d, 2H), 7.49 (m, 8H), 7.34 (m, 10H), 7.24 (m, 2H), 7.08 (m, 14H), 6.83 (m, 4H), 6.49 (s, 2H).

### Synthesis of Compound 65

Fused Polycyclic Compound 65 according to an embodiment may be synthesized, for example, by the steps of Reaction 6.

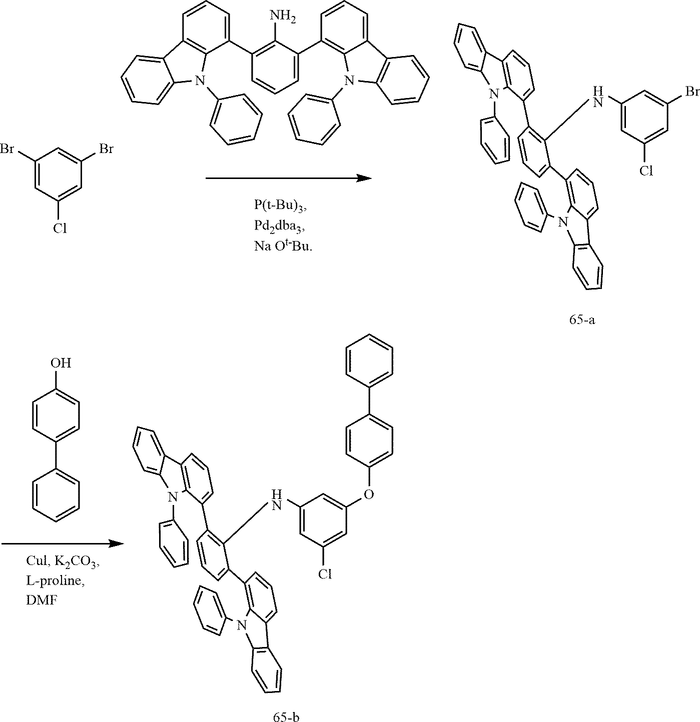

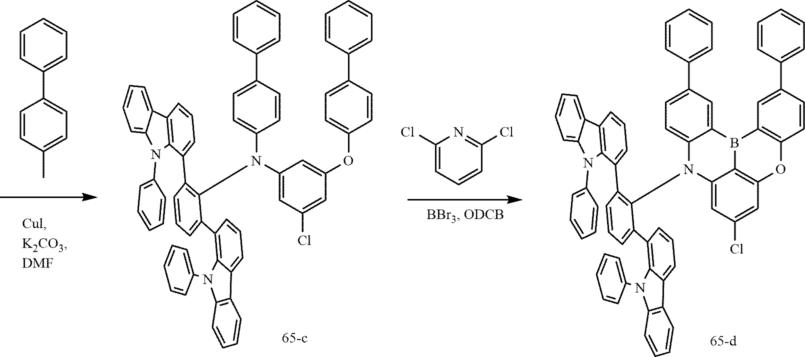

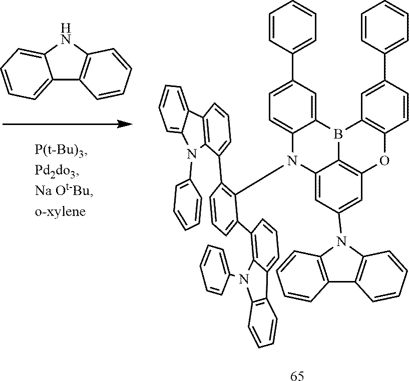

### 1) Synthesis of Intermediate Compound 65-a

Under an argon atmosphere, in a 1 L flask, 1,3-dibromo-5-chlorobenzene (27 g, 100 mmol), 2,6-bis(9-phenyl-9H-carbazol-1-yl)aniline (57 g, 100 mmol), Pd₂dba₃ (4.7 g, 5 mmol), tris-tert-butyl phosphine (4.8 mL, 10 mmol), and sodium tert-butoxide (29.1 g, 300 mmol) were dissolved in 1 L of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 65-a (white solid, 25 g, 33%). Through ESI-LCMS, the solid thus obtained was identified as Intermediate Compound 65-a.

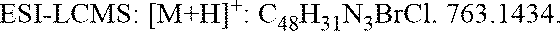

### 2) Synthesis of Intermediate Compound 65-b

Intermediate Compound 65-a (25 g, 34 mmol), [1,1′-biphenyl]-4-ol (5.7 g, 34 mmol), K₂CO₃ (14 g, 102 mmol), CuI (6.5 g, 34 mmol), and L-proline (3.9 g, 34 mmol) were dissolved in 300 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 65-b (white solid, 19 g, 66%). Through ESI-LCMS, the solid thus obtained was identified as Intermediate Compound 65-b.

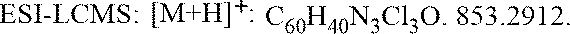

### 3) Synthesis of Intermediate Compound 65-c

Intermediate Compound 65-b (19 g, 22 mmol), 4-iodo-1,1′-biphenyl (12 g, 44 mmol), K₂CO₃ (15 g, 110 mmol), and CuI (4.2 g, 22 mmol) were dissolved in 200 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 65-c (white solid, 10 g, 47%). Through ESI-LCMS, the solid thus obtained was identified as Intermediate Compound 65-c.

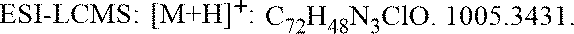

### 4) Synthesis of Intermediate Compound 65-d

Intermediate Compound 65-c (10 g, 10 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 65-d (yellow solid, 1.3 g, 13%). Through ESI-LCMS, the solid thus obtained was identified as Intermediate Compound 65-d.

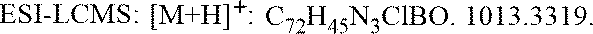

### 5) Synthesis of Compound 65

Under an argon atmosphere, in a 1 L flask, Intermediate Compound 65-d (1 g, 1 mmol), carbazole (0.34 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 65 (yellow solid, 0.8 g, 73%). Through ESI-LCMS and ¹H-NMR, the solid thus obtained was identified as Compound 65.

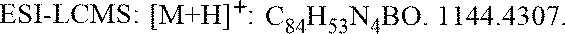

¹H-NMR (400 MHz, CDCI₃): 9.22 (d, 2H), 8.20 (d, 4H), 8.08 (d, 4H), 7.98 (m, 4H), 7.75 (d, 2H), 7.66 (m, 10H), 7.49 (m, 16H), 7.16 (m, 5H), 6.90 (s, 1H), 6.77 (s, 1H), 6.49 (s, 2H).

### Synthesis of Compound 72

Fused Polycyclic Compound 72 according to an embodiment may be synthesized, for example, by the steps of Reaction 7.

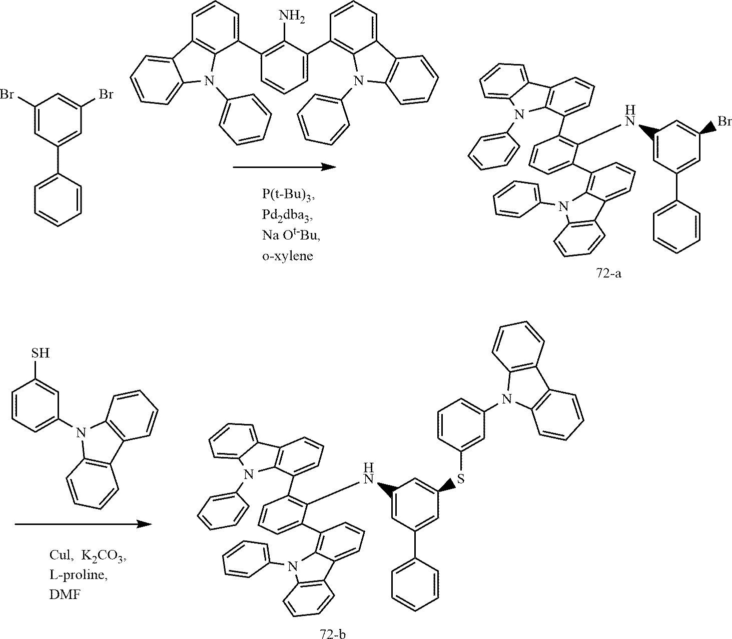

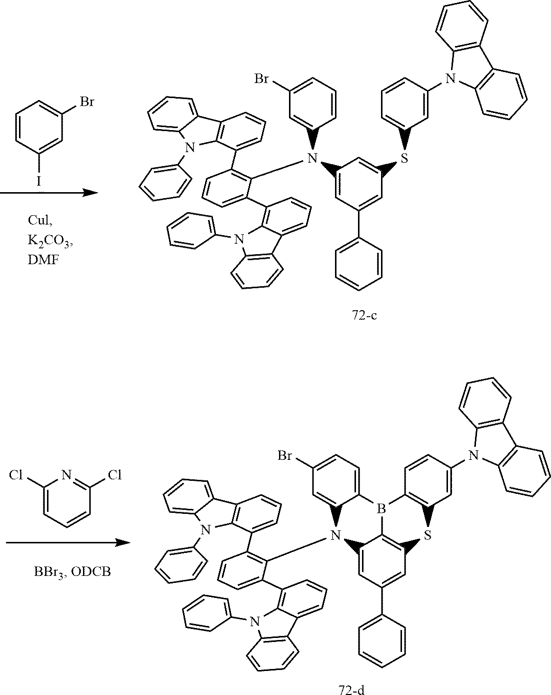

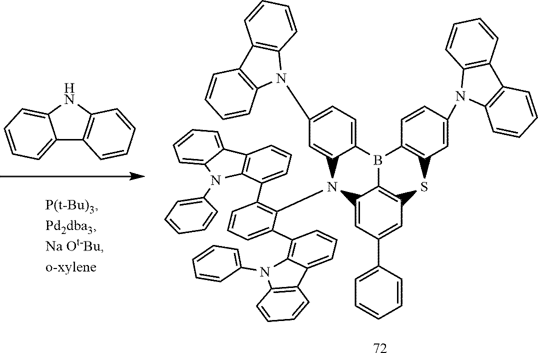

### 1) Synthesis of Intermediate Compound 72-a

Under an argon atmosphere, in a 1 L flask, 3,5-dibromo-1,1′-biphenyl (31.2 g, 100 mmol), 2,6-bis(9-phenyl-9H-carbazol-1-yl)aniline (57 g, 100 mmol), Pd₂dba₃ (4.7 g, 5 mmol), tris-tert-butyl phosphine (4.8 mL, 10 mmol), and sodium tert-butoxide (29.1 g, 300 mmol) were dissolved in 1 L of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 72-a (white solid, 33 g, 41%). Through ESI-LCMS, the solid thus obtained was identified as Intermediate Compound 72-a.

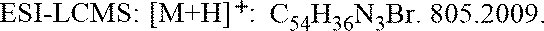

### 2) Synthesis of Intermediate Compound 72-b

Intermediate Compound 72-a (30 g, 37 mmol), 3-(9H-carbazol-9-yl)benzenethiol (10.2 g, 37 mmol), CuI (7 g, 37 mmol), L-proline (4.25 g, 37 mmol), and K₂CO₃ (14 g, 102 mmol) were dissolved in 500 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 72-b (white solid, 24 g, 65%). Through ESI-LCMS, the solid thus obtained was identified as Intermediate Compound 72-b.

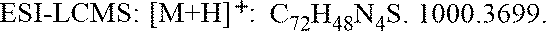

### 3) Synthesis of Intermediate Compound 72-c

Intermediate Compound 72-b (19 g, 24 mmol), 1-bromo-3-iodobenzene (12 g, 44 mmol), K₂CO₃ (15 g, 110 mmol), and CuI (4.2 g, 22 mmol) were dissolved in 200 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 72-c (white solid, 12 g, 43%). Through ESI-LCMS, the solid thus obtained was identified as Intermediate Compound 72-c.

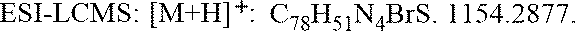

### 4) Synthesis of Intermediate Compound 72-d

Intermediate Compound 72-c (12 g, 10 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 72-d (yellow solid, 1.3 g, 13%). Through ESI-LCMS, the solid thus obtained was identified as Intermediate Compound 72-d.

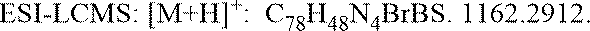

### 5) Synthesis of Compound 72

Under an argon atmosphere, in a 1 L flask, Intermediate Compound 72-d (1.1 g, 1 mmol), carbazole (0.34 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 72 (yellow solid, 0.85 g, 68%). Through ESI-LCMS and ¹H-NMR, the solid thus obtained was identified as Compound 72.

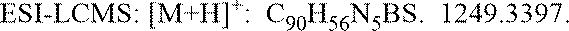

¹H-NMR (400 MHz, CDCI₃): 9.37 (d, 2H), 8.65 (d, 1H), 8.55 (d, 8H), 8.42 (d, 8H), 8.20 (m, 2H), 8.06 (m, 4H), 7.94 (d, 6H), 7.58 (m, 18H), 7.42 (m, 8H), 7.21 (m, 6H), 6.94 (s, 1H).

### Synthesis of Compound 75

Fused Polycyclic Compound 75 according to an embodiment may be synthesized, for example, by the steps of Reaction 8.

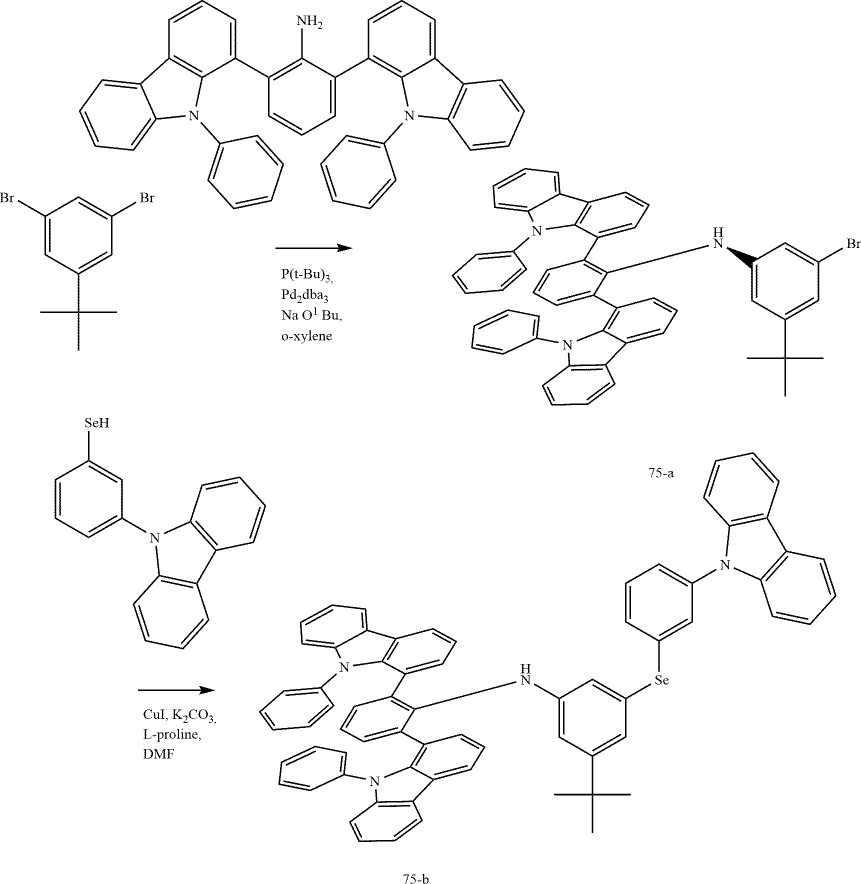

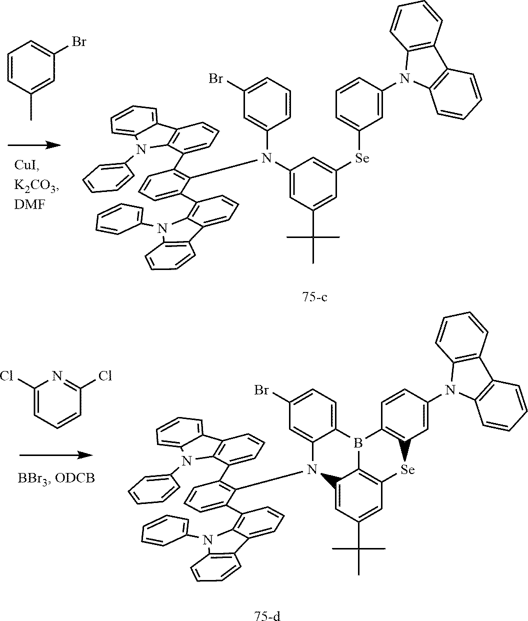

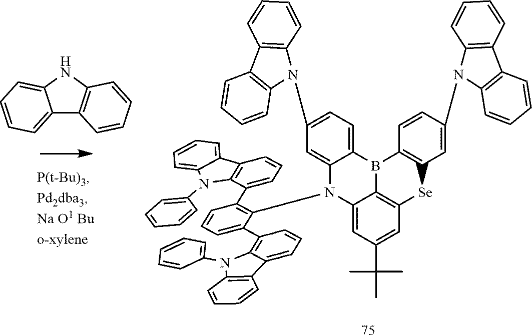

### 1) Synthesis of Intermediate Compound 75-a

Under an argon atmosphere, in a 1 L flask, 1,3-dibromo-5-tert-butylbenzene (29 g, 100 mmol), 2,6-bis(9-phenyl-9H-carbazol-1-yl)aniline (57 g, 100 mmol), Pd₂dba₃ (4.7 g, 5 mmol), tris-tert-butyl phosphine (4.8 mL, 10 mmol), and sodium tert-butoxide (29.1 g, 300 mmol) were dissolved in 1 L of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 75-a (white solid, 40 g, 51%). Through ESI-LCMS, the solid thus obtained was identified as Intermediate Compound 75-a.

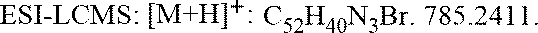

### 2) Synthesis of Intermediate Compound 75-b

Intermediate Compound 75-a (40 g, 50 mmol), 3-(9H-carbazol-9-yl)benzeneselenol (16 g, 50 mmol), CuI (9.5 g, 50 mmol), L-proline (5.8 g, 50 mmol), and K₂CO₃ (21 g, 150 mmol) were dissolved in 500 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 75-b (white solid, 11 g, 21%). Through ESI-LCMS, the solid thus obtained was identified as Intermediate Compound 75-b.

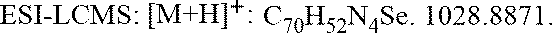

### 3) Synthesis of Intermediate Compound 75-c

Intermediate Compound 75-b (11 g, 11 mmol), 1-bromo-3-iodobenzene (16 g, 55 mmol), K₂CO₃ (15 g, 110 mmol), and CuI (2.1 g, 11 mmol) were dissolved in 150 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 75-c (white solid, 7.3 g, 56%). Through ESI-LCMS, the solid thus obtained was identified as Intermediate Compound 75-c.

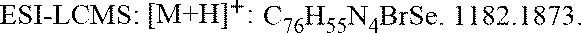

### 4) Synthesis of Intermediate Compound 75-d

Intermediate Compound 75-c (7 g, 5.9 mmol) was dissolved in 150 mL of o-dichlorobenzene and cooled to about 0° C. BBr₃ (5 equiv.) was slowly added thereto dropwisel, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Intermediate Compound 75-d (yellow solid, 1.05 g, 15%). Through ESI-LCMS, the solid thus obtained was identified as Intermediate Compound 75-d.

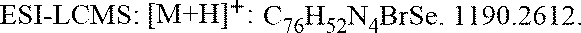

### 5) Synthesis of Compound 75

Under an argon atmosphere, in a 1 L flask, Intermediate Compound 75-d (1.2 g, 1 mmol), carbazole (0.34 g, 2 mmol), Pd₂dba₃ (0.05 g, 0.05 mmol), tris-tert-butyl phosphine (0.05 mL, 0.1 mmol), and sodium tert-butoxide (0.3 g, 3 mmol) were dissolved in 10 mL of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Compound 75 (yellow solid, 0.8 g, 73%). Through ESI-LCMS and ¹H-NMR, the solid thus obtained was identified as Compound 75.

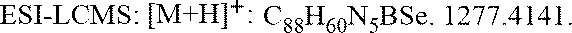

¹H-NMR (400 MHz, CDCI₃): 9.42 (d, 2H), 8.67 (d, 2H), 8.55 (d, 4H), 8.42 (d, 2H), 8.29 (d, 2H), 8.19 (m, 5H), 8.06 (d, 2H), 7.94 (d, 4H), 7.73 (d, 2H), 7.58 (m, 18H), 7.39 (m, 3H), 7.20 (m, 5H), 7.02 (s, 1H), 1.32 (s, 9H).

### Synthesis of Compound 81

Fused Polycyclic Compound 81 according to an embodiment may be synthesized, for example, by the steps of Reaction 9.

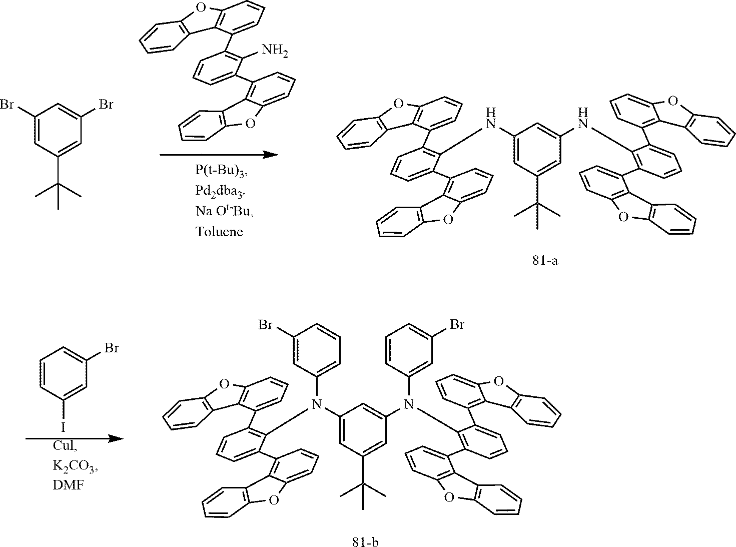

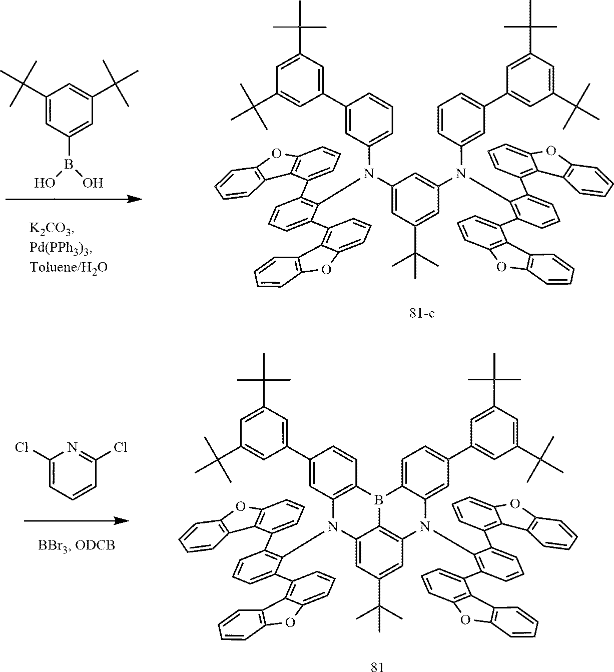

### 1) Synthesis of Intermediate Compound 81-a

Under an argon atmosphere, in a 1 L flask, 1,3-dibromo-5-tert-butylbenzene (29 g, 100 mmol), 2,6-bis(dibenzo[b,d]furan-1-yl)aniline (85 g, 200 mmol), Pd₂dba₃ (4.7 g, 5 mmol), tris-tert-butyl phosphine (4.8 mL, 10 mmol), and sodium tert-butoxide (29.1 g, 300 mmol) were dissolved in 1 L of o-xylene, and stirred at about 140° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 81-a (white solid, 65 g, 67%). Through ESI-LCMS, the solid thus obtained was identified as Intermediate Compound 81-a.

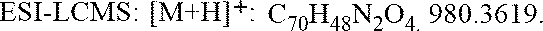

### 2) Synthesis of Intermediate Compound 81-b

Intermediate Compound 81-a (50 g, 51 mmol), 1-bromo-3-iodobenzene (30 g, 100 mmol), K₂CO₃ (20 g, 150 mmol), and CuI (10 g, 50 mmol) were dissolved in 500 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 81-b (white solid, 35 g, 53%). Through ESI-LCMS, the solid thus obtained was identified as Intermediate Compound 81-b.

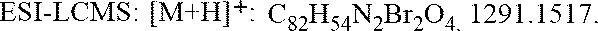

### 3) Synthesis of Intermediate Compound 81-c

Intermediate Compound 81-b (30 g, 23 mmol), 3,5-di-tert-butyl-phenyl boronic acid (11 g, 46 mmol), K₂CO₃ (8.2 g, 60 mmol), and Pd(PPh₃)₄ (1.3 g, 1.15 mmol) were dissolved in 150 mL of toluene and 50 mL of water, and stirred at about 110° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 81-c (white solid, 25 g, 71%). Through ESI-LCMS, the solid thus obtained was identified as Intermediate Compound 81-c.

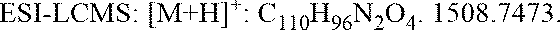

### 4) Synthesis of Compound 81

Intermediate Compound 81-c (10 g, 6.6 mmol) was dissolved in 150 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Compound 81 (yellow solid, 0.9 g, 9%). Through ESI-LCMS and ¹H-NMR, the solid thus obtained was identified as Compound 81.

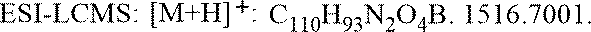

¹H-NMR (400 MHz, CDCI₃): 9.38 (d, 2H), 8.20 (d, 4H), 7.98 (d, 4H), 7.82 (d, 4H), 7.69 (d, 4H), 7.65 (s, 4H), 7.55 (s, 2H), 7.48 (m, 8H), 7.39 (m, 10H), 7.31 (m, 4H), 7.06 (s, 2H), 1.32 (s, 18H), 1.22 (s, 9H).

### Synthesis of Compound 88

Fused Polycyclic Compound 88 according to an embodiment may be synthesized, for example, by the steps of Reaction 10.

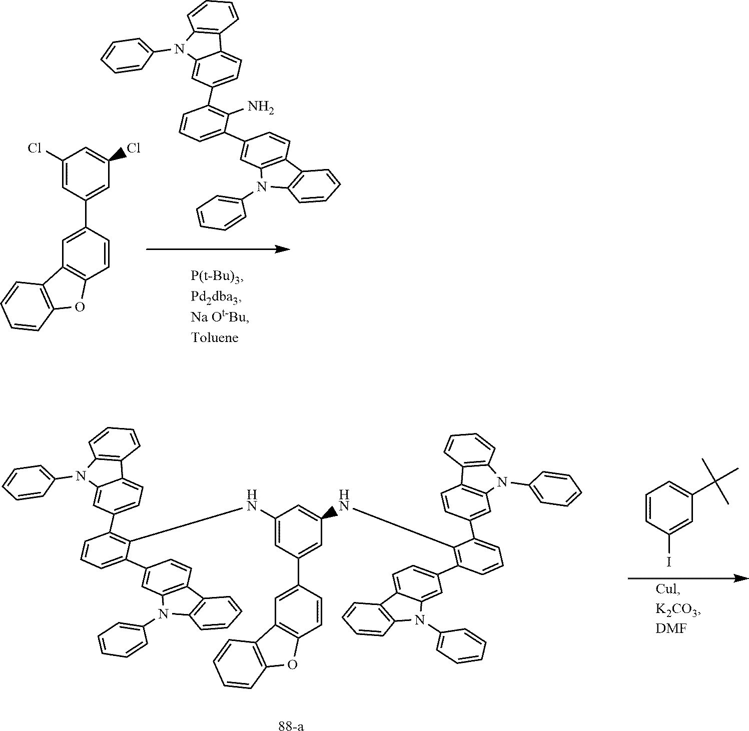

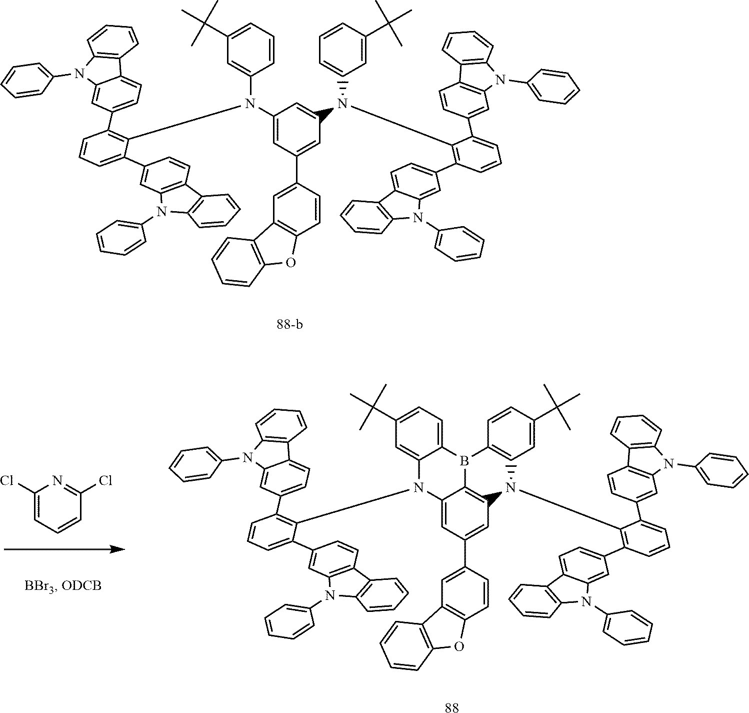

### 1) Synthesis of Intermediate Compound 88-a

Under an argon atmosphere, in a 1 L flask, 2-(3,5-dichlorophenyl)dibenzo[b,d]furan (10 g, 32 mmol), 2,6-bis(9-phenyl-9H-carbazol-2-yl)aniline (37 g, 64 mmol), Pd₂dba₃ (1.46 g, 1.6 mmol), tris-tert-butyl phosphine (1.5 mL, 3.2 mmol), and sodium tert-butoxide (9.6 g, 100 mmol) were dissolved in 300 mL of toluene, and stirred at about 110° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 88-a (white solid, 32.5 g, 73%). Through ESI-LCMS, the solid thus obtained was identified as Intermediate Compound 88-a.

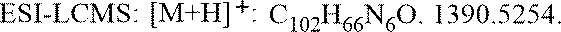

### 2) Synthesis of Intermediate Compound 88-b

Intermediate Compound 88-a (30 g, 22 mmol), 3-tert-butyl-iodobenzene (11 g, 43 mmol), K₂CO₃ (15.2 g, 110 mmol), and CuI (4.2 g, 22 mmol) were dissolved in 200 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 88-b (white solid, 16 g, 44%). Through ESI-LCMS, the solid thus obtained was identified as Intermediate Compound 88-b.

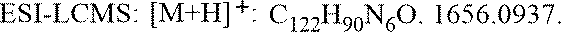

### 3) Synthesis of Compound 88

Intermediate Compound 88-b (10 g, 6 mmol) was dissolved in 150 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwisel. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Compound 88 (yellow solid, 1.3 g, 13%). Through ESI-LCMS and ¹H-NMR, the solid thus obtained was identified as Compound 88.

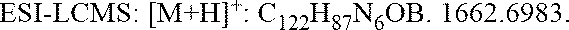

¹H-NMR (400 MHz, CDCI₃): 9.22 (d, 2H), 8.62 (d, 2H), 8.55 (d, 2H), 8.31 (d, 2H), 8.22 (m, 8H), 7.91 (m, 7H), 7.74 (m, 4H), 7.55 (m, 20H), 7.43 (m, 5H), 7.39 (m, 8H), 7.20 (m, 4H), 6.97 (d, 2H), 6.53 (s, 2H), 1.48 (s, 18H).

### Synthesis of Compound 89

Fused Polycyclic Compound 89 according to an embodiment may be synthesized, for example, by the steps of Reaction 11.

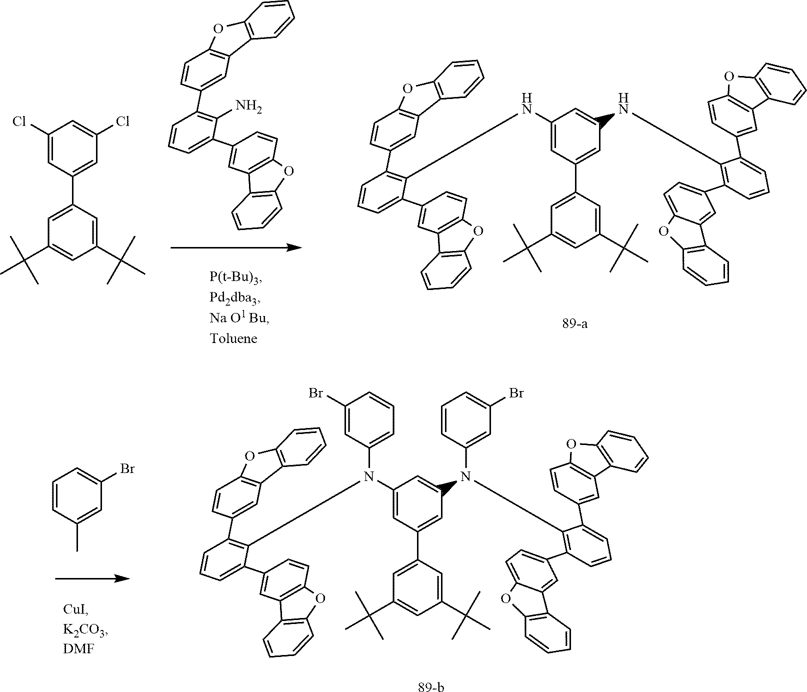

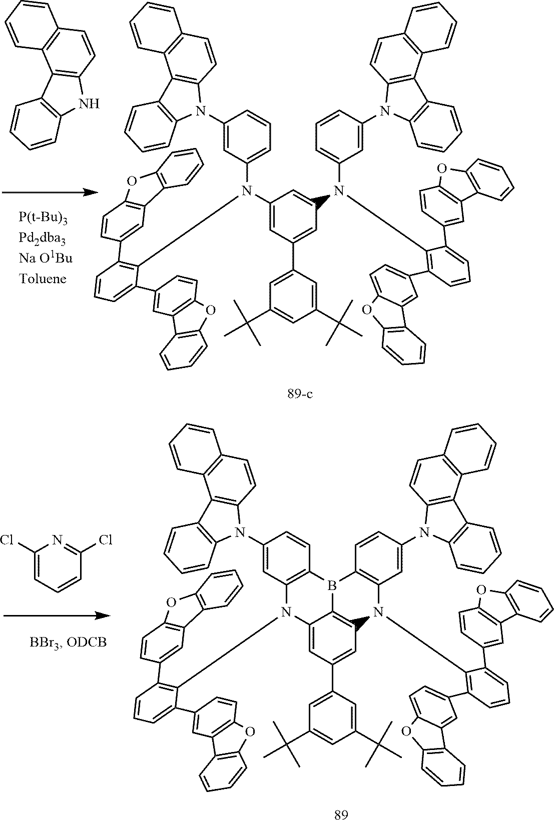

### 1) Synthesis of Intermediate Compound 89-a

Under an argon atmosphere, in a 1 L flask, 3,5-di-tert-butyl-3′,5′-dichloro-1,1′-biphenyl (10 g, 30 mmol), 2,6-bis(dibenzo[b,d]furan-2-yl)aniline (25.4 g, 60 mmol), Pd₂dba₃ (1.46 g, 1.6 mmol), tris-tert-butyl phosphine (1.5 mL, 3.2 mmol), and sodium tert-butoxide (9.6 g, 100 mmol) were dissolved in 300 mL of toluene, and stirred at about 110° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 89-a (white solid, 23 g, 69%). Through ESI-LCMS, the solid thus obtained was identified as Intermediate Compound 89-a.

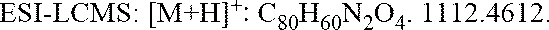

### 2) Synthesis of Intermediate Compound 89-b

Intermediate Compound 89-a (23 g, 20 mmol), 3-bromo-iodobenzene (5.8 g, 40 mmol), K₂CO₃ (15.2 g, 110 mmol), and CuI (4.2 g, 22 mmol) were dissolved in 200 mL of DMF, and stirred at about 160° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 89-b (white solid, 13 g, 46%). Through ESI-LCMS, the solid thus obtained was identified as Intermediate Compound 89-b.

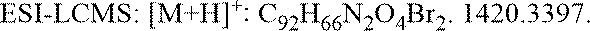

### 3) Synthesis of Intermediate Compound 89-c

Under an argon atmosphere, in 1 L flask, Intermediate Compound 89-a (13 g, 9 mmol), 7H-benzo[c]carbazole (4 g, 18 mmol), Pd₂dba₃ (0.4 g, 0.45 mmol), tris-tert-butyl phosphine (0.5 mL, 0.9 mmol), and sodium tert-butoxide (2.9 g, 30 mmol) were dissolved in 100 mL of toluene, and stirred at about 110° C. for about 12 hours. After cooling, the reaction product was extracted with ethyl acetate and water, an organic layer was separated and dried with MgSO₄, and then, filtering was performed. Organic layers were collected, and the solvent was removed under a reduced pressure. The crude product thus obtained was separated and purified by column chromatography utilizing silica gel and CH₂CI₂ and hexane as developing solvents to obtain Intermediate Compound 89-c (white solid, 10.7 g, 70%). Through ESI-LCMS, the solid thus obtained was identified as Intermediate Compound 89-c.

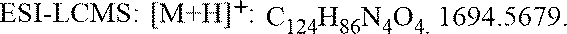

### 4) Synthesis of Compound 89

Intermediate Compound 89-c (10 g, 5.7 mmol) was dissolved in 200 mL of o-dichlorobenzene and cooled to about 0° C. BBr₃ (5 equiv.) was slowly added thereto dropwise, stirring was performed for about 20 minutes, and 2,6-dichloropyridine (3 equiv.) was added thereto dropwise. After stirring at room temperature for about 6 hours, the temperature was raised to about 180° C., and stirring was performed for about 12 hours. After cooling, diisopropylethylamine (5 equiv.) was added thereto dropwise to terminate the reaction, and the crude product thus obtained was separated and purified by column chromatography utilizing silica gel and CH₂CI₂ and hexane as developing solvents to obtain Compound 89 (yellow solid, 0.77 g, 9%). Through ESI-LCMS and ¹H-NMR, the solid thus obtained was identified as Compound 89.

ESI-LCMS: [M+H]⁺: C₁₂₄H₈₃N₄O₄B. 1702.6611.

¹H-NMR (400 MHz, CDCI₃): 9.56 (d, 2H), 8.54 (d, 4H), 8.20 (d, 4H), 7.94 (d, 2H, 7.88 (m, 16H), 7.73 (s, 2H), 7.61 (m, 13H), 7.35 (m, 12H), 7.30 (d, 2H), 7.16 (m, 2H), 6.93 (s, 2H), 1.61 (s, 18H).

### 2. Evaluation of Properties of Fused Polycyclic Compounds

Various (suitable) physical properties on the Example Compounds and Comparative Compounds were measured, and the results are shown in Table 1. Example Compounds

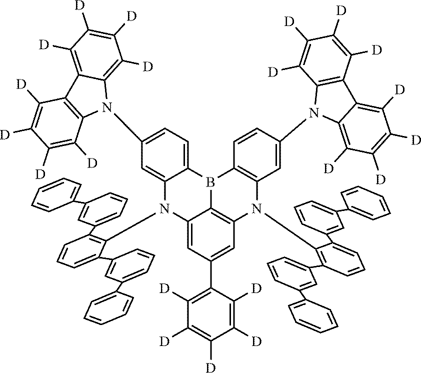 [SMILES: [2H]c1c([2H])c([2H])c(-c2cc3c4c(c2)N(c2c(-c5cccc(-c6ccccc6)c5)cccc2-c2cccc(-c5ccccc5)c2)c2cc(-n5c6c([2H])c([2H])c([2H])c([2H])c6c6c([2H])c([2H])c([2H])c([2H])c65)ccc2B4c2ccc(-n4c5c([2H])c([2H])c([2H])c([2H])c5c5c([2H])c([2H])c([2H])c([2H])c54)cc2N3c2c(-c3cccc(-c4ccccc4)c3)cccc2-c2cccc(-c3ccccc3)c2)c([2H])c1[2H]]

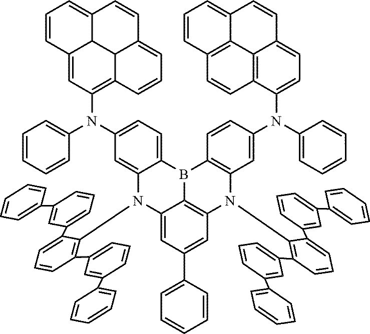 [SMILES: C1=CC2=CC(N(c3ccccc3)c3ccc4c(c3)N(c3c(-c5cccc(-c6ccccc6)c5)cccc3-c3cccc(-c5ccccc5)c3)c3cc(-c5ccccc5)cc5c3B4c3ccc(N(c4ccccc4)c4ccc6ccc7cccc8ccc4c6c78)cc3N5c3c(-c4cccc(-c5ccccc5)c4)cccc3-c3cccc(-c4ccccc4)c3)=C3C=CC=C4C=CC(=C1)C2C43]

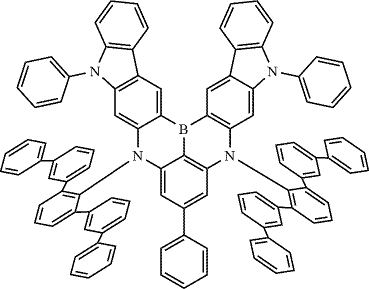 [SMILES: c1ccc(-c2cccc(-c3cccc(-c4cccc(-c5ccccc5)c4)c3N3c4cc5c(cc4B4c6cc7c8ccccc8n(-c8ccccc8)c7cc6N(c6c(-c7cccc(-c8ccccc8)c7)cccc6-c6cccc(-c7ccccc7)c6)c6cc(-c7ccccc7)cc3c64)c3ccccc3n5-c3ccccc3)c2)cc1]

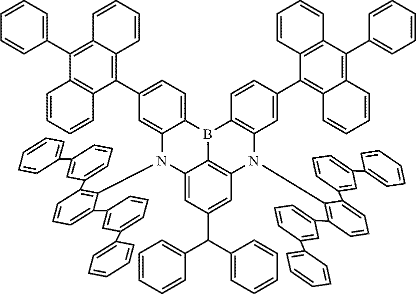 [SMILES: c1ccc(-c2cccc(-c3cccc(-c4cccc(-c5ccccc5)c4)c3N3c4cc(-c5c6ccccc6c(-c6ccccc6)c6ccccc56)ccc4B4c5ccc(-c6c7ccccc7c(-c7ccccc7)c7ccccc67)cc5N(c5c(-c6cccc(-c7ccccc7)c6)cccc5-c5cccc(-c6ccccc6)c5)c5cc(C(c6ccccc6)c6ccccc6)cc3c54)c2)cc1]

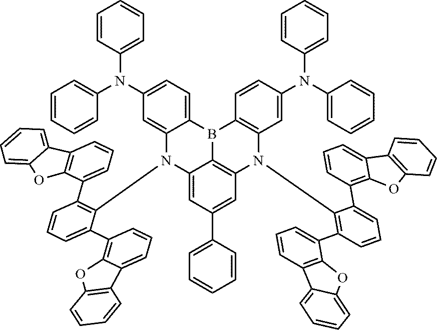 [SMILES: c1ccc(-c2cc3c4c(c2)N(c2c(-c5cccc6c5oc5ccccc56)cccc2-c2cccc5c2oc2ccccc25)c2cc(N(c5ccccc5)c5ccccc5)ccc2B4c2ccc(N(c4ccccc4)c4ccccc4)cc2N3c2c(-c3cccc4c3oc3ccccc34)cccc2-c2cccc3c2oc2ccccc23)cc1]

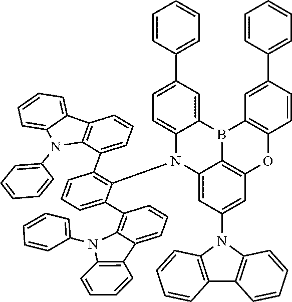 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)O3)cc1]

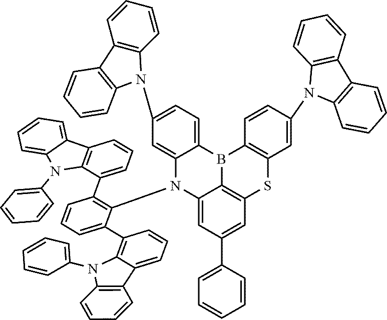 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2S3)cc1]

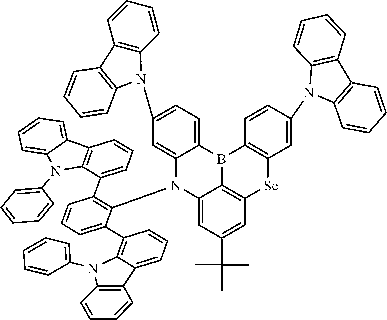 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1[Se]2]

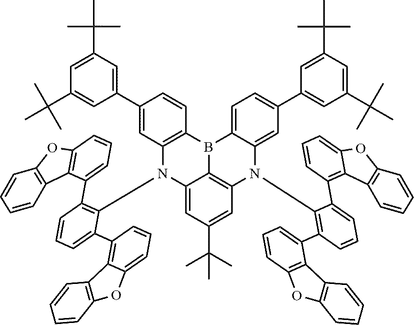 [SMILES: CC(C)(C)c1cc(-c2ccc3c(c2)N(c2c(-c4cccc5oc6ccccc6c45)cccc2-c2cccc4oc5ccccc5c24)c2cc(C(C)(C)C)cc4c2B3c2ccc(-c3cc(C(C)(C)C)cc(C(C)(C)C)c3)cc2N4c2c(-c3cccc4oc5ccccc5c34)cccc2-c2cccc3oc4ccccc4c23)cc(C(C)(C)C)c1]

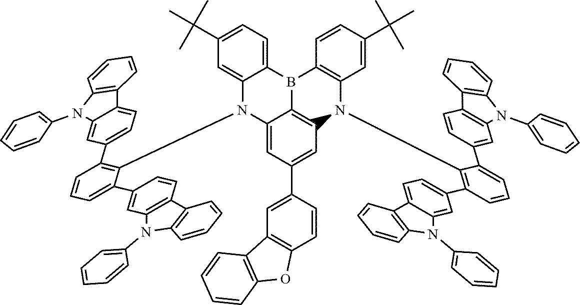

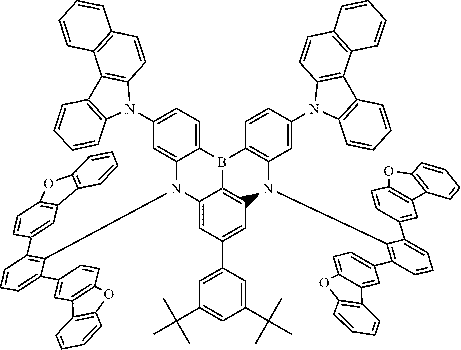

### Comparative Compounds

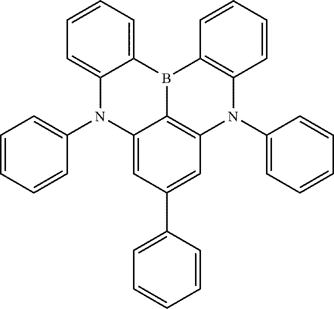 [SMILES: c1ccc(-c2cc3c4c(c2)N(c2ccccc2)c2ccccc2B4c2ccccc2N3c2ccccc2)cc1]

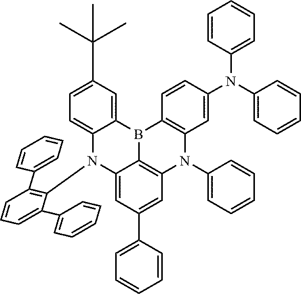 [SMILES: CC(C)(C)c1ccc2c(c1)B1c3ccc(N(c4ccccc4)c4ccccc4)cc3N(c3ccccc3)c3cc(-c4ccccc4)cc(c31)N2c1c(-c2ccccc2)cccc1-c1ccccc1]

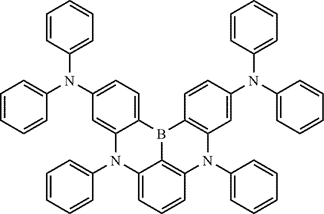 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

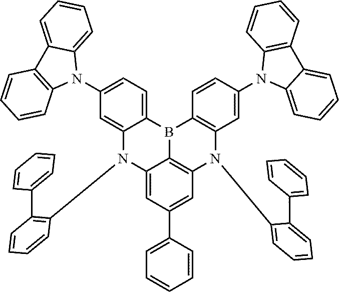 [SMILES: c1ccc(-c2cc3c4c(c2)N(c2ccccc2-c2ccccc2)c2cc(-n5c6ccccc6c6ccccc65)ccc2B4c2ccc(-n4c5ccccc5c5ccccc54)cc2N3c2ccccc2-c2ccccc2)cc1]

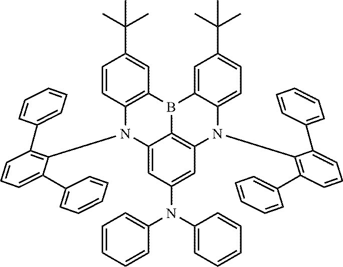 [SMILES: CC(C)(C)c1ccc2c(c1)B1c3cc(C(C)(C)C)ccc3N(c3c(-c4ccccc4)cccc3-c3ccccc3)c3cc(N(c4ccccc4)c4ccccc4)cc(c31)N2c1c(-c2ccccc2)cccc1-c1ccccc1]

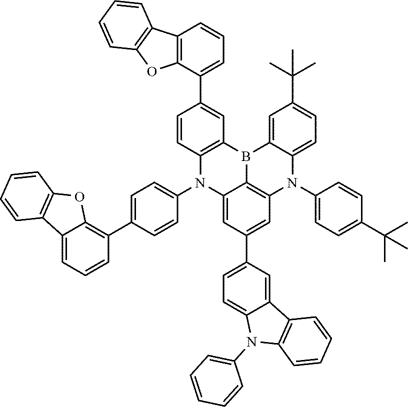 [SMILES: CC(C)(C)c1ccc(N2c3ccc(C(C)(C)C)cc3B3c4cc(-c5cccc6c5oc5ccccc56)ccc4N(c4ccc(-c5cccc6c5oc5ccccc56)cc4)c4cc(-c5ccc6c(c5)c5ccccc5n6-c5ccccc5)cc2c43)cc1]

In Table 1, the highest occupied molecular orbital (HOMO) energy level and the lowest unoccupied molecular orbital (LUMO) energy level were measured utilizing Smart Manager software of an SP2 electrochemical workstation equipment of ZIVE LAB Co. ΔE_{ST} represents the difference (S1-T1) between the lowest excitation singlet energy level (S1) and the lowest excitation triplet energy level (T1). λ_{Abs} was measured utilizing Labsolution UV-Vis software of a UV-1800 UV/Visible Scanning Spectrophotometer equipment of SHIMADZU Co., equipped with a Deuterium/Tungsten-Halogen light source and a silicon photodiode. λₑₘᵢ, λ_{film}, full-width quarter maximum (FWQM), the lowest excitation singlet energy level (S1) and the lowest excitation triplet energy level (T1) were measured utilizing FluorEssence software of a fluoromax+ spectrometer equipment of HORIBA Co., equipped with a xenon light source and a monochromator. Photoluminescence quantum yield (PLQY) was measured utilizing PLQY measurement software of a Quantaurus-QY Absolute PL quantum yield spectrometer equipment of Hamamatsu Co., equipped with a xenon light source, a monochromator, a photonic multichannel analyzer, and an integrating sphere. The lifetime (_{T}) of a compound was measured utilizing a Transient fluorescence lifetime spectrometer (equipped with a streak camera) of Hamamatsu Co., a PLP-10 Laser diode (M10306, excitation source), and a laser control panel program, and analyzed with an analyze mode utilizing a Fitting: u8167 program. Stokes-sift represents the difference between the maximum wavelength during absorbing energy and the maximum wavelength during emitting energy.

TABLE 1

| | Dopant | HOMO (eV) | LUMO (eV) | S1 (eV) | T1 (eV) | ΔE_{ST} (eV) | T (µs) | PLQY (%) | λ_{Abs} (nm) | λₑₘᵢ (nm) | λ_{film} (nm) | Stokes-shift | FWQM (nm) |
|---|---|---|---|---|---|---|---|---|---|---|---|---|---|
| Example 1 | Compound 8 | -5.48 | -2.42 | 2.68 | 2.54 | 0.14 | 98 | 95 | 449 | 462 | 463 | 13 | 36 |
| Example 2 | Compound 14 | -5.21 | -2.16 | 2.71 | 1.96 | 0.75 | - | 91 | 446 | 458 | 460 | 12 | 28 |
| Example 3 | Compound 16 | -5.09 | -2.41 | 2.66 | 2.47 | 0.19 | 196 | 88 | 456 | 468 | 469 | 12 | 32 |
| Example 4 | Compound 24 | -5.32 | -2.41 | 2.64 | - | - | - | 80 | 448 | 462 | 463 | 15 | 38 |
| Example 5 | Compound 42 | -5.15 | -2.07 | 2.71 | 2.55 | 0.16 | 84 | 78 | 444 | 458 | 459 | 14 | 31 |
| Example 6 | Compound 65 | -5.25 | -1.98 | 2.73 | 2.52 | 0.21 | 156 | 89 | 442 | 455 | 456 | 13 | 41 |
| Example 7 | Compound 72 | -5.24 | -2.12 | 2.71 | 2.54 | 0.17 | 62 | 74 | 447 | 460 | 461 | 14 | 42 |
| Example 8 | Compound 75 | -5.35 | -2.35 | 2.69 | 2.56 | 0.13 | 7 | 56 | 446 | 461 | 462 | 15 | 43 |
| Example 9 | Compound 81 | -5.25 | -2.36 | 2.71 | 2.61 | 0.10 | 73 | 88 | 449 | 458 | 460 | 9 | 39 |
| Example 10 | Compound 88 | -5.43 | -2.22 | 2.70 | 2.55 | 0.15 | 128 | 93 | 445 | 455 | 457 | 10 | 36 |
| Example 11 | Compound 89 | -5.39 | -2.24 | 2.71 | 2.56 | 0.15 | 92 | 91 | 450 | 460 | 461 | 10 | 35 |
| Comparative Example 1 | Compound a | -5.25 | -2.05 | 2.71 | 2.52 | 0.19 | 242. 1 | 85 | 447 | 461 | 467 | 17 | 40 |
| Comparative Example 2 | Compound b | -5.41 | -2.38 | 2.70 | 2.55 | 0.15 | 111 | 92 | 448 | 462 | 465 | 14 | 39 |
| Comparative Example 3 | Compound c | -5.29 | -2.17 | 2.70 | 2.56 | 0.14 | 112 | 90 | 447 | 459 | 463 | 12 | 38 |
| Comparative Example 4 | Compound d | -5.47 | -2.41 | 2.68 | 2.53 | 0.15 | 115 | 88 | 449 | 462 | 465 | 13 | 37 |
| Comparative Example 5 | Compound e | -5.11 | -2.38 | 2.76 | 2.60 | 0.16 | 48 | 72 | 437 | 450 | 452 | 13 | 46 |
| Comparative Example 6 | Compound f | -5.25 | -2.43 | 2.65 | 2.51 | 0.14 | 121 | 69 | 455 | 468 | 470 | 13 | 38 |

Referring to Table 1, the Example Compounds and the Comparative Compounds showed ΔE_{ST} of about 0.2 eV or less, and the triplet excitons could rapidly harvest the singlet excitons, and it could be found that the compounds could be applied as thermally activated delayed fluorescence dopants.

### 3. Manufacture and Evaluation of Light Emitting Element 1

The evaluation on the light emitting elements including the Example Compounds and Comparative Compounds in an emission layer was performed by a method describedbelow. The method of manufacturing a light emitting element for evaluating the element is also described.

Light emitting elements of Example 1 to Example 11 were manufactured utilizing Example Compounds 8, 14, 16, 24, 42, 65, 72, 75, 81, 88 and 89, suggested in Table 1 for use as the dopant materials of an emission layer. In some embodiments, Comparative Example 1 to Comparative Example 6 correspond to light emitting elements manufactured utilizing Comparative Compounds a to e as the dopant materials of an emission layer.

The compounds utilized for the manufacture of Light Emitting Element 1 to Light Emitting Element 4 are as follows. The materials were utilized for the manufacture of elements after performing sublimation purification with respect to purchased products.

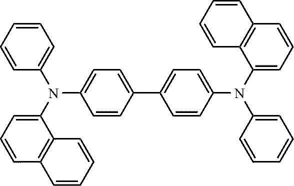 [SMILES: c1ccc(N(c2ccc(-c3ccc(N(c4ccccc4)c4cccc5ccccc45)cc3)cc2)c2cccc3ccccc23)cc1]

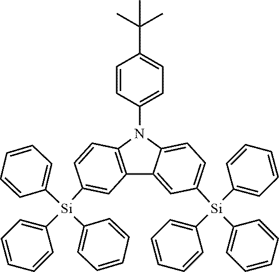 [SMILES: CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

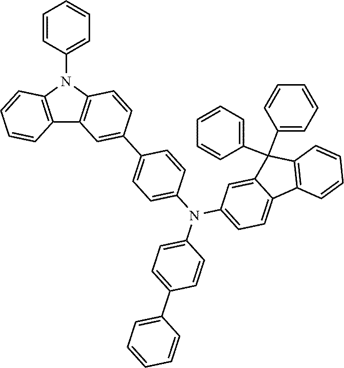 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

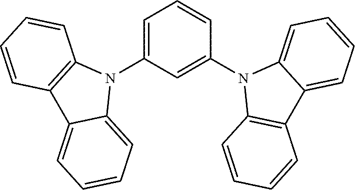 [SMILES: c1cc(-n2c3ccccc3c3ccccc32)cc(-n2c3ccccc3c3ccccc32)c1]

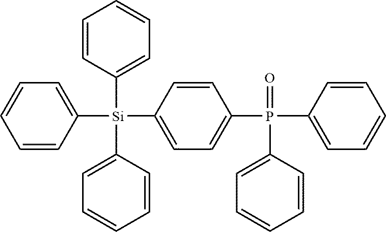 [SMILES: O=P(c1ccccc1)(c1ccccc1)c1ccc([Si](c2ccccc2)(c2ccccc2)c2ccccc2)cc1]

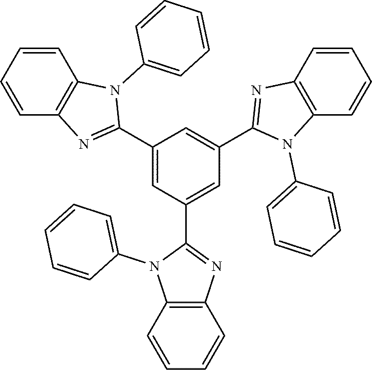 [SMILES: c1ccc(-n2c(-c3cc(-c4nc5ccccc5n4-c4ccccc4)cc(-c4nc5ccccc5n4-c4ccccc4)c3)nc3ccccc32)cc1]

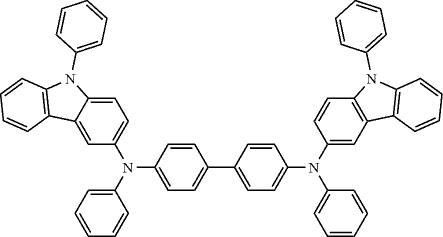 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

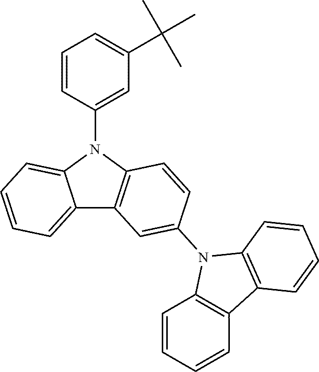 [SMILES: CC(C)(C)c1cccc(-n2c3ccccc3c3cc(-n4c5ccccc5c5ccccc54)ccc32)c1]

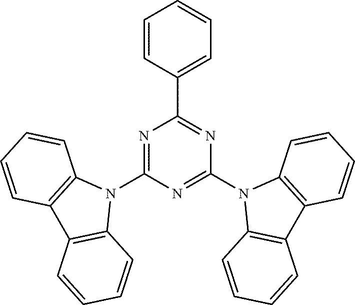 [SMILES: c1ccc(-c2nc(-n3c4ccccc4c4ccccc43)nc(-n3c4ccccc4c4ccccc43)n2)cc1]

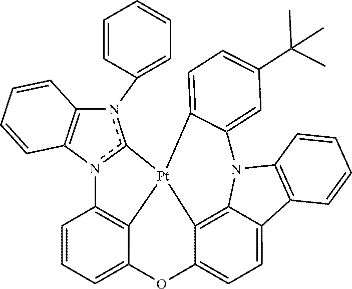

### Manufacture of Light Emitting Element 1

Aluminum (Al) having a thickness of about 3000 Å was installed as a first electrode on a vacuum deposition apparatus. On the first electrode, NPD was deposited to form a hole injection layer having a thickness of about 300 Å, and then, H-1-19 was deposited on the hole injection layer to form a hole transport layer having a thickness of about 200 Å.Then, CzSi was deposited on the hole transport layer to form an electron blocking layer having a thickness of about 100 Å.

On the electron blocking layer, a host compound obtained by mixing a first host (HT) and a second host (ET) in a ratio (e.g., amount) of 1:1, and the Example Compound or Comparative Compound were co-deposited in a weight ratio of about 97:3 as in Table 2, to form an emission layer having a thickness of about 200 Å.

Then, on the emission layer TSPO1 was deposited to form a hole blocking layer having a thickness of about 200 Å, on the hole blocking layer, TPBi was deposited to form an electron transport layer having a thickness of about 300 Å, and on the electron transport layer, LiF was deposited to form an electron injection layer having a thickness of about 10 Å. A glass substrate (product of Corning Co.) on which an ITO electrode of about 15 Ω/cm² (1200 Å) was formed, was cut into a size of about 50 mm x 50 mm x 0.7 mm, washed by ultrasonic waves utilizing isopropyl alcohol and pure water for about 5 minutes each, and cleaned by exposing to ultraviolet rays for about 30 minutes and exposing to ozone, and then the glass substrate was provided on the electron injection layer. On the electrode, P4 was deposited to form a capping layer having a thickness of about 700 Å to form a bottom emission-type or kind light emitting element.

In Table 2, evaluation results of the light emitting elements of Example 1 to Example 11 and Comparative Example 1 to Comparative Example 6 are shown. In the evaluation results of the properties for the Examples and Comparative Examples, a driving voltage (V) at a current density of about 1000 cd/m², emission efficiency (Cd/A), quantum efficiency (Q.E) and emission color were measured utilizing Keithley MU 236 and a luminance meter of PR650. A lifetime ratio (T₉₅) was obtained by measuring a time consumed from an initial luminance to a luminance of about 95%, and calculating as a relative lifetime based on Comparative Example 1, and the results are shown.

TABLE 2

| | Host (HT/ET) | Dopant | Driving voltage (V) | Efficiency (cd/A) | Emission wavelength (nm) | Lifetime ratio (T₉₅) | CIE (x,y) | Q.E (%) |
|---|---|---|---|---|---|---|---|---|
| Example 1 | HT1/ET1 | Compound 8 | 4.5 | 7.7 | 463 | 9.2 | 0.135, 0.127 | 9.1 |
| Example 2 | HT1/ET1 | Compound 14 | 4.8 | 4.5 | 462 | 9.4 | 0.144, 0.123 | 3.8 |
| Example 3 | HT1/ET1 | Compound 16 | 4.7 | 5.8 | 468 | 6.7 | 0.132, 0.200 | 8.3 |
| Example 4 | HT1/ET1 | Compound 24 | 4.4 | 3.8 | 463 | 11.5 | 0.136, 0.125 | 2.7 |
| Example 5 | HT1/ET1 | Compound 42 | 4.5 | 7.0 | 458 | 8.4 | 0.149, 0.092 | 9.3 |
| Example 6 | HT1/ET1 | Compound 65 | 4.3 | 4.9 | 461 | 7.1 | 0.142, 0.139 | 4.4 |
| Example 7 | HT1/ET1 | Compound 72 | 4.4 | 8.3 | 462 | 8.2 | 0.135, 0.112 | 9.8 |
| Example 8 | HT1/ET1 | Compound 75 | 4.5 | 9.5 | 463 | 13.8 | 0.133, 0.143 | 11.0 |
| Example 9 | HT1/ET1 | Compound 81 | 4.3 | 7.8 | 461 | 7.8 | 0.142, 0.139 | 9.5 |
| Example 10 | HT1/ET1 | Compound 88 | 4.5 | 7.3 | 458 | 9.5 | 0.149, 0.092 | 9.1 |
| Example 11 | HT1/ET1 | Compound 89 | 4.2 | 8.4 | 462 | 9.9 | 0.135, 0.112 | 10.3 |
| Comparative Example 1 | HT1/ET1 | Compound a | 5.5 | 2.5 | 460 | 1 | 0.140, 0.112 | 3.3 |
| Comparative Example 2 | HT1/ET1 | Compound b | 5.6 | 4.4 | 465 | 1.3 | 0.145, 0.101 | 5.6 |
| Comparative Example 3 | HT1/ET1 | Compound c | 4.9 | 5.3 | 463 | 2.5 | 0.134, 0.128 | 7.4 |
| Comparative Example 4 | HT1/ET1 | Compound d | 5.3 | 5.5 | 465 | 4.2 | 0.133, 0.142 | 7.9 |
| Comparative Example 5 | HT1/ET1 | Compound e | 4.7 | 4.1 | 453 | 3.8 | 0.142, 0.092 | 2.1 |
| Comparative Example 6 | HT1/ET1 | Compound f | 4.8 | 5.6 | 471 | 3.3 | 0.165, 0.087 | 4.7 |

Referring to the results of Table 2, it could be confirmed that the light emitting elements of all the Examples and Comparative Examples emitted light in a blue wavelength region with a maximum emission wavelength of about 450 nm to about 480 nm. In the evaluation of a relative element lifetime, it could be found that the light emitting elements of the Examples showed even better lifetime characteristics than the Comparative Examples.

### Manufacture of Light Emitting Element 2

A glass substrate (product of Corning Co.) on which an ITO electrode of about 15 Ω/cm² (1200 Å) was formed, was cut into a size of about 50 mm × 50 mm x 0.7 mm as a first electrode, washed by ultrasonic waves utilizing isopropyl alcohol and pure water for about 5 minutes each, and cleaned by exposing to ultraviolet rays for about 30 minutes and exposing to ozone, and then the glass substrate was installed on a vacuum deposition apparatus.

On the first electrode, NPD was deposited to form a hole injection layer having a thickness of about 300 Å, on the hole injection layer, H-1-19 was deposited to form a hole transport layer having a thickness of about 200 Å, and on the hole transport layer, CzSi was deposited to form an electron blocking layer having a thickness of about 100 Å.

TABLE 3

| | Host (HT/ET) | Sensitizer | Dopant | Driving voltage (V) | Efficiency (cd/A) | Emission wavelength (nm) | FWQM (nm) | Lifetime ratio (T₉₅) | CIE (x,y) | Q.E (%) |
|---|---|---|---|---|---|---|---|---|---|---|
| Example 1 | HT1/ET1 | PS1 | Compound 8 | 4.2 | 23.0 | 462 | 36 | 12.3 | 0.137, 0.050 | 47.8 |
| Example 2 | HT1/ET1 | PS1 | Compound 14 | 4.1 | 11.5 | 460 | 35 | 16.9 | 0.139, 0.048 | 26.4 |
| Example 3 | HT1/ET1 | PS1 | Compound 16 | 4.2 | 21.4 | 467 | 32 | 8.8 | 0.129, 0.068 | 40.6 |
| Example 4 | HT1/ET1 | PS1 | Compound 24 | 4.1 | 13.4 | 463 | 31 | 18.3 | 0.137, 0.059 | 31.8 |
| Example 5 | HT1/ET1 | PS1 | Compound 42 | 4.2 | 20.1 | 461 | 28 | 10.9 | 0.137, 0.052 | 44.4 |
| Example 6 | HT1/ET1 | PS1 | Compound 65 | 4.1 | 21.4 | 461 | 38 | 9.3 | 0.138, 0.050 | 47.1 |
| Example 7 | HT1/ET1 | PS1 | Compound 72 | 4.2 | 25.1 | 462 | 36 | 10.8 | 0.138, 0.052 | 50.1 |
| Example 8 | HT1/ET1 | PS1 | Compound 75 | 4.1 | 28.4 | 462 | 35 | 11.2 | 0.139, 0.051 | 54.9 |
| Example 9 | HT1/ET1 | PS1 | Compound 81 | 4.2 | 23.7 | 461 | 35 | 14.2 | 0.138, 0.050 | 48.5 |
| Example 10 | HT1/ET1 | PS1 | Compound 88 | 4.1 | 21.2 | 458 | 32 | 10.3 | 0.139, 0.048 | 46.9 |
| Example 11 | HT1/ET1 | PS1 | Compound 89 | 4.1 | 23.2 | 462 | 36 | 12.2 | 0.139, 0.051 | 49.4 |
| Comparative Example 1 | HT1/ET1 | PS1 | Compound a | 5.4 | 16.3 | 462 | 46 | 1 | 0.136, 0.054 | 35.3 |
| Comparative Example 2 | HT1/ET1 | PS1 | Compound b | 5.1 | 15.4 | 461 | 42 | 1.4 | 0.138, 0.050 | 34.7 |
| Comparative Example 3 | HT1/ET1 | PS1 | Compound c | 4.4 | 19.2 | 464 | 38 | 1.8 | 0.132, 0.061 | 40.2 |
| Comparative Example 4 | HT1/ET1 | PS1 | Compound d | 4.8 | 20.1 | 463 | 43 | 2.5 | 0.139, 0.060 | 45.1 |
| Comparative Example 5 | HT1/ET1 | PS1 | Compound e | 4.4 | 16.2 | 454 | 38 | 1.3 | 0.132, 0.061 | 40.2 |
| Comparative Example 6 | HT1/ET1 | PS1 | Compound f | 4.8 | 18.1 | 473 | 43 | 1.7 | 0.139, 0.060 | 45.1 |

Referring to the results of Table 3, it could be confirmed that the light emitting elements of all the Examples and Comparative Examples emitted light in a blue wavelength region with the maximum emission wavelength of about 450 nm to about 480 nm. The light emitting elements of Examples 1 to 11 showed low driving voltage properties and, in the evaluation of the relative element lifetime, excellent or suitable lifetime characteristics were shown in contrast to the light emitting elements of the Comparative Examples. Compound 14 and Compound 24 utilized in Example 2 and Example 4 are compounds introducing substituents having a relatively low T1 (see Table 1), and the light emitting elements of Example 2 and Example 4, utilizing such compounds showed relatively low efficiency. However, because Compound 14 and Compound 24, utilized in Example 2 and Example 4 have a low T1 orbital, triplet excitons were stabilized, and improved element lifetime was shown in contrast to the light emitting elements of the Comparative Examples.

In some embodiments, the light emitting elements of Examples 1, 3, and 5 to 11 showed better efficiency than the light emitting elements of the Comparative Examples.

### Manufacture of Light Emitting Element 3

A bottom emission-type or kind light emitting element was manufactured as the Light Emitting Element 1 except that a host compound obtained by mixing a first host (HT) and a second host (ET) in a ratio (e.g., amount) of about 1:1, a sensitizer (PS), and the Example Compound or Comparative Compound were co-deposited in a weight ratio of about 85:14:1 (host mixture: sensitizer: Example Compound or Comparative Compound) as in Table 4, on the electron blocking layer to form an emission layer having a thickness of about 200 Å.

In Table 4, the evaluation results of the bottom emission-type or kind light emitting elements of Example 1 to Example 11, and Comparative Example 1 to Comparative Example 6 are shown. In the evaluation results of the properties for the Examples and Comparative Examples, a driving voltage (V) at a current density of about 1000 cd/m², emission efficiency (Cd/A), quantum efficiency (Q.E) and emission color were measured utilizing Keithley MU 236 and a luminance meter of PR650. A lifetime ratio (T₉₅) was obtained by measuring a time consumed from an initial luminance to a luminance of about 95%, and calculating as a relative lifetime based on Comparative Example 1, and the results are shown. Full-width quarter maximum (FWQM) was measured utilizing FluorEssence software of a fluoromax+ spectrometer equipment of HORIBA Co., equipped with a xenon light source and a monochromator.

TABLE 4

| | Host (HT/ET) | Sensitizer | Dopant | Driving voltage (V) | Efficiency (cd/A) | Emission wavelength (nm) | FWQM (nm) | Lifetime ratio (T₉₅) | CIE (x,y) | Q.E (%) |
|---|---|---|---|---|---|---|---|---|---|---|
| Example 1 | HT1/ET1 | PS1 | Compound 8 | 4.1 | 19.4 | 463 | 38 | 9.8 | 0.136, 0.153 | 19.2 |
| Example 2 | HT1/ET1 | PS1 | Compound 14 | 4.0 | 15.2 | 462 | 28 | 14.3 | 0.139, 0.180 | 13.0 |
| Example 3 | HT1/ET1 | PS1 | Compound 16 | 4.1 | 19.7 | 468 | 32 | 10.1 | 0.132, 0.200 | 16.4 |
| Example 4 | HT1/ET1 | PS1 | Compound 24 | 4.1 | 13.8 | 463 | 36 | 15.5 | 0.136, 0.147 | 11.8 |
| Example 5 | HT1/ET1 | PS1 | Compound 42 | 4.0 | 20.7 | 461 | 31 | 9.3 | 0.138, 0.154 | 22.0 |
| Example 6 | HT1/ET1 | PS1 | Compound 65 | 4.2 | 20.2 | 462 | 39 | 8.4 | 0.136, 0.159 | 19.3 |
| Example 7 | HT1/ET1 | PS1 | Compound 72 | 4.1 | 21.4 | 462 | 37 | 9.6 | 0.134, 0.147 | 20.9 |
| Example 8 | HT1/ET1 | PS1 | Compound 75 | 4.2 | 22.8 | 462 | 35 | 10.9 | 0.135, 0.149 | 22.4 |
| Example 9 | HT1/ET1 | PS1 | Compound 81 | 4.0 | 22.0 | 461 | 33 | 10.5 | 0.135, 0.133 | 22.8 |
| Example 10 | HT1/ET1 | PS1 | Compound 88 | 4.1 | 21.4 | 458 | 36 | 10.8 | 0.134, 0.135 | 23.9 |
| Example 11 | HT1/ET1 | PS1 | Compound 89 | 4.1 | 22.9 | 462 | 35 | 12.5 | 0.135, 0.128 | 25.0 |
| Comparative Example 1 | HT1/ET1 | PS1 | Compound a | 4.6 | 9.7 | 462 | 46 | 1 | 0.136, 0.157 | 13.6 |
| Comparative Example 2 | HT1/ET1 | PS1 | Compound b | 4.7 | 13.8 | 461 | 45 | 1.9 | 0.142, 0.149 | 15.4 |
| Comparative Example 3 | HT1/ET1 | PS1 | Compound c | 4.5 | 18.1 | 463 | 38 | 2.7 | 0.136, 0.174 | 17.2 |
| Comparative Example 4 | HT1/ET1 | PS1 | Compound d | 4.9 | 19.5 | 463 | 45 | 3.3 | 0.138, 0.151 | 19.1 |
| Comparative Example 5 | HT1/ET1 | PS1 | Compound e | 4.7 | 15.2 | 453 | 36 | 1.6 | 0.125, 0.136 | 14.9 |
| Comparative Example 6 | HT1/ET1 | PS1 | Compound f | 4.5 | 17.8 | 470 | 40 | 2.3 | 0.122, 0.189 | 17.9 |

Referring to the results of Table 4, it could be confirmed that the light emitting elements of all the Examples and Comparative Examples emitted light in a blue wavelength region with the maximum emission wavelength of about 470 nm or less. The light emitting elements of the Examples showed low driving voltage properties and excellent or suitable lifetime characteristics in contrast to the light emitting elements of the Comparative Examples.

### Manufacture of Light Emitting Element 4

A top emission-type or kind light emitting element was manufactured as the Light Emitting Element 2 except that a host compound obtained by mixing a first host (HT) and a second host (ET) in a weight ratio described in Table 5, a sensitizer (PS), and the Example Compound or Comparative Compound were co-deposited in a weight ratio of about 85:14:1 (host mixture: sensitizer: Example Compound or Comparative Compound) on the electron blocking layer to form an emission layer having a thickness of about 200 Å.

In Table 5, the evaluation results of the top emission-type or kind light emitting elements of Example 1-A to Example 8-A, and Comparative Example 1-A to Comparative Example 4-A are shown. In some embodiments, in the evaluation results of the properties for the Examples and Comparative Examples, a driving voltage (V) at a current density of about 1000 cd/m², emission efficiency (Cd/A), quantum efficiency (Q.E) and emission color were measured utilizing Keithley MU 236 and a luminance meter of PR650. A lifetime ratio (T₉₅) was obtained by measuring a time consumed from an initial luminance to a luminance of about 95%, and calculating as a relative lifetime based on Comparative Example 1-A, and the results are shown. Full-width quarter maximum (FWQM) was measured utilizing FluorEssence software of a fluoromax+ spectrometer equipment of HORIBA Co., equipped with a xenon light source and a monochromator.

TABLE 5

| | Host (HT1/ET1) | Sensitizer | Dopant | Driving voltage (V) | Top efficiency (cd/A) | Emission wavelength (nm) | FWQM (nm) | Lifetime ratio (T95) | CIE (x,y) | Q.E (%) |
|---|---|---|---|---|---|---|---|---|---|---|
| Example 1-A | 5:5 | PS1 | Compound 8 | 4.5 | 23.0 | 462 | 24 | 6.5 | 0.137, 0.050 | 47.8 |
| Example 2-A | 4:6 | PS1 | Compound 8 | 4.5 | 22.1 | 462 | 25 | 4.9 | 0.138, 0.051 | 45.1 |
| Example 3-A | 6:4 | PS1 | Compound 8 | 4.4 | 24.4 | 462 | 24 | 7.1 | 0.139, 0.052 | 49.6 |
| Example 4-A | 7:3 | PS1 | Compound 8 | 4.4 | 25.8 | 461 | 23 | 8.3 | 0.136, 0.050 | 51.9 |
| Example 5-A | 5:5 | PS1 | Compound 75 | 4.6 | 28.4 | 462 | 26 | 3.2 | 0.139, 0.051 | 54.9 |
| Example 6-A | 4:6 | PS1 | Compound 75 | 4.5 | 27.7 | 462 | 25 | 2.7 | 0.138, 0.052 | 53.0 |
| Example 7-A | 6:4 | PS1 | Compound 75 | 4.5 | 29.5 | 462 | 25 | 3.8 | 0.138, 0.053 | 57.6 |
| Example 8-A | 7:3 | PS1 | Compound 75 | 4.5 | 32.3 | 462 | 25 | 4.5 | 0.137, 0.051 | 63.0 |
| Comparative Example 1-A | 5:5 | PS1 | Compound d | 4.8 | 20.1 | 463 | 23 | 1 | 0.139, 0.060 | 45.1 |
| Comparative Example 2-A | 4:6 | PS1 | Compound d | 4.9 | 19.1 | 463 | 25 | 1.8 | 0.139, 0.055 | 43.4 |
| Comparative Example 3-A | 6:4 | PS1 | Compound d | 4.8 | 21.1 | 463 | 25 | 2.9 | 0.139, 0.059 | 46.8 |
| Comparative Example 4-A | 7:3 | PS1 | Compound d | 4.9 | 22.2 | 464 | 25 | 3.3 | 0.138, 0.060 | 48.1 |

Referring to the results of Table 5, it could be confirmed that the light emitting elements of all the Examples and Comparative Examples emitted light in a blue wavelength region with the maximum emission wavelength of about 470 nm or less. In the evaluation of relative lifetime characteristics, it could be found that the light emitting elements of the Examples showed better lifetime characteristics than the Comparative Examples. The light emitting elements of the Examples showed lower driving voltage properties than the Comparative Examples. For example, when comparing the light emitting elements of the Examples to Comparative Examples, having the same ratio of the first host and the second host, Example 1-A and Example 5-A each showed better lifetime characteristics and a lower driving voltage than Comparative Example 1-A, and Example 2-A and Example 6-A each showed better lifetime characteristics and a lower driving voltage than Comparative Example 2-A. Example 3-A and Example 7-A each showed better lifetime characteristics and a lower driving voltage than Comparative Example 3-A, and Example 4-A and Example 8-A each showed better lifetime characteristics and a lower driving voltage than Comparative Example 4-A.

Referring to the overall results of Table 2 to Table 5, it could be confirmed that the Examples of the light emitting elements each utilizing the fused polycyclic compound according to an embodiment of the present disclosure as a material for an emission layer showed better lifetime characteristics when compared to the Comparative Examples. The Examples each showed relatively (relative to Comparative Examples) improved emission efficiency and a lower driving voltage value than the Comparative Examples.

The first compound of an embodiment may include a fused structure of multiple aromatic rings through at least one boron atom and two heteroatoms. The first compound may include a connected structure of ortho-type or kind penta-phenyl groups with two heteroatoms each.

The first compound of the present disclosure includes an ortho-type or kind penta-phenyl group in a plate-type or kind structure including a boron atom and may increase the relative distance between molecules and reduce intermolecular interaction to improve the stability of a whole molecule.

In some embodiments, the first compound includes a connected structure of an ortho-type or kind penta-phenyl group with a fused structure including a boron atom, to prevent or reduce the bonding of the boron atom to a nucleophile and to maintain the trigonal bonding structure of the boron atom. Accordingly, the molecular stability and multiple resonance may be reinforced (stabilized), a low ΔE_{ST} value may be shown, and improved delayed fluorescence emitting properties may be expected.

The light emitting element of the present disclosure includes the first compound in an emission layer as a thermally activated delayed fluorescence dopant, and may reduce the deterioration phenomenon of the element, improve element efficiency and lifetime, and show high color purity in a blue light wavelength region.

The light emitting element of an embodiment includes the fused polycyclic compound of an embodiment and may show improved lifetime characteristics. In some embodiments, the light emitting element of an embodiment includes the fused polycyclic compound of an embodiment as a material for an emission layer, and may achieve long lifetime-characteristics in a blue light wavelength region.

The light emitting element of an embodiment includes a fused polycyclic compound of an embodiment and may show a low driving voltage properties and improved lifetime characteristics.

The fused polycyclic compound of an embodiment may be utilized as a light emitting material for achieving improved properties of a light emitting element, with a low driving voltage and long lifetime.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present present disclosure as defined by the following claims and equivalents thereof.

What is claimed is:

1. A light emitting element, comprising:
a first electrode;
a second electrode on the first electrode; and
an emission layer between the first electrode and the second electrode,
wherein the emission layer comprises:
a first compound represented by Formula 1; and
at least one selected from among a second compound represented by Formula HT, a third compound represented by Formula ET, and a fourth compound represented by Formula D-1: 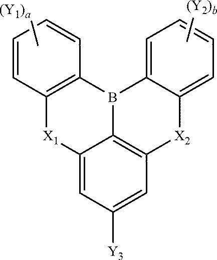
wherein in Formula 1,
X₁ and X₂ are each independently CR₁R₂, NR₃, NR₄, O, S, or Se, wherein at least one selected from among X₁ and X₂ is NR₄,
Y₁ to Y₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
“a” and “b” are each independently an integer of 0 to 4,
R₁ to R₃ are each independently a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring, and
R₄ is represented by Formula 2 or Formula 3: 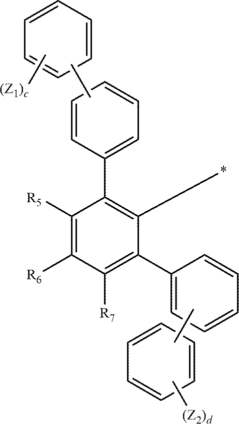 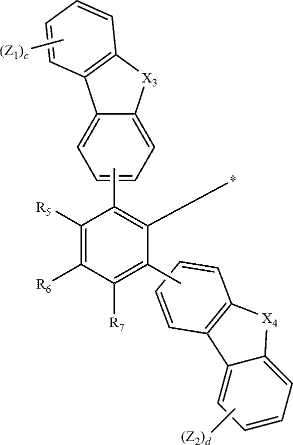
in Formula 3,
X₃ and X₄ are each independently CR₈R₉, NR₁₀, O, S, or Se,
wherein in Formula 2 and Formula 3,
R₅ to R₁₀ are each independently a hydrogen atom, a deuterium atom, a halogen atom, a cyano group, a nitro group, a hydroxyl group, a substituted or unsubstituted silyl group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring,
Z₁ and Z₂ are each independently a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and
“c” and “d” are each independently an integer of 0 to 4, 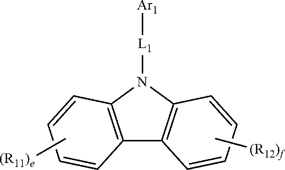
wherein in Formula HT,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₁₁ and R₁₂ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
“e” and “f” are each independently an integer of 0 to 4, 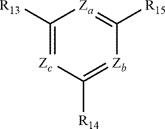
wherein in Formula ET,
at least one selected from among Zₐ to Z_{c} is N, and the Zₐ to Z_{c} that are not N are CR₁₆, and
R₁₃ to R₁₆ are each independently a hydrogen atom, a deuterium atom, a cyano group, a substituted or unsubstituted silyl group, a substituted or unsubstituted aryl group of 6 to 30 ring-forming carbon atoms, or a substituted or unsubstituted heteroaryl group of 2 to 30 ring-forming carbon atoms, 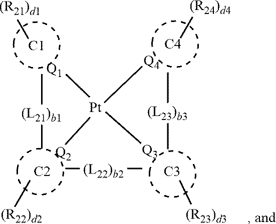
wherein in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₂₁ to L₂₃ are each independently a direct linkage, 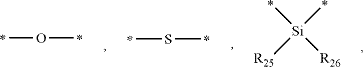 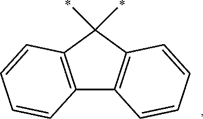
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₂₁ to R₂₆ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 1 to 30 ring-forming carbon atoms, and/or combined with an adjacent group to form a ring, and
d1 to d4 are each independently an integer of 0 to 4.

2. The light emitting element of claim 1, wherein Formula 2 is represented by Formula 2-1: 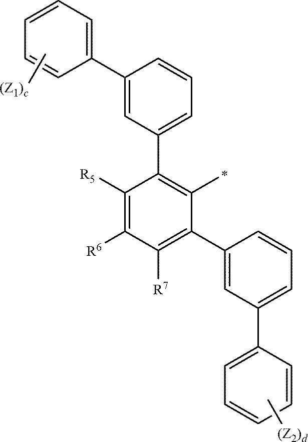
wherein in Formula 2-1,
R₅ to R₇, Z₁, Z₂, “c” and “d” are the same as defined in Formula 2.

3. The light emitting element of claim 1, wherein Formula 3 is represented by any one selected from among Formula 3-1 to Formula 3-4: 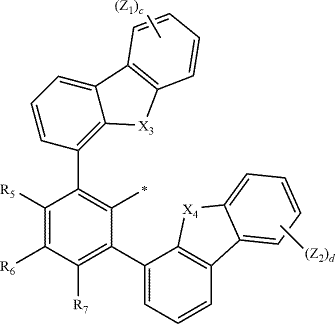 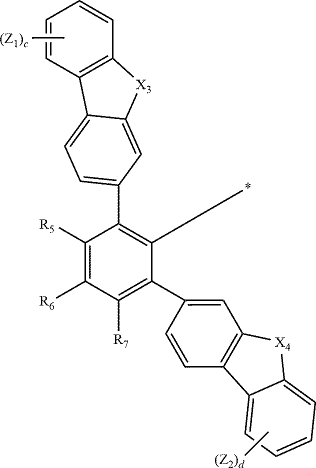 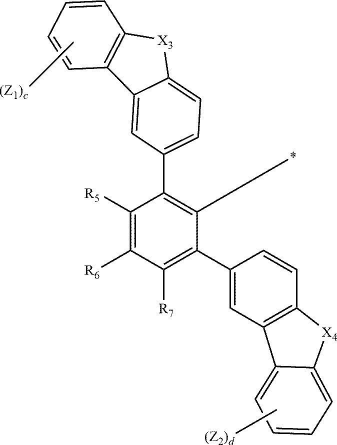 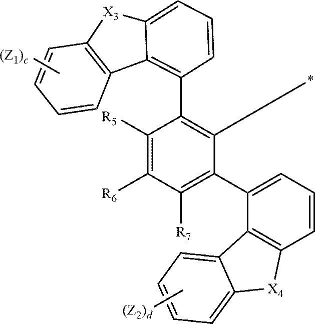
wherein in Formula 3-1 to Formula 3-4,
R₅ to R₇, X₃, X₄, Z₁, Z₂, “c” and “d” are the same as defined in Formula 3.

4. The light emitting element of claim 2, wherein the first compound is represented by any one selected from among Formula 4-1 to Formula 4-3: 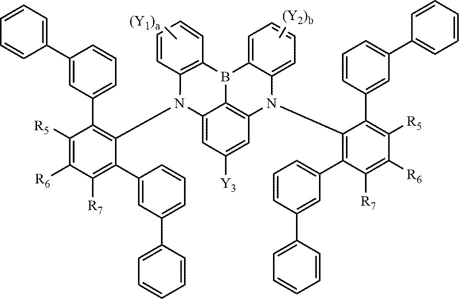 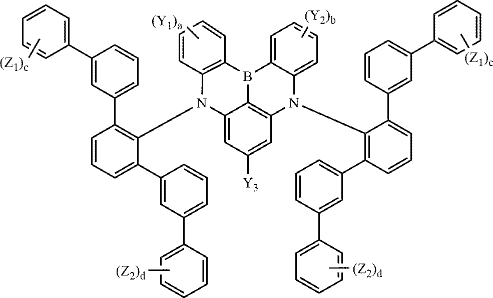 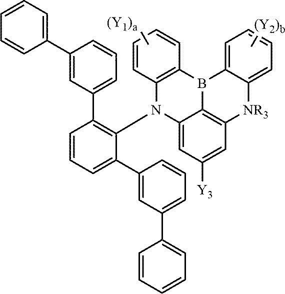
wherein in Formula 4-1 to Formula 4-3,
Y₁ to Y₃, R₃, R₅ to R₇, Z₁, Z₂, and “a” to “d” are the same as defined in Formula 1 and Formula 2.

5. The light emitting element of claim 3, wherein the first compound is represented by any one selected from among Formula 5-1 to Formula 5-12: 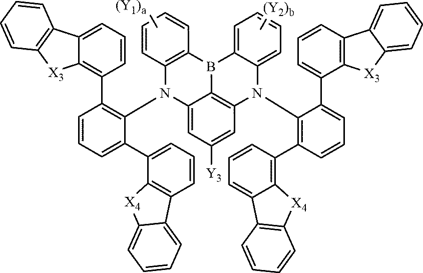 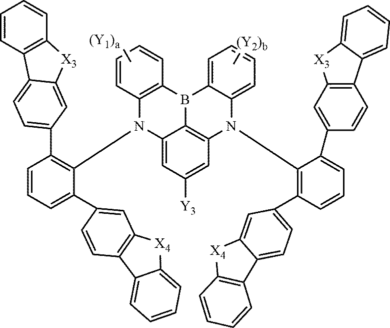 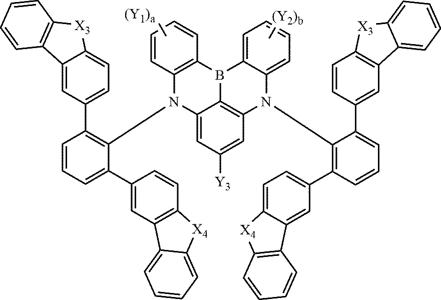 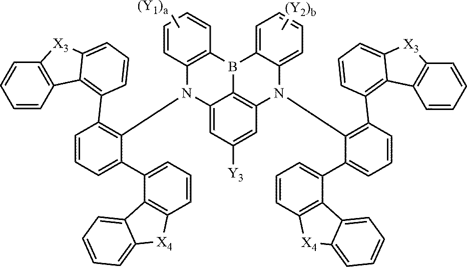 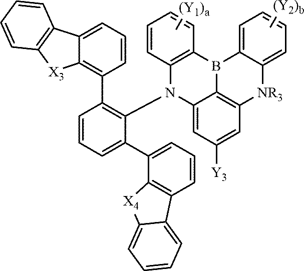 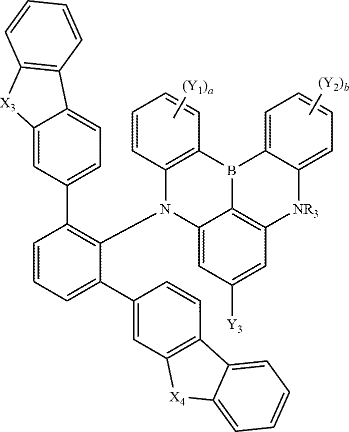 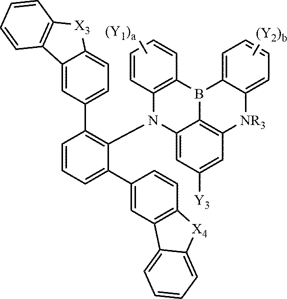 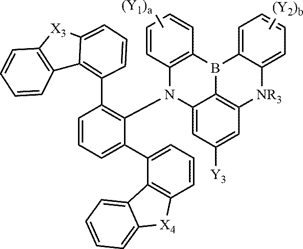 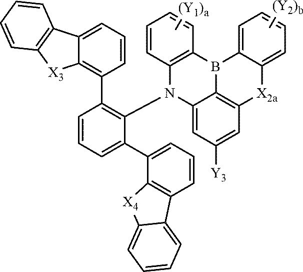 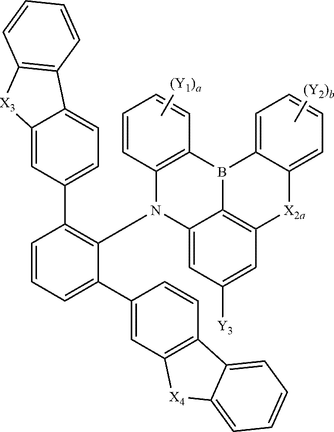 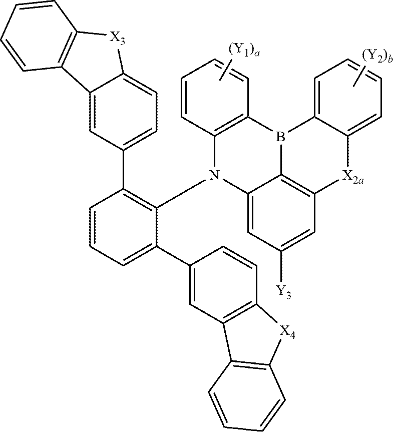 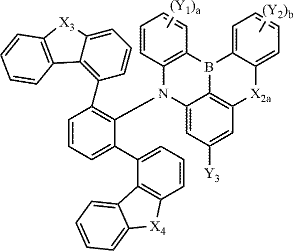
wherein in Formula 5-1 to Formula 5-12,
X₂ₐ is CR₁R₂, O, S or Se, and Y₁ to Y₃, R₁ to R₃, “a”, “b”, X₃ and X₄ are the same as defined in Formula 1 and Formula 3.

6. The light emitting element of claim 1, wherein
Y₁ and Y₂ in Formula 1 are each independently a hydrogen atom, a deuterium atom, a substituted or unsubstituted amino group, a substituted or unsubstituted alkyl group of 1 to 20 carbon atoms, a substituted or unsubstituted oxy group, a substituted or unsubstituted cycloalkyl group of 3 to 20 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
Y₃ is a hydrogen atom, a substituted or unsubstituted amino group, a substituted or unsubstituted alkyl group of 1 to 20 carbon atoms, a substituted or unsubstituted cycloalkyl group of 3 to 20 ring-forming carbon atoms, a substituted or unsubstituted aryl group of 6 to30 ring-forming carbon atoms, or a substituted or unsubstituted heteroaryl group of 2 to 30 ring-forming carbon atoms, and
“a” and “b” are the same as defined in Formula 1.

7. The light emitting element of claim 1, wherein R₅ to R₇, Z₁ and Z₂ are each independently a hydrogen atom, or a substituted or unsubstituted alkyl group of 1 to 20 carbon atoms.

8. The light emitting element of claim 1, wherein
X₃ and X₄ are the same and are NR₁₀, O, S or Se, and
R₁₀ is the same as defined in Formula 3.

9. The light emitting element of claim 1, wherein the first compound has a light emitting central wavelength in a wavelength region of about440 nm to about 480 nm.

10. The light emitting element of claim 1, wherein the emission layer is configured to emit delayed fluorescence.

11. The light emitting element of claim 1, wherein the emission layer comprises the first compound, the second compound, and the third compound.

12. The light emitting element of claim 1, wherein the emission layer comprises the first compound, the second compound, the third compound, and the fourth compound.

13. The light emitting element of claim 11, wherein the second compound and the third compound are comprised in the emission layer, and a weight ratio of the second compound to the third compound is about 4:6 to about 7:3.

14. The light emitting element of claim 1, wherein Formula 1 is represented by any one selected from among fused polycyclic compounds in Compound Group 1: Compound Group 1 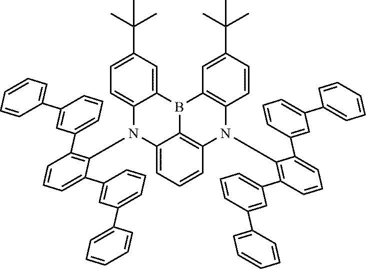 [SMILES: CC(C)(C)c1ccc2c(c1)B1c3cc(C(C)(C)C)ccc3N(c3c(-c4cccc(-c5ccccc5)c4)cccc3-c3cccc(-c4ccccc4)c3)c3cccc(c31)N2c1c(-c2cccc(-c3ccccc3)c2)cccc1-c1cccc(-c2ccccc2)c1] 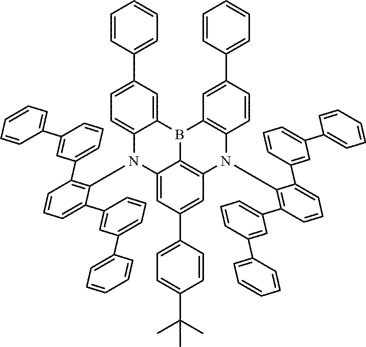 [SMILES: CC(C)(C)c1ccc(-c2cc3c4c(c2)N(c2c(-c5cccc(-c6ccccc6)c5)cccc2-c2cccc(-c5ccccc5)c2)c2ccc(-c5ccccc5)cc2B4c2cc(-c4ccccc4)ccc2N3c2c(-c3cccc(-c4ccccc4)c3)cccc2-c2cccc(-c3ccccc3)c2)cc1] 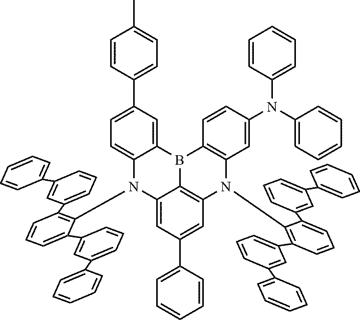 [SMILES: Cc1ccc(-c2ccc3c(c2)B2c4ccc(N(c5ccccc5)c5ccccc5)cc4N(c4c(-c5cccc(-c6ccccc6)c5)cccc4-c4cccc(-c5ccccc5)c4)c4cc(-c5ccccc5)cc(c42)N3c2c(-c3cccc(-c4ccccc4)c3)cccc2-c2cccc(-c3ccccc3)c2)cc1] 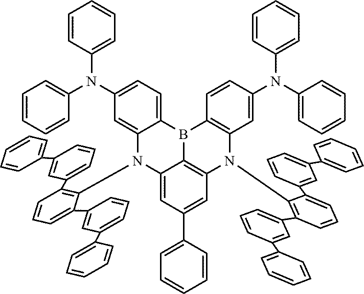 [SMILES: c1ccc(-c2cccc(-c3cccc(-c4cccc(-c5ccccc5)c4)c3N3c4cc(N(c5ccccc5)c5ccccc5)ccc4B4c5ccc(N(c6ccccc6)c6ccccc6)cc5N(c5c(-c6cccc(-c7ccccc7)c6)cccc5-c5cccc(-c6ccccc6)c5)c5cc(-c6ccccc6)cc3c54)c2)cc1] 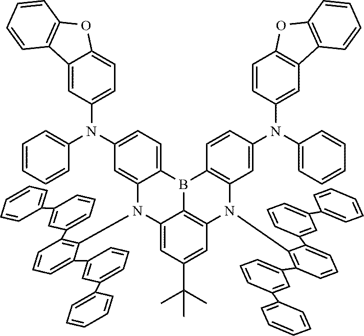 [SMILES: CC(C)(C)c1cc2c3c(c1)N(c1c(-c4cccc(-c5ccccc5)c4)cccc1-c1cccc(-c4ccccc4)c1)c1cc(N(c4ccccc4)c4ccc5oc6ccccc6c5c4)ccc1B3c1ccc(N(c3ccccc3)c3ccc4oc5ccccc5c4c3)cc1N2c1c(-c2cccc(-c3ccccc3)c2)cccc1-c1cccc(-c2ccccc2)c1] 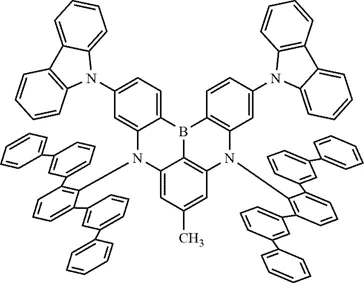 [SMILES: Cc1cc2c3c(c1)N(c1c(-c4cccc(-c5ccccc5)c4)cccc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(-c3ccccc3)c2)cccc1-c1cccc(-c2ccccc2)c1] 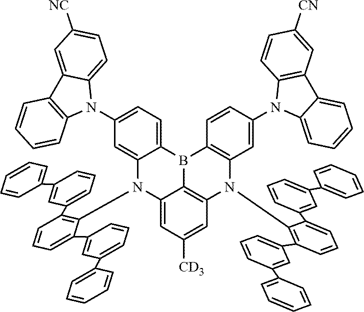 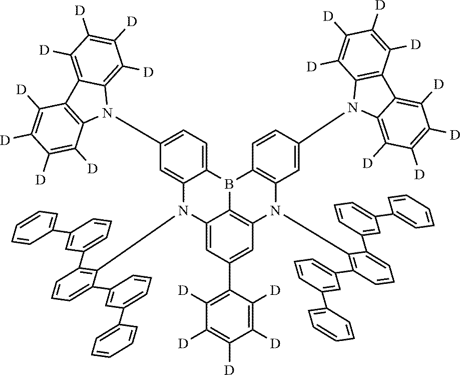 [SMILES: [2H]c1c([2H])c([2H])c(-c2cc3c4c(c2)N(c2c(-c5cccc(-c6ccccc6)c5)cccc2-c2cccc(-c5ccccc5)c2)c2cc(-n5c6c([2H])c([2H])c([2H])c([2H])c6c6c([2H])c([2H])c([2H])c([2H])c65)ccc2B4c2ccc(-n4c5c([2H])c([2H])c([2H])c([2H])c5c5c([2H])c([2H])c([2H])c([2H])c54)cc2N3c2c(-c3cccc(-c4ccccc4)c3)cccc2-c2cccc(-c3ccccc3)c2)c([2H])c1[2H]] 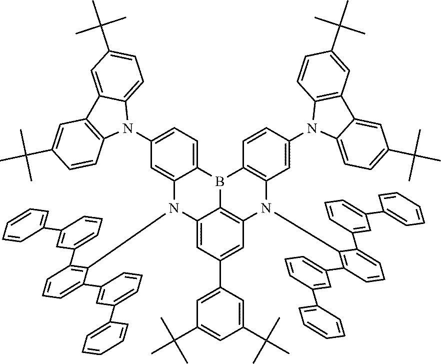 [SMILES: CC(C)(C)c1cc(-c2cc3c4c(c2)N(c2c(-c5cccc(-c6ccccc6)c5)cccc2-c2cccc(-c5ccccc5)c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3cccc(-c4ccccc4)c3)cccc2-c2cccc(-c3ccccc3)c2)cc(C(C)(C)C)c1] 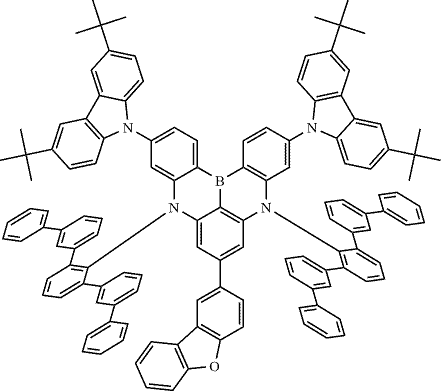 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4oc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 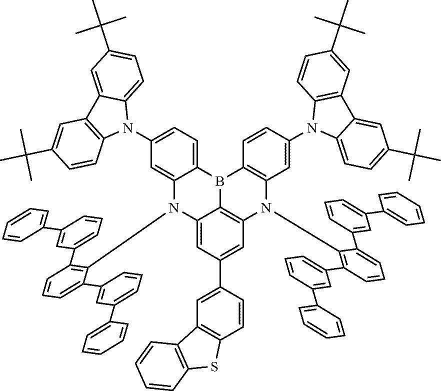 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4sc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 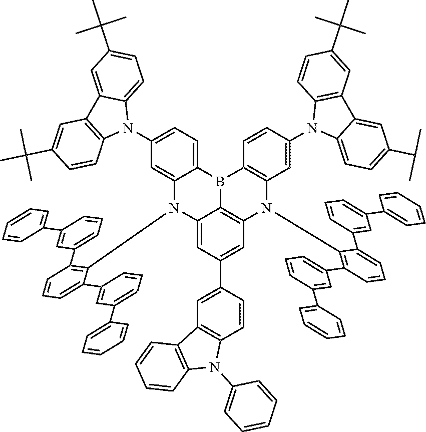 [SMILES: CC(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4c(c3)c3ccccc3n4-c3ccccc3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 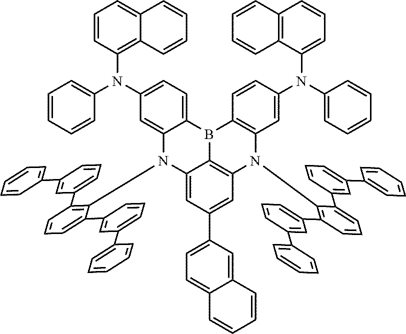 [SMILES: c1ccc(-c2cccc(-c3cccc(-c4cccc(-c5ccccc5)c4)c3N3c4cc(N(c5ccccc5)c5cccc6ccccc56)ccc4B4c5ccc(N(c6ccccc6)c6cccc7ccccc67)cc5N(c5c(-c6cccc(-c7ccccc7)c6)cccc5-c5cccc(-c6ccccc6)c5)c5cc(-c6ccc7ccccc7c6)cc3c54)c2)cc1] 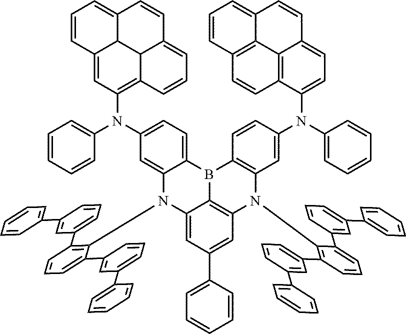 [SMILES: C1=CC2=CC(N(c3ccccc3)c3ccc4c(c3)N(c3c(-c5cccc(-c6ccccc6)c5)cccc3-c3cccc(-c5ccccc5)c3)c3cc(-c5ccccc5)cc5c3B4c3ccc(N(c4ccccc4)c4ccc6ccc7cccc8ccc4c6c78)cc3N5c3c(-c4cccc(-c5ccccc5)c4)cccc3-c3cccc(-c4ccccc4)c3)=C3C=CC=C4C=CC(=C1)C2C43] 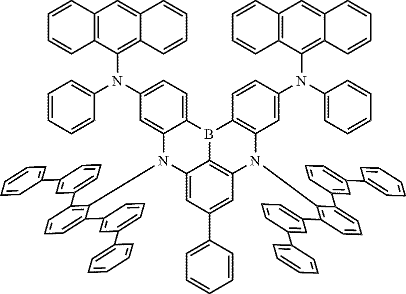 [SMILES: c1ccc(-c2cccc(-c3cccc(-c4cccc(-c5ccccc5)c4)c3N3c4cc(N(c5ccccc5)c5c6ccccc6cc6ccccc56)ccc4B4c5ccc(N(c6ccccc6)c6c7ccccc7cc7ccccc67)cc5N(c5c(-c6cccc(-c7ccccc7)c6)cccc5-c5cccc(-c6ccccc6)c5)c5cc(-c6ccccc6)cc3c54)c2)cc1] 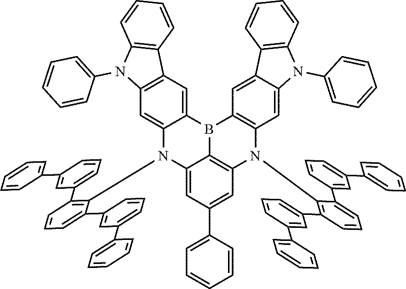 [SMILES: c1ccc(-c2cccc(-c3cccc(-c4cccc(-c5ccccc5)c4)c3N3c4cc5c(cc4B4c6cc7c8ccccc8n(-c8ccccc8)c7cc6N(c6c(-c7cccc(-c8ccccc8)c7)cccc6-c6cccc(-c7ccccc7)c6)c6cc(-c7ccccc7)cc3c64)c3ccccc3n5-c3ccccc3)c2)cc1] 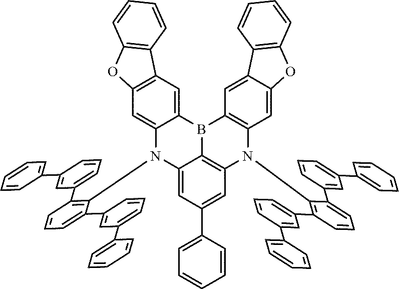 [SMILES: c1ccc(-c2cccc(-c3cccc(-c4cccc(-c5ccccc5)c4)c3N3c4cc5oc6ccccc6c5cc4B4c5cc6c(cc5N(c5c(-c7cccc(-c8ccccc8)c7)cccc5-c5cccc(-c7ccccc7)c5)c5cc(-c7ccccc7)cc3c54)oc3ccccc36)c2)cc1] 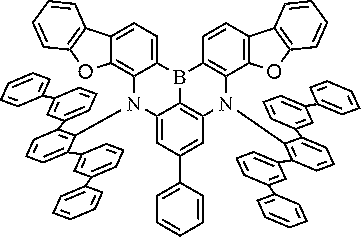 [SMILES: c1ccc(-c2cccc(-c3cccc(-c4cccc(-c5ccccc5)c4)c3N3c4cc(-c5ccccc5)cc5c4B(c4ccc6c(oc7ccccc76)c43)c3ccc4c(oc6ccccc64)c3N5c3c(-c4cccc(-c5ccccc5)c4)cccc3-c3cccc(-c4ccccc4)c3)c2)cc1] 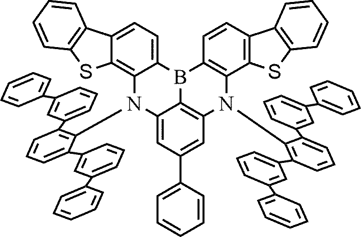 [SMILES: c1ccc(-c2cccc(-c3cccc(-c4cccc(-c5ccccc5)c4)c3N3c4cc(-c5ccccc5)cc5c4B(c4ccc6c(sc7ccccc76)c43)c3ccc4c(sc6ccccc64)c3N5c3c(-c4cccc(-c5ccccc5)c4)cccc3-c3cccc(-c4ccccc4)c3)c2)cc1] 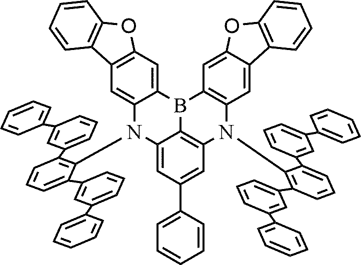 [SMILES: c1ccc(-c2cccc(-c3cccc(-c4cccc(-c5ccccc5)c4)c3N3c4cc5c(cc4B4c6cc7oc8ccccc8c7cc6N(c6c(-c7cccc(-c8ccccc8)c7)cccc6-c6cccc(-c7ccccc7)c6)c6cc(-c7ccccc7)cc3c64)oc3ccccc35)c2)cc1] 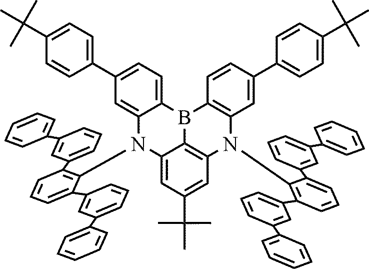 [SMILES: CC(C)(C)c1ccc(-c2ccc3c(c2)N(c2c(-c4cccc(-c5ccccc5)c4)cccc2-c2cccc(-c4ccccc4)c2)c2cc(C(C)(C)C)cc4c2B3c2ccc(-c3ccc(C(C)(C)C)cc3)cc2N4c2c(-c3cccc(-c4ccccc4)c3)cccc2-c2cccc(-c3ccccc3)c2)cc1] 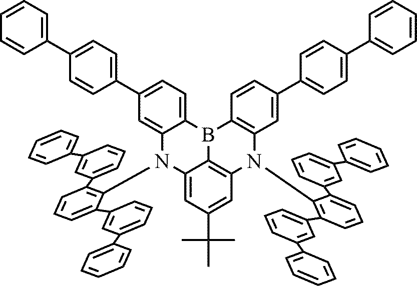 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)cc4)ccc1B3c1ccc(-c3ccc(-c4ccccc4)cc3)cc1N2c1c(-c2cccc(-c3ccccc3)c2)cccc1-c1cccc(-c2ccccc2)c1] 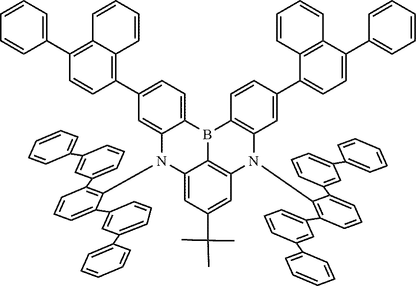 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)c5ccccc45)ccc1B3c1ccc(-c3ccc(-c4ccccc4)c4ccccc34)cc1N2c1c(-c2cccc(-c3ccccc3)c2)cccc1-c1cccc(-c2ccccc2)c1] 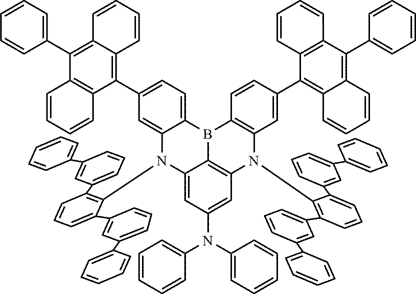 [SMILES: c1ccc(-c2cccc(-c3cccc(-c4cccc(-c5ccccc5)c4)c3N3c4cc(-c5c6ccccc6c(-c6ccccc6)c6ccccc56)ccc4B4c5ccc(-c6c7ccccc7c(-c7ccccc7)c7ccccc67)cc5N(c5c(-c6cccc(-c7ccccc7)c6)cccc5-c5cccc(-c6ccccc6)c5)c5cc(N(c6ccccc6)c6ccccc6)cc3c54)c2)cc1] 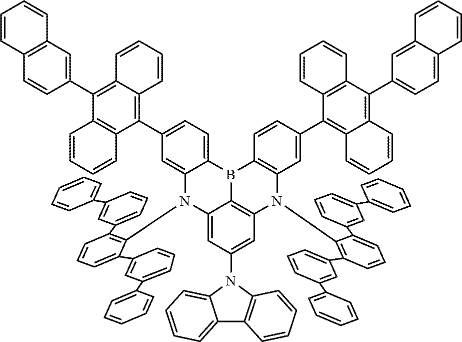 [SMILES: c1ccc(-c2cccc(-c3cccc(-c4cccc(-c5ccccc5)c4)c3N3c4cc(-c5c6ccccc6c(-c6ccc7ccccc7c6)c6ccccc56)ccc4B4c5ccc(-c6c7ccccc7c(-c7ccc8ccccc8c7)c7ccccc67)cc5N(c5c(-c6cccc(-c7ccccc7)c6)cccc5-c5cccc(-c6ccccc6)c5)c5cc(-n6c7ccccc7c7ccccc76)cc3c54)c2)cc1] 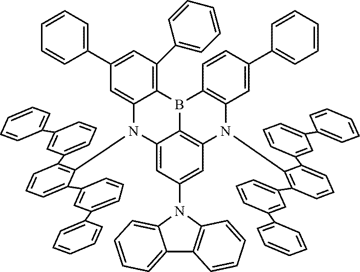 [SMILES: c1ccc(-c2cccc(-c3cccc(-c4cccc(-c5ccccc5)c4)c3N3c4cc(-c5ccccc5)ccc4B4c5c(-c6ccccc6)cc(-c6ccccc6)cc5N(c5c(-c6cccc(-c7ccccc7)c6)cccc5-c5cccc(-c6ccccc6)c5)c5cc(-n6c7ccccc7c7ccccc76)cc3c54)c2)cc1] 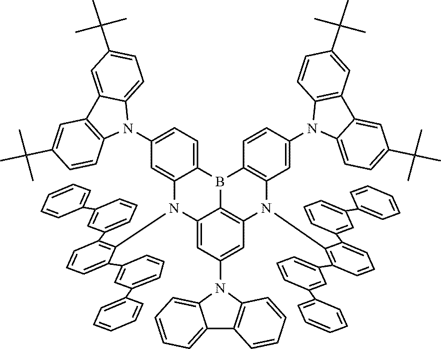 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-n3c4ccccc4c4ccccc43)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 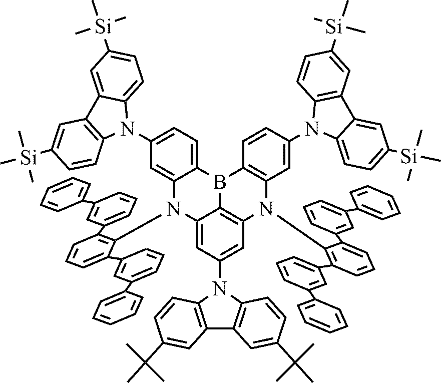 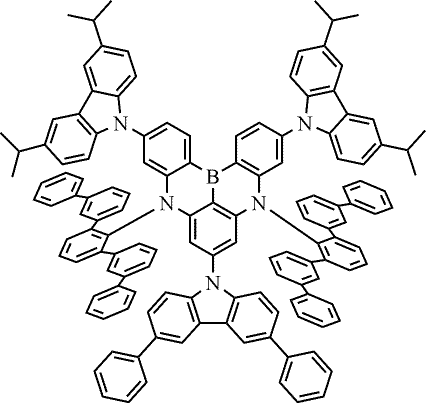 [SMILES: CC(C)c1ccc2c(c1)c1cc(C(C)C)ccc1n2-c1ccc2c(c1)N(c1c(-c3cccc(-c4ccccc4)c3)cccc1-c1cccc(-c3ccccc3)c1)c1cc(-n3c4ccc(-c5ccccc5)cc4c4cc(-c5ccccc5)ccc43)cc3c1B2c1ccc(-n2c4ccc(C(C)C)cc4c4cc(C(C)C)ccc42)cc1N3c1c(-c2cccc(-c3ccccc3)c2)cccc1-c1cccc(-c2ccccc2)c1] 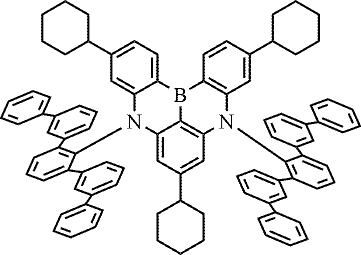 [SMILES: c1ccc(-c2cccc(-c3cccc(-c4cccc(-c5ccccc5)c4)c3N3c4cc(C5CCCCC5)ccc4B4c5ccc(C6CCCCC6)cc5N(c5c(-c6cccc(-c7ccccc7)c6)cccc5-c5cccc(-c6ccccc6)c5)c5cc(C6CCCCC6)cc3c54)c2)cc1] 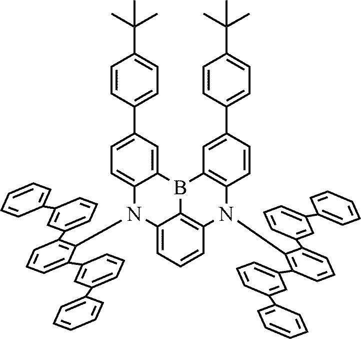 [SMILES: CC(C)(C)c1ccc(-c2ccc3c(c2)B2c4cc(-c5ccc(C(C)(C)C)cc5)ccc4N(c4c(-c5cccc(-c6ccccc6)c5)cccc4-c4cccc(-c5ccccc5)c4)c4cccc(c42)N3c2c(-c3cccc(-c4ccccc4)c3)cccc2-c2cccc(-c3ccccc3)c2)cc1] 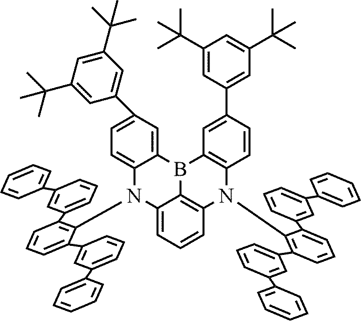 [SMILES: CC(C)(C)c1cc(-c2ccc3c(c2)B2c4cc(-c5cc(C(C)(C)C)cc(C(C)(C)C)c5)ccc4N(c4c(-c5cccc(-c6ccccc6)c5)cccc4-c4cccc(-c5ccccc5)c4)c4cccc(c42)N3c2c(-c3cccc(-c4ccccc4)c3)cccc2-c2cccc(-c3ccccc3)c2)cc(C(C)(C)C)c1] 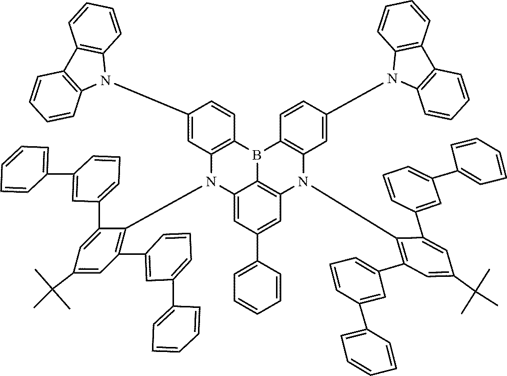 [SMILES: CC(C)(C)c1cc(-c2cccc(-c3ccccc3)c2)c(N2c3cc(-n4c5ccccc5c5ccccc54)ccc3B3c4ccc(-n5c6ccccc6c6ccccc65)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1] 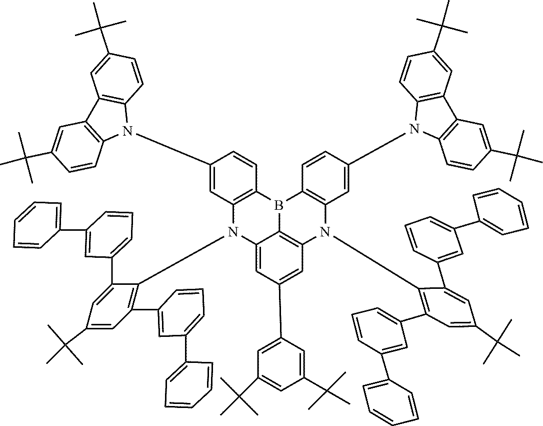 [SMILES: CC(C)(C)c1cc(-c2cc3c4c(c2)N(c2c(-c5cccc(-c6ccccc6)c5)cc(C(C)(C)C)cc2-c2cccc(-c5ccccc5)c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3cccc(-c4ccccc4)c3)cc(C(C)(C)C)cc2-c2cccc(-c3ccccc3)c2)cc(C(C)(C)C)c1] 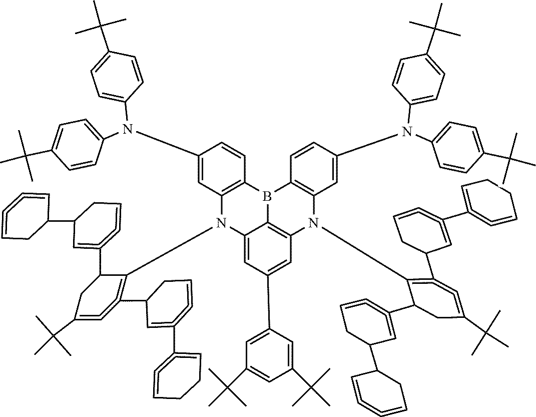 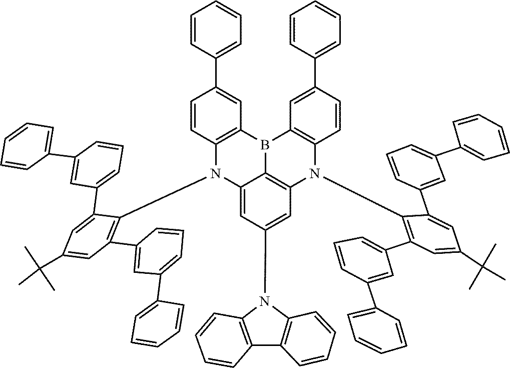 [SMILES: CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc(-c5ccccc5)c4)c4cc(-n5c6ccccc6c6ccccc65)cc2c43)c(-c2cccc(-c3ccccc3)c2)c1] 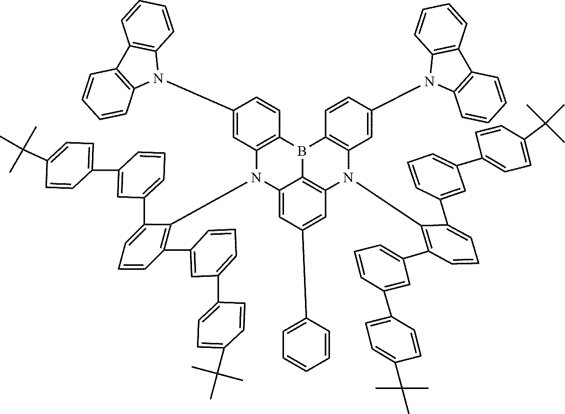 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-c6ccccc6)cc3c54)c2)cc1] 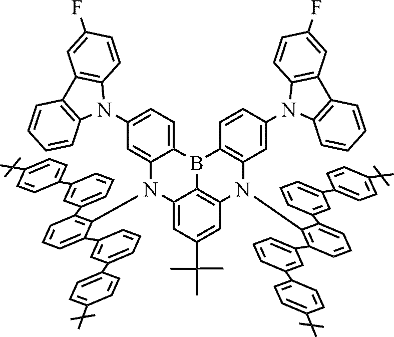 [SMILES: CC(C)(C)c1ccc(-c2cccc(-c3cccc(-c4cccc(-c5ccc(C(C)(C)C)cc5)c4)c3N3c4cc(-n5c6ccccc6c6cc(F)ccc65)ccc4B4c5ccc(-n6c7ccccc7c7cc(F)ccc76)cc5N(c5c(-c6cccc(-c7ccc(C(C)(C)C)cc7)c6)cccc5-c5cccc(-c6ccc(C(C)(C)C)cc6)c5)c5cc(C(C)(C)C)cc3c54)c2)cc1] 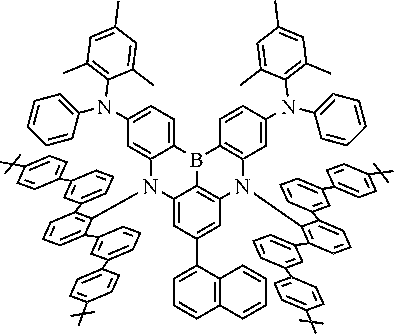 [SMILES: Cc1cc(C)c(N(c2ccccc2)c2ccc3c(c2)N(c2c(-c4cccc(-c5ccc(C(C)(C)C)cc5)c4)cccc2-c2cccc(-c4ccc(C(C)(C)C)cc4)c2)c2cc(-c4cccc5ccccc45)cc4c2B3c2ccc(N(c3ccccc3)c3c(C)cc(C)cc3C)cc2N4c2c(-c3cccc(-c4ccc(C(C)(C)C)cc4)c3)cccc2-c2cccc(-c3ccc(C(C)(C)C)cc3)c2)c(C)c1] 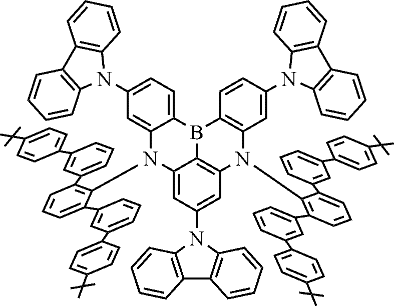 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-n6c7ccccc7c7ccccc76)cc3c54)c2)cc1] 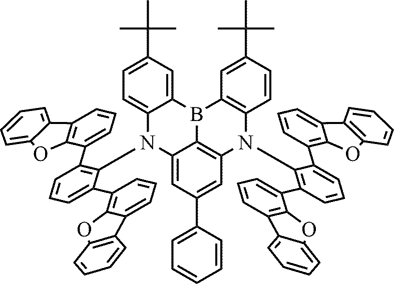 [SMILES: CC(C)(C)c1ccc2c(c1)B1c3cc(C(C)(C)C)ccc3N(c3c(-c4cccc5c4oc4ccccc45)cccc3-c3cccc4c3oc3ccccc34)c3cc(-c4ccccc4)cc(c31)N2c1c(-c2cccc3c2oc2ccccc23)cccc1-c1cccc2c1oc1ccccc12] 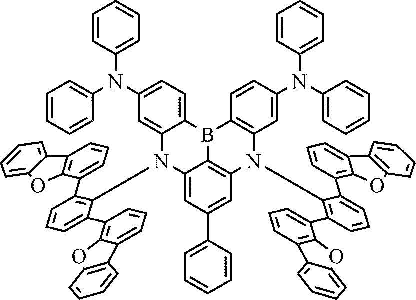 [SMILES: c1ccc(-c2cc3c4c(c2)N(c2c(-c5cccc6c5oc5ccccc56)cccc2-c2cccc5c2oc2ccccc25)c2cc(N(c5ccccc5)c5ccccc5)ccc2B4c2ccc(N(c4ccccc4)c4ccccc4)cc2N3c2c(-c3cccc4c3oc3ccccc34)cccc2-c2cccc3c2oc2ccccc23)cc1] 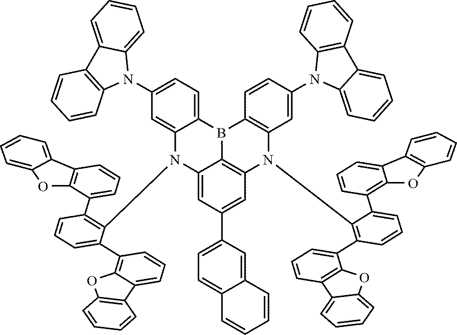 [SMILES: c1cc(-c2cccc3c2oc2ccccc23)c(N2c3cc(-n4c5ccccc5c5ccccc54)ccc3B3c4ccc(-n5c6ccccc6c6ccccc65)cc4N(c4c(-c5cccc6c5oc5ccccc56)cccc4-c4cccc5c4oc4ccccc45)c4cc(-c5ccc6ccccc6c5)cc2c43)c(-c2cccc3c2oc2ccccc23)c1] 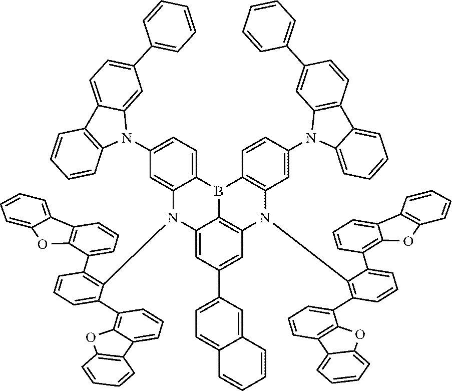 [SMILES: c1ccc(-c2ccc3c4ccccc4n(-c4ccc5c(c4)N(c4c(-c6cccc7c6oc6ccccc67)cccc4-c4cccc6c4oc4ccccc46)c4cc(-c6ccc7ccccc7c6)cc6c4B5c4ccc(-n5c7ccccc7c7ccc(-c8ccccc8)cc75)cc4N6c4c(-c5cccc6c5oc5ccccc56)cccc4-c4cccc5c4oc4ccccc45)c3c2)cc1] 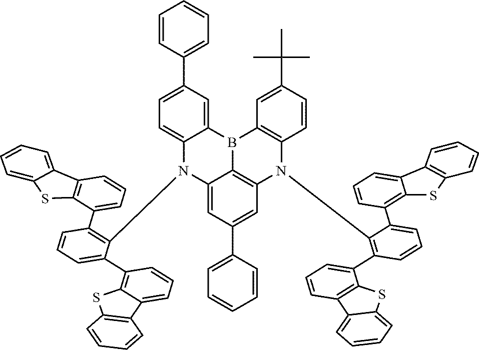 [SMILES: CC(C)(C)c1ccc2c(c1)B1c3cc(-c4ccccc4)ccc3N(c3c(-c4cccc5c4sc4ccccc45)cccc3-c3cccc4c3sc3ccccc34)c3cc(-c4ccccc4)cc(c31)N2c1c(-c2cccc3c2sc2ccccc23)cccc1-c1cccc2c1sc1ccccc12] 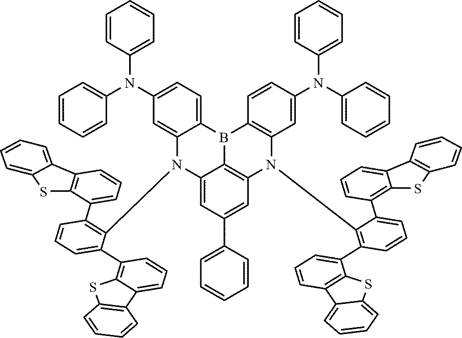 [SMILES: c1ccc(-c2cc3c4c(c2)N(c2c(-c5cccc6c5sc5ccccc56)cccc2-c2cccc5c2sc2ccccc25)c2cc(N(c5ccccc5)c5ccccc5)ccc2B4c2ccc(N(c4ccccc4)c4ccccc4)cc2N3c2c(-c3cccc4c3sc3ccccc34)cccc2-c2cccc3c2sc2ccccc23)cc1] 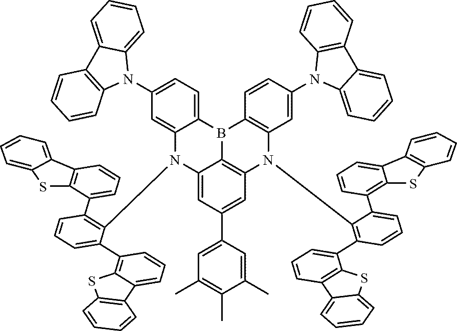 [SMILES: Cc1cc(-c2cc3c4c(c2)N(c2c(-c5cccc6c5sc5ccccc56)cccc2-c2cccc5c2sc2ccccc25)c2cc(-n5c6ccccc6c6ccccc65)ccc2B4c2ccc(-n4c5ccccc5c5ccccc54)cc2N3c2c(-c3cccc4c3sc3ccccc34)cccc2-c2cccc3c2sc2ccccc23)cc(C)c1C] 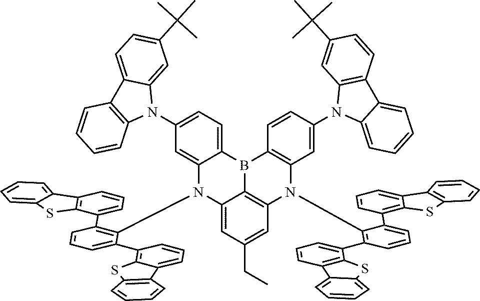 [SMILES: CCc1cc2c3c(c1)N(c1c(-c4cccc5c4sc4ccccc45)cccc1-c1cccc4c1sc1ccccc14)c1cc(-n4c5ccccc5c5ccc(C(C)(C)C)cc54)ccc1B3c1ccc(-n3c4ccccc4c4ccc(C(C)(C)C)cc43)cc1N2c1c(-c2cccc3c2sc2ccccc23)cccc1-c1cccc2c1sc1ccccc12] 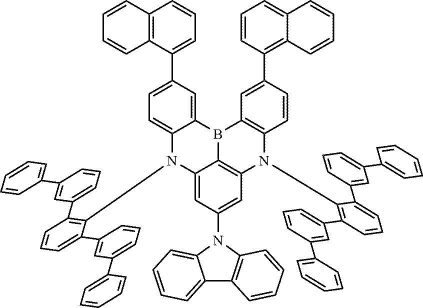 [SMILES: c1ccc(-c2cccc(-c3cccc(-c4cccc(-c5ccccc5)c4)c3N3c4ccc(-c5cccc6ccccc56)cc4B4c5cc(-c6cccc7ccccc67)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 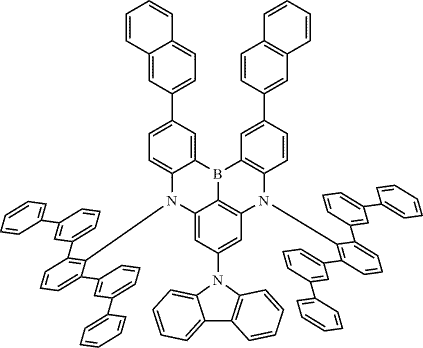 [SMILES: c1ccc(-c2cccc(-c3cccc(-c4cccc(-c5ccccc5)c4)c3N3c4ccc(-c5ccc6ccccc6c5)cc4B4c5cc(-c6ccc7ccccc7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 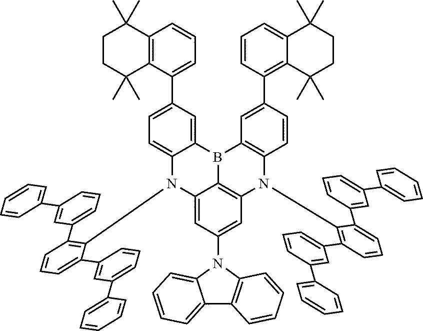 [SMILES: CC1(C)CCC(C)(C)c2c(-c3ccc4c(c3)B3c5cc(-c6cccc7c6C(C)(C)CCC7(C)C)ccc5N(c5c(-c6cccc(-c7ccccc7)c6)cccc5-c5cccc(-c6ccccc6)c5)c5cc(-n6c7ccccc7c7ccccc76)cc(c53)N4c3c(-c4cccc(-c5ccccc5)c4)cccc3-c3cccc(-c4ccccc4)c3)cccc21] 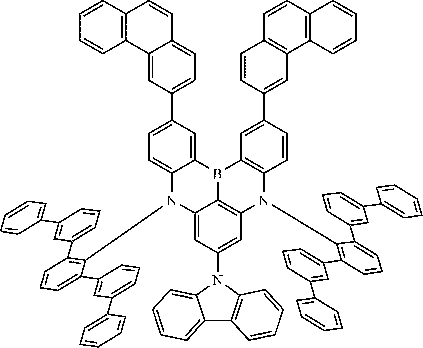 [SMILES: c1ccc(-c2cccc(-c3cccc(-c4cccc(-c5ccccc5)c4)c3N3c4ccc(-c5ccc6ccc7ccccc7c6c5)cc4B4c5cc(-c6ccc7ccc8ccccc8c7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 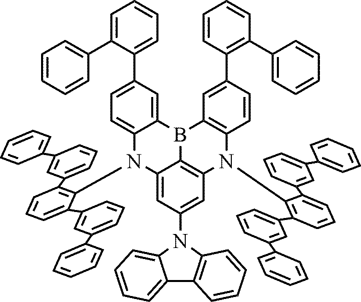 [SMILES: c1ccc(-c2cccc(-c3cccc(-c4cccc(-c5ccccc5)c4)c3N3c4ccc(-c5ccccc5-c5ccccc5)cc4B4c5cc(-c6ccccc6-c6ccccc6)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 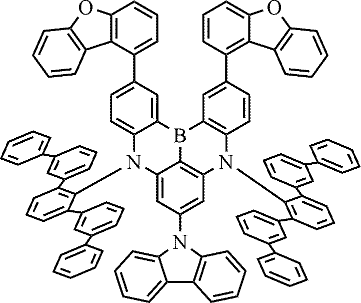 [SMILES: c1ccc(-c2cccc(-c3cccc(-c4cccc(-c5ccccc5)c4)c3N3c4ccc(-c5cccc6oc7ccccc7c56)cc4B4c5cc(-c6cccc7oc8ccccc8c67)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 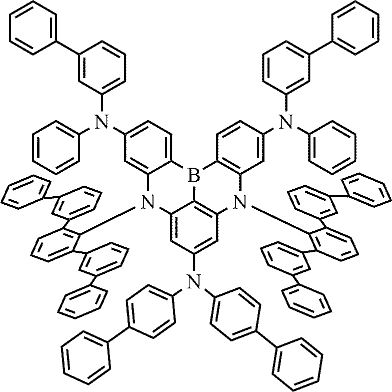 [SMILES: c1ccc(-c2ccc(N(c3ccc(-c4ccccc4)cc3)c3cc4c5c(c3)N(c3c(-c6cccc(-c7ccccc7)c6)cccc3-c3cccc(-c6ccccc6)c3)c3cc(N(c6ccccc6)c6cccc(-c7ccccc7)c6)ccc3B5c3ccc(N(c5ccccc5)c5cccc(-c6ccccc6)c5)cc3N4c3c(-c4cccc(-c5ccccc5)c4)cccc3-c3cccc(-c4ccccc4)c3)cc2)cc1] 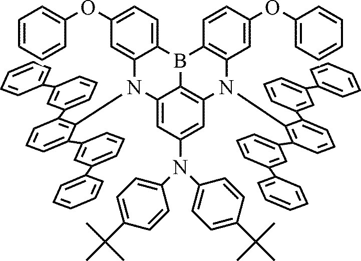 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(Oc5ccccc5)ccc2B4c2ccc(Oc4ccccc4)cc2N3c2c(-c3cccc(-c4ccccc4)c3)cccc2-c2cccc(-c3ccccc3)c2)cc1] 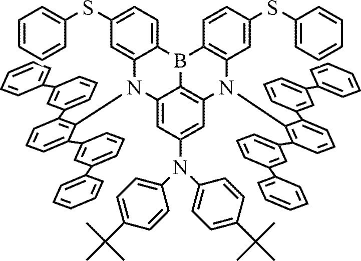 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(Sc5ccccc5)ccc2B4c2ccc(Sc4ccccc4)cc2N3c2c(-c3cccc(-c4ccccc4)c3)cccc2-c2cccc(-c3ccccc3)c2)cc1] 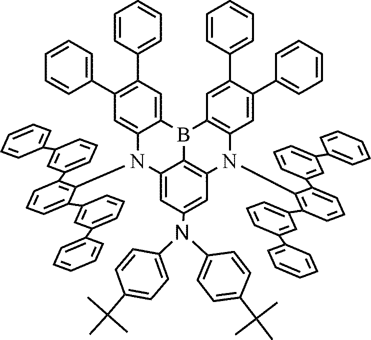 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)c(-c5ccccc5)cc2B4c2cc(-c4ccccc4)c(-c4ccccc4)cc2N3c2c(-c3cccc(-c4ccccc4)c3)cccc2-c2cccc(-c3ccccc3)c2)cc1] 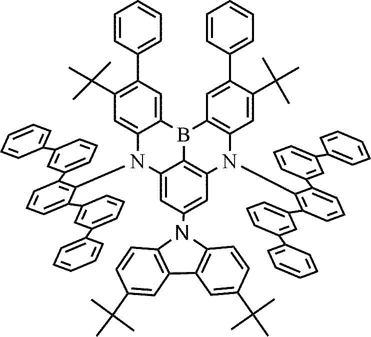 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(C(C)(C)C)c(-c4ccccc4)cc1B3c1cc(-c3ccccc3)c(C(C)(C)C)cc1N2c1c(-c2cccc(-c3ccccc3)c2)cccc1-c1cccc(-c2ccccc2)c1] 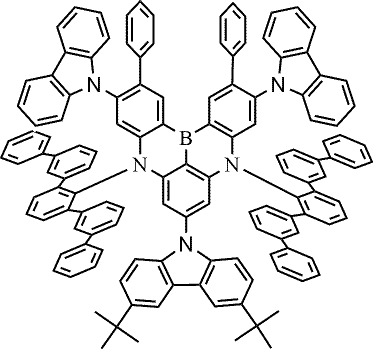 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(-n4c5ccccc5c5ccccc54)c(-c4ccccc4)cc1B3c1cc(-c3ccccc3)c(-n3c4ccccc4c4ccccc43)cc1N2c1c(-c2cccc(-c3ccccc3)c2)cccc1-c1cccc(-c2ccccc2)c1] 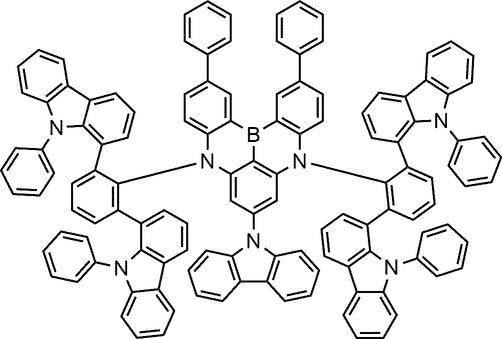 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)N3c2c(-c3cccc4c5ccccc5n(-c5ccccc5)c34)cccc2-c2cccc3c4ccccc4n(-c4ccccc4)c23)cc1] 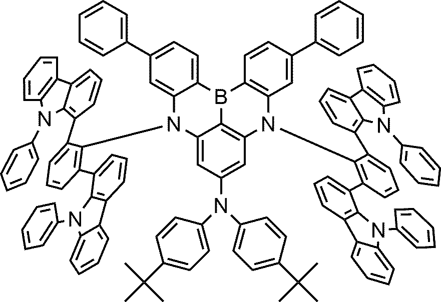 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2N3c2c(-c3cccc4c5ccccc5n(-c5ccccc5)c34)cccc2-c2cccc3c4ccccc4n(-c4ccccc4)c23)cc1] 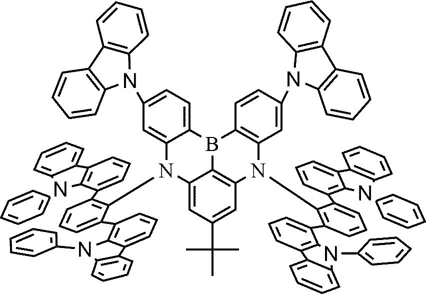 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1N2c1c(-c2cccc3c4ccccc4n(-c4ccccc4)c23)cccc1-c1cccc2c3ccccc3n(-c3ccccc3)c12] 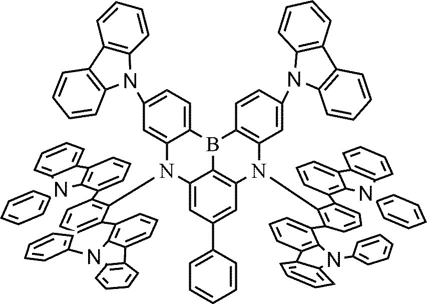 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2N3c2c(-c3cccc4c5ccccc5n(-c5ccccc5)c34)cccc2-c2cccc3c4ccccc4n(-c4ccccc4)c23)cc1] 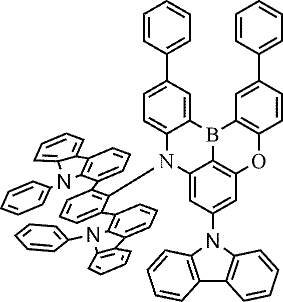 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)O3)cc1] 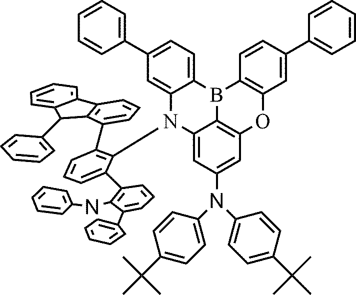 [SMILES: CC(C)(C)c1ccc(N(c2ccc(C(C)(C)C)cc2)c2cc3c4c(c2)N(c2c(-c5cccc6c5[C@@H](c5ccccc5)c5ccccc5-6)cccc2-c2cccc5c6ccccc6n(-c6ccccc6)c25)c2cc(-c5ccccc5)ccc2B4c2ccc(-c4ccccc4)cc2O3)cc1] 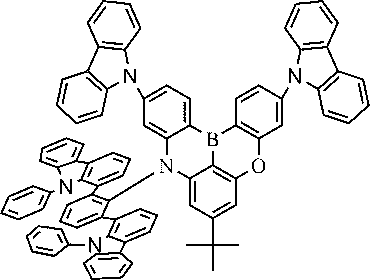 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1O2] 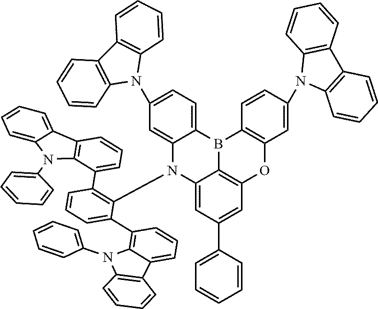 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2O3)cc1] 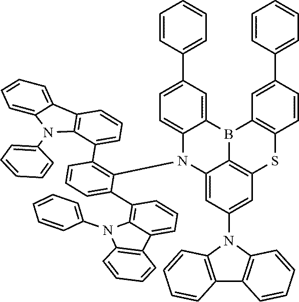 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)S3)cc1] 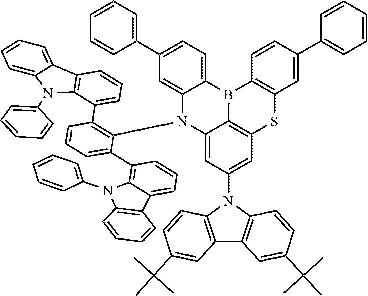 [SMILES: CC(C)(C)c1ccc2c(c1)c1cc(C(C)(C)C)ccc1n2-c1cc2c3c(c1)N(c1c(-c4cccc5c6ccccc6n(-c6ccccc6)c45)cccc1-c1cccc4c5ccccc5n(-c5ccccc5)c14)c1cc(-c4ccccc4)ccc1B3c1ccc(-c3ccccc3)cc1S2] 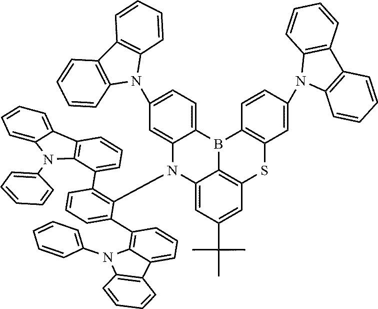 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1S2] 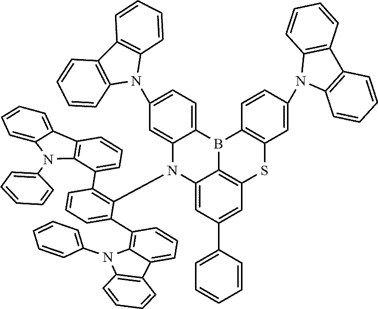 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2S3)cc1] 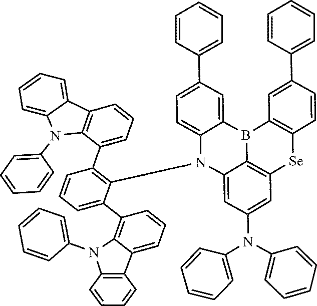 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(N(c5ccccc5)c5ccccc5)cc(c42)[Se]3)cc1] 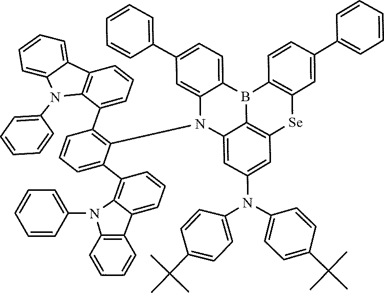 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2[Se]3)cc1] 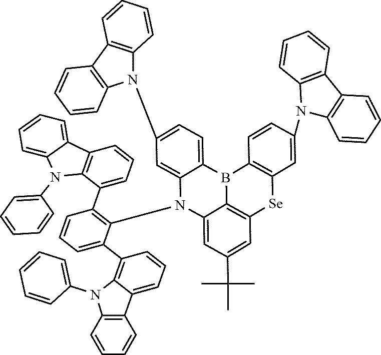 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1[Se]2] 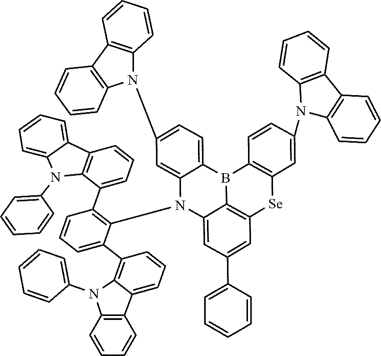 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2[Se]3)cc1] 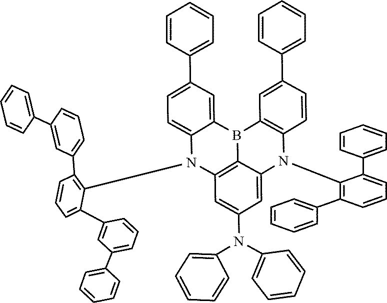 [SMILES: c1ccc(-c2cccc(-c3cccc(-c4cccc(-c5ccccc5)c4)c3N3c4ccc(-c5ccccc5)cc4B4c5cc(-c6ccccc6)ccc5N(c5c(-c6ccccc6)cccc5-c5ccccc5)c5cc(N(c6ccccc6)c6ccccc6)cc3c54)c2)cc1] 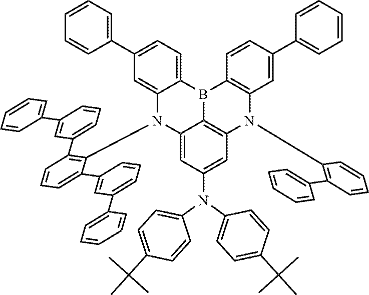 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)ccc2B4c2ccc(-c4ccccc4)cc2N3c2ccccc2-c2ccccc2)cc1] 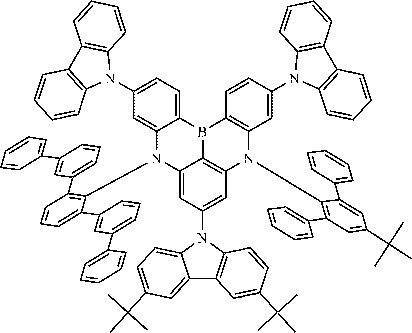 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc(-c6ccccc6)c5)cccc4-c4cccc(-c5ccccc5)c4)c4cc(-n5c6ccc(C(C)(C)C)cc6c6cc(C(C)(C)C)ccc65)cc2c43)c(-c2ccccc2)c1] 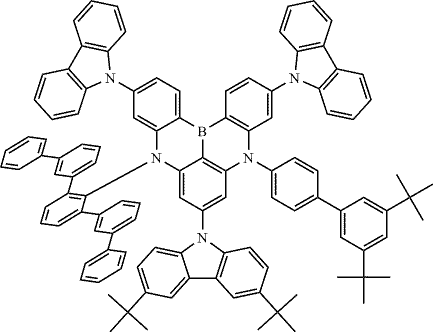 [SMILES: CC(C)(C)c1cc(-c2ccc(N3c4cc(-n5c6ccccc6c6ccccc65)ccc4B4c5ccc(-n6c7ccccc7c7ccccc76)cc5N(c5c(-c6cccc(-c7ccccc7)c6)cccc5-c5cccc(-c6ccccc6)c5)c5cc(-n6c7ccc(C(C)(C)C)cc7c7cc(C(C)(C)C)ccc76)cc3c54)cc2)cc(C(C)(C)C)c1] 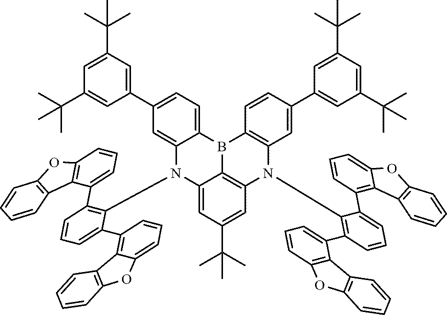 [SMILES: CC(C)(C)c1cc(-c2ccc3c(c2)N(c2c(-c4cccc5oc6ccccc6c45)cccc2-c2cccc4oc5ccccc5c24)c2cc(C(C)(C)C)cc4c2B3c2ccc(-c3cc(C(C)(C)C)cc(C(C)(C)C)c3)cc2N4c2c(-c3cccc4oc5ccccc5c34)cccc2-c2cccc3oc4ccccc4c23)cc(C(C)(C)C)c1] 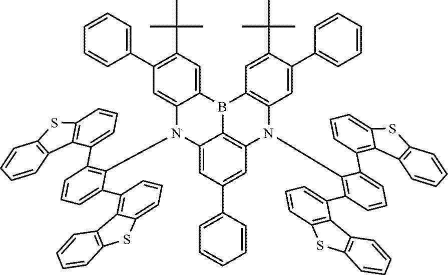 [SMILES: CC(C)(C)c1cc2c(cc1-c1ccccc1)N(c1c(-c3cccc4sc5ccccc5c34)cccc1-c1cccc3sc4ccccc4c13)c1cc(-c3ccccc3)cc3c1B2c1cc(C(C)(C)C)c(-c2ccccc2)cc1N3c1c(-c2cccc3sc4ccccc4c23)cccc1-c1cccc2sc3ccccc3c12] 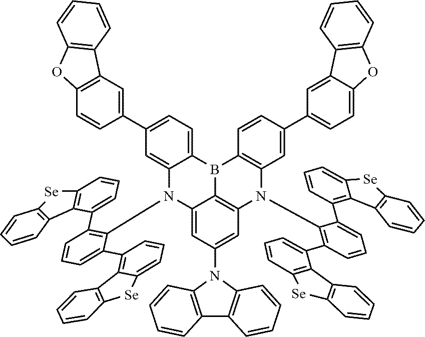 [SMILES: c1cc(-c2cccc3[se]c4ccccc4c23)c(N2c3cc(-c4ccc5oc6ccccc6c5c4)ccc3B3c4ccc(-c5ccc6oc7ccccc7c6c5)cc4N(c4c(-c5cccc6[se]c7ccccc7c56)cccc4-c4cccc5[se]c6ccccc6c45)c4cc(-n5c6ccccc6c6ccccc65)cc2c43)c(-c2cccc3[se]c4ccccc4c23)c1] 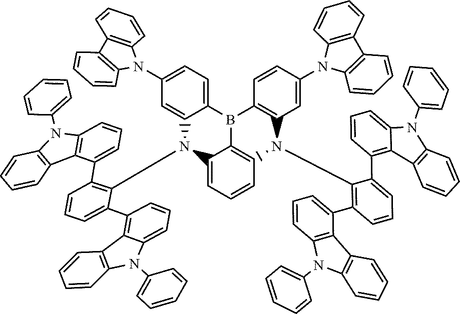 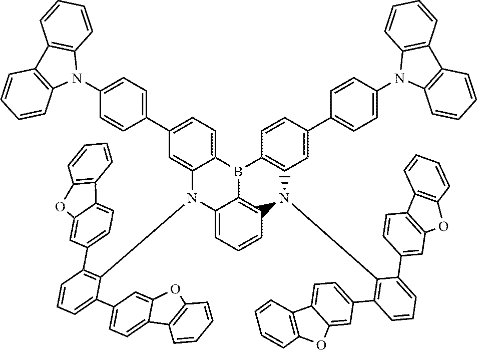 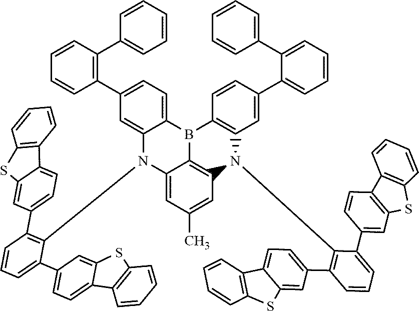 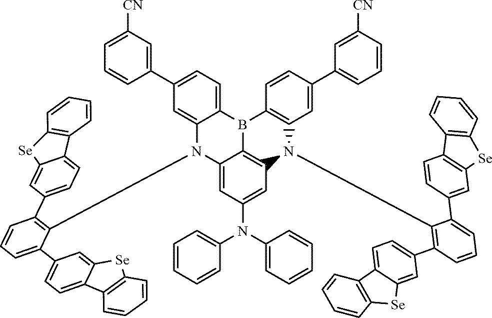 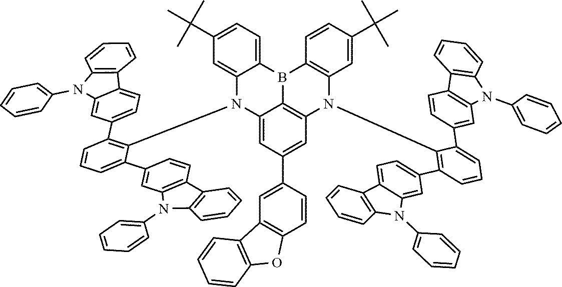 [SMILES: CC(C)(C)c1ccc2c(c1)N(c1c(-c3ccc4c5ccccc5n(-c5ccccc5)c4c3)cccc1-c1ccc3c4ccccc4n(-c4ccccc4)c3c1)c1cc(-c3ccc4oc5ccccc5c4c3)cc3c1B2c1ccc(C(C)(C)C)cc1N3c1c(-c2ccc3c4ccccc4n(-c4ccccc4)c3c2)cccc1-c1ccc2c3ccccc3n(-c3ccccc3)c2c1] 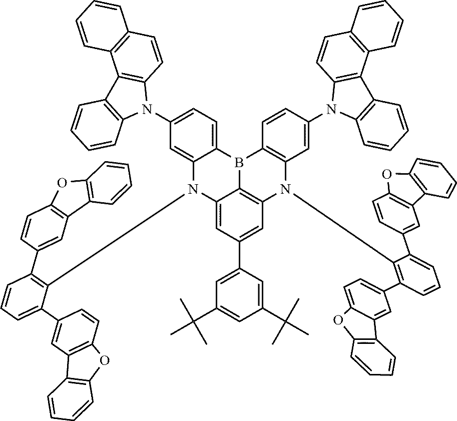 [SMILES: CC(C)(C)c1cc(-c2cc3c4c(c2)N(c2c(-c5ccc6oc7ccccc7c6c5)cccc2-c2ccc5oc6ccccc6c5c2)c2cc(-n5c6ccccc6c6c7ccccc7ccc65)ccc2B4c2ccc(-n4c5ccccc5c5c6ccccc6ccc54)cc2N3c2c(-c3ccc4oc5ccccc5c4c3)cccc2-c2ccc3oc4ccccc4c3c2)cc(C(C)(C)C)c1] 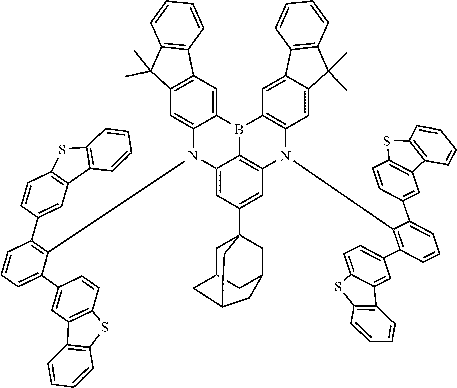 [SMILES: CC1(C)c2ccccc2-c2cc3c(cc21)N(c1c(-c2ccc4sc5ccccc5c4c2)cccc1-c1ccc2sc4ccccc4c2c1)c1cc(C24CCC5CC(CC(C5)C2)C4)cc2c1B3c1cc3c(cc1N2c1c(-c2ccc4sc5ccccc5c4c2)cccc1-c1ccc2sc4ccccc4c2c1)C(C)(C)c1ccccc1-3] 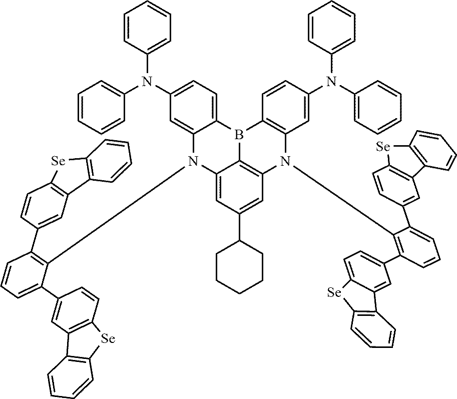 [SMILES: c1ccc(N(c2ccccc2)c2ccc3c(c2)N(c2c(-c4ccc5[se]c6ccccc6c5c4)cccc2-c2ccc4[se]c5ccccc5c4c2)c2cc(C4CCCCC4)cc4c2B3c2ccc(N(c3ccccc3)c3ccccc3)cc2N4c2c(-c3ccc4[se]c5ccccc5c4c3)cccc2-c2ccc3[se]c4ccccc4c3c2)cc1] 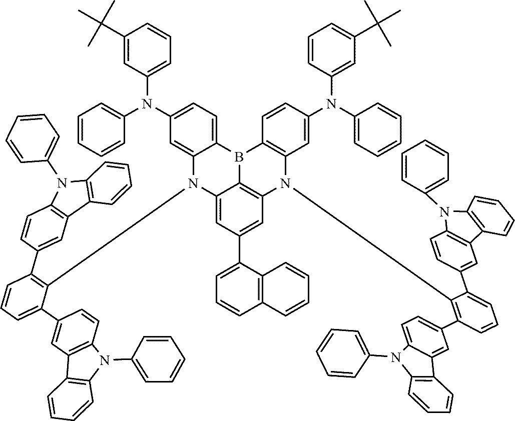 [SMILES: CC(C)(C)c1cccc(N(c2ccccc2)c2ccc3c(c2)N(c2c(-c4ccc5c(c4)c4ccccc4n5-c4ccccc4)cccc2-c2ccc4c(c2)c2ccccc2n4-c2ccccc2)c2cc(-c4cccc5ccccc45)cc4c2B3c2ccc(N(c3ccccc3)c3cccc(C(C)(C)C)c3)cc2N4c2c(-c3ccc4c(c3)c3ccccc3n4-c3ccccc3)cccc2-c2ccc3c(c2)c2ccccc2n3-c2ccccc2)c1] 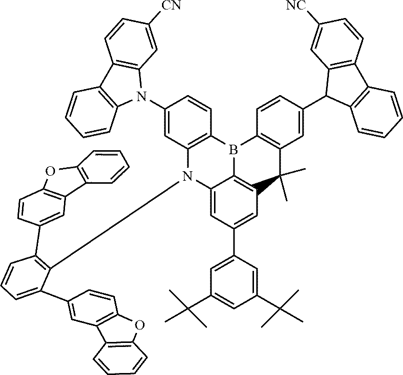 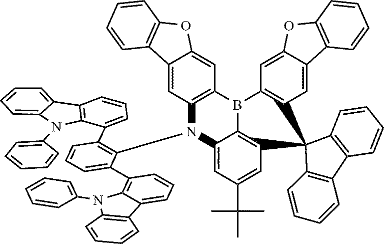 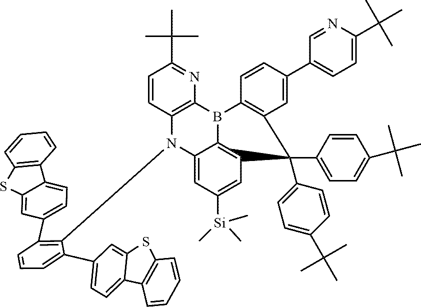 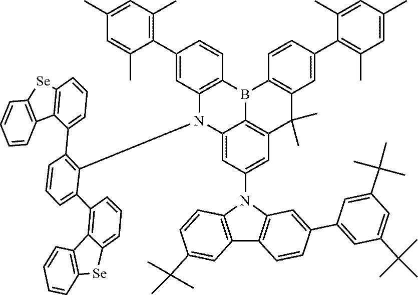 [SMILES: Cc1cc(C)c(-c2ccc3c(c2)N(c2c(-c4cccc5[se]c6ccccc6c45)cccc2-c2cccc4[se]c5ccccc5c24)c2cc(-n4c5ccc(C(C)(C)C)cc5c5ccc(-c6cc(C(C)(C)C)cc(C(C)(C)C)c6)cc54)cc4c2B3c2ccc(-c3c(C)cc(C)cc3C)cc2C4(C)C)c(C)c1]
.

15. A light emitting element comprising:
a first electrode;
a hole transport region on the first electrode;
an emission layer on the hole transport region;
an electron transport region on the emission layer; and
a second electrode on the electron transport region,
wherein the emission layer comprises a first compound represented by Formula 1, and
the hole transport region comprises a hole transport compound represented by Formula H-1: Formula 1 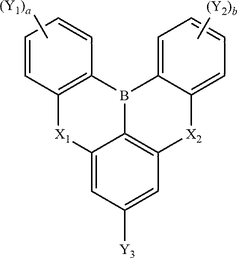
wherein in Formula 1,
X₁ and X₂ are each independently CR₁R₂, NR₃, NR₄, O, S, or Se, where at least one among X₁ and X₂ is NR₄,
Y₁ to Y₃ are each independently a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted oxy group, a substituted or unsubstituted cycloalkyl group of 3 to60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
“a” and “b” are each independently an integer of 0 to 4, in the case where “a” and “b” are integers of 2 or more, each of multiple Y₁ and Y₂ are the same or different,
R₁ to R₃ are each independently a hydrogen atom, a deuterium atom, a halogen atom, a cyano group, a nitro group, a hydroxyl group, a substituted or unsubstituted silyl group, a substituted or unsubstituted alkyl group of 1 to60 carbon atoms, a substituted or unsubstituted oxy group, a substituted or unsubstituted cycloalkyl group of 3 to60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring, and
R₄ is represented by Formula 2 or Formula 3: 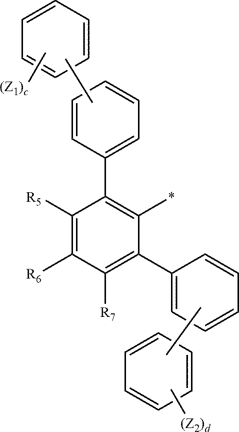 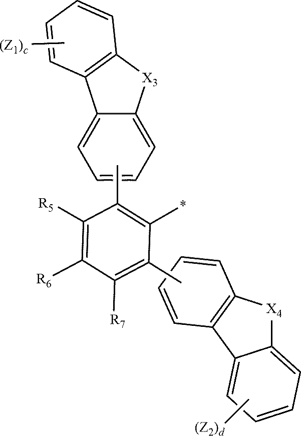
wherein in Formula 2 and Formula 3,
X₃ and X₄ are each independently CR₈R₉, NR₁₀, O, S, or Se,
R₅ to R₁₀ are each independently a hydrogen atom, a deuterium atom, a halogen atom, a cyano group, a nitro group, a hydroxyl group, a substituted or unsubstituted silyl group, a substituted or unsubstituted alkyl group of 1 to60 carbon atoms, a substituted or unsubstituted oxy group, a substituted or unsubstituted cycloalkyl group of 3 to 60 ring-forming carbon atoms, a substituted or unsubstituted aryl group of 6 to 60 ring-forming carbon atoms, a substituted or unsubstituted amine group, a substituted or unsubstituted thio group, or a substituted or unsubstituted heteroaryl group of 2 to 60 ring-forming carbon atoms, and/or combined with an adjacent group to form a ring,
Z₁ and Z₂ are each independently a hydrogen atom, a deuterium atom, a halogen atom, a cyano group, a nitro group, a substituted or unsubstituted silyl group, a substituted or unsubstituted amino group, a substituted or unsubstituted alkyl group of 1 to 60 carbon atoms, a substituted or unsubstituted oxy group, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to60 ring-forming carbon atoms, and
“c” and “d” are each independently an integer of 0 to 4, in the case where “c” and “d” are integers of 2 or more, each of multiple Z₁ and Z₂ are the same or different, 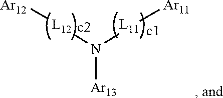
wherein in Formula H-1,
c1 and c2 are each independently an integer of 0 to 10,
L₁₁ and L₁₂ are each independently a direct linkage, a substituted or unsubstituted arylene group of 6 to 30 ring-forming carbon atoms, or a substituted or unsubstituted heteroarylene group of 2 to 30 ring-forming carbon atoms,
Ar₁₁ and Ar₁₂ are each independently a substituted or unsubstituted aryl group of 6 to 30 ring-forming carbon atoms, or a substituted or unsubstituted heteroaryl group of 2 to 30 ring-forming carbon atoms, and
Ar₁₃ is a substituted or unsubstituted aryl group of 6 to 30 ring-forming carbon atoms.

16. The light emitting element of claim 15, wherein Formula 2 is represented by Formula 2-1: 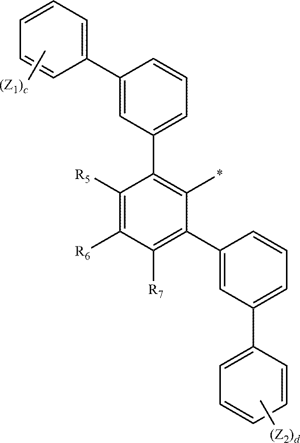
wherein in Formula 2-1,
R₅ to R₇, Z₁, Z₂, “c” and “d” are the same as defined in Formula 2.

17. The light emitting element of claim 15, wherein Formula 3 is represented by any one selected from among Formula 3-1 to Formula 3-4: 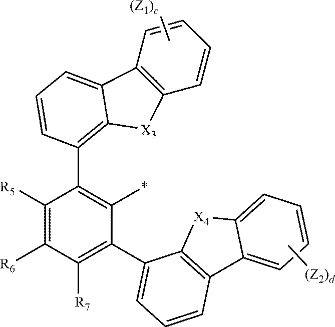 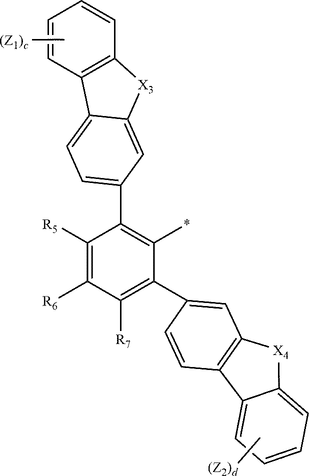 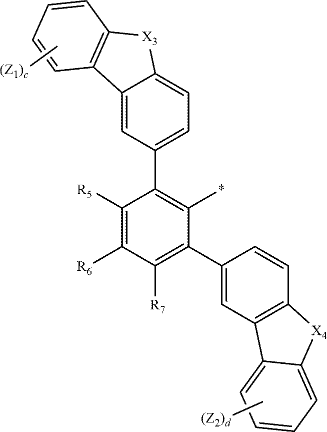 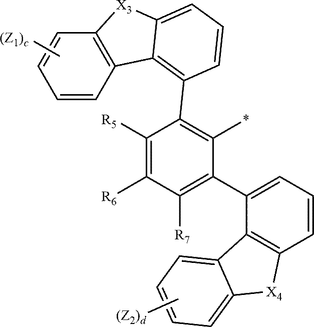
wherein in Formula 3-1 to Formula 3-4,
R₅ to R₇, X₃, X₄, Z₁, Z₂, “c” and “d” are the same as defined in Formula 3.

18. The light emitting element of claim 16, wherein the first compound is represented by any one selected from among Formula 4-1 to Formula 4-3: 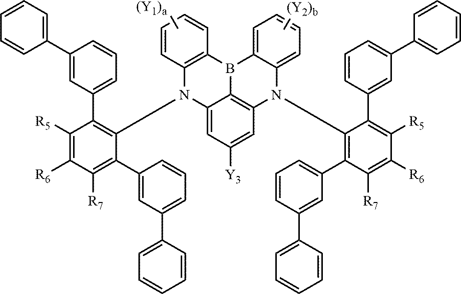 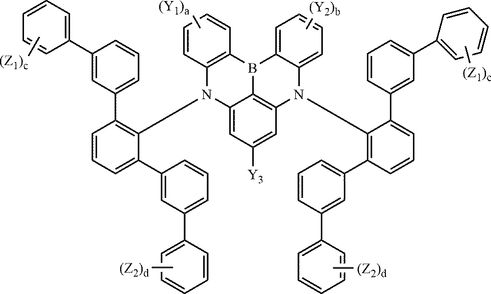 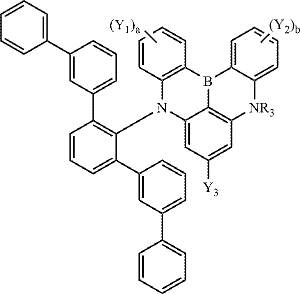
wherein in Formula 4-1 to Formula 4-3,
Y₁ to Y₃, R₃, R₅ to R₇, Z₁, Z₂, and “a” to “d” are the same as defined in Formula 1 and Formula 2.

19. The light emitting element of claim 17, wherein the first compound is represented by any one selected from among Formula 5-1 to Formula 5-12: 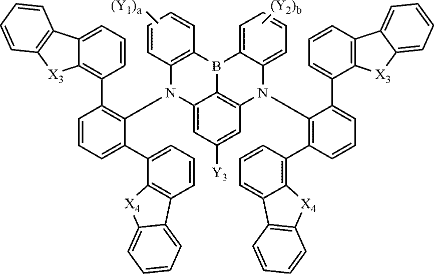 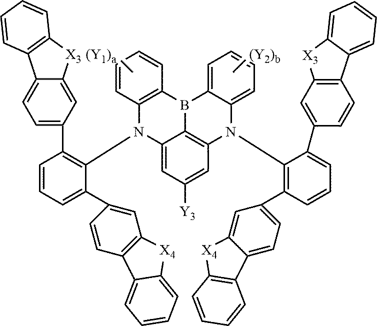 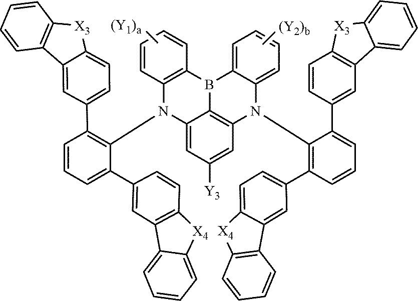 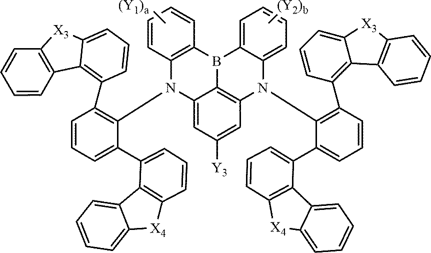 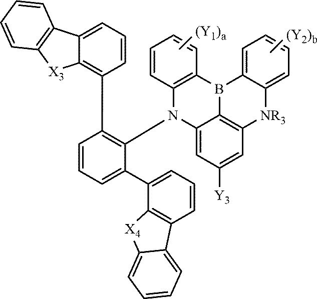 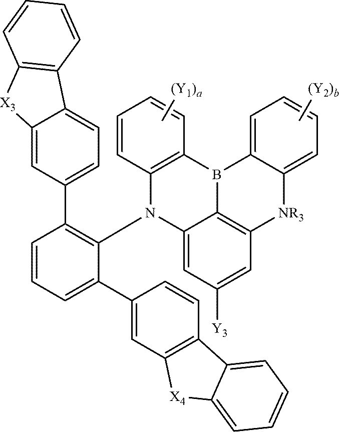 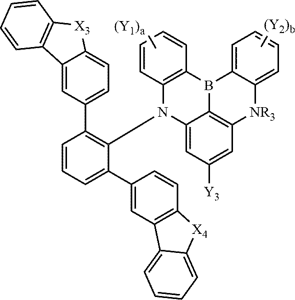 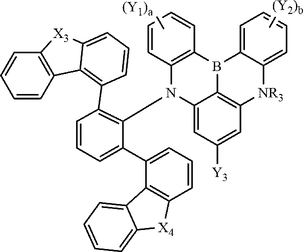 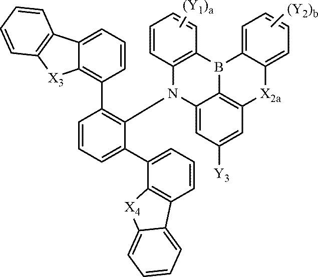 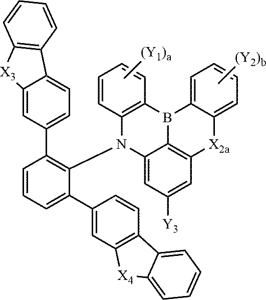 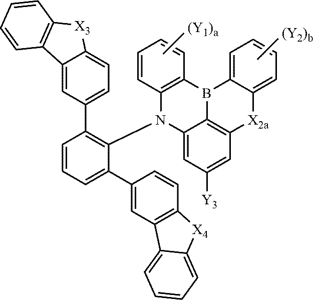 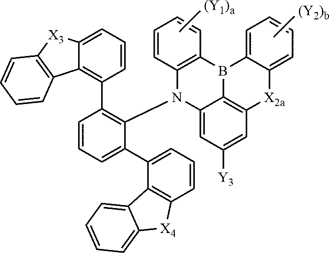
wherein in Formula 5-1 to Formula 5-12,
X₂ₐ is CR₁R₂, O, S or Se, and Y₁ to Y₃, R₁ to R₃, “a”, “b”, X₃ and X₄ are the same as defined in Formula 1 and Formula 3-1 to Formula 3-3.

20. The light emitting element of claim 15, wherein the first compound is represented by any one selectedf rom among compounds in Compound Group 1: Compound Group 1 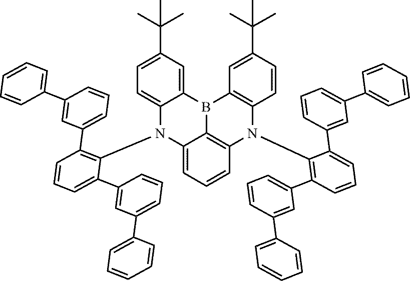 [SMILES: CC(C)(C)c1ccc2c(c1)B1c3cc(C(C)(C)C)ccc3N(c3c(-c4cccc(-c5ccccc5)c4)cccc3-c3cccc(-c4ccccc4)c3)c3cccc(c31)N2c1c(-c2cccc(-c3ccccc3)c2)cccc1-c1cccc(-c2ccccc2)c1] 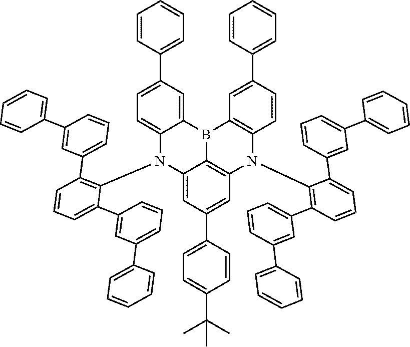 [SMILES: CC(C)(C)c1ccc(-c2cc3c4c(c2)N(c2c(-c5cccc(-c6ccccc6)c5)cccc2-c2cccc(-c5ccccc5)c2)c2ccc(-c5ccccc5)cc2B4c2cc(-c4ccccc4)ccc2N3c2c(-c3cccc(-c4ccccc4)c3)cccc2-c2cccc(-c3ccccc3)c2)cc1] 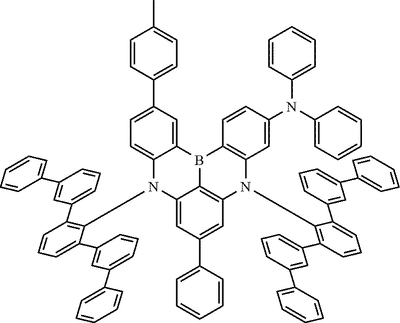 [SMILES: Cc1ccc(-c2ccc3c(c2)B2c4ccc(N(c5ccccc5)c5ccccc5)cc4N(c4c(-c5cccc(-c6ccccc6)c5)cccc4-c4cccc(-c5ccccc5)c4)c4cc(-c5ccccc5)cc(c42)N3c2c(-c3cccc(-c4ccccc4)c3)cccc2-c2cccc(-c3ccccc3)c2)cc1] 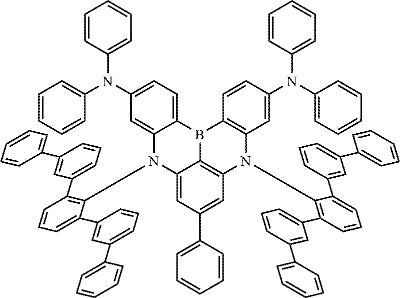 [SMILES: c1ccc(-c2cccc(-c3cccc(-c4cccc(-c5ccccc5)c4)c3N3c4cc(N(c5ccccc5)c5ccccc5)ccc4B4c5ccc(N(c6ccccc6)c6ccccc6)cc5N(c5c(-c6cccc(-c7ccccc7)c6)cccc5-c5cccc(-c6ccccc6)c5)c5cc(-c6ccccc6)cc3c54)c2)cc1] 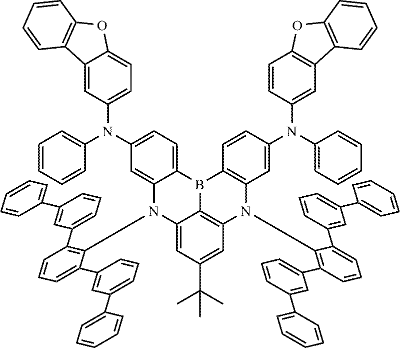 [SMILES: CC(C)(C)c1cc2c3c(c1)N(c1c(-c4cccc(-c5ccccc5)c4)cccc1-c1cccc(-c4ccccc4)c1)c1cc(N(c4ccccc4)c4ccc5oc6ccccc6c5c4)ccc1B3c1ccc(N(c3ccccc3)c3ccc4oc5ccccc5c4c3)cc1N2c1c(-c2cccc(-c3ccccc3)c2)cccc1-c1cccc(-c2ccccc2)c1] 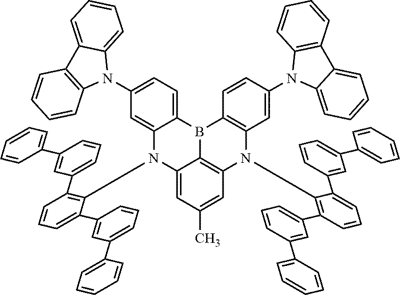 [SMILES: Cc1cc2c3c(c1)N(c1c(-c4cccc(-c5ccccc5)c4)cccc1-c1cccc(-c4ccccc4)c1)c1cc(-n4c5ccccc5c5ccccc54)ccc1B3c1ccc(-n3c4ccccc4c4ccccc43)cc1N2c1c(-c2cccc(-c3ccccc3)c2)cccc1-c1cccc(-c2ccccc2)c1] 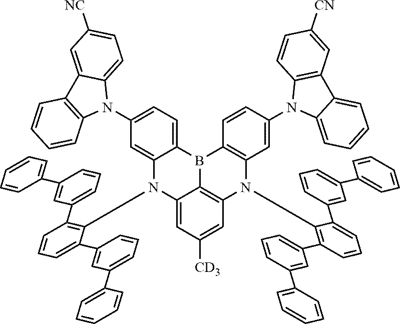 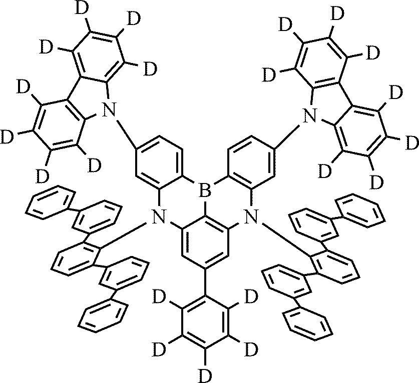 [SMILES: [2H]c1c([2H])c([2H])c(-c2cc3c4c(c2)N(c2c(-c5cccc(-c6ccccc6)c5)cccc2-c2cccc(-c5ccccc5)c2)c2cc(-n5c6c([2H])c([2H])c([2H])c([2H])c6c6c([2H])c([2H])c([2H])c([2H])c65)ccc2B4c2ccc(-n4c5c([2H])c([2H])c([2H])c([2H])c5c5c([2H])c([2H])c([2H])c([2H])c54)cc2N3c2c(-c3cccc(-c4ccccc4)c3)cccc2-c2cccc(-c3ccccc3)c2)c([2H])c1[2H]] 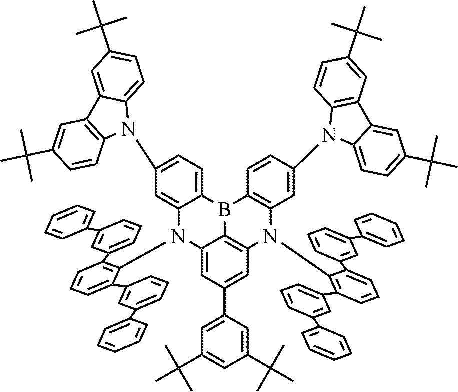 [SMILES: CC(C)(C)c1cc(-c2cc3c4c(c2)N(c2c(-c5cccc(-c6ccccc6)c5)cccc2-c2cccc(-c5ccccc5)c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3cccc(-c4ccccc4)c3)cccc2-c2cccc(-c3ccccc3)c2)cc(C(C)(C)C)c1] 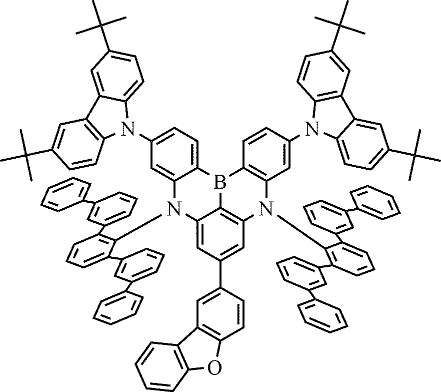 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4oc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 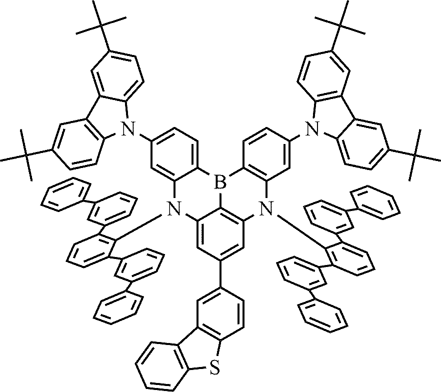 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4sc5ccccc5c4c3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 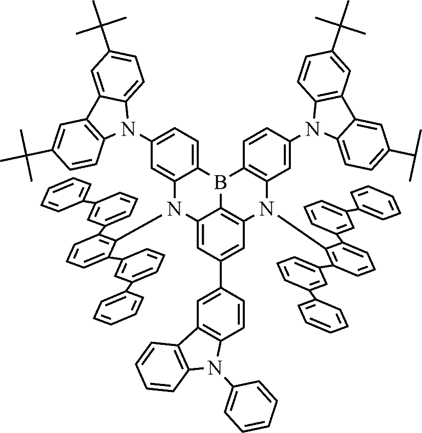 [SMILES: CC(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-c3ccc4c(c3)c3ccccc3n4-c3ccccc3)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 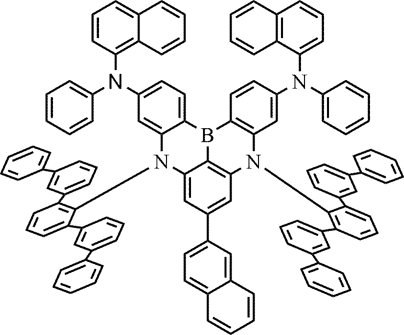 [SMILES: c1ccc(-c2cccc(-c3cccc(-c4cccc(-c5ccccc5)c4)c3N3c4cc(N(c5ccccc5)c5cccc6ccccc56)ccc4B4c5ccc(N(c6ccccc6)c6cccc7ccccc67)cc5N(c5c(-c6cccc(-c7ccccc7)c6)cccc5-c5cccc(-c6ccccc6)c5)c5cc(-c6ccc7ccccc7c6)cc3c54)c2)cc1] 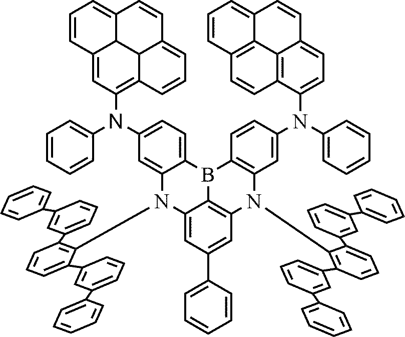 [SMILES: C1=CC2=CC(N(c3ccccc3)c3ccc4c(c3)N(c3c(-c5cccc(-c6ccccc6)c5)cccc3-c3cccc(-c5ccccc5)c3)c3cc(-c5ccccc5)cc5c3B4c3ccc(N(c4ccccc4)c4ccc6ccc7cccc8ccc4c6c78)cc3N5c3c(-c4cccc(-c5ccccc5)c4)cccc3-c3cccc(-c4ccccc4)c3)=C3C=CC=C4C=CC(=C1)C2C43] 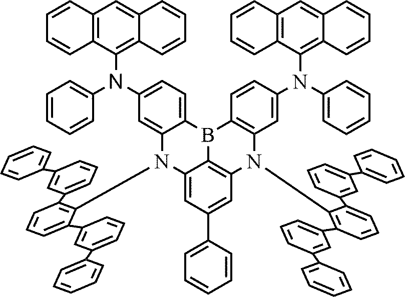 [SMILES: c1ccc(-c2cccc(-c3cccc(-c4cccc(-c5ccccc5)c4)c3N3c4cc(N(c5ccccc5)c5c6ccccc6cc6ccccc56)ccc4B4c5ccc(N(c6ccccc6)c6c7ccccc7cc7ccccc67)cc5N(c5c(-c6cccc(-c7ccccc7)c6)cccc5-c5cccc(-c6ccccc6)c5)c5cc(-c6ccccc6)cc3c54)c2)cc1] 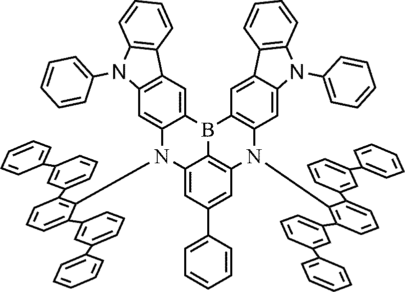 [SMILES: c1ccc(-c2cccc(-c3cccc(-c4cccc(-c5ccccc5)c4)c3N3c4cc5c(cc4B4c6cc7c8ccccc8n(-c8ccccc8)c7cc6N(c6c(-c7cccc(-c8ccccc8)c7)cccc6-c6cccc(-c7ccccc7)c6)c6cc(-c7ccccc7)cc3c64)c3ccccc3n5-c3ccccc3)c2)cc1] 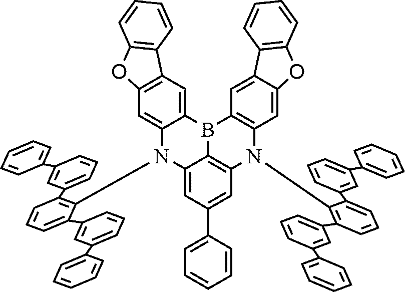 [SMILES: c1ccc(-c2cccc(-c3cccc(-c4cccc(-c5ccccc5)c4)c3N3c4cc5oc6ccccc6c5cc4B4c5cc6c(cc5N(c5c(-c7cccc(-c8ccccc8)c7)cccc5-c5cccc(-c7ccccc7)c5)c5cc(-c7ccccc7)cc3c54)oc3ccccc36)c2)cc1] 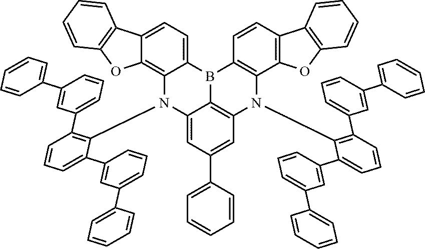 [SMILES: c1ccc(-c2cccc(-c3cccc(-c4cccc(-c5ccccc5)c4)c3N3c4cc(-c5ccccc5)cc5c4B(c4ccc6c(oc7ccccc76)c43)c3ccc4c(oc6ccccc64)c3N5c3c(-c4cccc(-c5ccccc5)c4)cccc3-c3cccc(-c4ccccc4)c3)c2)cc1] 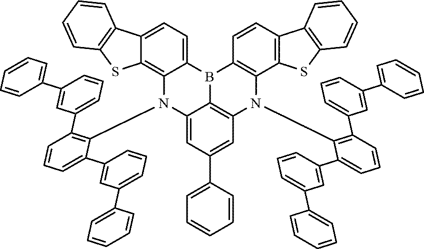 [SMILES: c1ccc(-c2cccc(-c3cccc(-c4cccc(-c5ccccc5)c4)c3N3c4cc(-c5ccccc5)cc5c4B(c4ccc6c(sc7ccccc76)c43)c3ccc4c(sc6ccccc64)c3N5c3c(-c4cccc(-c5ccccc5)c4)cccc3-c3cccc(-c4ccccc4)c3)c2)cc1] 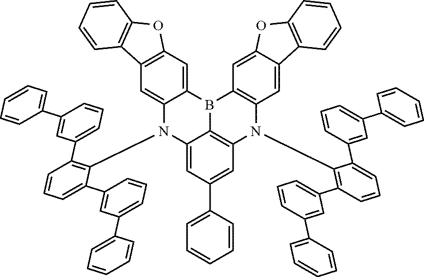 [SMILES: c1ccc(-c2cccc(-c3cccc(-c4cccc(-c5ccccc5)c4)c3N3c4cc5c(cc4B4c6cc7oc8ccccc8c7cc6N(c6c(-c7cccc(-c8ccccc8)c7)cccc6-c6cccc(-c7ccccc7)c6)c6cc(-c7ccccc7)cc3c64)oc3ccccc35)c2)cc1] 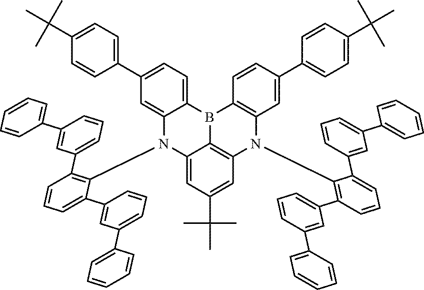 [SMILES: CC(C)(C)c1ccc(-c2ccc3c(c2)N(c2c(-c4cccc(-c5ccccc5)c4)cccc2-c2cccc(-c4ccccc4)c2)c2cc(C(C)(C)C)cc4c2B3c2ccc(-c3ccc(C(C)(C)C)cc3)cc2N4c2c(-c3cccc(-c4ccccc4)c3)cccc2-c2cccc(-c3ccccc3)c2)cc1] 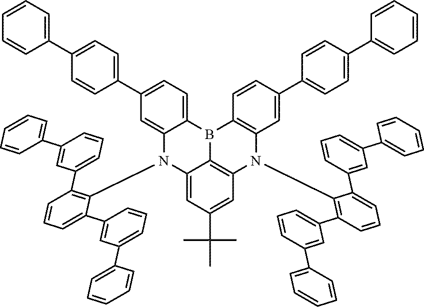 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)cc4)ccc1B3c1ccc(-c3ccc(-c4ccccc4)cc3)cc1N2c1c(-c2cccc(-c3ccccc3)c2)cccc1-c1cccc(-c2ccccc2)c1] 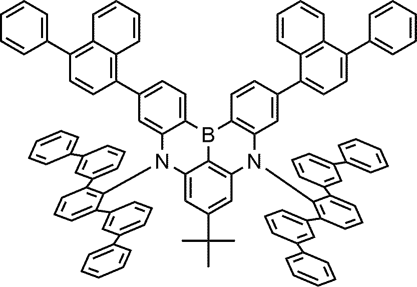 [SMILES: CC(C)(C)c1cc2c3c(c1)N(c1c(-c4cccc(-c5ccccc5)c4)cccc1-c1cccc(-c4ccccc4)c1)c1cc(-c4ccc(-c5ccccc5)c5ccccc45)ccc1B3c1ccc(-c3ccc(-c4ccccc4)c4ccccc34)cc1N2c1c(-c2cccc(-c3ccccc3)c2)cccc1-c1cccc(-c2ccccc2)c1] 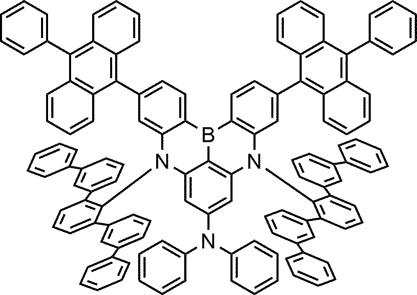 [SMILES: c1ccc(-c2cccc(-c3cccc(-c4cccc(-c5ccccc5)c4)c3N3c4cc(-c5c6ccccc6c(-c6ccccc6)c6ccccc56)ccc4B4c5ccc(-c6c7ccccc7c(-c7ccccc7)c7ccccc67)cc5N(c5c(-c6cccc(-c7ccccc7)c6)cccc5-c5cccc(-c6ccccc6)c5)c5cc(N(c6ccccc6)c6ccccc6)cc3c54)c2)cc1] 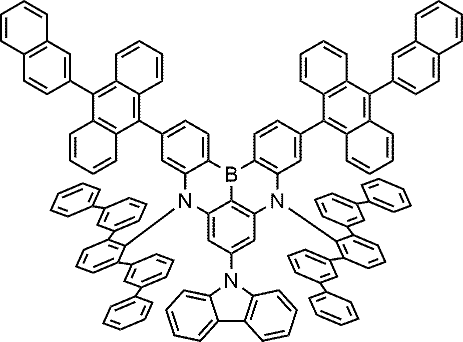 [SMILES: c1ccc(-c2cccc(-c3cccc(-c4cccc(-c5ccccc5)c4)c3N3c4cc(-c5c6ccccc6c(-c6ccc7ccccc7c6)c6ccccc56)ccc4B4c5ccc(-c6c7ccccc7c(-c7ccc8ccccc8c7)c7ccccc67)cc5N(c5c(-c6cccc(-c7ccccc7)c6)cccc5-c5cccc(-c6ccccc6)c5)c5cc(-n6c7ccccc7c7ccccc76)cc3c54)c2)cc1] 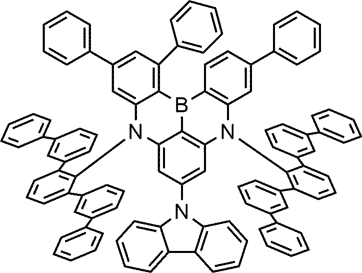 [SMILES: c1ccc(-c2cccc(-c3cccc(-c4cccc(-c5ccccc5)c4)c3N3c4cc(-c5ccccc5)ccc4B4c5c(-c6ccccc6)cc(-c6ccccc6)cc5N(c5c(-c6cccc(-c7ccccc7)c6)cccc5-c5cccc(-c6ccccc6)c5)c5cc(-n6c7ccccc7c7ccccc76)cc3c54)c2)cc1] 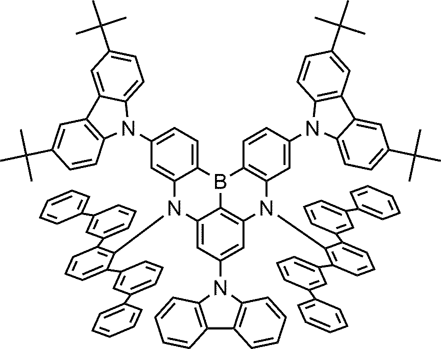 [SMILES: CC(C)(C)c1ccc2c(c1)c1cc(C(C)(C)C)ccc1n2-c1ccc2c(c1)N(c1c(-c3cccc(-c4ccccc4)c3)cccc1-c1cccc(-c3ccccc3)c1)c1cc(-n3c4ccccc4c4ccccc43)cc3c1B2c1ccc(-n2c4ccc(C(C)(C)C)cc4c4cc(C(C)(C)C)ccc42)cc1N3c1c(-c2cccc(-c3ccccc3)c2)cccc1-c1cccc(-c2ccccc2)c1] 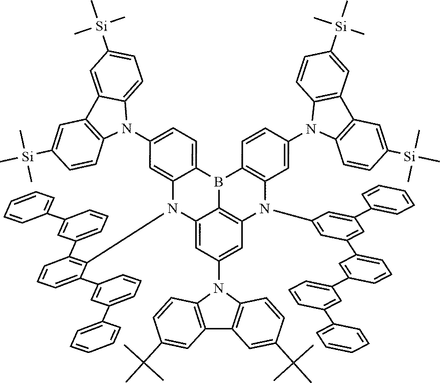 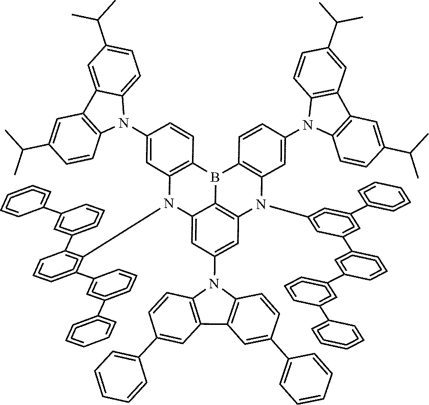 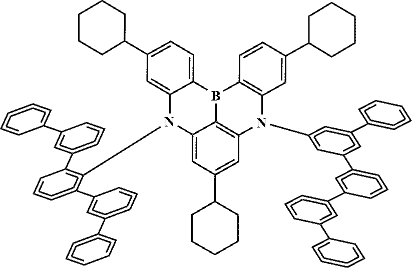 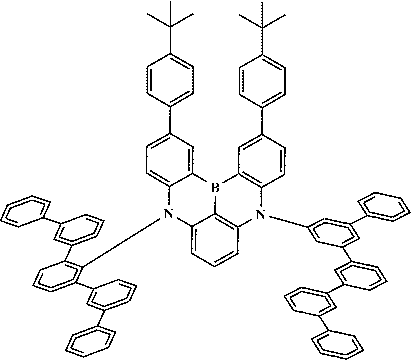 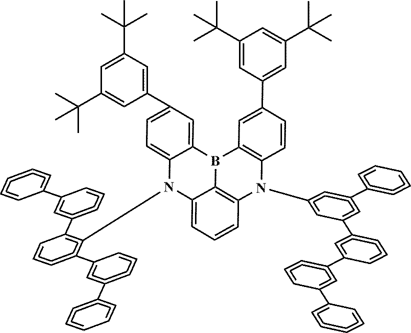 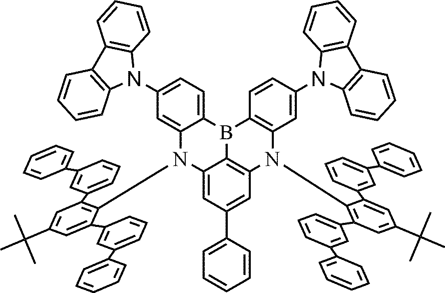 [SMILES: CC(C)(C)c1cc(-c2cccc(-c3ccccc3)c2)c(N2c3cc(-n4c5ccccc5c5ccccc54)ccc3B3c4ccc(-n5c6ccccc6c6ccccc65)cc4N(c4c(-c5cccc(-c6ccccc6)c5)cc(C(C)(C)C)cc4-c4cccc(-c5ccccc5)c4)c4cc(-c5ccccc5)cc2c43)c(-c2cccc(-c3ccccc3)c2)c1] 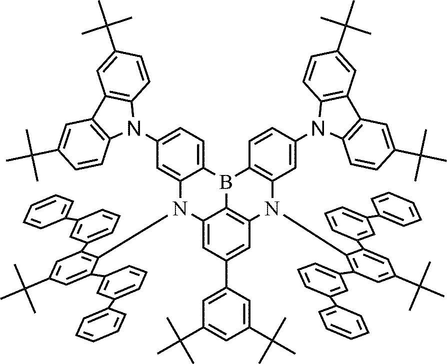 [SMILES: CC(C)(C)c1cc(-c2cc3c4c(c2)N(c2c(-c5cccc(-c6ccccc6)c5)cc(C(C)(C)C)cc2-c2cccc(-c5ccccc5)c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3cccc(-c4ccccc4)c3)cc(C(C)(C)C)cc2-c2cccc(-c3ccccc3)c2)cc(C(C)(C)C)c1] 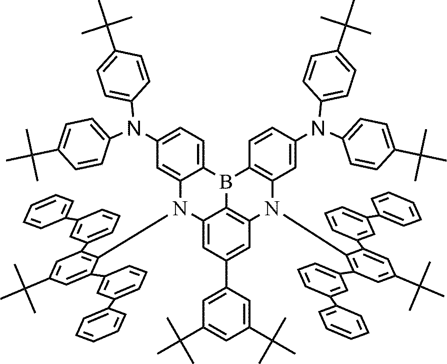 [SMILES: CC(C)(C)c1ccc(N(c2ccc(C(C)(C)C)cc2)c2ccc3c(c2)N(c2c(-c4cccc(-c5ccccc5)c4)cc(C(C)(C)C)cc2-c2cccc(-c4ccccc4)c2)c2cc(-c4cc(C(C)(C)C)cc(C(C)(C)C)c4)cc4c2B3c2ccc(N(c3ccc(C(C)(C)C)cc3)c3ccc(C(C)(C)C)cc3)cc2N4c2c(-c3cccc(-c4ccccc4)c3)cc(C(C)(C)C)cc2-c2cccc(-c3ccccc3)c2)cc1] 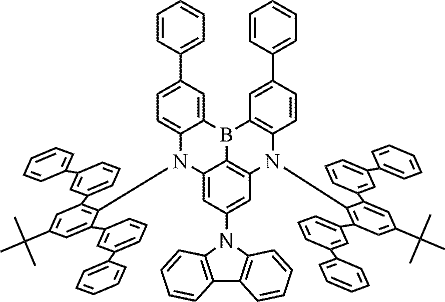 [SMILES: CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc(-c5ccccc5)c4)c4cc(-n5c6ccccc6c6ccccc65)cc2c43)c(-c2cccc(-c3ccccc3)c2)c1] 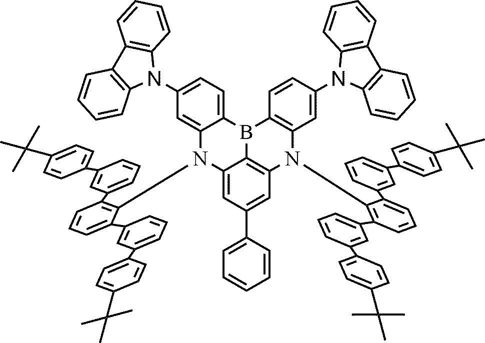 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-c6ccccc6)cc3c54)c2)cc1] 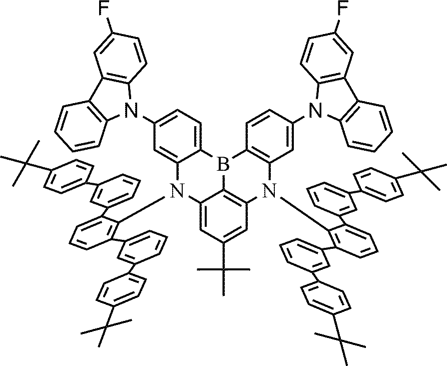 [SMILES: CC(C)(C)c1ccc(-c2cccc(-c3cccc(-c4cccc(-c5ccc(C(C)(C)C)cc5)c4)c3N3c4cc(-n5c6ccccc6c6cc(F)ccc65)ccc4B4c5ccc(-n6c7ccccc7c7cc(F)ccc76)cc5N(c5c(-c6cccc(-c7ccc(C(C)(C)C)cc7)c6)cccc5-c5cccc(-c6ccc(C(C)(C)C)cc6)c5)c5cc(C(C)(C)C)cc3c54)c2)cc1] 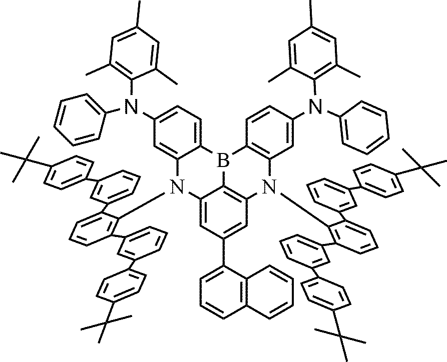 [SMILES: Cc1cc(C)c(N(c2ccccc2)c2ccc3c(c2)N(c2c(-c4cccc(-c5ccc(C(C)(C)C)cc5)c4)cccc2-c2cccc(-c4ccc(C(C)(C)C)cc4)c2)c2cc(-c4cccc5ccccc45)cc4c2B3c2ccc(N(c3ccccc3)c3c(C)cc(C)cc3C)cc2N4c2c(-c3cccc(-c4ccc(C(C)(C)C)cc4)c3)cccc2-c2cccc(-c3ccc(C(C)(C)C)cc3)c2)c(C)c1] 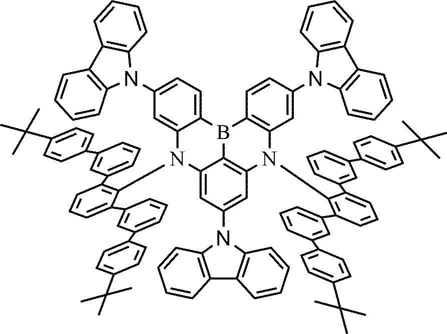 [SMILES: CC(C)(C)c1ccc(-c2cccc(-c3cccc(-c4cccc(-c5ccc(C(C)(C)C)cc5)c4)c3N3c4cc(-n5c6ccccc6c6ccccc65)ccc4B4c5ccc(-n6c7ccccc7c7ccccc76)cc5N(c5c(-c6cccc(-c7ccc(C(C)(C)C)cc7)c6)cccc5-c5cccc(-c6ccc(C(C)(C)C)cc6)c5)c5cc(-n6c7ccccc7c7ccccc76)cc3c54)c2)cc1] 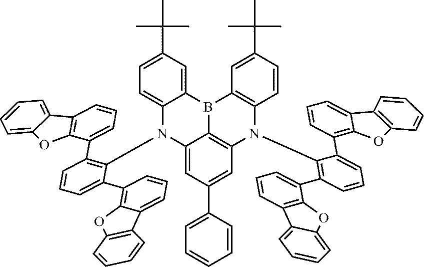 [SMILES: CC(C)(C)c1ccc2c(c1)B1c3cc(C(C)(C)C)ccc3N(c3c(-c4cccc5c4oc4ccccc45)cccc3-c3cccc4c3oc3ccccc34)c3cc(-c4ccccc4)cc(c31)N2c1c(-c2cccc3c2oc2ccccc23)cccc1-c1cccc2c1oc1ccccc12] 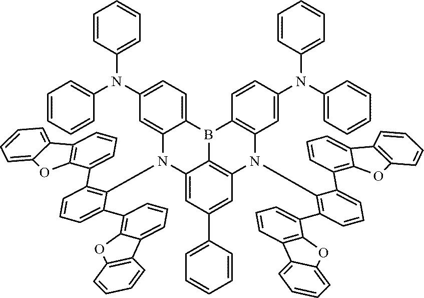 [SMILES: c1ccc(-c2cc3c4c(c2)N(c2c(-c5cccc6c5oc5ccccc56)cccc2-c2cccc5c2oc2ccccc25)c2cc(N(c5ccccc5)c5ccccc5)ccc2B4c2ccc(N(c4ccccc4)c4ccccc4)cc2N3c2c(-c3cccc4c3oc3ccccc34)cccc2-c2cccc3c2oc2ccccc23)cc1] 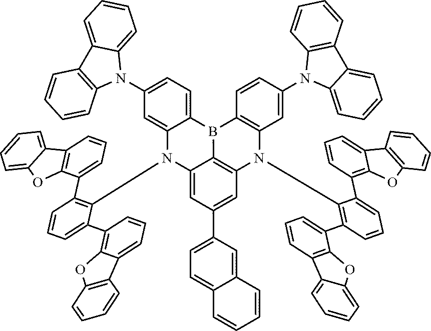 [SMILES: c1cc(-c2cccc3c2oc2ccccc23)c(N2c3cc(-n4c5ccccc5c5ccccc54)ccc3B3c4ccc(-n5c6ccccc6c6ccccc65)cc4N(c4c(-c5cccc6c5oc5ccccc56)cccc4-c4cccc5c4oc4ccccc45)c4cc(-c5ccc6ccccc6c5)cc2c43)c(-c2cccc3c2oc2ccccc23)c1] 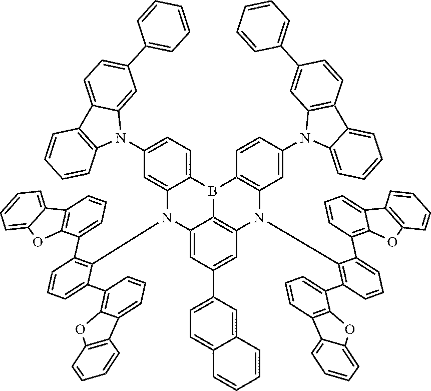 [SMILES: c1ccc(-c2ccc3c4ccccc4n(-c4ccc5c(c4)N(c4c(-c6cccc7c6oc6ccccc67)cccc4-c4cccc6c4oc4ccccc46)c4cc(-c6ccc7ccccc7c6)cc6c4B5c4ccc(-n5c7ccccc7c7ccc(-c8ccccc8)cc75)cc4N6c4c(-c5cccc6c5oc5ccccc56)cccc4-c4cccc5c4oc4ccccc45)c3c2)cc1] 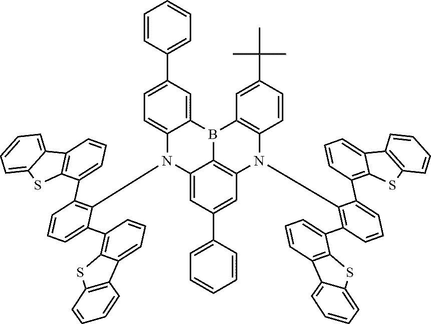 [SMILES: CC(C)(C)c1ccc2c(c1)B1c3cc(-c4ccccc4)ccc3N(c3c(-c4cccc5c4sc4ccccc45)cccc3-c3cccc4c3sc3ccccc34)c3cc(-c4ccccc4)cc(c31)N2c1c(-c2cccc3c2sc2ccccc23)cccc1-c1cccc2c1sc1ccccc12] 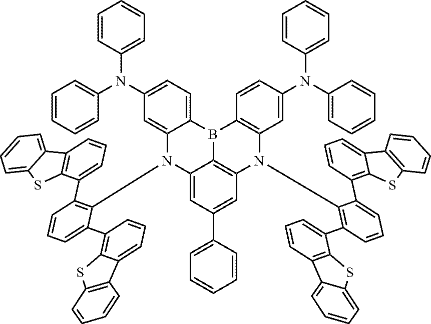 [SMILES: c1ccc(-c2cc3c4c(c2)N(c2c(-c5cccc6c5sc5ccccc56)cccc2-c2cccc5c2sc2ccccc25)c2cc(N(c5ccccc5)c5ccccc5)ccc2B4c2ccc(N(c4ccccc4)c4ccccc4)cc2N3c2c(-c3cccc4c3sc3ccccc34)cccc2-c2cccc3c2sc2ccccc23)cc1] 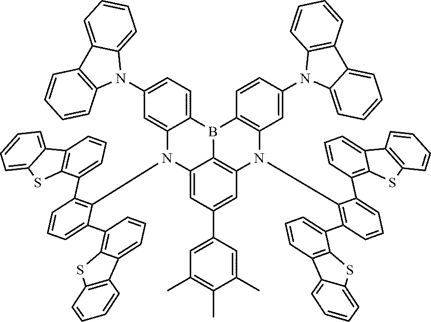 [SMILES: Cc1cc(-c2cc3c4c(c2)N(c2c(-c5cccc6c5sc5ccccc56)cccc2-c2cccc5c2sc2ccccc25)c2cc(-n5c6ccccc6c6ccccc65)ccc2B4c2ccc(-n4c5ccccc5c5ccccc54)cc2N3c2c(-c3cccc4c3sc3ccccc34)cccc2-c2cccc3c2sc2ccccc23)cc(C)c1C] 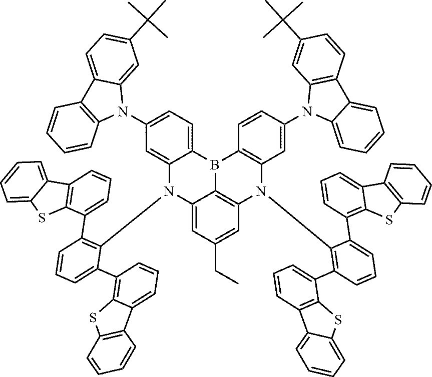 [SMILES: CCc1cc2c3c(c1)N(c1c(-c4cccc5c4sc4ccccc45)cccc1-c1cccc4c1sc1ccccc14)c1cc(-n4c5ccccc5c5ccc(C(C)(C)C)cc54)ccc1B3c1ccc(-n3c4ccccc4c4ccc(C(C)(C)C)cc43)cc1N2c1c(-c2cccc3c2sc2ccccc23)cccc1-c1cccc2c1sc1ccccc12] 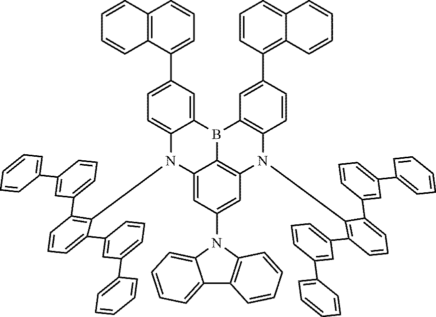 [SMILES: c1ccc(-c2cccc(-c3cccc(-c4cccc(-c5ccccc5)c4)c3N3c4ccc(-c5cccc6ccccc56)cc4B4c5cc(-c6cccc7ccccc67)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 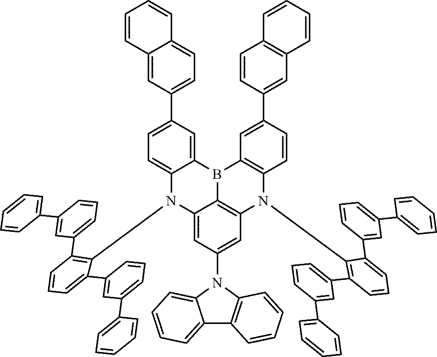 [SMILES: c1ccc(-c2cccc(-c3cccc(-c4cccc(-c5ccccc5)c4)c3N3c4ccc(-c5ccc6ccccc6c5)cc4B4c5cc(-c6ccc7ccccc7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 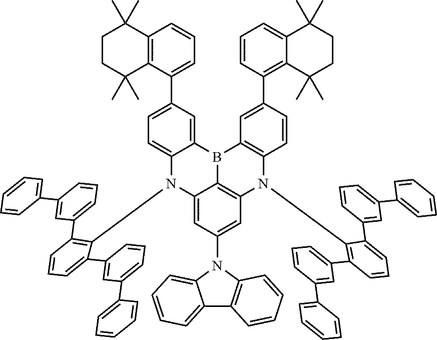 [SMILES: CC1(C)CCC(C)(C)c2c(-c3ccc4c(c3)B3c5cc(-c6cccc7c6C(C)(C)CCC7(C)C)ccc5N(c5c(-c6cccc(-c7ccccc7)c6)cccc5-c5cccc(-c6ccccc6)c5)c5cc(-n6c7ccccc7c7ccccc76)cc(c53)N4c3c(-c4cccc(-c5ccccc5)c4)cccc3-c3cccc(-c4ccccc4)c3)cccc21] 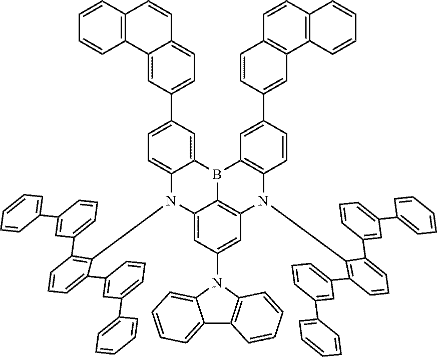 [SMILES: c1ccc(-c2cccc(-c3cccc(-c4cccc(-c5ccccc5)c4)c3N3c4ccc(-c5ccc6ccc7ccccc7c6c5)cc4B4c5cc(-c6ccc7ccc8ccccc8c7c6)ccc5N(c5c(-c6cccc(-c7ccccc7)c6)cccc5-c5cccc(-c6ccccc6)c5)c5cc(-n6c7ccccc7c7ccccc76)cc3c54)c2)cc1] 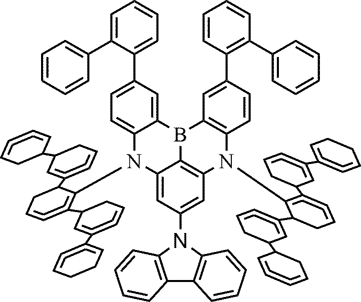 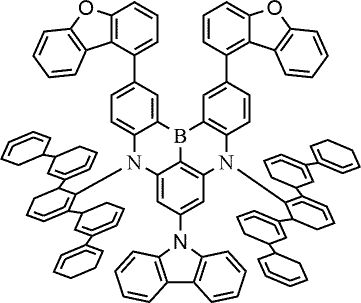 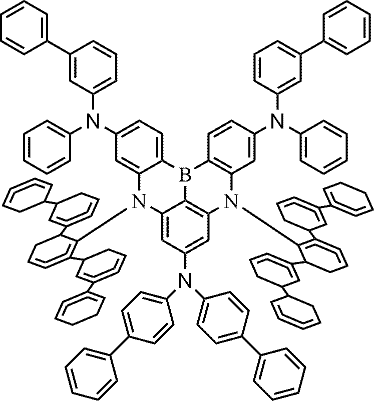 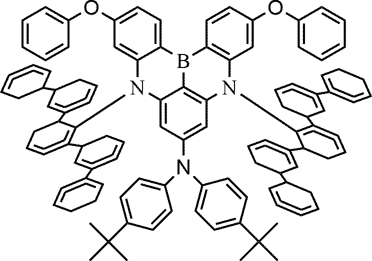 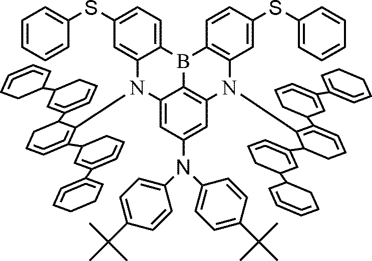 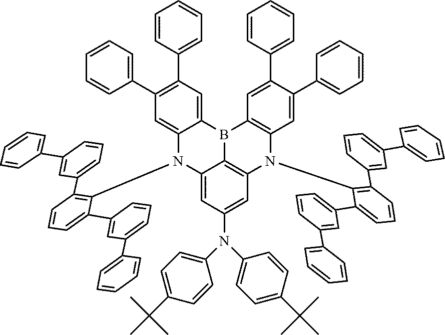 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)c(-c5ccccc5)cc2B4c2cc(-c4ccccc4)c(-c4ccccc4)cc2N3c2c(-c3cccc(-c4ccccc4)c3)cccc2-c2cccc(-c3ccccc3)c2)cc1] 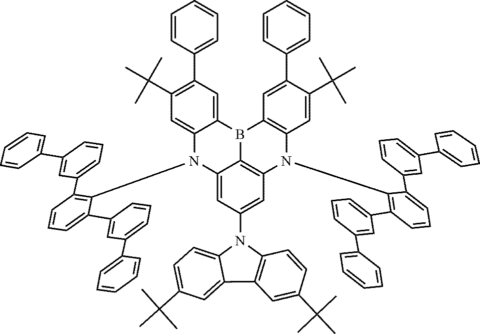 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(C(C)(C)C)c(-c4ccccc4)cc1B3c1cc(-c3ccccc3)c(C(C)(C)C)cc1N2c1c(-c2cccc(-c3ccccc3)c2)cccc1-c1cccc(-c2ccccc2)c1] 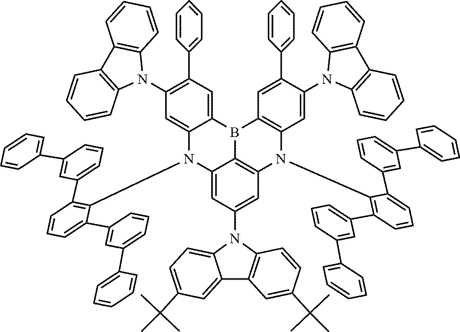 [SMILES: CC(C)(C)c1ccc2c(c1)c1cc(C(C)(C)C)ccc1n2-c1cc2c3c(c1)N(c1c(-c4cccc(-c5ccccc5)c4)cccc1-c1cccc(-c4ccccc4)c1)c1cc(-n4c5ccccc5c5ccccc54)c(-c4ccccc4)cc1B3c1cc(-c3ccccc3)c(-n3c4ccccc4c4ccccc43)cc1N2c1c(-c2cccc(-c3ccccc3)c2)cccc1-c1cccc(-c2ccccc2)c1] 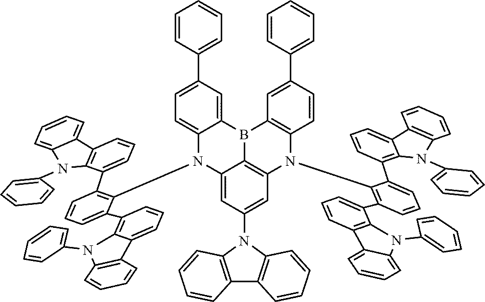 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)N3c2c(-c3cccc4c5ccccc5n(-c5ccccc5)c34)cccc2-c2cccc3c4ccccc4n(-c4ccccc4)c23)cc1] 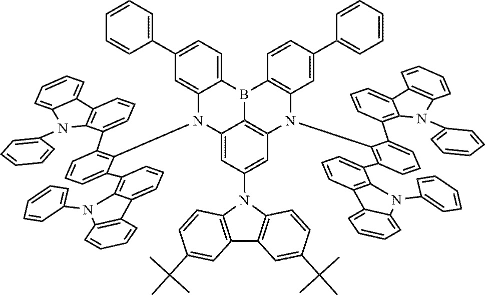 [SMILES: CC(C)(C)c1ccc2c(c1)c1cc(C(C)(C)C)ccc1n2-c1cc2c3c(c1)N(c1c(-c4cccc5c6ccccc6n(-c6ccccc6)c45)cccc1-c1cccc4c5ccccc5n(-c5ccccc5)c14)c1cc(-c4ccccc4)ccc1B3c1ccc(-c3ccccc3)cc1N2c1c(-c2cccc3c4ccccc4n(-c4ccccc4)c23)cccc1-c1cccc2c3ccccc3n(-c3ccccc3)c12] 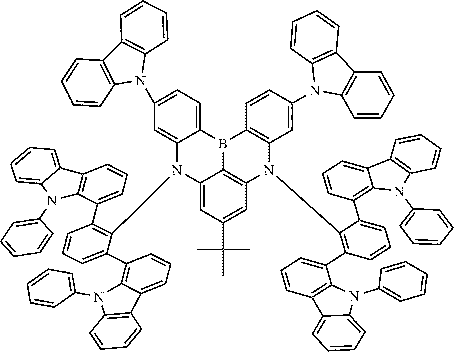 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1N2c1c(-c2cccc3c4ccccc4n(-c4ccccc4)c23)cccc1-c1cccc2c3ccccc3n(-c3ccccc3)c12] 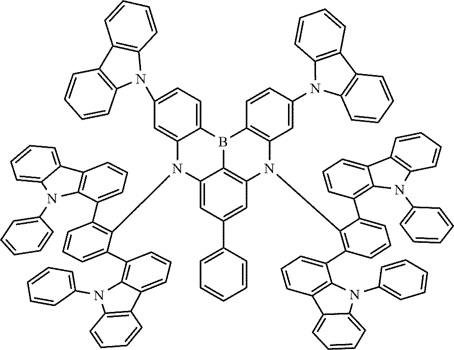 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2N3c2c(-c3cccc4c5ccccc5n(-c5ccccc5)c34)cccc2-c2cccc3c4ccccc4n(-c4ccccc4)c23)cc1] 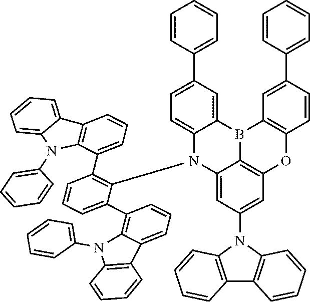 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)O3)cc1] 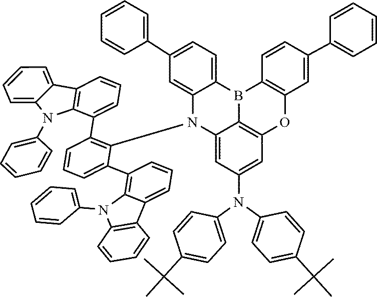 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2O3)cc1] 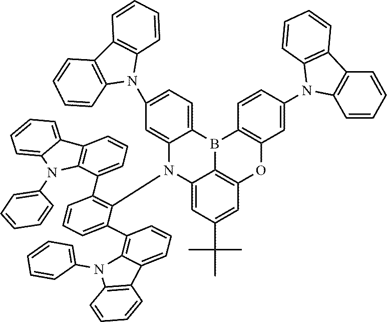 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1O2] 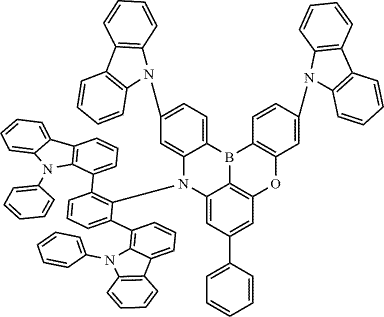 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2O3)cc1] 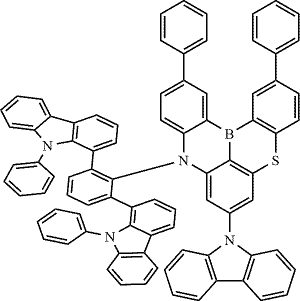 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)S3)cc1] 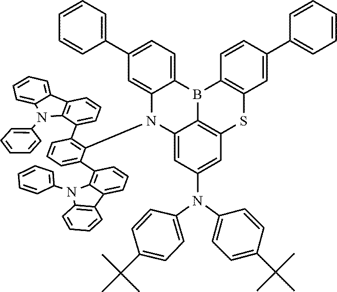 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2S3)cc1] 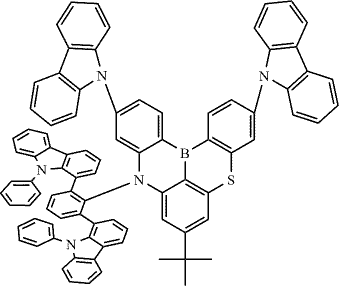 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1S2] 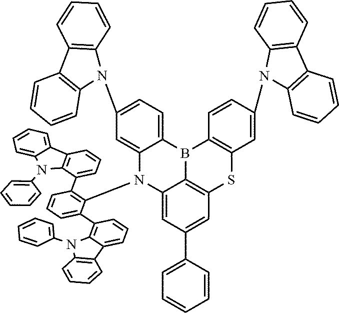 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2S3)cc1] 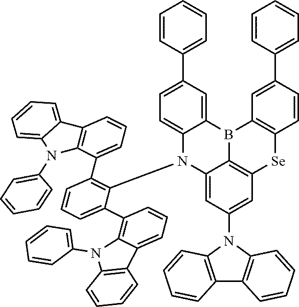 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(-n5c6ccccc6c6ccccc65)cc(c42)[Se]3)cc1] 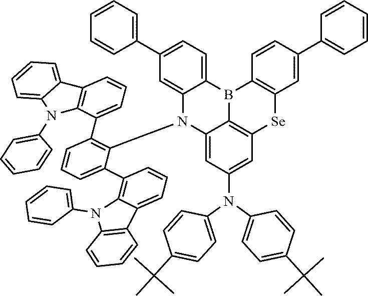 [SMILES: CC(C)(C)c1ccc(N(c2ccc(C(C)(C)C)cc2)c2cc3c4c(c2)N(c2c(-c5cccc6c7ccccc7n(-c7ccccc7)c56)cccc2-c2cccc5c6ccccc6n(-c6ccccc6)c25)c2cc(-c5ccccc5)ccc2B4c2ccc(-c4ccccc4)cc2[Se]3)cc1] 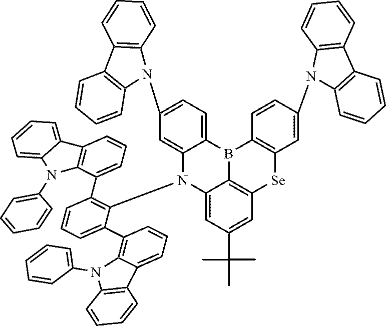 [SMILES: CC(C)(C)c1cc2c3c(c1)N(c1c(-c4cccc5c6ccccc6n(-c6ccccc6)c45)cccc1-c1cccc4c5ccccc5n(-c5ccccc5)c14)c1cc(-n4c5ccccc5c5ccccc54)ccc1B3c1ccc(-n3c4ccccc4c4ccccc43)cc1[Se]2] 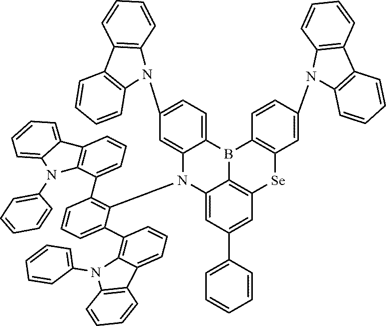 [SMILES: c1ccc(-c2cc3c4c(c2)N(c2c(-c5cccc6c7ccccc7n(-c7ccccc7)c56)cccc2-c2cccc5c6ccccc6n(-c6ccccc6)c25)c2cc(-n5c6ccccc6c6ccccc65)ccc2B4c2ccc(-n4c5ccccc5c5ccccc54)cc2[Se]3)cc1] 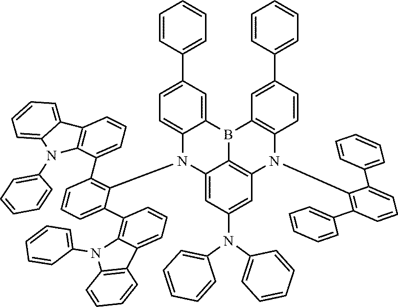 [SMILES: c1ccc(-c2ccc3c(c2)B2c4cc(-c5ccccc5)ccc4N(c4c(-c5cccc6c7ccccc7n(-c7ccccc7)c56)cccc4-c4cccc5c6ccccc6n(-c6ccccc6)c45)c4cc(N(c5ccccc5)c5ccccc5)cc(c42)N3c2c(-c3ccccc3)cccc2-c2ccccc2)cc1] 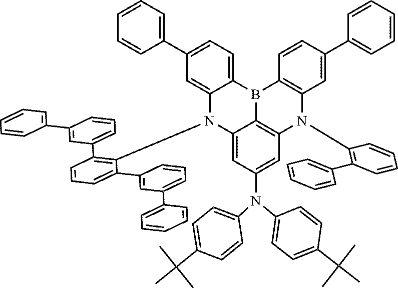 [SMILES: CC(C)(C)c1ccc(N(c2ccc(C(C)(C)C)cc2)c2cc3c4c(c2)N(c2c(-c5cccc(-c6ccccc6)c5)cccc2-c2cccc(-c5ccccc5)c2)c2cc(-c5ccccc5)ccc2B4c2ccc(-c4ccccc4)cc2N3c2ccccc2-c2ccccc2)cc1] 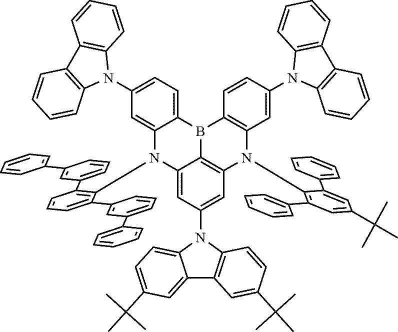 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc(-c6ccccc6)c5)cccc4-c4cccc(-c5ccccc5)c4)c4cc(-n5c6ccc(C(C)(C)C)cc6c6cc(C(C)(C)C)ccc65)cc2c43)c(-c2ccccc2)c1] 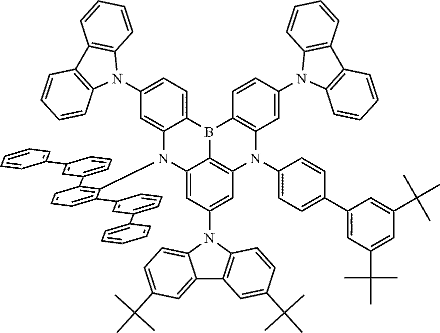 [SMILES: CC(C)(C)c1cc(-c2ccc(N3c4cc(-n5c6ccccc6c6ccccc65)ccc4B4c5ccc(-n6c7ccccc7c7ccccc76)cc5N(c5c(-c6cccc(-c7ccccc7)c6)cccc5-c5cccc(-c6ccccc6)c5)c5cc(-n6c7ccc(C(C)(C)C)cc7c7cc(C(C)(C)C)ccc76)cc3c54)cc2)cc(C(C)(C)C)c1] 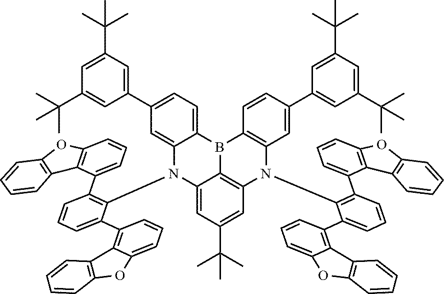 [SMILES: CC(C)(C)c1cc(-c2ccc3c(c2)N(c2c(-c4cccc5oc6ccccc6c45)cccc2-c2cccc4oc5ccccc5c24)c2cc(C(C)(C)C)cc4c2B3c2ccc(-c3cc(C(C)(C)C)cc(C(C)(C)C)c3)cc2N4c2c(-c3cccc4oc5ccccc5c34)cccc2-c2cccc3oc4ccccc4c23)cc(C(C)(C)C)c1] 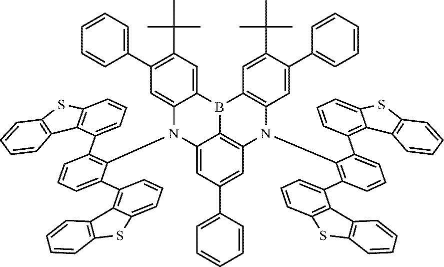 [SMILES: CC(C)(C)c1cc2c(cc1-c1ccccc1)N(c1c(-c3cccc4sc5ccccc5c34)cccc1-c1cccc3sc4ccccc4c13)c1cc(-c3ccccc3)cc3c1B2c1cc(C(C)(C)C)c(-c2ccccc2)cc1N3c1c(-c2cccc3sc4ccccc4c23)cccc1-c1cccc2sc3ccccc3c12] 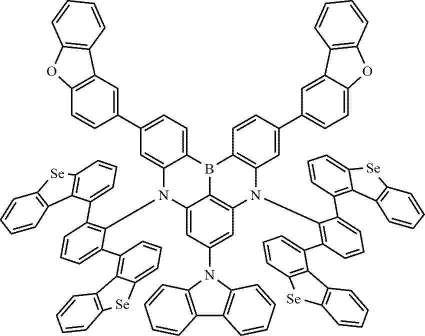 [SMILES: c1cc(-c2cccc3[se]c4ccccc4c23)c(N2c3cc(-c4ccc5oc6ccccc6c5c4)ccc3B3c4ccc(-c5ccc6oc7ccccc7c6c5)cc4N(c4c(-c5cccc6[se]c7ccccc7c56)cccc4-c4cccc5[se]c6ccccc6c45)c4cc(-n5c6ccccc6c6ccccc65)cc2c43)c(-c2cccc3[se]c4ccccc4c23)c1] 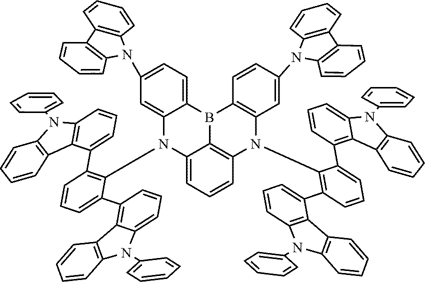 [SMILES: c1ccc(-n2c3ccccc3c3c(-c4cccc(-c5cccc6c5c5ccccc5n6-c5ccccc5)c4N4c5cc(-n6c7ccccc7c7ccccc76)ccc5B5c6ccc(-n7c8ccccc8c8ccccc87)cc6N(c6c(-c7cccc8c7c7ccccc7n8-c7ccccc7)cccc6-c6cccc7c6c6ccccc6n7-c6ccccc6)c6cccc4c65)cccc32)cc1] 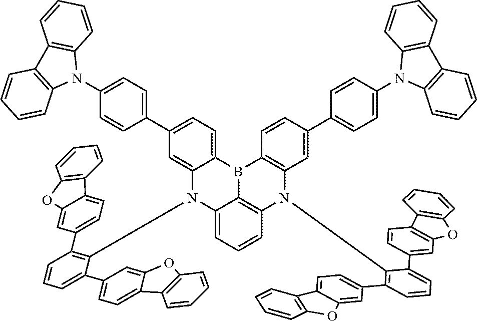 [SMILES: c1cc(-c2ccc3c(c2)oc2ccccc23)c(N2c3cc(-c4ccc(-n5c6ccccc6c6ccccc65)cc4)ccc3B3c4ccc(-c5ccc(-n6c7ccccc7c7ccccc76)cc5)cc4N(c4c(-c5ccc6c(c5)oc5ccccc56)cccc4-c4ccc5c(c4)oc4ccccc45)c4cccc2c43)c(-c2ccc3c(c2)oc2ccccc23)c1] 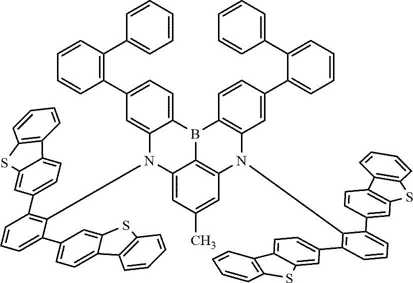 [SMILES: Cc1cc2c3c(c1)N(c1c(-c4ccc5c(c4)sc4ccccc45)cccc1-c1ccc4c(c1)sc1ccccc14)c1cc(-c4ccccc4-c4ccccc4)ccc1B3c1ccc(-c3ccccc3-c3ccccc3)cc1N2c1c(-c2ccc3c(c2)sc2ccccc23)cccc1-c1ccc2c(c1)sc1ccccc12] 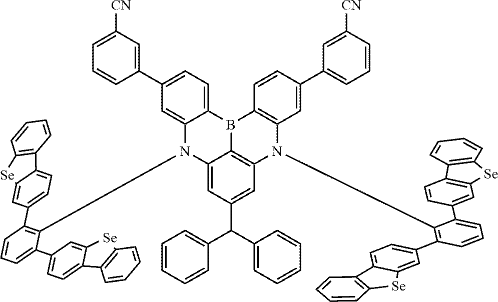 [SMILES: N#Cc1cccc(-c2ccc3c(c2)N(c2c(-c4ccc5c(c4)[se]c4ccccc45)cccc2-c2ccc4c(c2)[se]c2ccccc24)c2cc(C(c4ccccc4)c4ccccc4)cc4c2B3c2ccc(-c3cccc(C#N)c3)cc2N4c2c(-c3ccc4c(c3)[se]c3ccccc34)cccc2-c2ccc3c(c2)[se]c2ccccc23)c1] 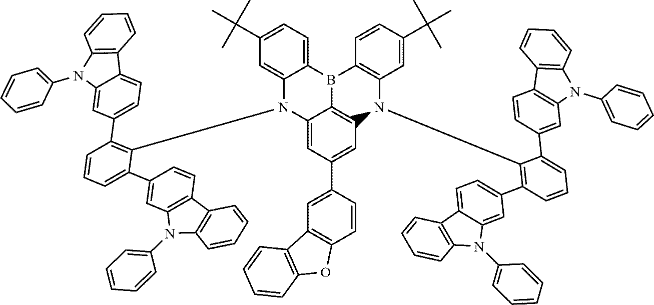 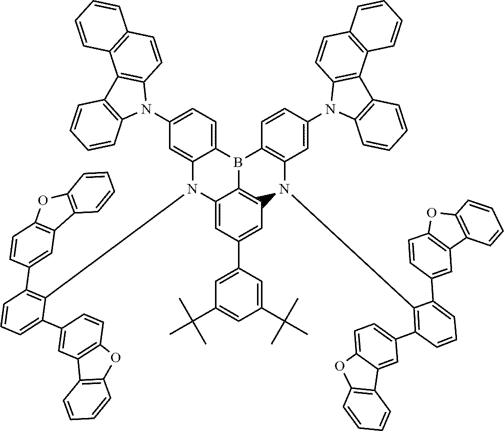 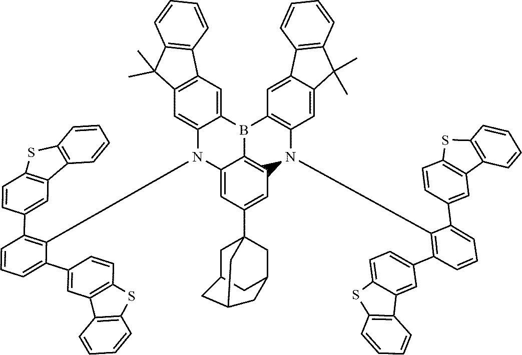 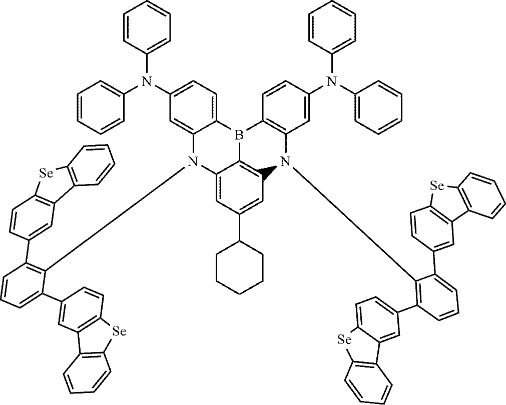 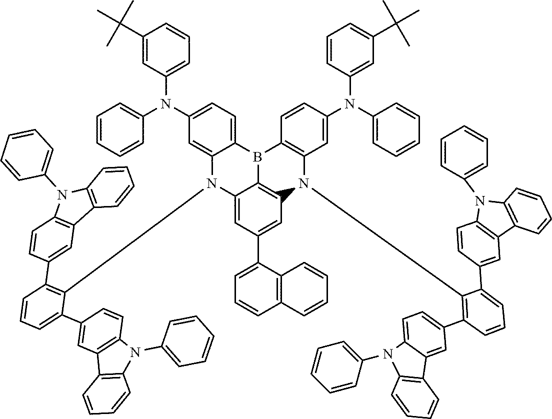 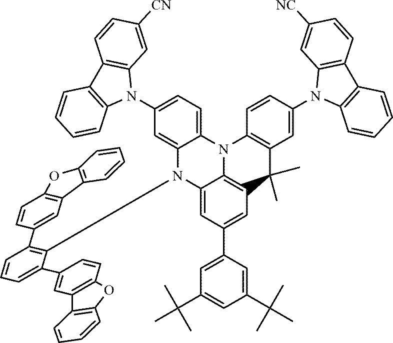 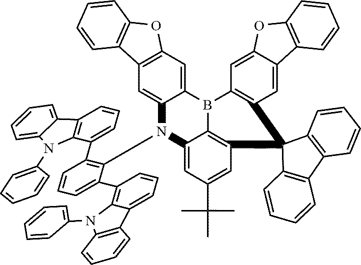 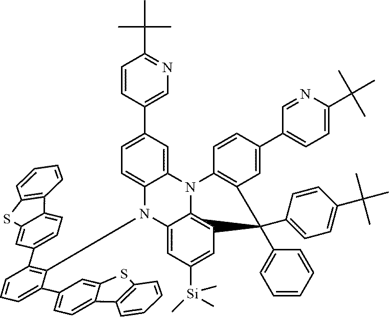 [SMILES: CC(C)(C)c1ccc([C@]2(c3ccccc3)c3cc(-c4ccc(C(C)(C)C)nc4)ccc3N3c4cc(-c5ccc(C(C)(C)C)nc5)ccc4N(c4c(-c5ccc6c(c5)sc5ccccc56)cccc4-c4ccc5c(c4)sc4ccccc45)c4cc([Si](C)(C)C)cc2c43)cc1] 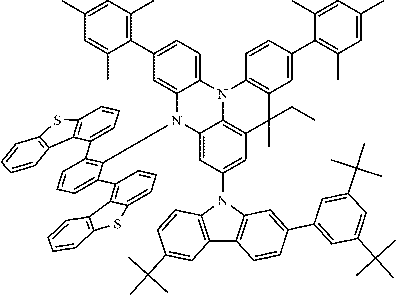 [SMILES: CCC1(C)c2cc(-c3c(C)cc(C)cc3C)ccc2N2c3ccc(-c4c(C)cc(C)cc4C)cc3N(c3c(-c4cccc5sc6ccccc6c45)cccc3-c3cccc4sc5ccccc5c34)c3cc(-n4c5ccc(C(C)(C)C)cc5c5ccc(-c6cc(C(C)(C)C)cc(C(C)(C)C)c6)cc54)cc1c32]
.
